(19) United States
(12) Patent Application Publication
(10) Pub. No.: US 2024/0298518 A1
(43) Pub. Date: Sep. 5, 2024

(54) ORGANIC ELECTROLUMINESCENT MATERIALS AND DEVICES

(71) Applicant: Universal Display Corporation, Ewing, NJ (US)

(72) Inventors: Rasha HAMZE, Philadelphia, PA (US); Hsiao-Fan CHEN, Lawrence Township, NJ (US); Chun LIN, Yardley, PA (US)

(73) Assignee: Universal Display Corporation, Ewing, NJ (US)

(21) Appl. No.: 18/422,703

(22) Filed: Jan. 25, 2024

Related U.S. Application Data
(60) Provisional application No. 63/484,904, filed on Feb. 14, 2023.

(51) Int. Cl. H10K 85/30; C07F 15/00; C09K 11/06; H10K 85/40; H10K 50/12

(52) U.S. Cl. CPC H10K 85/346; C07F 15/0086; C09K 11/06; H10K 85/40; C07B 2200/05; C09K 2211/1044; C09K 2211/1048; C09K 2211/1051; C09K 2211/1059; C09K 2211/1062; C09K 2211/1077; C09K 2211/185; H10K 50/12

(57) ABSTRACT

A compound of Formula I,

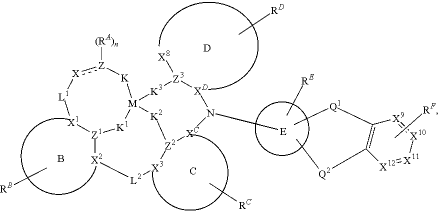

is provided. In Formula I, M is Pt or Pd; moieties B, C, and D are independently a monocyclic ring or a polycyclic fused ring system; moiety E is a monocyclic ring or a bicyclic fused ring system; n is 0, 1, or 2; K and K¹ to K³ are independently a direct bond or a linker; Z is C or a heteroatom; each of Z¹ to Z³ is independently C or N; X is CR, CRR′, NR, or PRR′; each of X^{C}, X^{D}, X¹ to X³ and X⁸ to X¹² is independently C or N; L¹ is a direct bond or a linker; L² is absent a bond, a direct bond, or a linker; each of Q¹ and Q² is a direct bond or a linker; each R substituent is independently hydrogen or a General Substituent. Formulations, OLEDs, and consumer products containing the same are also provided.

### CROSS-REFERENCE TO RELATED APPLICATIONS

This application claims priority under 35 U.S.C. § 119(e) to U.S. Provisional Application No. 63/484,904, filed on Feb. 14, 2023, the entire contents of which are incorporated herein by reference.

### FIELD

The present disclosure generally relates to organometallic compounds and formulations and their various uses including as emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound of Formula I,

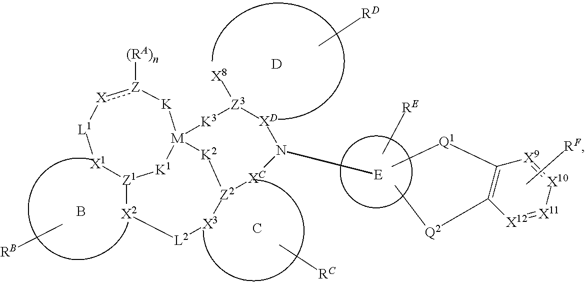

### In Formula I:

M is Pt or Pd;
each of moiety B, moiety C, and moiety D independently represents a monocyclic ring or a polycyclic fused ring system, wherein the monocyclic ring or each ring of the polycyclic fused ring system is independently a 5-membered to 10-membered carbocyclic or heterocyclic ring;
moiety E represents a monocyclic ring or a bicyclic fused ring system, wherein the monocyclic ring or each ring of the bicyclic fused ring system is independently a 5-membered to 10-membered carbocyclic or heterocyclic ring;
n is 0, 1, or 2, as needed to fill the valence of Z;
K is selected from the group consisting of a direct bond, O, S, Se, NR, NRR′, and PRR′;
each of K¹ to K³ is independently selected from the group consisting of a direct bond, O, S, N(R^{α}),
P(R^{α}), B(R^{α}), C(R^{α})(R^{β}), and Si(R^{α})(R^{β});
Z is selected from the group consisting of C, N, O, S, B, and P;
n is 0, 1, or 2, as needed to fill the valence of Z;
each of Z¹ to Z³ is independently C or N;
X is selected from the group consisting of CR, CRR′, NR, and PRR′;
each of X^{C}, X^{D}, X¹ to X³ and X⁸ to X¹² is independently C or N;
L¹ is selected from the group consisting of a direct bond, BR, BRR′, NR, PR, P(O)R, O, S, Se, C═O, C═S, C═Se, C═NR′, C═CR′R″, S═O, SO₂, CR, CRR′, SiRR′, GeRR′, alkylene, cycloalkyl, aryl, cycloalkylene, arylene, heteroarylene, and combinations thereof;
L² is selected from the group consisting of absent a bond, a direct bond, BR, BRR′, NR, PR, P(O)R, O, S, Se, C═O, C═S, C═Se, C═NR, C═CRR, S═O, SO₂, CR, CRR′, SiRR′, GeRR′, alkylene, cycloalkyl, aryl, cycloalkylene, arylene, heteroarylene, and combinations thereof, and if L² is absent, at least one R^{A} and at least one R^{D} are bonded or fused to form a ring including M;
each of Q¹ and Q² is independently selected from the group consisting of a direct bond, C, CRR′, SiRR′, O, S, Se, BR, and NR;
each [symbol] independently represents a single or double bond in a Lewis structure; each of R^{A}, R^{B}, R^{C}, R^{D}, R^{E}, and R^{F} independently represents mono to the maximum allowable substitution, or no substitution;
each R, R′, R″, R^{α}, R^{β}, R^{A}, R^{B}, R^{C}, R^{D}, and R^{F} is independently a hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents may be joined or fused to form a ring.

In another aspect, the present disclosure provides a formulation comprises a compound of Formula I as described herein.

In yet another aspect, the present disclosure provides an OLED having an organic layer comprising a compound of Formula I as described herein.

In yet another aspect, the present disclosure provides a consumer product comprising an OLED with an organic layer comprising a compound of Formula I as described herein.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows emission spectra of an inventive compound and a comparison compound in PMMA film at room temperature.

FIG. 4 shows overlaid spectra of thin PMMA films comprising the inventive and comparison compounds.

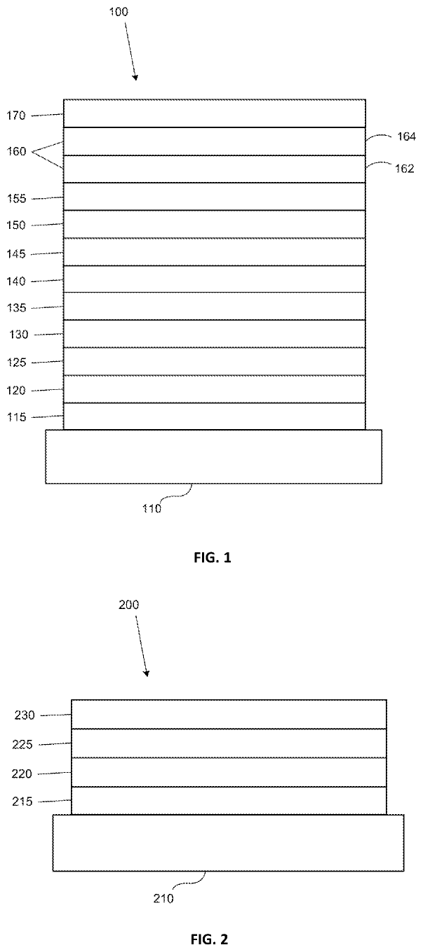

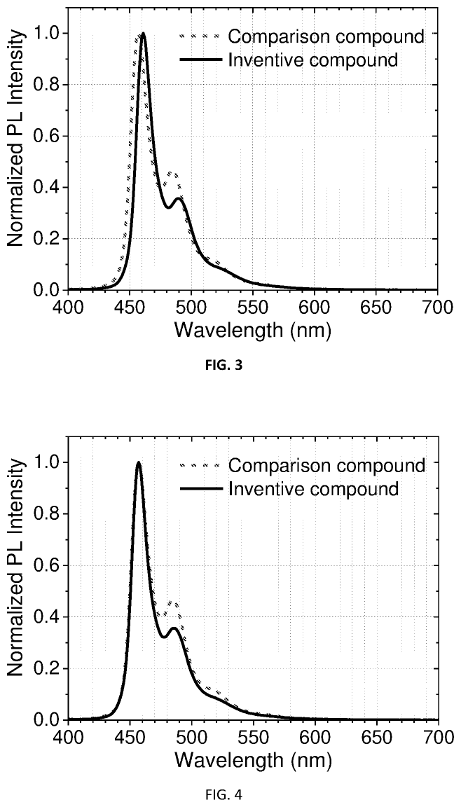

### DETAILED DESCRIPTION

### A. Terminology

Unless otherwise specified, the below terms used herein are defined as follows:

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “NIR”, “red”, “green”, “blue”, “yellow” layer, material, region, or device refers to a layer, a material, a region, or a device that emits light in the wavelength range of about 700-1500 nm, 580-700 nm, 500-600 nm, 400-500 nm, 540-600 nm, respectively, or a layer, a material, a region, or a device that has a highest peak in its emission spectrum in the respective wavelength region. In some arrangements, separate regions, layers, materials, or devices may provide separate “deep blue” and “light blue” emissions. As used herein, the “deep blue” emission component refers to an emission having a peak emission wavelength that is at least about 4 nm less than the peak emission wavelength of the “light blue” emission component. Typically, a “light blue” emission component has a peak emission wavelength in the range of about 465-500 nm, and a “deep blue” emission component has a peak emission wavelength in the range of about 400-470 nm, though these ranges may vary for some configurations.

In some arrangements, a color altering layer that converts, modifies, or shifts the color of the light emitted by another layer to an emission having a different wavelength is provided. Such a color altering layer can be formulated to shift wavelength of the light emitted by the other layer by a defined amount, as measured by the difference in the wavelength of the emitted light and the wavelength of the resulting light. In general, there are two classes of color altering layers: color filters that modify a spectrum by removing light of unwanted wavelengths, and color changing layers that convert photons of higher energy to lower energy. For example, a “red” color filter can be present in order to filter an input light to remove light having a wavelength outside the range of about 580-700 nm. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material, region, or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373I, 0.6245]; [0.6270, 0.3725]; |
| | Interior: [0.3700, 0.4087]; [0.2886, 0.4572] |

The terms “halo,” “halogen,” and “halide” are used interchangeably and refer to fluorine, chlorine, bromine, and iodine.

The term “acyl” refers to a substituted carbonyl group (—C(O)—Rₛ).

The term “ester” refers to a substituted oxycarbonyl (—O—C(O)—Rₛ or —C(O)—O—Rₛ) group.

The term “ether” refers to an —OR, group.

The terms “sulfanyl” or “thio-ether” are used interchangeably and refer to a —SR, group.

The term “selenyl” refers to a —SeRₛ group.

The term “sulfinyl” refers to a —S(O)—Rₛ group.

The term “sulfonyl” refers to a —SO₂—Rₛ group.

The term “phosphino” refers to a group containing at least one phosphorus atom bonded to the relevant structure. Common examples of phosphino groups include, but are not limited to, groups such as a —P(Rₛ)₂ group or a —PO(Rₛ)₂ group, wherein each Rₛ can be same or different.

The term “silyl” refers to a group containing at least one silicon atom bonded to the relevant structure. Common examples of silyl groups include, but are not limited to, groups such as a —Si(Rₛ)₃ group, wherein each Rₛ can be same or different.

The term “germyl” refers to a group containing at least one germanium atom bonded to the relevant structure. Common examples of germyl groups include, but are not limited to, groups such as a —Ge(Rₛ)₃ group, wherein each Rₛ can be same or different.

The term “boryl” refers to a group containing at least one boron atom bonded to the relevant structure. Common examples of boryl groups include, but are not limited to, groups such as a —B(Rₛ)₂ group or its Lewis adduct —B(Rₛ)₃ group, wherein Rₛ can be same or different.

In each of the above, Rₛ can be hydrogen or a substituent selected from the group consisting of the general substituents as defined in this application. Preferred Rₛ is selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. More preferably Rₛ is selected from the group consisting of alkyl, cycloalkyl, aryl, heteroaryl, and combination thereof.

The term “alkyl” refers to and includes both straight and branched chain alkyl groups having an alkyl carbon atom bonded to the relevant structure. Preferred alkyl groups are those containing from one to fifteen carbon atoms, preferably one to nine carbon atoms, and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group can be further substituted.

The term “cycloalkyl” refers to and includes monocyclic, polycyclic, and spiro alkyl groups having a ring alkyl carbon atom bonded to the relevant structure. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group can be further substituted.

The terms “heteroalkyl” or “heterocycloalkyl” refer to an alkyl or a cycloalkyl group, respectively, having at least one carbon atom replaced by a heteroatom. Optionally the at least one heteroatom is selected from O, S, N, P, B, Si, Ge and Se, preferably, O, S or N. Additionally, the heteroalkyl or heterocycloalkyl group can be further substituted.

The term “alkenyl” refers to and includes both straight and branched chain alkene groups. Alkenyl groups are essentially alkyl groups that include at least one carbon-carbon double bond in the alkyl chain with one carbon atom from the carbon-carbon double bond that is bonded to the relevant structure. Cycloalkenyl groups are essentially cycloalkyl groups that include at least one carbon-carbon double bond in the cycloalkyl ring. The term “heteroalkenyl” as used herein refers to an alkenyl group having at least one carbon atom replaced by a heteroatom. Optionally the at least one heteroatom is selected from O, S, N, P, B, Si, Ge, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group can be further substituted.

The term “alkynyl” refers to and includes both straight and branched chain alkyne groups. Alkynyl groups are essentially alkyl groups that include at least one carbon-carbon triple bond in the alkyl chain with one carbon atom from the carbon-carbon triple bond that is bonded to the relevant structure. Preferred alkynyl groups are those containing two to fifteen carbon atoms. Additionally, the alkynyl group can be further substituted.

The terms “aralkyl” or “arylalkyl” are used interchangeably and refer to an aryl-substituted alkyl group having an alkyl carbon atom bonded to the relevant structure. Additionally, the aralkyl group can be further substituted.

The term “heterocyclic group” refers to and includes aromatic and non-aromatic cyclic groups containing at least one heteroatom. Optionally the at least one heteroatom is selected from O, S, Se, N, P, B, Si, Ge, and Se, preferably, O, S, N, or B. Hetero-aromatic cyclic groups may be used interchangeably with heteroaryl. Preferred hetero-non-aromatic cyclic groups are those containing 3 to 10 ring atoms, preferably those containing 3 to 7 ring atoms, which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group can be further substituted or fused.

The term “aryl” refers to and includes both single-ring and polycyclic aromatic hydrocarbyl groups. The polycyclic rings may have two or more rings in which two carbons are common to two adjoining rings (the rings are “fused”). Preferred aryl groups are those containing six to thirty carbon atoms, preferably six to twenty-four carbon atoms, six to eighteen carbon atoms, and more preferably six to twelve carbon atoms. Especially preferred is an aryl group having six carbons, ten carbons, twelve carbons, fourteen carbons, or eighteen carbons. Suitable aryl groups include phenyl, biphenyl, triphenyl, triphenylene, tetraphenylene, naphthalene, anthracene, phenalene, phenanthrene, pyrene, chrysene, perylene, and azulene, preferably phenyl, biphenyl, triphenyl, triphenylene, and naphthalene. Additionally, the aryl group can be further substituted or fused, such as, without limitation, fluorene.

The term “heteroaryl” refers to and includes both single-ring aromatic groups and polycyclic aromatic ring systems that include at least one heteroatom. The heteroatoms include, but are not limited to O, S, Se, N, P, B, Si, Ge, and Se. In many instances, O, S, N, or B are the preferred heteroatoms. Hetero-single ring aromatic systems are preferably single rings with 5 or 6 ring atoms, and the ring can have from one to six heteroatoms. The hetero-polycyclic ring systems can have two or more aromatic rings in which two atoms are common to two adjoining rings (the rings are “fused”) wherein at least one of the rings is a heteroaryl. The hetero-polycyclic aromatic ring systems can have from one to six heteroatoms per ring of the polycyclic aromatic ring system. Preferred heteroaryl groups are those containing three to thirty carbon atoms, preferably three to twenty-four carbon atoms, three to eighteen carbon atoms, and more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, selenophenodipyridine, azaborine, borazine, 5I²,9I²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene; preferably dibenzothiophene, dibenzofuran, dibenzoselenophene, carbazole, indolocarbazole, imidazole, pyridine, triazine, benzimidazole, 5I²,9I²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene. Additionally, the heteroaryl group can be further substituted or fused.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, benzimidazole, 5I²,9I²-diaza-13b-boranaphtho[2,3,4-de]anthracene, 5λ²-benzo[d]benzo[4,5]imidazo[3,2-a]imidazole, 5,9-dioxa-13b-boranaphtho[3,2,1-de]anthracene, and the respective aza-analogs of each thereof are of particular interest.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, germyl, boryl, aryl, heteroaryl, nitrile, sulfanyl, and combinations thereof.

In some instances, the Even More Preferred General Substituents are selected from the group consisting of deuterium, fluorine, alkyl, cycloalkyl, silyl, aryl, heteroaryl, nitrile, and combinations thereof.

In yet other instances, the Most Preferred General Substituents are selected from the group consisting of deuterium, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for all available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

As used herein, any specifically listed substituent, such as, without limitation, methyl, phenyl, pyridyl, etc. includes undeuterated, partially deuterated, and fully deuterated versions thereof. Similarly, classes of substituents such as, without limitation, alkyl, aryl, cycloalkyl, heteroaryl, etc. also include undeuterated, partially deuterated, and fully deuterated versions thereof. Unless otherwise specified, atoms in chemical structures without valences fully filled by H or D should be considered to include undeuterated, partially deuterated, and fully deuterated versions thereof. For example, the chemical structure of [symbol] implies to include C₆H₆, C₆D₆, C₆H₃D₃, and any other partially deuterated variants thereof. Some common basic partially or fully deuterated group include, without limitation, CD₃, CD₂C(CH₃)₃, C(CD₃)₃, and C₆D₅.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of substituents in the molecule can be optionally joined or fused into a ring. The preferred ring is a five to nine-membered carbocyclic or heterocyclic ring, includes both instances where the portion of the ring formed by the pair of substituents is saturated and where the portion of the ring formed by the pair of substituents is unsaturated. In yet other instances, a pair of adjacent substituents can be optionally joined or fused into a ring. As used herein, “adjacent” means that the two substituents involved can be on the same ring next to each other, or on two neighboring rings having the two closest available substitutable positions, such as 2, 2′ positions in a biphenyl, or 1, 8 position in a naphthalene.

### B. The Compounds of the Present Disclosure

In one aspect, the present disclosure provides a compound of Formula I,

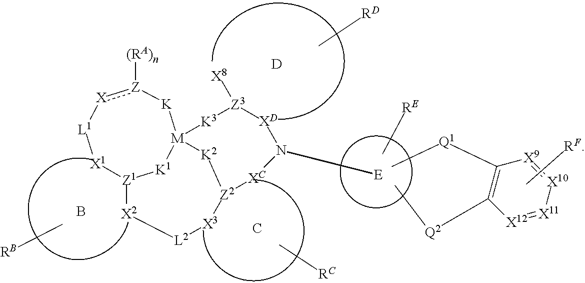

### In Formula I:

M is Pt or Pd;
each of moiety B, moiety C, and moiety D independently represents a monocyclic ring or a polycyclic fused ring system, wherein the monocyclic ring or each ring of the polycyclic fused ring system is independently a 5-membered to 10-membered carbocyclic or heterocyclic ring;
moiety E represents a monocyclic ring or a bicyclic fused ring system, wherein the monocyclic ring or each ring of the bicyclic fused ring system is independently a 5-membered to 10-membered carbocyclic or heterocyclic ring;
n is 0, 1, or 2, as needed to fill the valence of Z;
K is selected from the group consisting of a direct bond, O, S, Se, NR, NRR′, and PRR′;
each of K¹ to K³ is independently selected from the group consisting of a direct bond, O, S, N(R^{α}),
P(R^{α}), B(R^{α}), C(R^{α})(R^{β}), and Si(R^{α})(R^{β});
Z is selected from the group consisting of C, N, O, S, B, and P;
n is 0, 1, or 2, as needed to fill the valence of Z;
each of Z¹ to Z³ is independently C or N;
X is selected from the group consisting of CR, CRR′, NR, and PRR′;
each of X^{C}, X^{D}, X¹ to X³ and X⁸ to X¹² is independently C or N;
L¹ is selected from the group consisting of a direct bond, BR, BRR′, NR, PR, P(O)R, O, S, Se, C═O, C═S, C═Se, C═NR′, C═CR′R″, S═O, SO₂, CR, CRR′, SiRR′, GeRR′, alkylene, cycloalkyl, aryl, cycloalkylene, arylene, heteroarylene, and combinations thereof;
L² is selected from the group consisting of absent a bond, a direct bond, BR, BRR′, NR, PR, P(O)R, O, S, Se, C═O, C═S, C═Se, C═NR, C═CRR, S═O, SO₂, CR, CRR′, SiRR′, GeRR′, alkylene, cycloalkyl, aryl, cycloalkylene, arylene, heteroarylene, and combinations thereof, and if L² is absent, at least one R^{A} and at least one R^{D} are bonded or fused to form a ring including M;
each of Q¹ and Q² is independently selected from the group consisting of a direct bond, C, CRR′, SiRR′, O, S, Se, BR, and N;
each [symbol] independently represents a single or double bond in a Lewis structure;
each of R^{A}, R^{B}, R^{C}, R^{D}, R^{E}, and R^{F} independently represents mono to the maximum allowable substitution, or no substitution;
each R, R′, R″, R^{α}, R^{β}, R^{A}, R^{B}, R^{c}, R^{D}, and R^{F} is independently a hydrogen or a substituent selected from the group consisting of the General Substituents defined herein; and any two substituents may be joined or fused to form a ring.

In some embodiments, each R, R′, R″, R^{α}, R^{β}, R^{A}, R^{B}, R^{c}, R^{D}, and R^{F} is independently a hydrogen or a substituent selected from the group consisting of the Preferred General Substituents defined herein

In some embodiments, moiety C and moiety E and/or moiety D and moiety E are linked by a linker selected from a direct bond, BR, BRR′, NR, PR, P(O)R, O, S, Se, C═O, C═S, C═Se, C═NR′, C═CR′R″, S═O, SO₂, CR, CRR′, SiRR′, GeRR′, alkylene, cycloalkyl, aryl, cycloalkylene, arylene, heteroarylene, and combinations thereof. In some embodiments, moiety D and moiety E are linked by a direct bond. In some embodiments, moiety C and moiety E are joined by a direct bond. In some embodiments when moiety C and moiety E are linked by a direct bond, then moiety D and moiety E are not linked by a direct bond.

In some embodiments, each of moiety B, moiety C, and moiety D independently represents a monocyclic ring or a polycyclic fused ring system, wherein the monocyclic ring or each ring of the polycyclic fused ring system is independently a 5-membered or 6-membered carbocyclic or heterocyclic ring. In some of these embodiments, the 5-membered or 6-membered carbocyclic or heterocyclic ring is an aromatic ring.

In some embodiments, moiety E represents a monocyclic ring or a bicyclic fused ring system, wherein the monocyclic ring or each ring of the bicyclic fused ring system is independently a 5-membered or 6-membered carbocyclic or heterocyclic ring. In some of these embodiments, the 5-membered or 6-membered carbocyclic or heterocyclic ring is an aromatic ring.

In some such embodiments, each of moiety C, moiety D, and moiety E is independently a monocyclic aryl or heteroaryl group. In some such embodiments, each of moiety C, moiety D, and moiety E can be independently be selected from benzene, pyridine, pyrimidine, pyridazine, pyrazine, triazine, imidazole, pyrazole, pyrrole, oxazole, furan, thiophene, or thiazole. In some such embodiments, each of moiety C, moiety D, and moiety E can independently be benzene or pyridine. In some such embodiments, each of moiety C, moiety D, and moiety E can be benzene.

In some embodiments, one R^{A} and one R^{D} are joined. In some embodiments, one R^{A} and one R^{D} are joined, and L² is absent. In some embodiments, one R^{A} and one R^{D} are joined, and L² is selected from the group consisting of a direct bond, BR, BRR′, NR, PR, P(O)R, O, S, Se, C═O, C═S, C═Se, C═NR, C═CRR, S═O, SO₂, CR, CRR′, SiRR′, GeRR′, alkylene, cycloalkyl, aryl, cycloalkylene, arylene, heteroarylene, and combinations thereof. In some embodiments, one R^{A} and one R^{D} are joined, and L² is selected from O, S, Se, C═O, C═S, C═Se, C═NR, C═CRR, S═O, SO₂, CR, CRR′, SiRR′, or GeRR′.

Moieties B, C, and D can be saturated, partially unsaturated, or aromatic. As a result, the bonds between X¹—Z¹, Z¹—X², X³—Z², Z²—X^{C}, X^{D}—Z³, Z³—X⁸ can be single bonds or double bonds as is consistent with such moieties. Thus, it should of course be understood the bonds between X¹—Z¹ and Z¹—X² cannot be both double bonds at the same time. The same is true for the bonds between X³—Z² and Z²—X^{C}, and the bonds between X^{D}—Z³ and Z³—X⁸.

In some embodiments, the compound has a structure of Formula IA

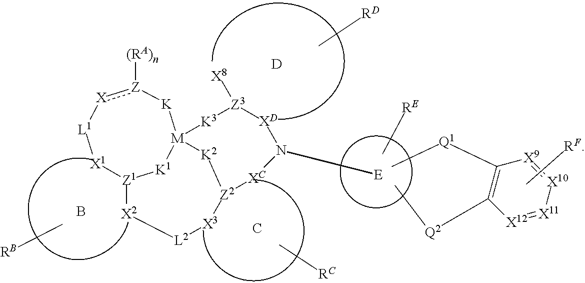

In some embodiments, the compound has a structure of Formula IB

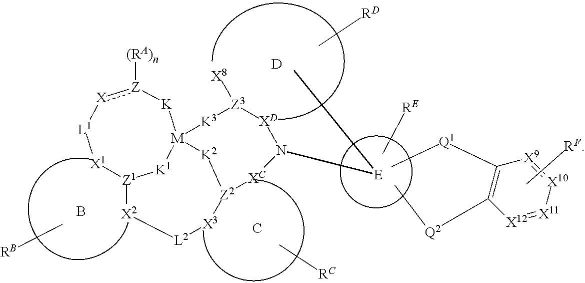

In some embodiments, the compound has a structure of Formula IC

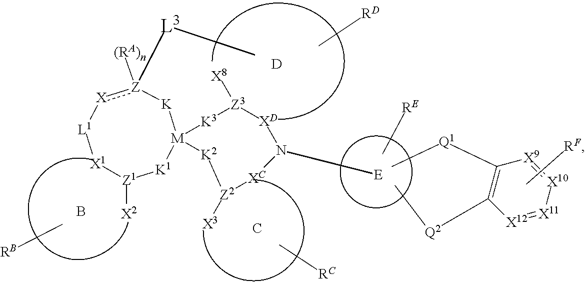

wherein L³ is selected from the group consisting of BR, BRR′, NR, PR, P(O)R, O, S, Se, C═O, C═S, C═Se, C═NR, C═CRR, S═O, SO₂, CR, CRR′, SiRR′, GeRR′, alkylene, cycloalkyl, aryl, cycloalkylene, arylene, heteroarylene, and combinations thereof,

In some embodiments, the compound has a structure of Formula ID

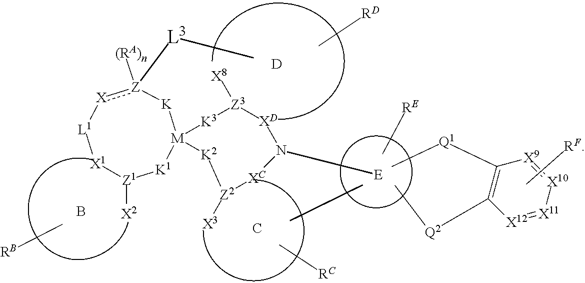

In some embodiments, the compound has a structure of Formula IE

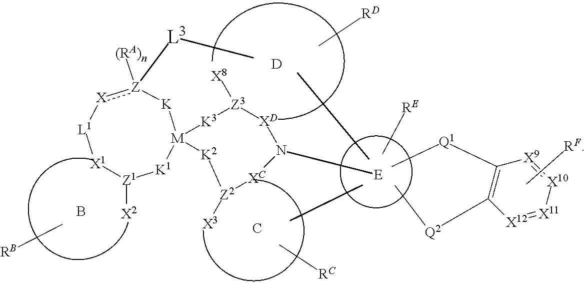

In some embodiments, the compound has a structure of Formula II,

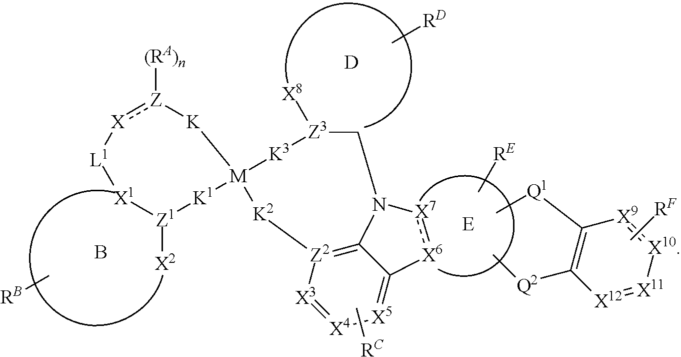

### In Formula II:

each of K¹ to K³ is independently selected from the group consisting of a direct bond, O, and S;
each of X¹ to X¹² is independently C or N;
each of L¹ and L² is independently selected from the group consisting of a direct bond, BR, BRR′, NR, PR, P(O)R, O, S, Se, C═O, C═S, C═Se, C═NR′, C═CR′R″, S═O, SO₂, CR, CRR′, SiRR′, GeRR′, alkylene, cycloalkyl, aryl, cycloalkylene, arylene, heteroarylene, and combinations thereof;
at least one of the following conditions is true:
   (1) the compound comprises at least one deuterium atom;
   (2) at least one of K, K¹, K² and K³ is not a direct bond;
   (3) X is CR, NR, or PRR′, and R does not join with an R^{A} substituent to form a ring;
   (4) L¹ is a direct bond, X is NR, Z is C, and R and R^{A} join to comprise a structure of Formula III,

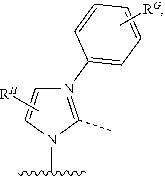

wherein the dashed line represents a direct bond to M, two R^{F} substituents do not join to form a ring, and at least one R^{G} substituent is not hydrogen; and
(5) L¹ is a direct bond, X is NR, Z is C, and R and R^{A} join to comprise a structure of Formula IV,

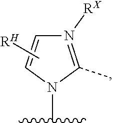

wherein R^{X} has a molecular weight of at least 153 grams/mol or R^{X} and R^{H} are joined to form a ring;
wherein each of R^{G} and R^{H} independently represents mono to the maximum allowable substitution, or no substitution;
each R^{G}, R^{H}, and R^{X} is independently a hydrogen or a substituent selected from the group consisting of the General Substituents defined herein; and
any two substituents may be joined or fused to form a ring subject to the above conditions.

In some embodiments, the compound is not

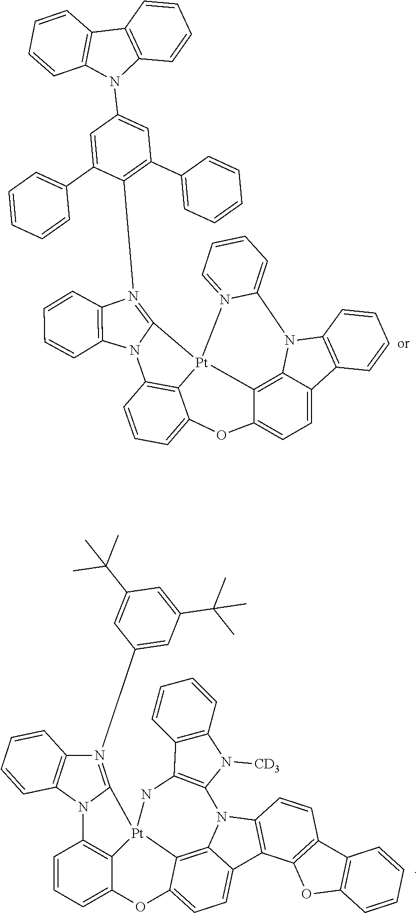

In some embodiments, each R, R′, R^{A}, R^{B}, R^{c}, R^{D}, R^{F}, R^{G}, R^{H}, and R^{X} is independently a hydrogen or a substituent selected from the group consisting of the Preferred General Substituents. In some embodiments, each R, R′, R^{A}, R^{B}, R^{c}, R^{D}, R^{F}, R^{G}, R^{H}, and R^{X} is independently a hydrogen or a substituent selected from the group consisting of the More Preferred General Substituents. In some embodiments, each R, R′, R^{A}, R^{B}, R^{c}, R^{D}, R^{F}, R^{G}, R^{H}, and R^{X} is independently a hydrogen or a substituent selected from the group consisting of the Most Preferred General Substituents.

In some embodiments, the compound emits at room temperature with an emission lineshape having a full-width at half max (FWHM) less than 25 nm. In some embodiments, the compound emits at room temperature with an emission lineshape having a full-width at half max (FWHM) less than 24 nm, or 23 nm, or 22 nm, or 21 nm, or 20 nm, or 19 nm, or 18 nm, or 17 nm, or 16 nm, or 15 nm.

In some embodiments, the compound emits at 77K with an emission lineshape having a second vibronic peak (b-peak) with at most 35% intensity of the main vibronic peak. In some embodiments, the compound emits at 77K with an emission lineshape having a second vibronic peak (b-peak) with at most 30%, or at most 25%, or at most 20% intensity of the main vibronic peak.

In some embodiments, the compound emits at 77K with an excited state decay time >3.7 μs.

In some embodiments, X⁶ is N, X⁷ is C, and moiety E is a fused heterocyclic system constituted of a 5-membered ring and a 6-membered ring. In some such embodiments, moiety E is 5λ²-benzo[d]benzo[4,5]imidazo[3,2-a]imidazole.

In some embodiments, L¹ is a direct bond, X is NR, Z is C, and R and R^{A} join to comprise a structure of Formula II or Formula III, and R^{A} comprises D.

In some embodiments, L¹ is a direct bond, X is NR, Z is C, and R and one R^{A} join to comprise a structure of Formula III, and R^{X} comprises an N-bound ortho-biphenyl moiety.

In some embodiments, M is Pt. In some embodiments, M is Pd.

In some embodiments, moiety B is aromatic.

In some embodiments, moiety B is a monocyclic ring. In some embodiments, moiety B is selected from the group consisting of benzene, pyridine, pyrimidine, pyridazine, pyrazine, triazine, imidazole, imidazole derived carbene, pyrazole, pyrrole, oxazole, furan, thiophene, and thiazole. In some embodiments, moiety B is benzene.

In some embodiments, moiety B is a polycyclic fused-ring system. In some embodiments, moiety B is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

In some embodiments, the aza variant includes one N on a benzo ring. In some embodiments, the aza variant includes one N on a benzo ring and the N is bonded to the metal M

In some embodiments, moiety B is selected from the group consisting of pyridine, imidazole, imidazole derived carbene, aza-phenanthrene, and aza-anthracene. In some embodiments, moiety B is pyridine. In some embodiments, moiety B is aza-phenanthrene or aza-anthracene, there is only one N and it is in an end ring and is bonded to metal M.

In some embodiments, moiety D is aromatic.

In some embodiments, moiety D is a monocyclic ring. In some embodiments, moiety D is selected from the group consisting of benzene, pyridine, pyrimidine, pyridazine, pyrazine, triazine, imidazole, imidazole derived carbene, pyrazole, pyrrole, oxazole, furan, thiophene, and thiazole.

In some embodiments, moiety D is pyridine or imidazole. In some such embodiments, Z³ is N. 23. The compound of any one of claims 1-18, wherein moiety D is a polycyclic fused-ring system.

In some embodiments, moiety D is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene. In some embodiments, the aza variant includes one N on a benzo ring. In some embodiments, the aza variant includes one N on a benzo ring and the N is bonded to the metal M.

In some embodiments, moiety D is selected from the group consisting of pyridine, imidazole, aza-phenanthrene, and aza-anthracene. In some embodiments, moiety D is pyridine. In some embodiments, moiety D is aza-phenanthrene or aza-anthracene, there is only one N, and it is in an end ring and is bonded to metal M.

In some embodiments, two R^{c} are joined or fused to form a ring. In some embodiments, two R^{c} are fused to form a polycyclic fused ring structure.

As used herein, “moiety C” refers to the ring containing Z² and any rings formed by R^{c} that are fused thereto.

In some embodiments, each of moiety A, moiety B, and moiety C can independently be a polycyclic fused ring structure. In some embodiments, each of moiety A, moiety B, and moiety C can independently be a polycyclic fused ring structure comprising at least three fused rings. In some embodiments, the polycyclic fused ring structure has two 6-membered rings and one 5-membered ring. In some such embodiments, the 5-membered ring is fused to the ring coordinated to metal M and the second 6-membered ring is fused to the 5-membered ring. In some embodiments, each of moiety A, moiety B, and moiety C can independently be selected from the group consisting of dibenzofuran, dibenzothiophene, dibenzoselenophene, and aza-variants thereof. In some such embodiments, each of moiety A, moiety B, and moiety C can independently be further substituted at the ortho- or meta-position of the O, S, or Se atom by a substituent selected from the group consisting of deuterium, fluorine, nitrile, alkyl, cycloalkyl, aryl, heteroaryl, and combinations thereof. In some such embodiments, the aza-variants contain exactly one N atom at the 6-position (ortho to the O, S, or Se) with a substituent at the 7-position (meta to the O, S, or Se).

In some embodiments, each of moiety A, moiety B, and moiety C can independently be a polycyclic fused ring structure comprising at least four fused rings. In some embodiments, the polycyclic fused ring structure comprises three 6-membered rings and one 5-membered ring. In some such embodiments, the 5-membered ring is fused to the ring coordinated to metal M, the second 6-membered ring is fused to the 5-membered ring, and the third 6-membered ring is fused to the second 6-membered ring. In some such embodiments, the third 6-membered ring is further substituted by a substituent selected from the group consisting of deuterium, fluorine, nitrile, alkyl, cycloalkyl, aryl, heteroaryl, and combinations thereof.

In some embodiments, each of moiety A, moiety B, and moiety C can independently be a polycyclic fused ring structure comprising at least five fused rings. In some embodiments, the polycyclic fused ring structure comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring. In some embodiments with one 5-membered ring, the 5-membered ring is fused to the ring coordinated to metal M, the second 6-membered ring is fused to the 5-membered ring, the third 6-membered ring is fused to the second 6-membered ring, and the fourth 6-membered ring is fused to the third-6-membered ring.

In some embodiments, each of moiety A, moiety B, and moiety C can independently be an aza version of the polycyclic fused rings described above. In some such embodiments, each of moiety A, moiety B, and moiety C can independently contain exactly one aza N atom. In some such embodiments, each of moiety A, moiety B, and moiety C can contain exactly two aza N atoms, which can be in one ring, or in two different rings. In some such embodiments, the ring having aza N atom is separated by at least two other rings from the metal M atom. In some such embodiments, the ring having aza N atom is separated by at least three other rings from the metal M atom. In some such embodiments, each of the ortho position of the aza N atom is substituted.

In some embodiments, moiety E is a monocyclic ring. In some embodiments, moiety E is selected from the group consisting of benzene, pyridine, pyrimidine, pyridazine, pyrazine, triazine, imidazole, pyrazole, pyrrole, oxazole, furan, thiophene, and thiazole. In some embodiments, moiety E is benzene.

In some embodiments, moiety E is a bicyclic fused-ring system. In some embodiments, moiety E is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, and aza-benzimidazole.

In some embodiments, K is a direct bond. In some embodiments, K is O, S, or Se. IN some embodiments, K is NR. In some embodiments, K is NRR′ or PRR′. In some embodiments, each of K¹ to K³ is a direct bond.

In some embodiments, at least one of K¹ to K³ is O or S. In some embodiments, exactly one of K¹ to K³ is O or S.

In some embodiments, Z is C. In some such embodiments, n is 1, X is NR, R^{A} and R are joined to form an imidazole ring, and Z is a carbene carbon.

In some embodiments, Z is S or O. In some embodiments, Z is N. In some embodiments, Z is P. In some such embodiments, n is 2.

In some embodiments, Z¹ is C. In some embodiments, Z¹ is N. In some embodiments, Z² is C. In some embodiments, Z² is N. In some embodiments, Z³ is N. In some embodiments, Z³ is C. In some embodiments, Z¹ is C, Z² is C, and Z³ is N.

In some embodiments, X is CR. In some embodiments, X is CRR′ or PRR′. In some embodiments, X is NR. In some embodiments, where X comprises R, R is joined with R^{A} to form a ring.

In some embodiments, at least one of X¹ to X¹² is N. In some embodiments, each of X¹ to X² is C.

In some embodiments, each of X³ to X⁵ is C. In some embodiments, X³ is C. In some embodiments, X³ is N.

In some embodiments, each of X⁶ to X⁷ is C. In some embodiments, one of X⁶ to X⁷ is N.

In some embodiments, X⁸ is C. In some embodiments, X⁸ is N.

In some embodiments, each of X⁹ to X¹² is C.

In some embodiments, each of X¹ to X¹² is C.

In some embodiments, L¹ is a direct bond. In some embodiments, L¹ is selected from the group consisting of BR, NR, and PR. In some embodiments, L¹ is selected from the group consisting of O, S, and Se. In some embodiments, L¹ is selected from the group consisting of BRR′, CRR′, SiRR′, and GeRR′. In some embodiments, L¹ is selected from the group consisting of P(O)R, C═O, C═S, C═Se, C═NR′, C═CR′R″, S═O, and SO₂. In some embodiments, L¹ is selected from the group consisting of alkylene, cycloalkyl, aryl, cycloalkylene, arylene, and heteroarylene. In some embodiments, L¹ is CR.

In some embodiments, L² is a direct bond. In some embodiments, L² is selected from the group consisting of BR, NR, and PR. In some embodiments, L² is 0. In some embodiments, L² is S. In some embodiments, L² is Se. In some embodiments, L² is selected from the group consisting of BRR′, CRR′, SiRR′, and GeRR′. In some embodiments, L² is selected from the group consisting of P(O)R, C═O, C═S, C═Se, C═NR′, C═CR′R″, S═O, and SO₂. In some embodiments, L² is selected from the group consisting of alkylene, cycloalkyl, aryl, cycloalkylene, arylene, and heteroarylene. In some embodiments, L² is CR.

In some embodiments, one of L¹ and L² is a direct bond.

In some embodiments, L¹ is a direct bond, and L² is O.

In some embodiments, one of Q¹ and Q² is a direct bond. In some embodiments, Q¹ is 0. In some embodiments, Q¹ is S. In some embodiments, Q¹ is Se. In some embodiments, Q¹ is NR. In some embodiments, Q¹ is CRR′. In some embodiments, Q¹ is SiRR′. In some embodiments, Q¹ is C. In some embodiments, Q¹ is a direct bond.

In some embodiments, Q² is O. In some embodiments, Q² is S. In some embodiments, Q² is Se. In some embodiments, Q² is NR. In some embodiments, Q² is CRR′. In some embodiments, Q² is SiRR′. In some embodiments, Q² is C. In some embodiments, Q² is a direct bond.

In some embodiments, the [symbol] between X and Z is a single bond in a Lewis structure.

In some embodiments, the [symbol] between X and Z is a double bond in a Lewis structure.

In some embodiments, the [symbol] between X⁶ and X⁷ is a single bond in a Lewis structure.

In some embodiments, the [symbol] between X⁶ and X⁷ is a double bond in a Lewis structure.

In some embodiments, the compound comprises at least one deuterium atom. In some embodiments, the compound comprises at least two deuterium atoms. In some embodiments, the compound comprises at least three deuterium atoms. In some embodiments, the compound comprises at least four deuterium atoms. In some embodiments, the compound comprises at least five deuterium atoms.

In some embodiments, at least one of K, K¹, K² and K³ is not a direct bond. In some embodiments, exactly one of K, K¹, K² and K³ is not a direct bond.

In some embodiments, X is CR, NR, or PRR′, and R^{A} does not join with R or R¹ to form a ring.

In some embodiments, X is NR, Z is C, and Rand R^{A} join to comprise a structure of Formula III,

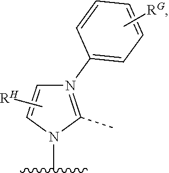

wherein the dashed line represents a direct bond to M.

In some embodiments of Formula III, L¹ is a direct bond; two R^{F} substituents do not join to form a ring; and at least one R^{G} substituent is not hydrogen.

In some embodiments of Formula III, one R^{G} and on R^{H} are joined to form a ring.

In some embodiments of Formula III, at least one R^{G} ortho to the bond with the imidazole is not substituted by hydrogen or deuterium. In some embodiments of Formula III, each R^{G} ortho to the bond with the imidazole is not substituted by hydrogen or deuterium.

In some embodiments of Formula III, at least one R^{G} ortho to the bond with the imidazole is substituted by a moiety selected from the group consisting of alkyl, cycloalkyl, aryl, and heteroaryl. In some embodiments of Formula III, at least one R^{G} ortho to the bond with the imidazole is substituted by substituted or unsubstituted aryl. In some embodiments of Formula III, at least one R^{G} ortho to the bond with the imidazole is substituted by substituted or unsubstituted benzene.

In some embodiments of Formula III, each R^{G} ortho to the bond with the imidazole is independently substituted by a moiety selected from the group consisting of alkyl, cycloalkyl, aryl, and heteroaryl. In some embodiments of Formula III, each R^{G} ortho to the bond with the imidazole is independently substituted by substituted or unsubstituted aryl. In some embodiments of Formula III, each R^{G} ortho to the bond with the imidazole is independently substituted by substituted or unsubstituted benzene.

In some embodiments of Formula III, the R^{G} para to the imidazole ring is substituted by a moiety selected from the group consisting of alkyl, cycloalkyl, aryl, and heteroaryl. In some embodiments of Formula III, the R^{G} para to the imidazole ring is substituted by substituted or unsubstituted phenyl or by substituted or unsubstituted biphenyl.

In some embodiments of Formula III, at least one R^{G} meta to the bond with the imidazole is substituted by a moiety selected from the group consisting of alkyl, cycloalkyl, aryl, and heteroaryl. In some embodiments of Formula III, at least one R^{G} meta to the bond with the imidazole is substituted by substituted or unsubstituted aryl. In some embodiments of Formula III, at least one R^{G} meta to the bond with the imidazole is substituted by substituted or unsubstituted benzene.

In some embodiments of Formula III, each R^{G} meta to the bond with the imidazole is independently substituted by a moiety selected from the group consisting of alkyl, cycloalkyl, aryl, and heteroaryl. In some embodiments of Formula III, each R^{G} meta to the bond with the imidazole is substituted independently by substituted or unsubstituted aryl. In some embodiments of Formula III, each R^{G} meta to the bond with the imidazole is independently substituted by substituted or unsubstituted benzene.

In some embodiments of Formula III, at least one R^{H} is not hydrogen.

In some embodiments of Formula III, two R^{H} are joined to form a ring. In some embodiments of Formula III, two R^{H} are joined to form a benzene ring.

In some embodiments, the compound has a structure of Formula V:

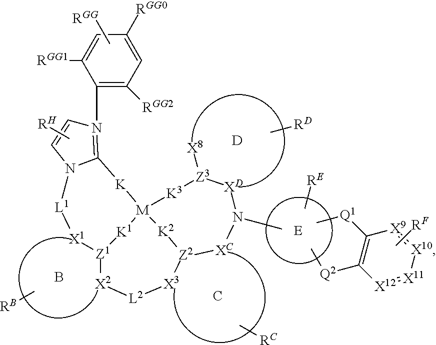

wherein R^{GG} each independently represents zero, mono, or up to maximum allowed substitutions; each of R^{GG}, R^{GG0}, R^{GG1} and R^{GG2} is independently hydrogen or a substituent selected from the group consisting of the General Substituents defined herein.

In some embodiments, R^{GG0} is selected from the group consisting of halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof. In some embodiments, R^{GG1} is the same as R^{GG2}. In some embodiments, R^{GG1} is different from R^{GG2}. In some embodiments, at least one of R^{GG1} and R^{GG2} comprises a chemical group containing at least three 6-membered aromatic rings that are not fused next to each other. In some embodiments, at least one of R^{GG1} and R^{GG2} comprises a chemical group containing at least four 6-membered aromatic rings that are not fused next to each other. In some embodiments, at least one of R^{GG1} and R^{GG2} comprises a chemical group containing at least five 6-membered aromatic rings that are not fused next to each other. In some embodiments, at least one of R^{GG1} and R^{GG2} comprises a chemical group containing at least six 6-membered aromatic rings that are not fused next to each other. In some embodiments, both R^{GG1} and R^{GG2} comprise a chemical group containing at least three to six 6-membered aromatic rings that are not fused next to each other. In some embodiments, at least one of R^{GG1} and R^{GG2} Comprises a group R^{W} having a structure selected from the group consisting of:
Formula IIIA, -Q^{A}(R^{1a})(R^{2a})ₐ(R^{3a})_{b}, Formula IIIB,

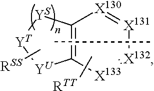

### Formula IIIC,

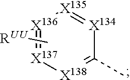

wherein
each of R^{SS}, R^{TT}, and R^{UU} independently represents mono to the maximum allowable number of substitutions, or no substitution;
   each of X¹³⁰ to X¹³⁸ is independently C or N;
   each of Y^{S}, Y^{T}, and Y^{U} is independently CRR′, SiRR′ or GeRR′;
   n is an integer between 1 and 8, when n is more than 1, each Y^{Q} can be same or different;
   Q^{A} is selected from C, Si, Ge, N, P, O, S, Se, and B;
      a and b are each independently 0 or 1;
      a+b=2 when Q^{A} is C, Si, or Ge;
      a+b=1 when Q^{A} is N or P;
   a+b can be 1 or 2 when Q^{A} is B;
      a+b=0 when Q^{A} is O, S, or Se;
each R, R′, R^{1a}, R^{2a}, R^{3a}, R^{SS}, R^{TT}, and R^{UU} is independently hydrogen or a substituent selected from the group consisting of the General Substituents defined herein;
and any two substituents may be optionally fused or joined to form a ring.

In some embodiments, at least one of R^{GG1} and R^{GG2} comprises a group R^{W}. In some embodiments, both R^{GG1} and R^{GG2} comprise a group R^{W}. In some embodiments, both R^{GG1} and R^{GG2} comprise Formula IIIA. In some embodiments, both R^{GG1} and R^{GG2} comprise Formula IIIB. In some embodiments, both R^{GG}1 and R^{GG2} comprise Formula IIIC. In some embodiments, one of R^{GG}1 and R^{GG2} comprises Formula IIIA, and the other one of R^{GG1} and R^{GG2} comprises Formula IIIB. In some embodiments, one of R^{GG1} and R^{GG2} comprises Formula IIIA, and the other one of R^{GG1} and R^{GG2} comprises Formula IIIC. In some embodiments, one of R^{GG1} and R^{GG2} comprises Formula IIIB, and the other one of R^{GG1} and R^{GG2} comprises Formula IIIC.

In some embodiments, R^{GG1} has a molecular weight (MW) greater than 15 g/mol and R^{GG2} has a molecular weight greater than that of R^{GG1}. In some embodiments, R^{GG1} has a molecular weight (MW) greater than 56 g/mol and R^{GG2} has a molecular weight greater than that of R^{GG1}. In some embodiments, R^{GG1} has a molecular weight (MW) greater than 76 g/mol and R^{GG2} has a molecular weight greater than that of R^{GG1}. In some embodiments, R^{GG1} has a molecular weight (MW) greater than 81 g/mol and R^{GG2} has a molecular weight greater than that of R^{GG1}. In some embodiments, R^{GG1} or R^{GG2} has a molecular weight (MW) greater than 165 g/mol. In some embodiments, R^{GG1} or R^{GG2} has a molecular weight (MW) greater than 166 g/mol. In some embodiments, R^{GG1} or R^{GG2} has a molecular weight (MW) greater than 182 g/mol. In some embodiments, R^{GG1} has one more 6-membered aromatic ring than R^{GG2}. In some embodiments, R^{GG1} has two more 6-membered aromatic rings than R^{GG2}. In some embodiments, R^{GG1} has three more 6-membered aromatic rings than R^{GG2}. In some embodiments, R^{GG1} has four more 6-membered aromatic rings than R^{GG2}. In some embodiments, R^{GG1} has five more 6-membered aromatic rings than R^{GG2}. In some embodiments, R^{GG1} comprises at least one heteroatom and R^{GG2} consists of hydrocarbon and deuterated variant thereof. In some embodiments, R^{GG1} comprises at least two heteroatoms and R^{GG2} consists of hydrocarbon and deuterated variant thereof. In some embodiments, R^{GG1} comprises at least three heteroatoms and R^{GG2} consists of hydrocarbon and deuterated variant thereof. In some embodiments, R^{GG1} comprises exactly one heteroatom and R^{GG2} consists of hydrocarbon and deuterated variant thereof. In some embodiments, R^{GG1} comprises exactly two heteroatoms and R^{GG2} consists of hydrocarbon and deuterated variant thereof. In some embodiments, R^{GG1} comprises exactly three heteroatoms and R^{GG2} consists of hydrocarbon and deuterated variant thereof. In some embodiments, R^{GG1} comprises exactly one heteroatom and R^{GG2} comprises exactly one heteroatom that is different from the heteroatom in R^{GG1}. In some embodiments, R^{GG1} comprises exactly one heteroatom and R^{GG2} comprises exactly one heteroatom that is same as the heteroatom in R^{GG1}.

In some embodiments, R^{GG1} comprises exactly two heteroatoms and R^{GG2} comprises exactly one heteroatom. In some embodiments, R^{GG1} comprises exactly two heteroatoms and R^{GG2} comprises exactly two heteroatoms. In some embodiments, R^{GG1} comprises exactly three heteroatoms and R^{GG2} comprises exactly one heteroatom. In some embodiments, R^{GG1} comprises exactly three heteroatoms and R^{GG2} comprises exactly two heteroatoms. In some embodiments, R^{GG1} comprises exactly three heteroatoms and R^{GG2} comprises exactly three heteroatoms.

In some embodiments, at least one of R^{GG1} and R^{GG2} comprises an aromatic ring fused by a non-aromatic ring. In some embodiments, both R^{GG1} and R^{GG2} comprise an aromatic ring fused by a non-aromatic ring. In some embodiments, the aromatic ring is a phenyl ring and the non-aromatic ring is a cycloalkyl ring. In some embodiments, at least one of R^{GG1} and R^{GG2} is partially or fully deuterated. In some embodiments, both R^{GG1} and R^{GG2} are partially or fully deuterated.

In some embodiments of Formula V, L¹ is a direct bond.

In some embodiments of Formula V, at least one R^{H} is not H.

In some embodiments of Formula V, two R^{H} are joined to form a ring. In some embodiments of Formula V, two R^{H} are joined to form a benzene ring.

In some embodiments, X is NR, Z is C, and R and R^{A} join to comprise a structure of Formula IV,

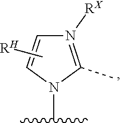

wherein R^{X} has a molecular weight of at least 153 grams/mol or R^{X} and R^{H} are joined to form a ring.

In some embodiments of Formula IV, L¹ is a direct bond.

In some embodiments of Formula IV, at least one R^{H} is not H.

In some embodiments of Formula IV, two R^{H} are joined to form a ring. In some embodiments of Formula IV, two R^{H} are joined to form a benzene ring.

In some embodiments of Formula IV, R^{X} has a structure selected from the group consisting of the structures in the following LIST 1:

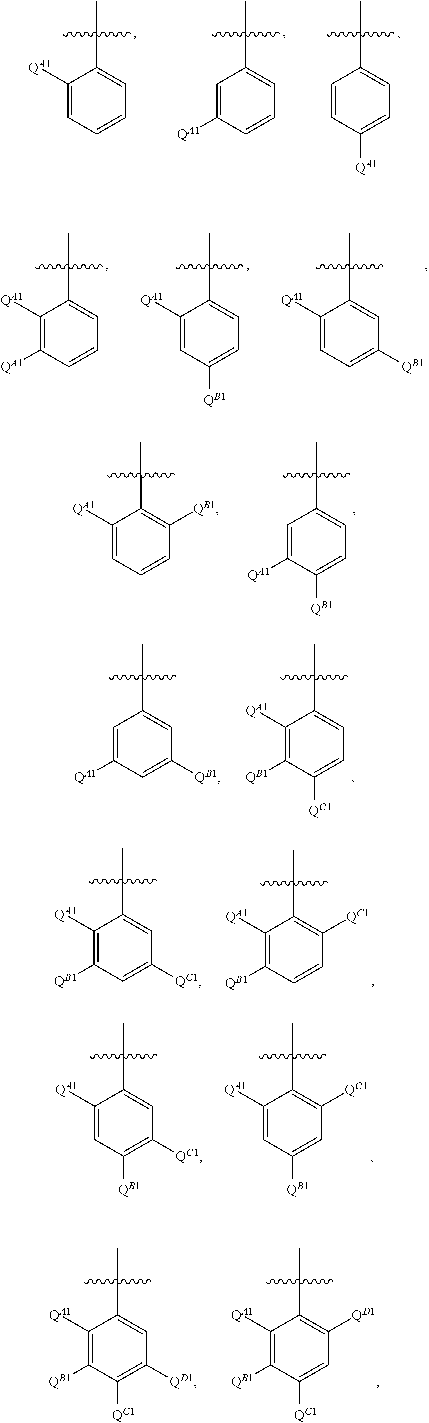

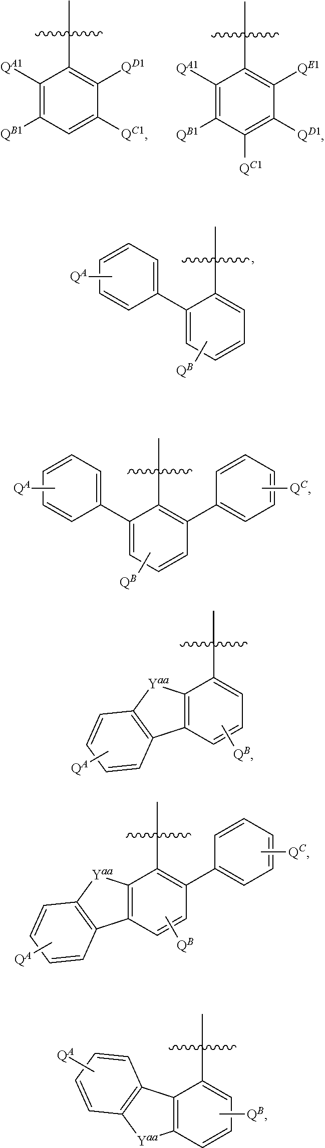

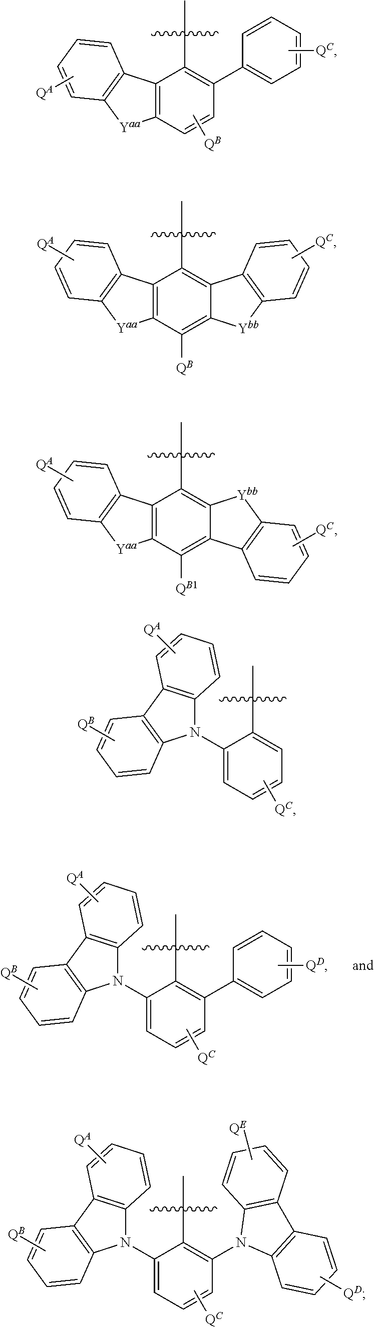

wherein each of Q^{A}, Q^{B}, Q^{C}, Q^{D}, and Q^{E} independently represents mono to the maximum allowable substitutions, or no substitutions;
wherein each Q^{A}, Q^{B}, Q^{C}, Q^{D}, Q^{E}, Q^{A1}, Q^{B1}, Q^{C1}, Q^{D1} and Q^{E1} is independently a hydrogen or a substituent selected from the group consisting of the General Substituents defined herein;
each Y^{aa} and Y^{bb} is independently selected from the group consisting of a direct bond, BR, BRR′, NR, PR, O, S, Se, C═O, C═S, C═Se, C═NR, C═CRR′, S═O, SO₂, CR, CRR′, SiRR′, GeRR′, alkyl, cycloalkyl, aryl, heteroaryl, and combinations thereof; and any two substituents can be joined or fused to form a ring.

In some embodiments of Formula IV, R^{X} has a structure selected from the group consisting of the structures of LIST 1; wherein each of Q^{A1}, Q^{B1}, Q^{C1}, Q^{D1} and Q^{E1} is independently selected from the group consisting of the structures of the following LIST 2:

| | Structure |
|---|---|
| Q1 | 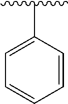 [SMILES: *c1ccccc1] |
| Q2 | 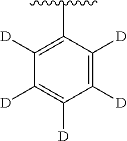 [SMILES: *c1c([2H])c([2H])c([2H])c([2H])c1[2H]] |
| Q3 | 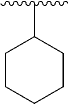 [SMILES: *C1CCCCC1] |
| Q4 | 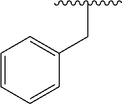 [SMILES: *Cc1ccccc1] |
| Q5 | 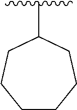 [SMILES: *C1CCCCCC1] |
| Q6 | 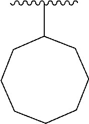 [SMILES: *C1CCCCCCC1] |
| Q7 | 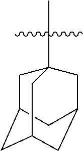 [SMILES: *C12CC3CC(CC(C3)C1)C2] |
| Q8 | 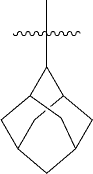 [SMILES: *C1C2CC3CC(C2)CC1C3] |
| Q9 | 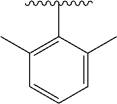 |
| Q10 | 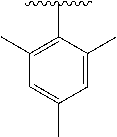 |
| Q11 | 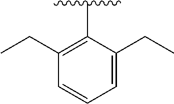 [SMILES: *c1c(CC)cccc1CC] |
| Q12 | 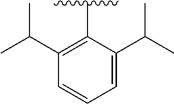 [SMILES: *c1c(C(C)C)cccc1C(C)C] |
| Q13 | 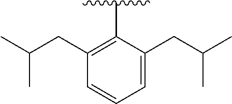 [SMILES: *c1c(CC(C)C)cccc1CC(C)C] |
| Q14 | 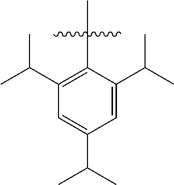 [SMILES: *c1c(C(C)C)cc(C(C)C)cc1C(C)C] |
| Q15 | 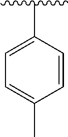 [SMILES: *c1ccc(C)cc1] |
| Q16 | 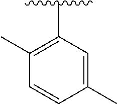 |
| Q17 | 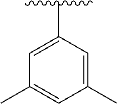 |
| Q18 | 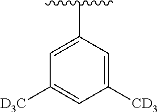 [SMILES: *c1cc(C([2H])([2H])[2H])cc(C([2H])([2H])[2H])c1] |
| Q19 | 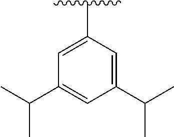 [SMILES: *c1cc(C(C)C)cc(C(C)C)c1] |
| Q20 | 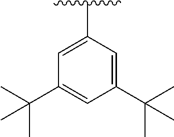 [SMILES: *c1cc(C(C)(C)C)cc(C(C)(C)C)c1] |
| Q21 | 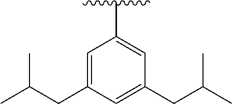 [SMILES: *c1cc(CC(C)C)cc(CC(C)C)c1] |
| Q22 | 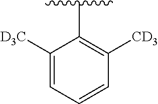 [SMILES: *c1c(C([2H])([2H])[2H])cccc1C([2H])([2H])[2H]] |
| Q23 | 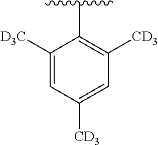 [SMILES: *c1c(C([2H])([2H])[2H])cc(C([2H])([2H])[2H])cc1C([2H])([2H])[2H]] |
| Q24 | 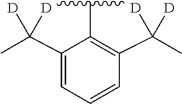 [SMILES: *c1c(C([2H])([2H])C)cccc1C([2H])([2H])C] |
| Q25 | 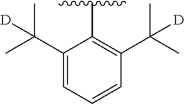 [SMILES: *c1c(C([2H])(C)C)cccc1C([2H])(C)C] |
| Q26 | 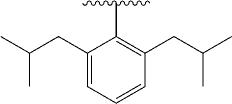 [SMILES: *c1c(CC(C)C)cccc1CC(C)C] |
| Q27 | 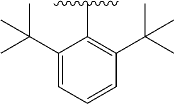 [SMILES: *c1c(C(C)(C)C)cccc1C(C)(C)C] |
| Q28 | 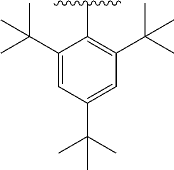 [SMILES: *c1c(C(C)(C)C)cc(C(C)(C)C)cc1C(C)(C)C] |
| Q29 | 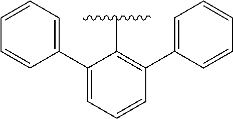 [SMILES: *c1c(-c2ccccc2)cccc1-c1ccccc1] |
| Q30 | 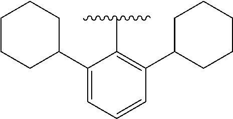 [SMILES: *c1c(C2CCCCC2)cccc1C1CCCCC1] |
| Q31 | 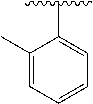 [SMILES: *c1ccccc1C] |
| Q32 | 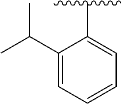 [SMILES: *c1ccccc1C(C)C] |
| Q33 | 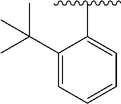 [SMILES: *c1ccccc1C(C)(C)C] |
| Q34 | 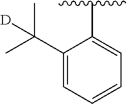 [SMILES: *c1ccccc1C([2H])(C)C] |
| Q35 | 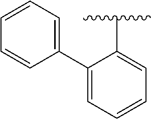 [SMILES: *c1ccccc1-c1ccccc1] |
| Q36 | 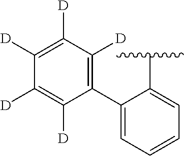 [SMILES: *c1ccccc1-c1c([2H])c([2H])c([2H])c([2H])c1[2H]] |
| Q37 | 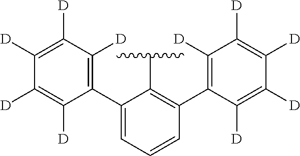 [SMILES: *c1c(-c2c([2H])c([2H])c([2H])c([2H])c2[2H])cccc1-c1c([2H])c([2H])c([2H])c([2H])c1[2H]] |
| Q38 | 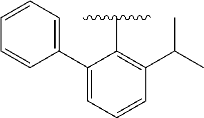 [SMILES: *c1c(-c2ccccc2)cccc1C(C)C] |
| Q39 | 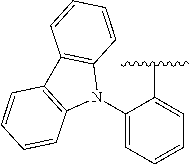 [SMILES: *c1ccccc1-n1c2ccccc2c2ccccc21] |
| Q40 | 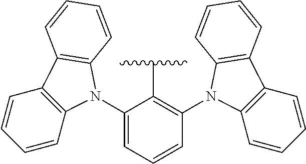 [SMILES: *c1c(-n2c3ccccc3c3ccccc32)cccc1-n1c2ccccc2c2ccccc21] |
| Q41 | 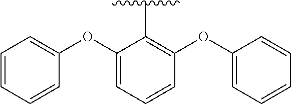 [SMILES: *c1c(Oc2ccccc2)cccc1Oc1ccccc1] |
| Q42 | 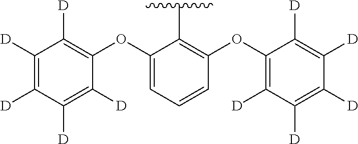 [SMILES: *c1c(Oc2c([2H])c([2H])c([2H])c([2H])c2[2H])cccc1Oc1c([2H])c([2H])c([2H])c([2H])c1[2H]] |
| Q43 | 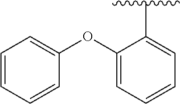 [SMILES: *c1ccccc1Oc1ccccc1] |
| Q44 | 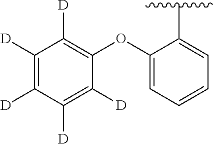 [SMILES: *c1ccccc1Oc1c([2H])c([2H])c([2H])c([2H])c1[2H]] |
| Q45 | 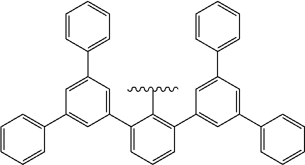 [SMILES: *c1c(-c2cc(-c3ccccc3)cc(-c3ccccc3)c2)cccc1-c1cc(-c2ccccc2)cc(-c2ccccc2)c1] |
| Q46 | 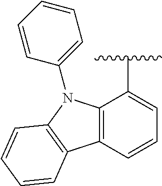 [SMILES: *c1cccc2c3ccccc3n(-c3ccccc3)c12] |
| Q47 | 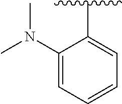 [SMILES: *c1ccccc1N(C)C] |
| Q48 | 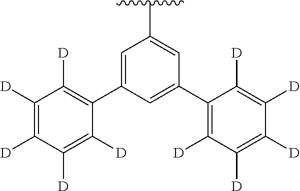 [SMILES: *c1cc(-c2c([2H])c([2H])c([2H])c([2H])c2[2H])cc(-c2c([2H])c([2H])c([2H])c([2H])c2[2H])c1] |
| Q49 | 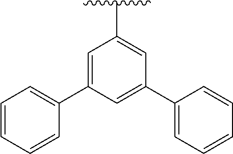 [SMILES: *c1cc(-c2ccccc2)cc(-c2ccccc2)c1] |
| Q50 | 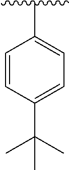 [SMILES: *c1ccc(C(C)(C)C)cc1] |
| Q51 | 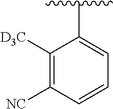 [SMILES: *c1cccc(C#N)c1C([2H])([2H])[2H]] |
| Q52 | 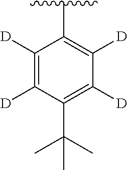 [SMILES: *c1c([2H])c([2H])c(C(C)(C)C)c([2H])c1[2H]] |
| Q53 | 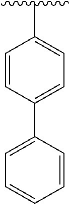 [SMILES: *c1ccc(-c2ccccc2)cc1] |
| Q54 | 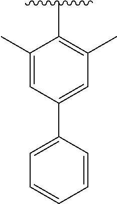 |
| Q55 | 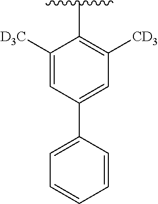 [SMILES: *c1c(C([2H])([2H])[2H])cc(-c2ccccc2)cc1C([2H])([2H])[2H]] |
| Q56 | 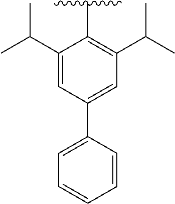 [SMILES: *c1c(C(C)C)cc(-c2ccccc2)cc1C(C)C] |
| Q57 | 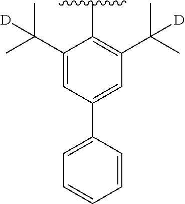 [SMILES: *c1c(C([2H])(C)C)cc(-c2ccccc2)cc1C([2H])(C)C] |
| Q58 | 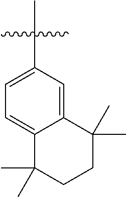 |
| Q59 | 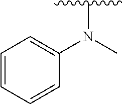 [SMILES: *N(C)c1ccccc1] |
| Q60 | 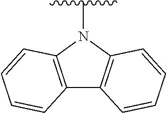 [SMILES: *n1c2ccccc2c2ccccc21] |
| Q61 | 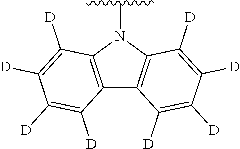 [SMILES: *n1c2c([2H])c([2H])c([2H])c([2H])c2c2c([2H])c([2H])c([2H])c([2H])c21] |
| Q62 | 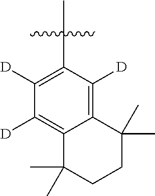 [SMILES: *c1c([2H])c([2H])c2c(c1[2H])C(C)(C)CCC2(C)C] |
| Q63 | 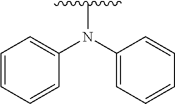 [SMILES: *N(c1ccccc1)c1ccccc1] |
| Q64 | 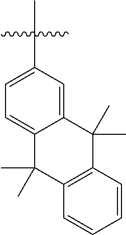 |
| Q65 | 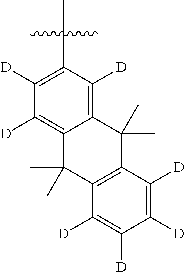 [SMILES: *c1c([2H])c([2H])c2c(c1[2H])C(C)(C)c1c([2H])c([2H])c([2H])c([2H])c1C2(C)C] |
| Q66 | 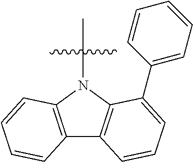 [SMILES: *n1c2ccccc2c2cccc(-c3ccccc3)c21] |
| Q67 | 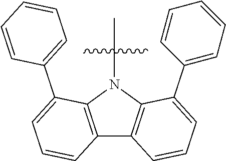 [SMILES: *n1c2c(-c3ccccc3)cccc2c2cccc(-c3ccccc3)c21] |
| Q68 | 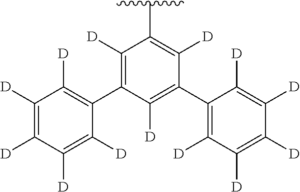 [SMILES: *c1c([2H])c(-c2c([2H])c([2H])c([2H])c([2H])c2[2H])c([2H])c(-c2c([2H])c([2H])c([2H])c([2H])c2[2H])c1[2H]] |
| Q69 | 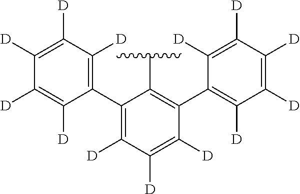 [SMILES: *c1c(-c2c([2H])c([2H])c([2H])c([2H])c2[2H])c([2H])c([2H])c([2H])c1-c1c([2H])c([2H])c([2H])c([2H])c1[2H]] |
| Q70 | 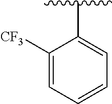 [SMILES: *c1ccccc1C(F)(F)F] |
| Q71 | 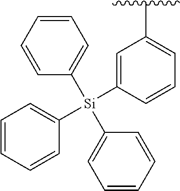 [SMILES: *c1cccc([Si](c2ccccc2)(c2ccccc2)c2ccccc2)c1] |
| Q72 | 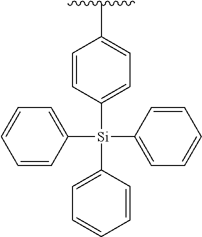 [SMILES: *c1ccc([Si](c2ccccc2)(c2ccccc2)c2ccccc2)cc1] |
| Q73 | 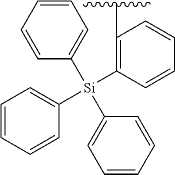 [SMILES: *c1ccccc1[Si](c1ccccc1)(c1ccccc1)c1ccccc1] |
| Q74 | 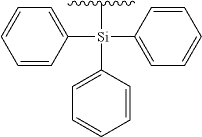 [SMILES: *[Si](c1ccccc1)(c1ccccc1)c1ccccc1] |
| Q75 | 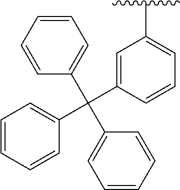 [SMILES: *c1cccc(C(c2ccccc2)(c2ccccc2)c2ccccc2)c1] |
| Q76 | 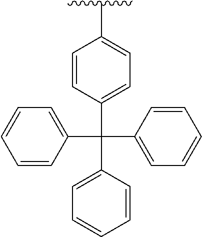 [SMILES: *c1ccc(C(c2ccccc2)(c2ccccc2)c2ccccc2)cc1] |
| Q77 | 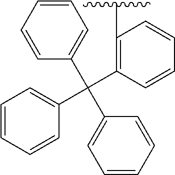 [SMILES: *c1ccccc1C(c1ccccc1)(c1ccccc1)c1ccccc1] |
| Q78 | 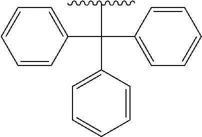 [SMILES: *C(c1ccccc1)(c1ccccc1)c1ccccc1] |
| Q79 | 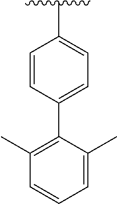 |
| Q80 | 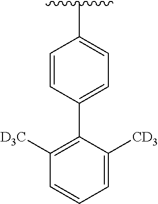 [SMILES: *c1ccc(-c2c(C([2H])([2H])[2H])cccc2C([2H])([2H])[2H])cc1] |
| Q81 | 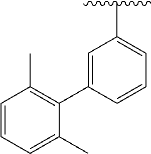 [SMILES: *c1cccc(-c2c(C)cccc2C)c1] |
| Q82 | 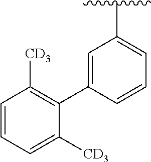 [SMILES: *c1cccc(-c2c(C([2H])([2H])[2H])cccc2C([2H])([2H])[2H])c1] |
| Q83 | 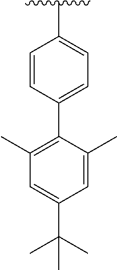 |
| Q84 | 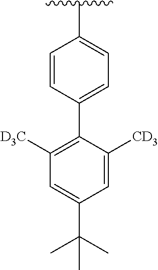 [SMILES: *c1ccc(-c2c(C([2H])([2H])[2H])cc(C(C)(C)C)cc2C([2H])([2H])[2H])cc1] |
| Q85 | 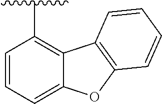 [SMILES: *c1cccc2oc3ccccc3c12] |
| Q86 | 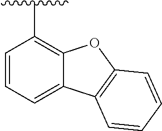 [SMILES: *c1cccc2c1oc1ccccc12] |
| Q87 | 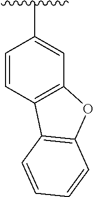 [SMILES: *c1ccc2c(c1)oc1ccccc12] |
| Q88 | 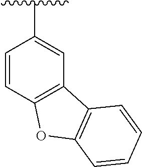 [SMILES: *c1ccc2oc3ccccc3c2c1] |
| Q89 | 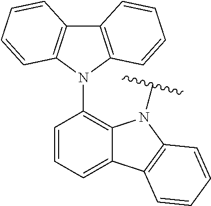 [SMILES: *n1c2ccccc2c2cccc(-n3c4ccccc4c4ccccc43)c21] |
| Q90 | 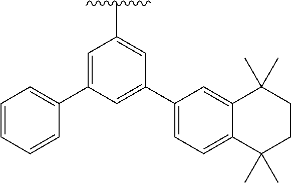 [SMILES: *c1cc(-c2ccccc2)cc(-c2ccc3c(c2)C(C)(C)CCC3(C)C)c1] |
| Q91 | 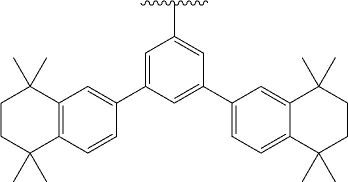 [SMILES: *c1cc(-c2ccc3c(c2)C(C)(C)CCC3(C)C)cc(-c2ccc3c(c2)C(C)(C)CCC3(C)C)c1] |
| Q92 | 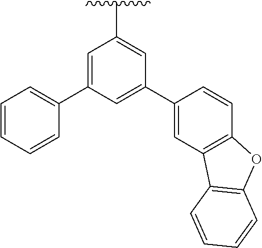 [SMILES: *c1cc(-c2ccccc2)cc(-c2ccc3oc4ccccc4c3c2)c1] |
| Q93 | 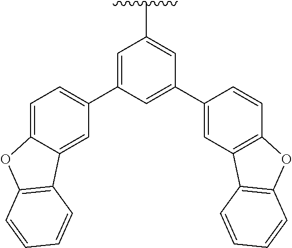 [SMILES: *c1cc(-c2ccc3oc4ccccc4c3c2)cc(-c2ccc3oc4ccccc4c3c2)c1] |
| Q94 | 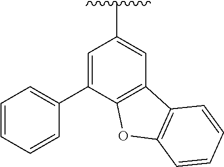 [SMILES: *c1cc(-c2ccccc2)c2oc3ccccc3c2c1] |
| Q95 | 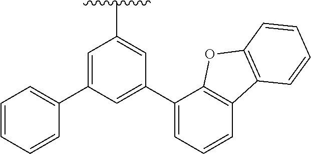 [SMILES: *c1cc(-c2ccccc2)cc(-c2cccc3c2oc2ccccc23)c1] |
| Q96 | 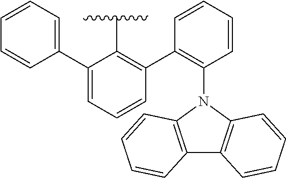 [SMILES: *c1c(-c2ccccc2)cccc1-c1ccccc1-n1c2ccccc2c2ccccc21] |
| Q97 | 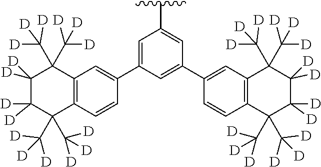 [SMILES: *c1cc(-c2ccc3c(c2)C(C([2H])([2H])[2H])(C([2H])([2H])[2H])C([2H])([2H])C([2H])([2H])C3(C([2H])([2H])[2H])C([2H])([2H])[2H])cc(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c1] |
| Q98 | 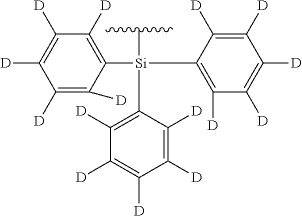 [SMILES: *[Si](c1c([2H])c([2H])c([2H])c([2H])c1[2H])(c1c([2H])c([2H])c([2H])c([2H])c1[2H])c1c([2H])c([2H])c([2H])c([2H])c1[2H]] |
| Q99 | 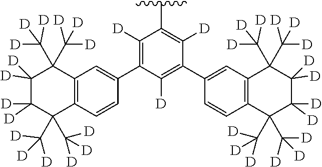 [SMILES: *c1c([2H])c(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c([2H])c(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c1[2H]] |
| Q100 | 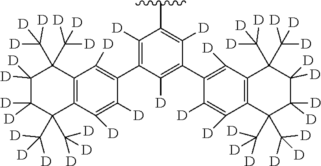 [SMILES: *c1c([2H])c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])c([2H])c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])c1[2H]] |
| Q101 | 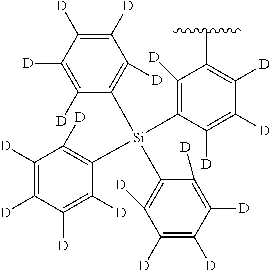 [SMILES: *c1c([2H])c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c1[2H]] |
| Q102 | 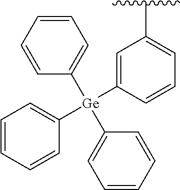 |
| Q103 | 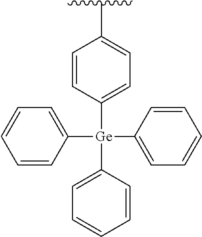 |
| Q104 | 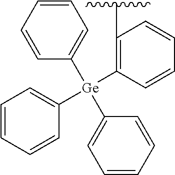 |
| Q105 | 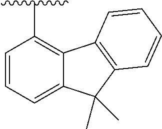 [SMILES: *c1cccc2c1-c1ccccc1C2(C)C] |
| Q106 | 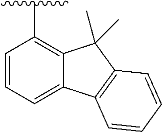 [SMILES: *c1cccc2c1C(C)(C)c1ccccc1-2] |
| Q107 | 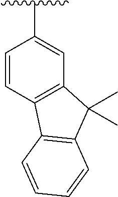 [SMILES: *c1ccc2c(c1)C(C)(C)c1ccccc1-2] |
| Q108 | 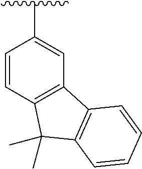 [SMILES: *c1ccc2c(c1)-c1ccccc1C2(C)C] |
| Q109 | 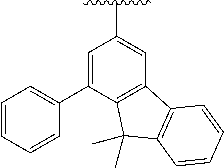 [SMILES: *c1cc(-c2ccccc2)c2c(c1)-c1ccccc1C2(C)C] |
| Q110 | 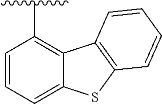 [SMILES: *c1cccc2sc3ccccc3c12] |
| Q111 | 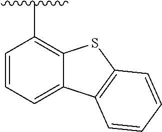 [SMILES: *c1cccc2c1sc1ccccc12] |
| Q112 | 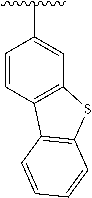 [SMILES: *c1ccc2c(c1)sc1ccccc12] |
| Q113 | 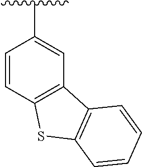 [SMILES: *c1ccc2sc3ccccc3c2c1] |
| Q114 | 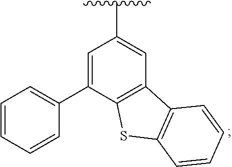 [SMILES: *c1cc(-c2ccccc2)c2sc3ccccc3c2c1] |

and wherein each Q^{A}, Q^{B}, Q^{C}, Q^{D}, and Q^{E} is independently hydrogen or a substituent selected from the group consisting of LIST 2.

In some embodiments of Formula IV, R^{X} is selected from the structures of the following LIST 3:

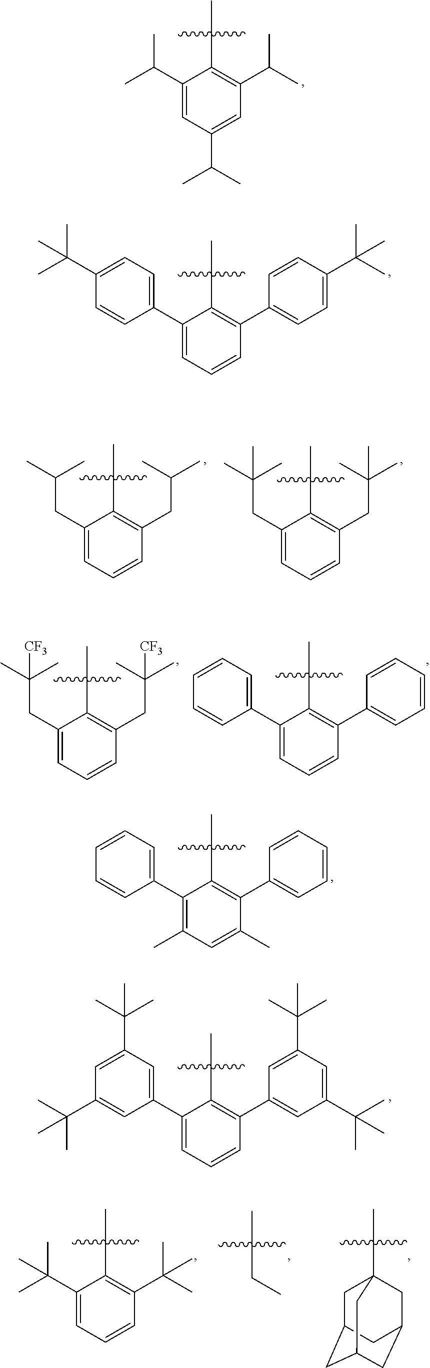

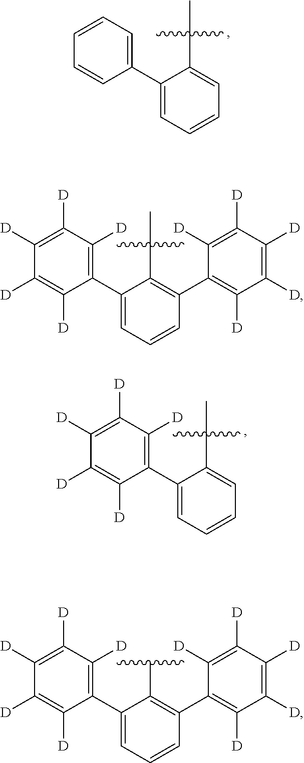

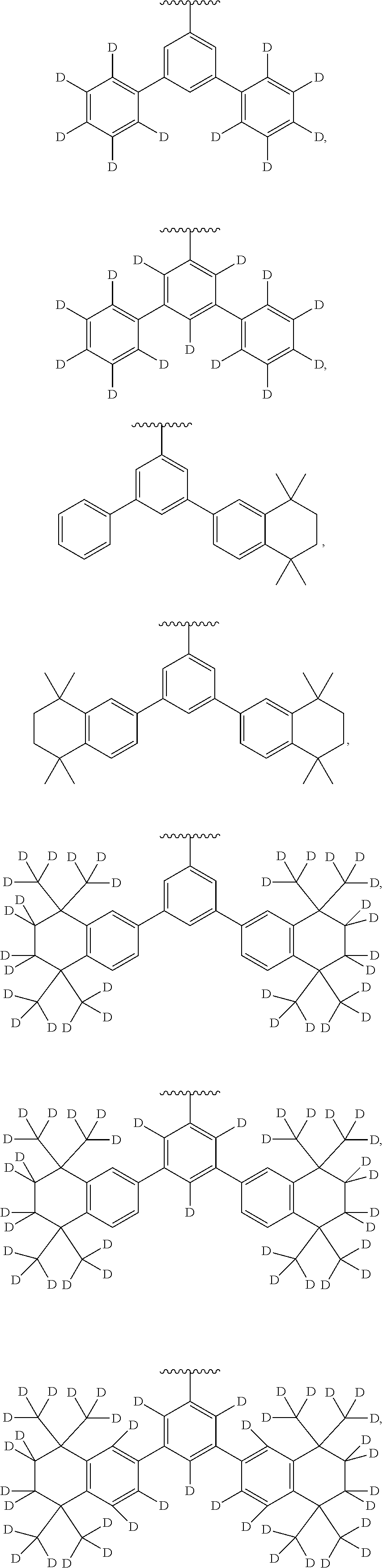

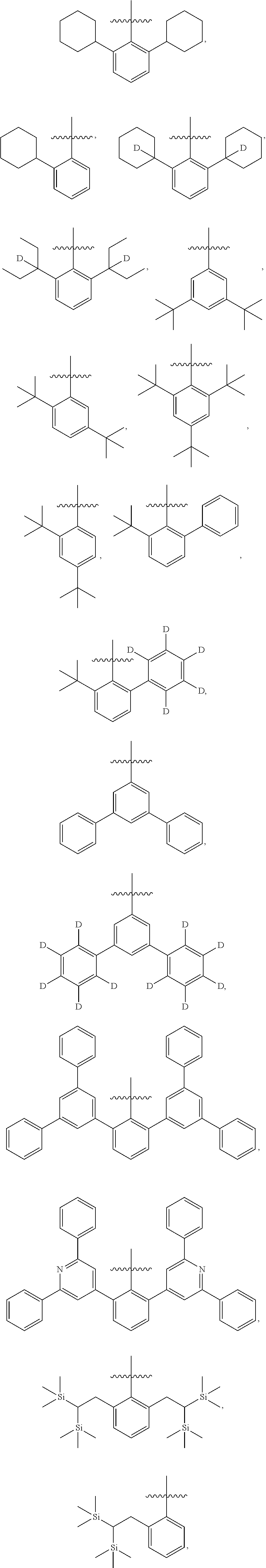

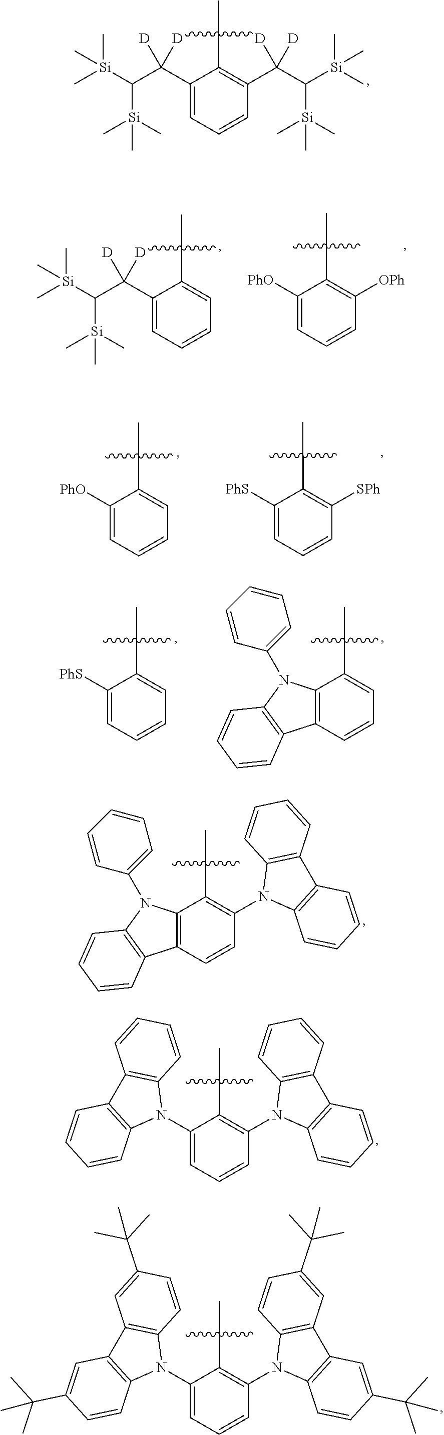

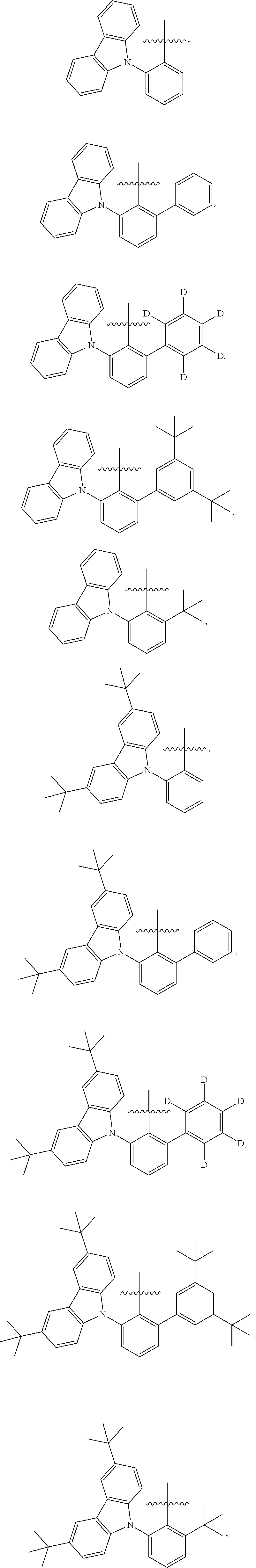

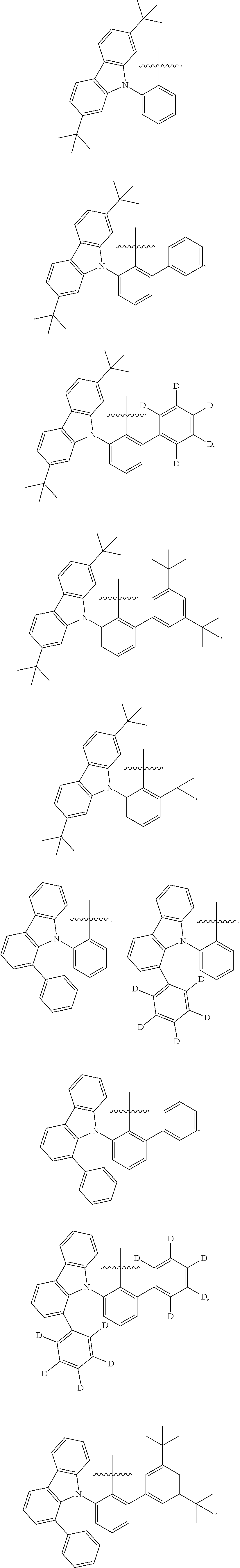

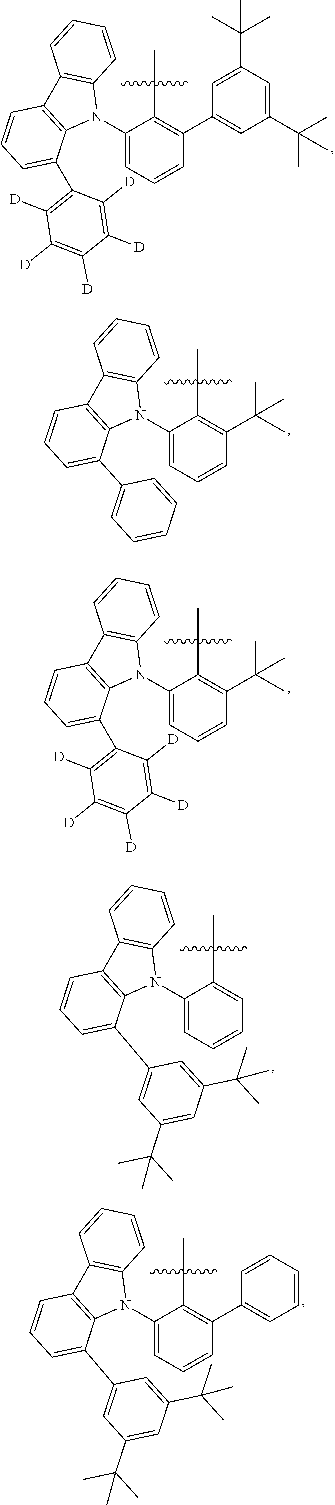

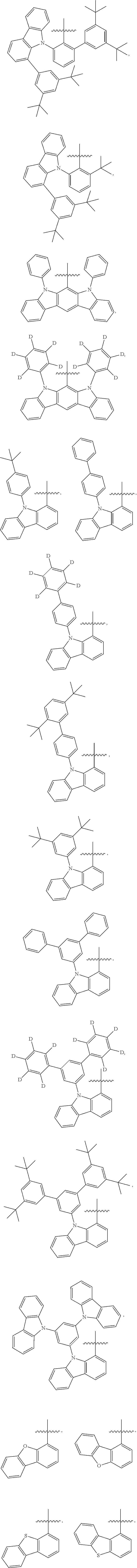

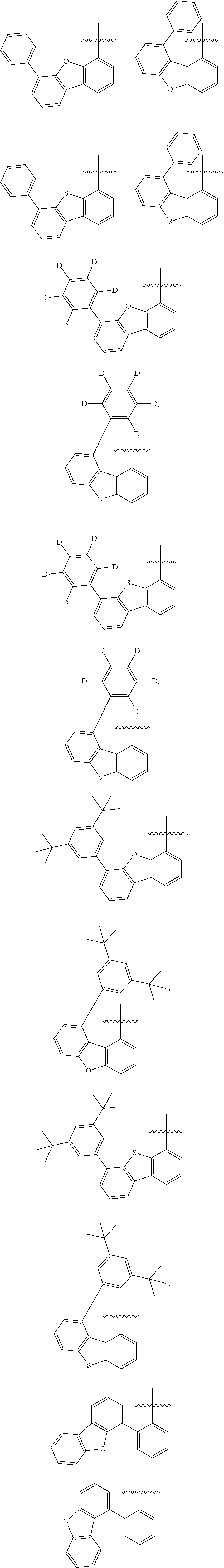

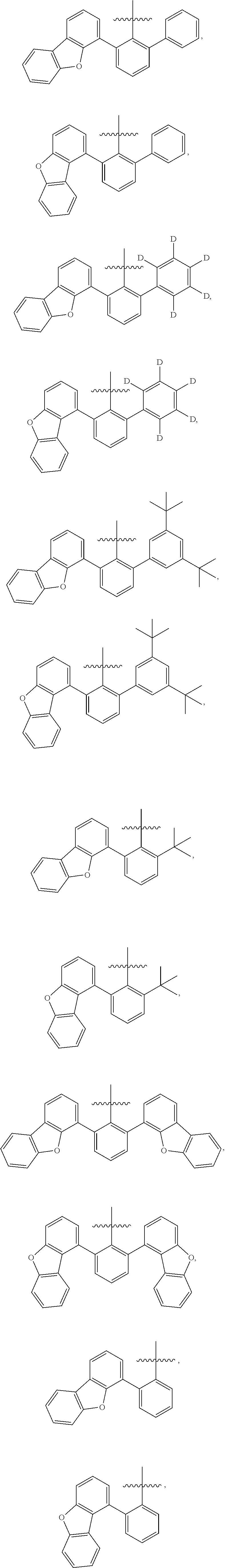

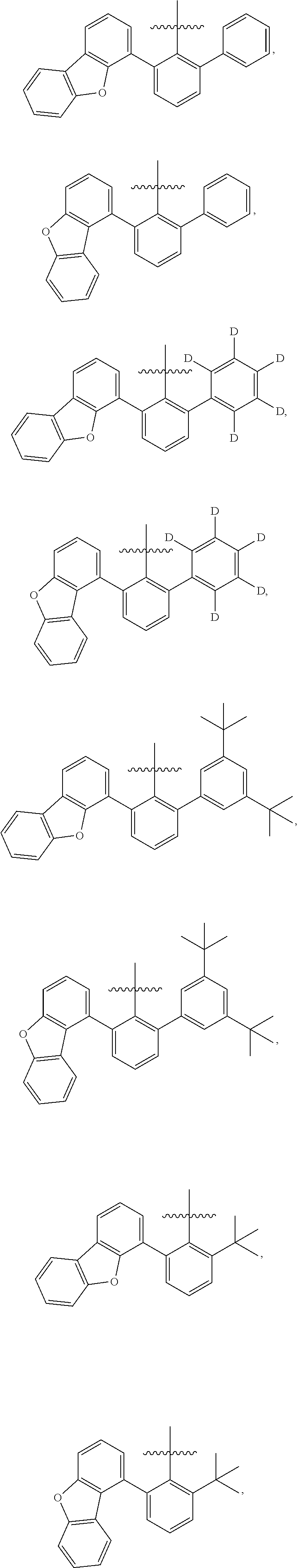

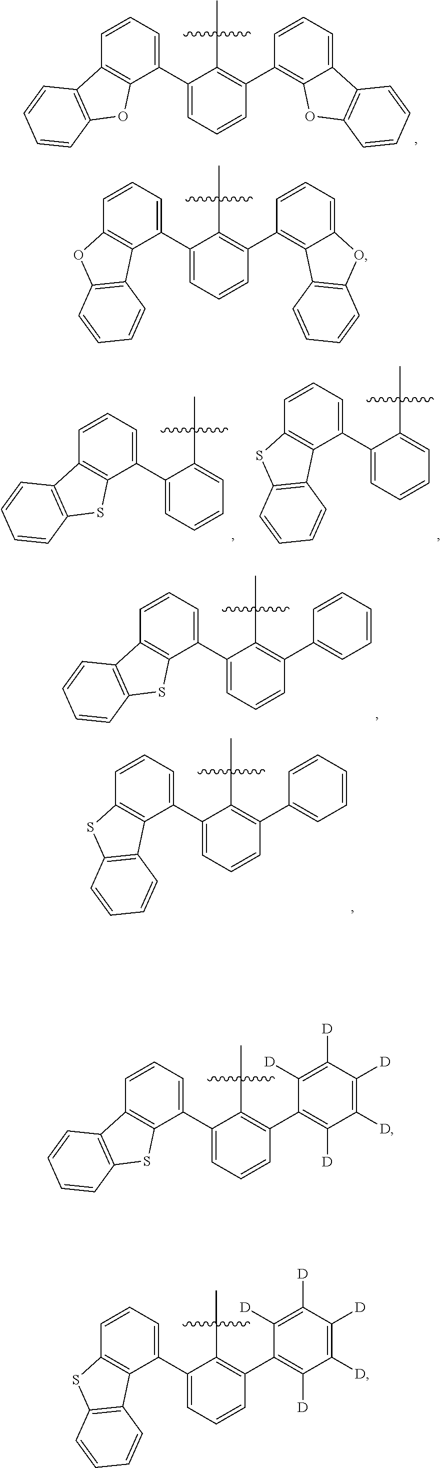

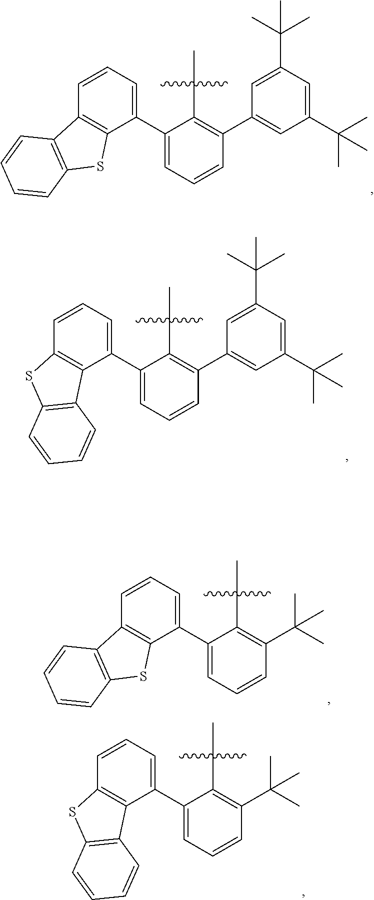 [SMILES: *c1c(-c2cc(C(C)(C)C)cc(C(C)(C)C)c2)cccc1-c1cccc2c1sc1ccccc12 ; *c1c(-c2cc(C(C)(C)C)cc(C(C)(C)C)c2)cccc1-c1cccc2sc3ccccc3c12 ; *c1c(-c2cccc3c2sc2ccccc23)cccc1C(C)(C)C ; *c1c(-c2cccc3sc4ccccc4c23)cccc1C(C)(C)C]

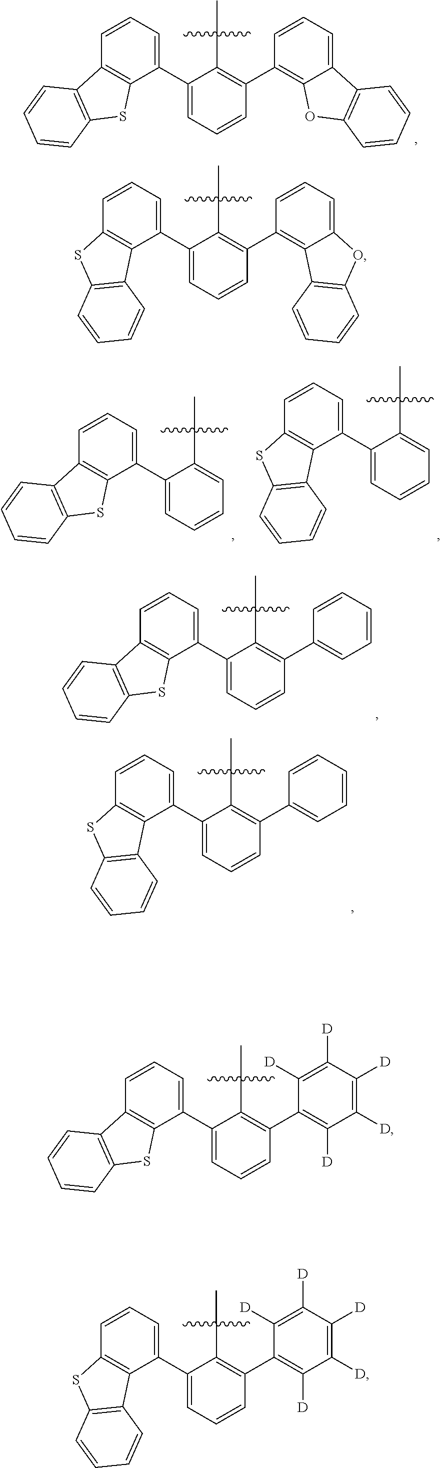

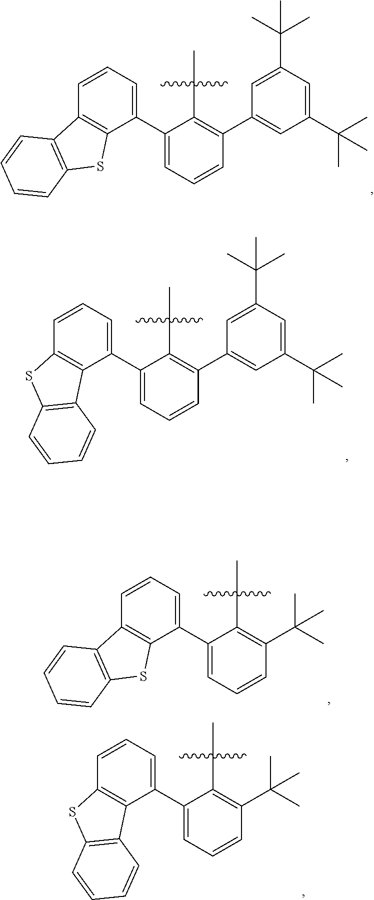 [SMILES: *c1c(-c2cc(C(C)(C)C)cc(C(C)(C)C)c2)cccc1-c1cccc2c1sc1ccccc12 ; *c1c(-c2cc(C(C)(C)C)cc(C(C)(C)C)c2)cccc1-c1cccc2sc3ccccc3c12 ; *c1c(-c2cccc3c2sc2ccccc23)cccc1C(C)(C)C ; *c1c(-c2cccc3sc4ccccc4c23)cccc1C(C)(C)C]

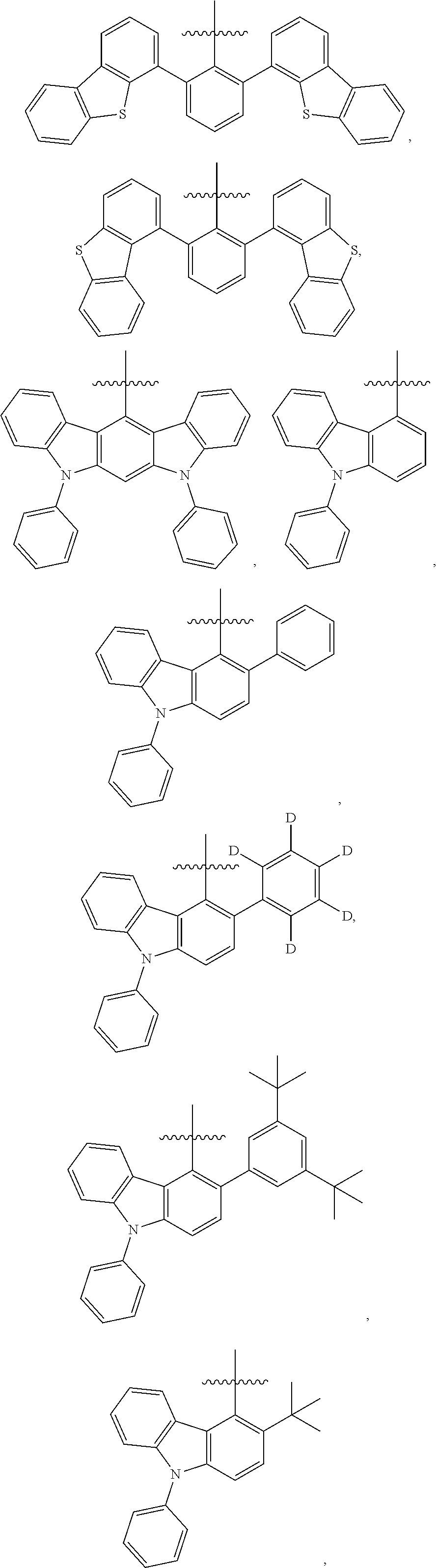

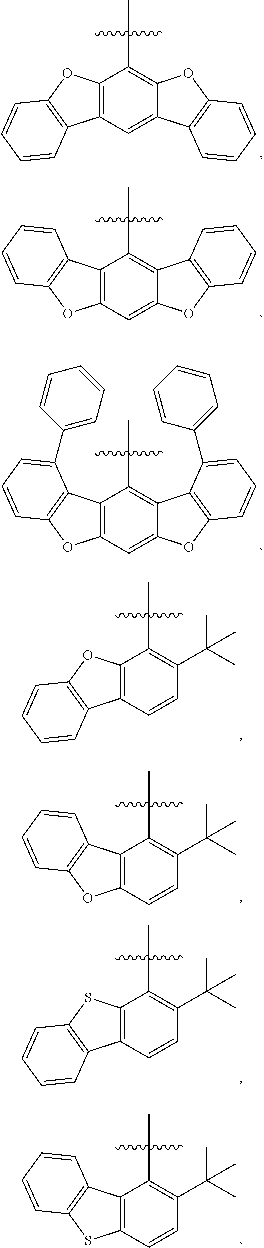

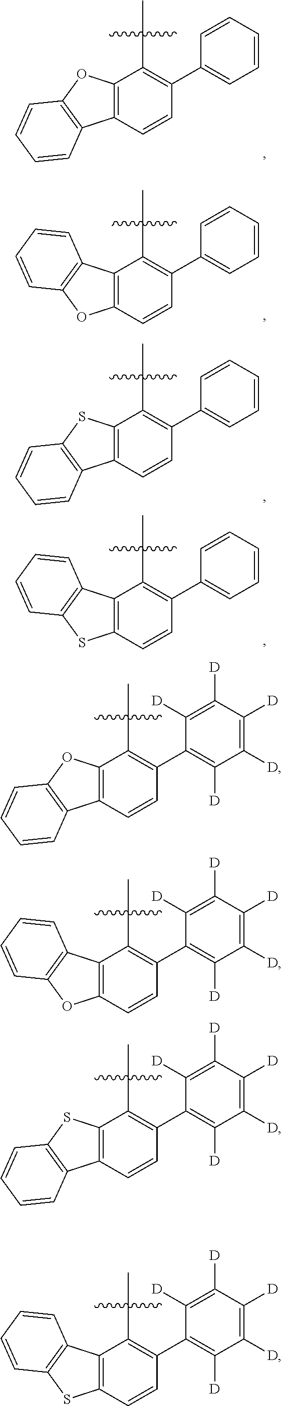

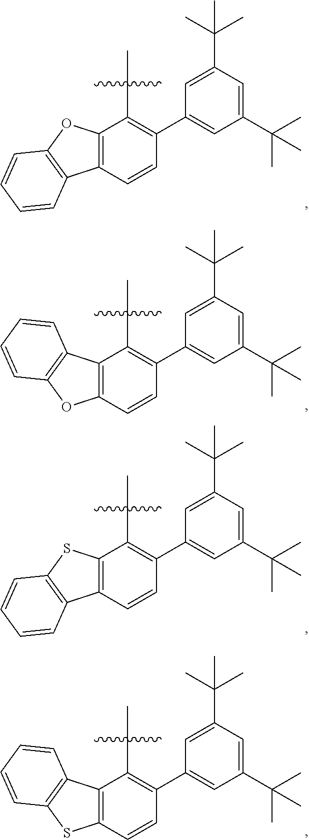 [SMILES: *c1c(-c2cc(C(C)(C)C)cc(C(C)(C)C)c2)ccc2c1oc1ccccc12 ; *c1c(-c2cc(C(C)(C)C)cc(C(C)(C)C)c2)ccc2oc3ccccc3c12 ; *c1c(-c2cc(C(C)(C)C)cc(C(C)(C)C)c2)ccc2c1sc1ccccc12 ; *c1c(-c2cc(C(C)(C)C)cc(C(C)(C)C)c2)ccc2sc3ccccc3c12]

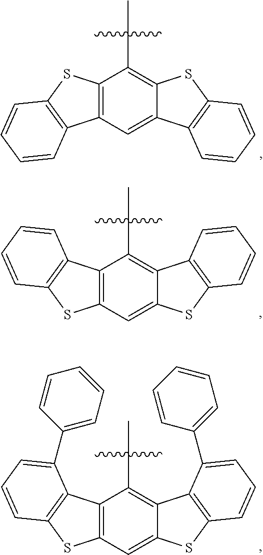 [SMILES: *c1c2sc3ccccc3c2cc2c1sc1ccccc12 ; *c1c2c(cc3sc4ccccc4c13)sc1ccccc12 ; *c1c2c(cc3sc4cccc(-c5ccccc5)c4c13)sc1cccc(-c3ccccc3)c12]

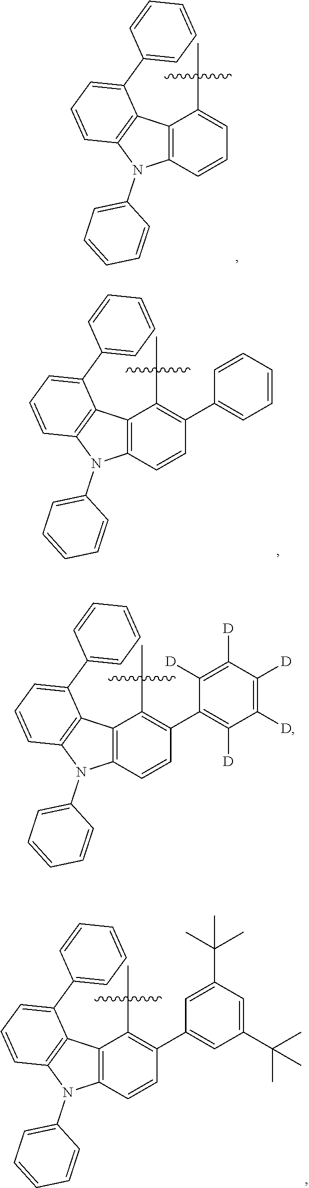

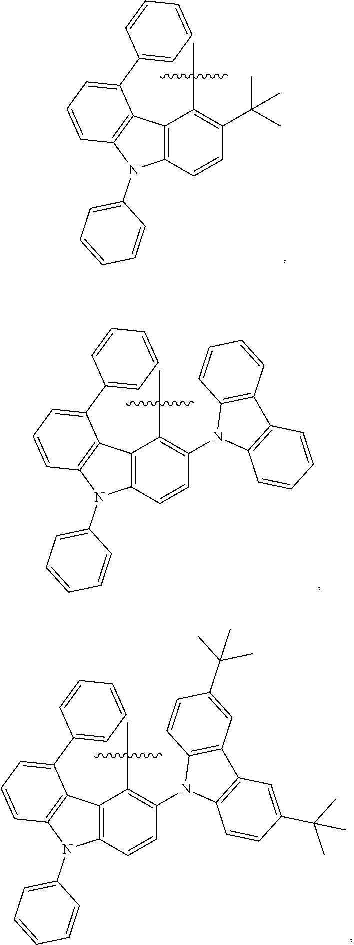 [SMILES: *c1c(C(C)(C)C)ccc2c1c1c(-c3ccccc3)cccc1n2-c1ccccc1 ; *c1c(-n2c3ccccc3c3ccccc32)ccc2c1c1c(-c3ccccc3)cccc1n2-c1ccccc1 ; *c1c(-n2c3ccc(C(C)(C)C)cc3c3cc(C(C)(C)C)ccc32)ccc2c1c1c(-c3ccccc3)cccc1n2-c1ccccc1]

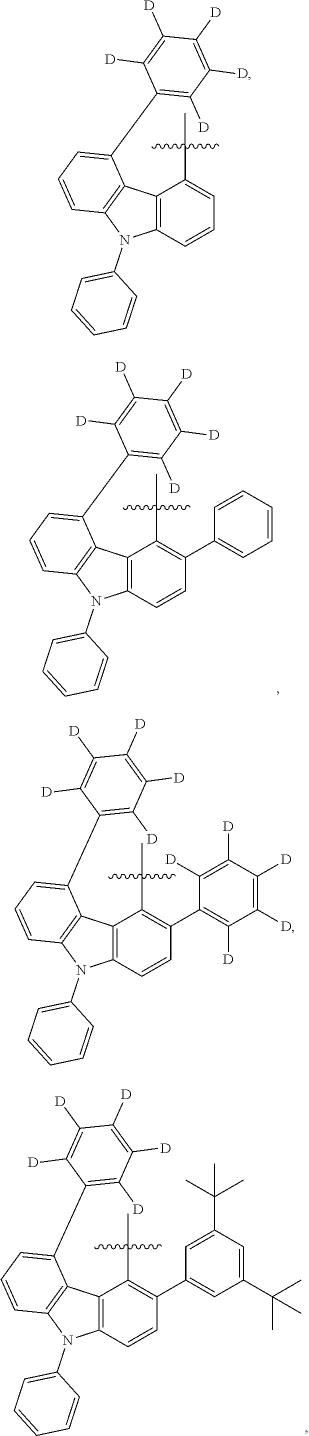

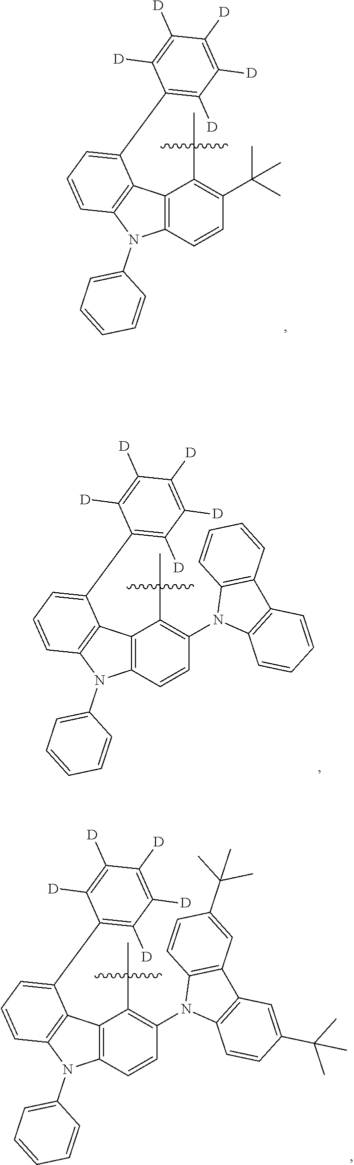 [SMILES: *c1c(C(C)(C)C)ccc2c1c1c(-c3c([2H])c([2H])c([2H])c([2H])c3[2H])cccc1n2-c1ccccc1 ; *c1c(-n2c3ccccc3c3ccccc32)ccc2c1c1c(-c3c([2H])c([2H])c([2H])c([2H])c3[2H])cccc1n2-c1ccccc1 ; *c1c(-n2c3ccc(C(C)(C)C)cc3c3cc(C(C)(C)C)ccc32)ccc2c1c1c(-c3c([2H])c([2H])c([2H])c([2H])c3[2H])cccc1n2-c1ccccc1]

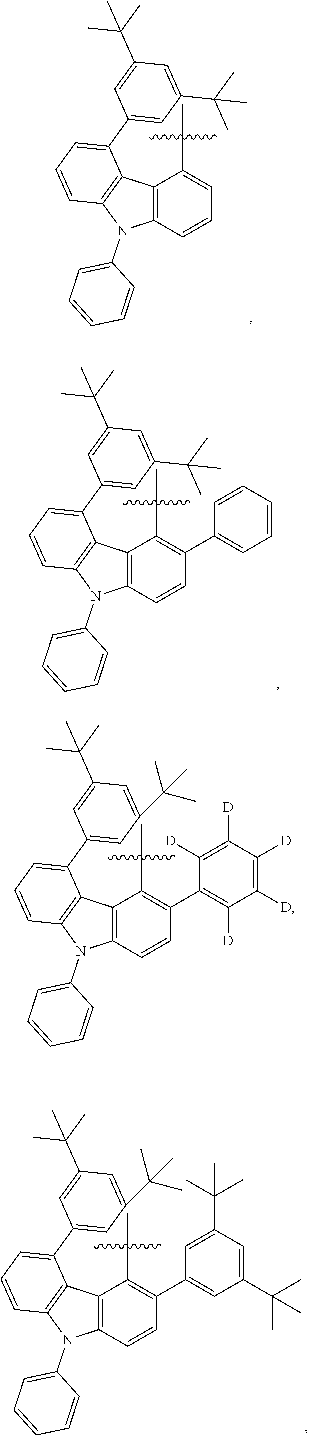

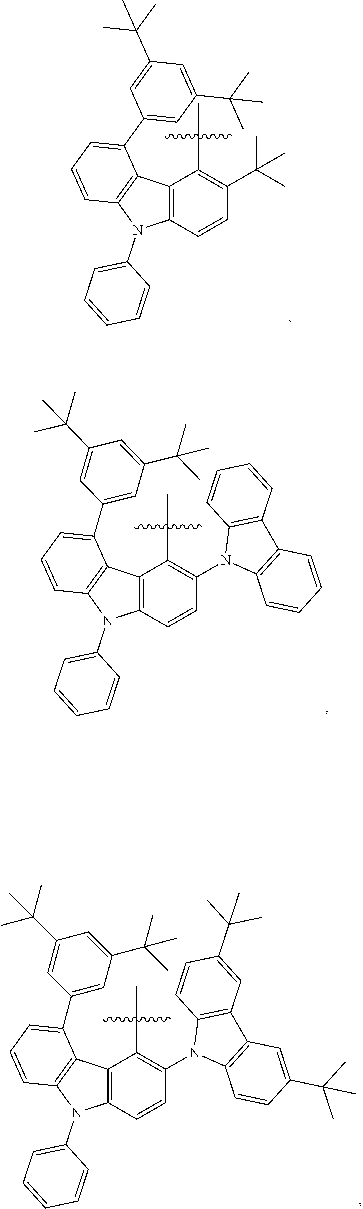

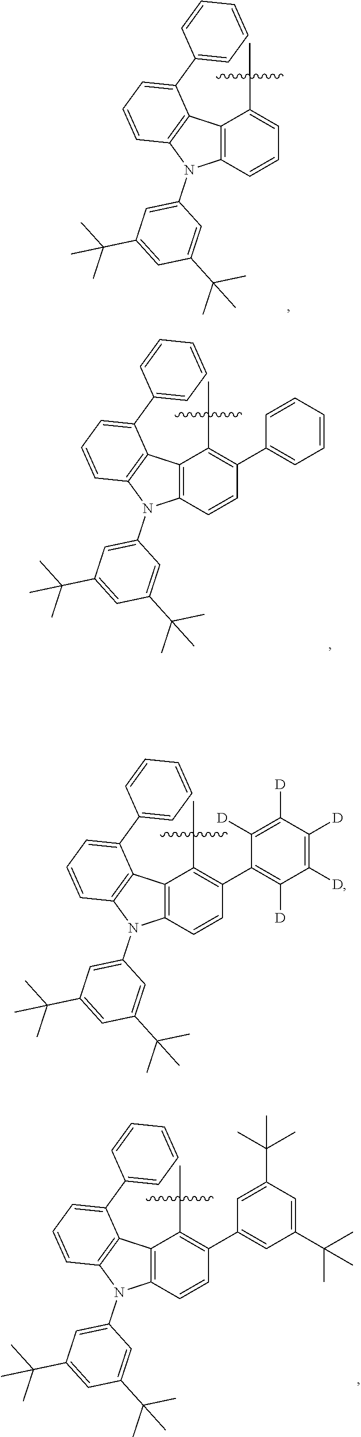

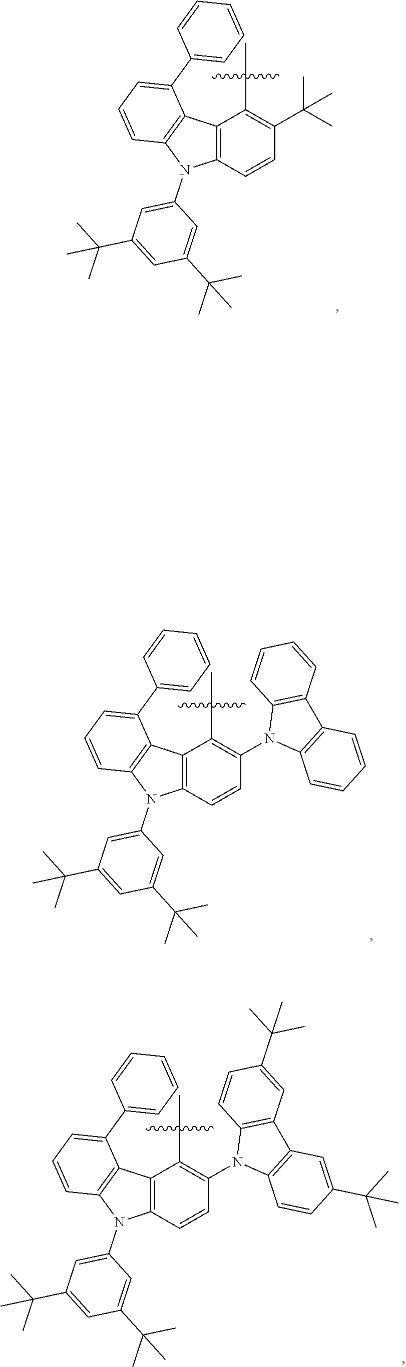

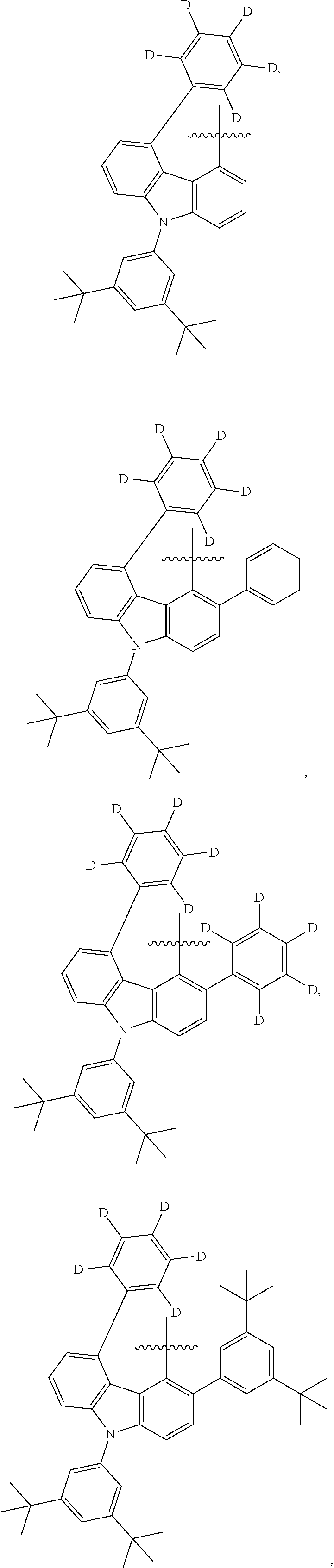

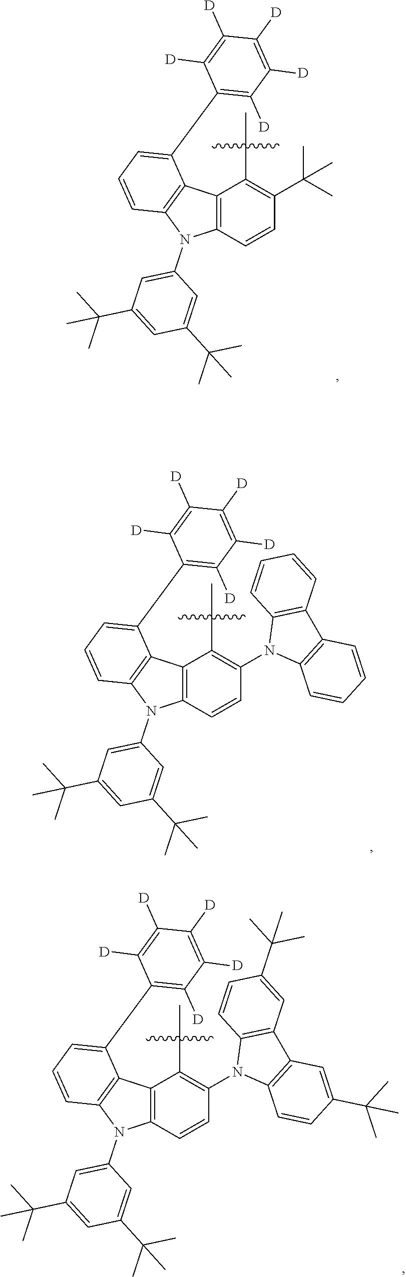

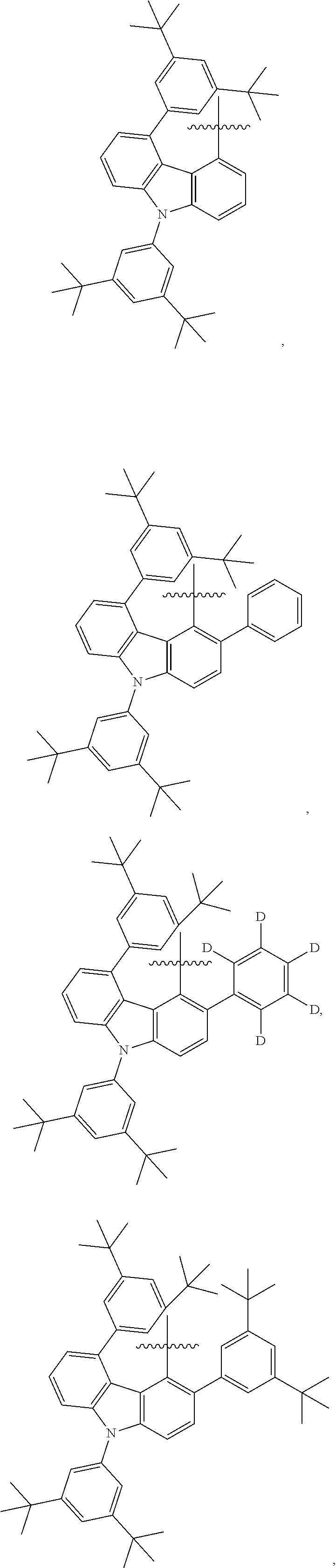

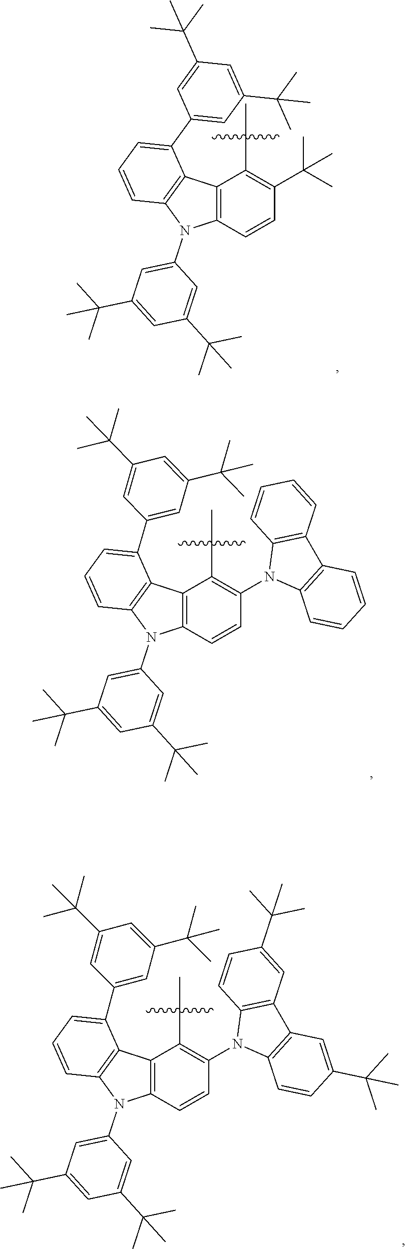

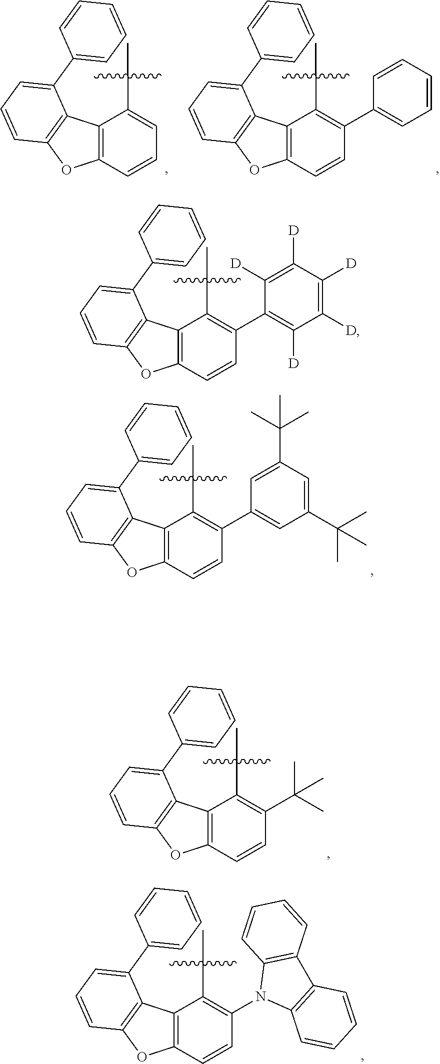

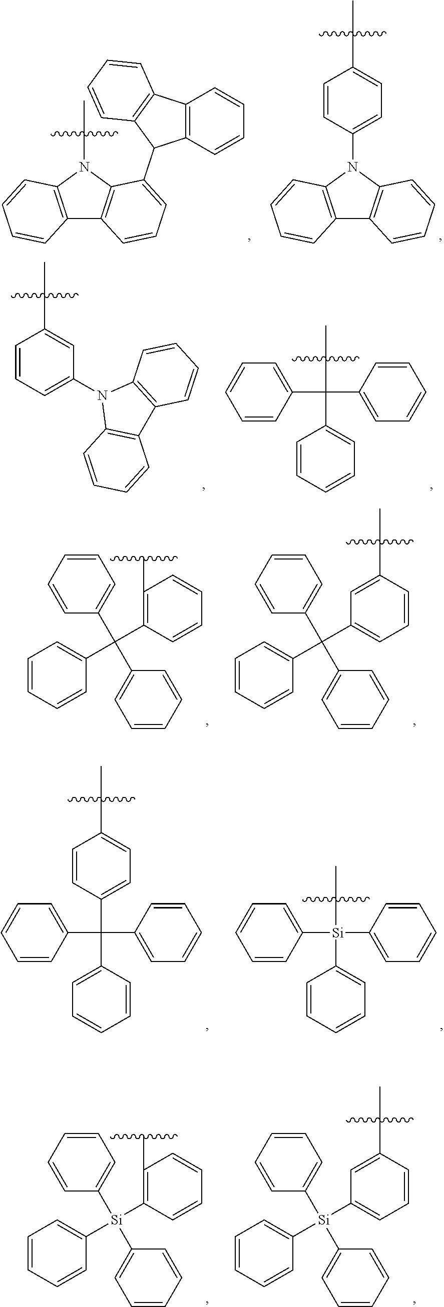

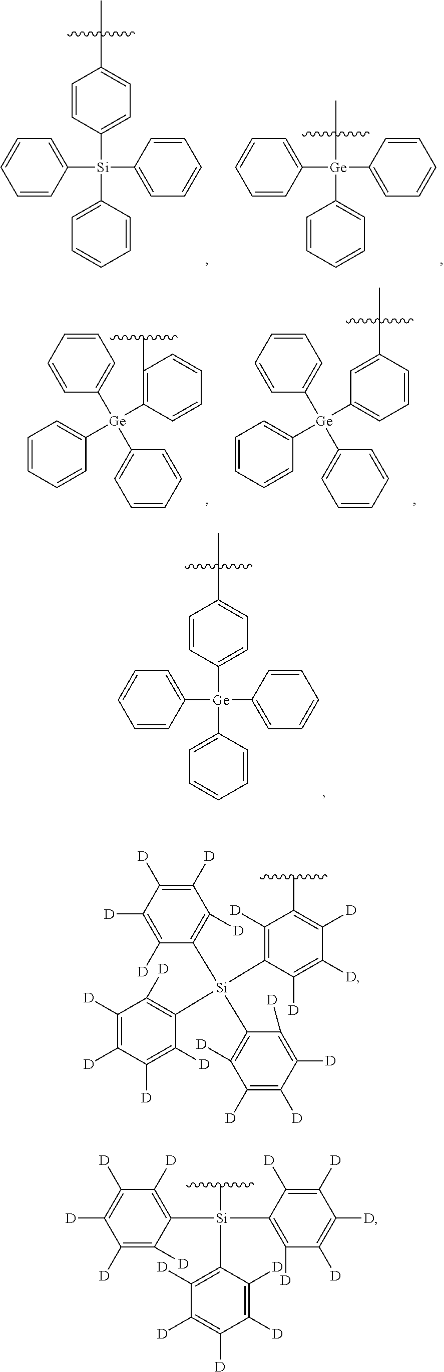

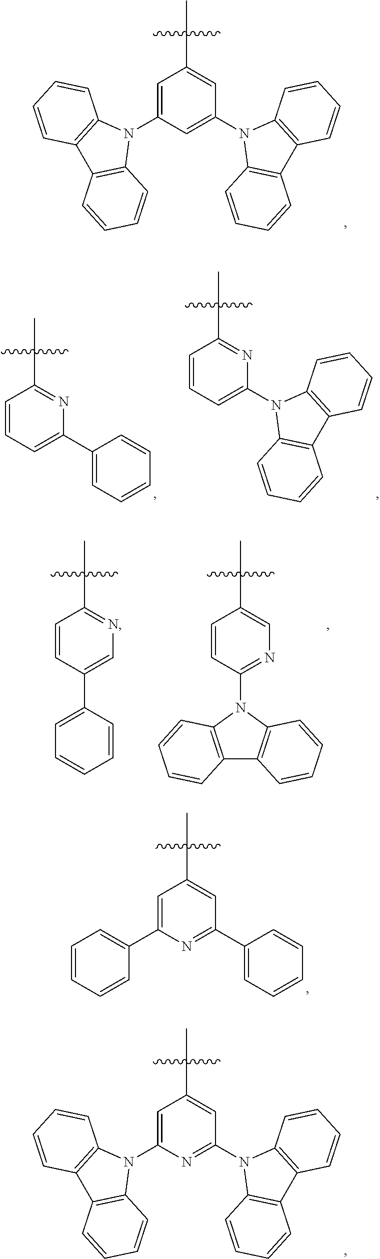

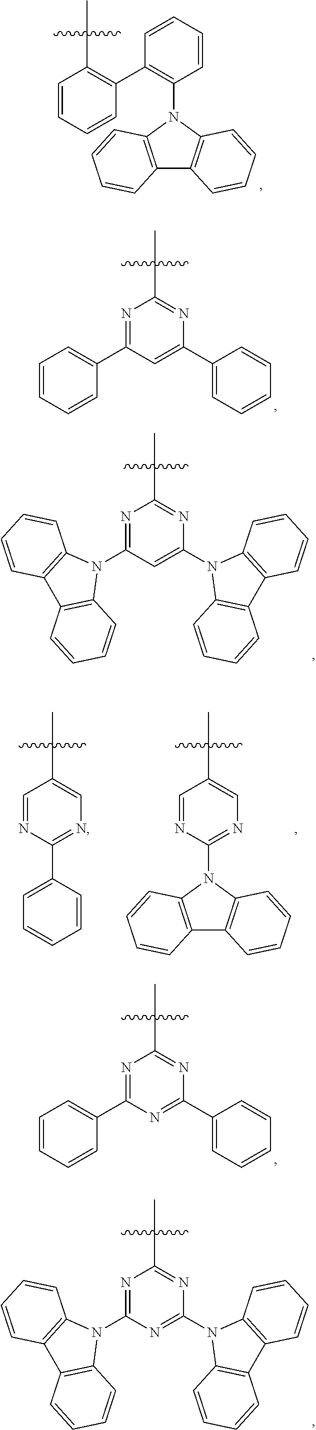

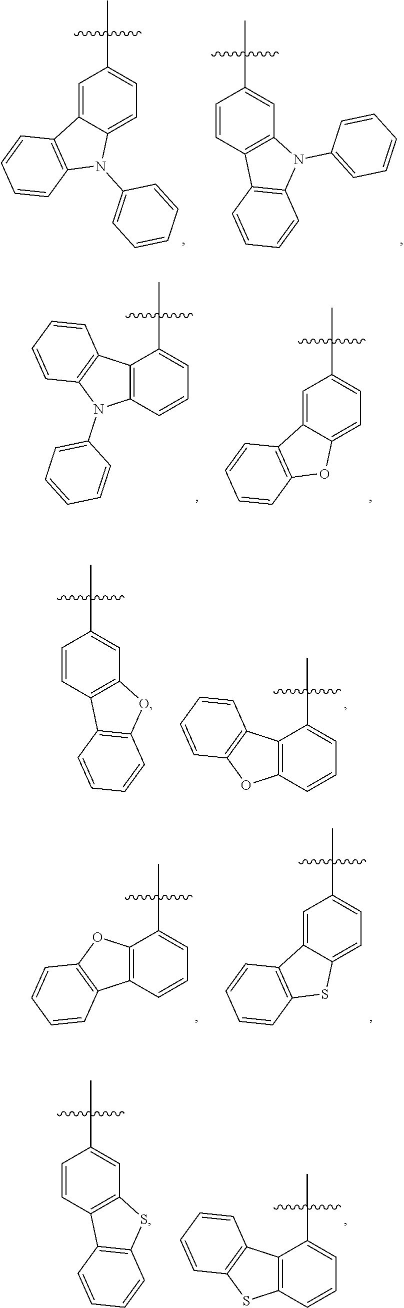

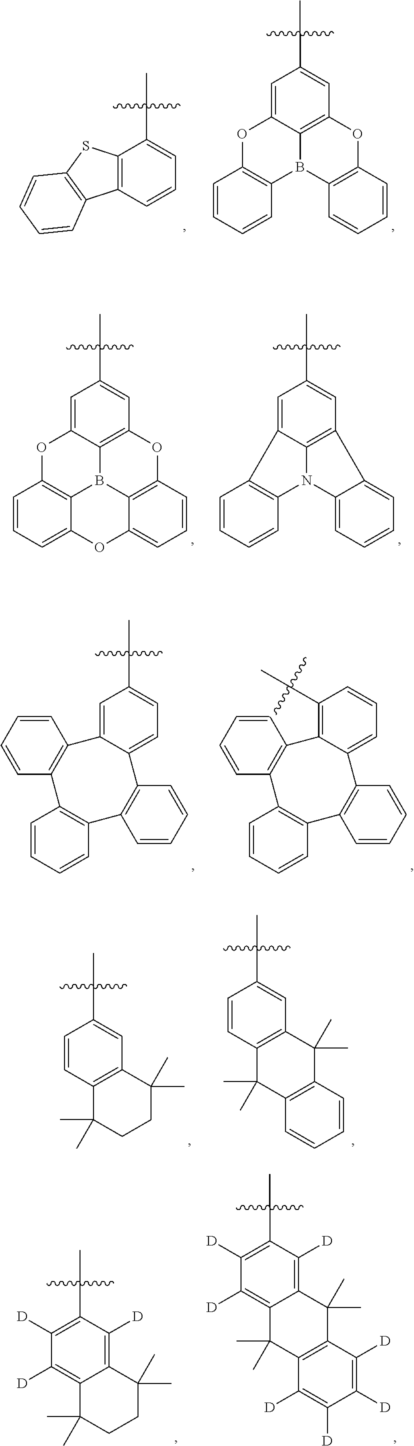

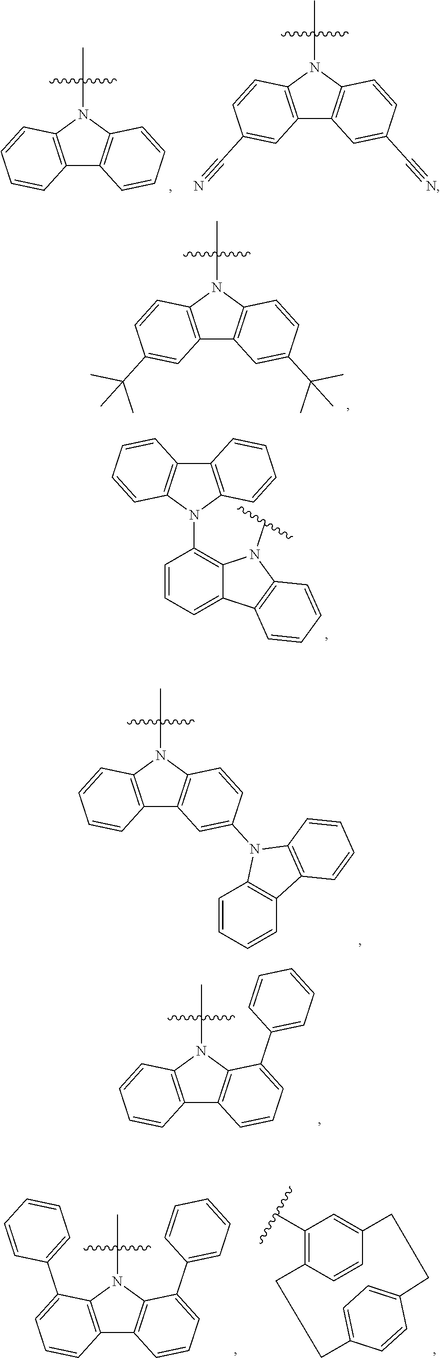

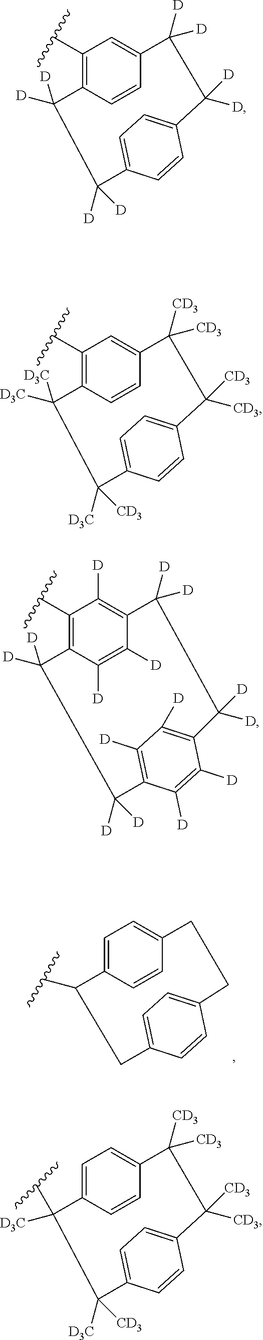

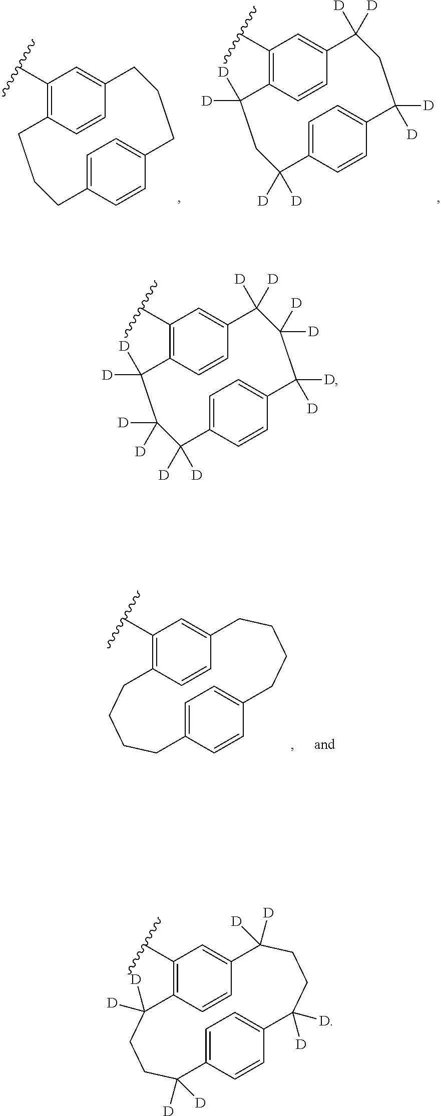

In some embodiments, the compound of the present disclosure comprises an electron-withdrawing group. In some embodiments, the electron-withdrawing group has a Hammett constant larger than 0. In some embodiments, the electron-withdrawing group has a Hammett constant equal or larger than 0.1, 0.2, 0.3, 0.4, 0.5, 0.6, 0.7, 0.8, 0.9, 1.0, or 1.1.

In some embodiments, the compound comprises an electron-withdrawn group selected from the group consisting of the structures of the following EWG1 LIST: F, CF₃, CN, COCH₃, CHO, COCF₃, COOMe, COOCF₃, NO₂, SF₃, SiF₃, PF₄, SFs, OCF₃, SCF₃, SeCF₃, SOCF₃, SeOCF₃, SO₂F, SO₂CF₃, SeO₂CF₃, OSeO₂CF₃, OCN, SCN, SeCN, NC, *N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

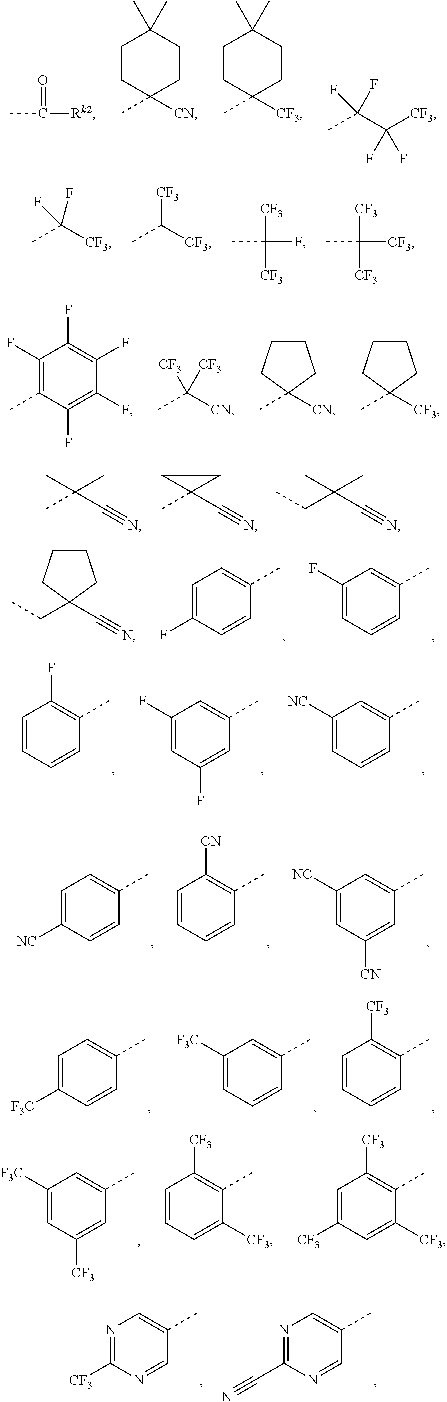

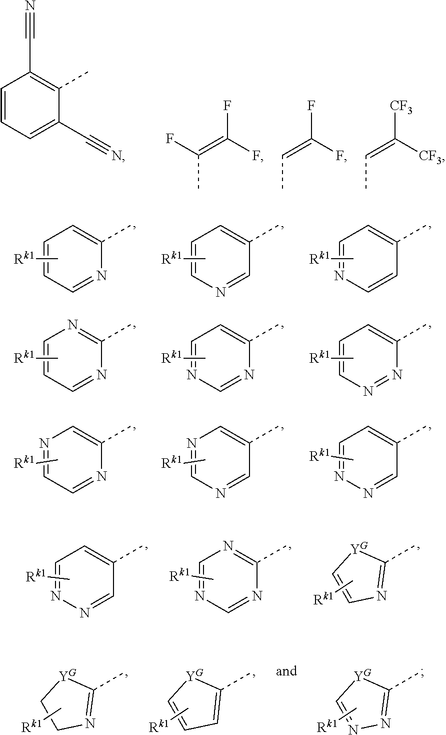

wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k1}, R^{k2}, R^{k3}, Rₑ, and R_{f} is independently a hydrogen or a substituent selected from the group consisting of the General Substituents defined herein.

In some embodiments, the compound comprises an electron-withdrawing group selected from the group consisting of the structures of the following EWG2 List:

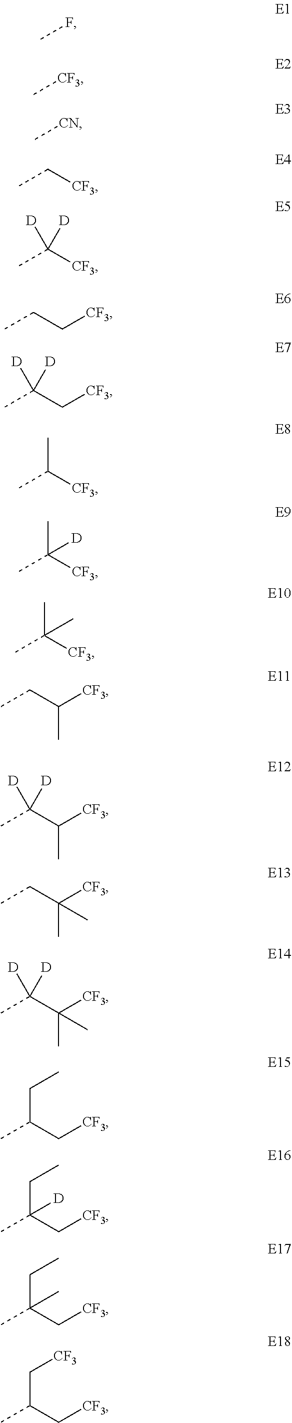

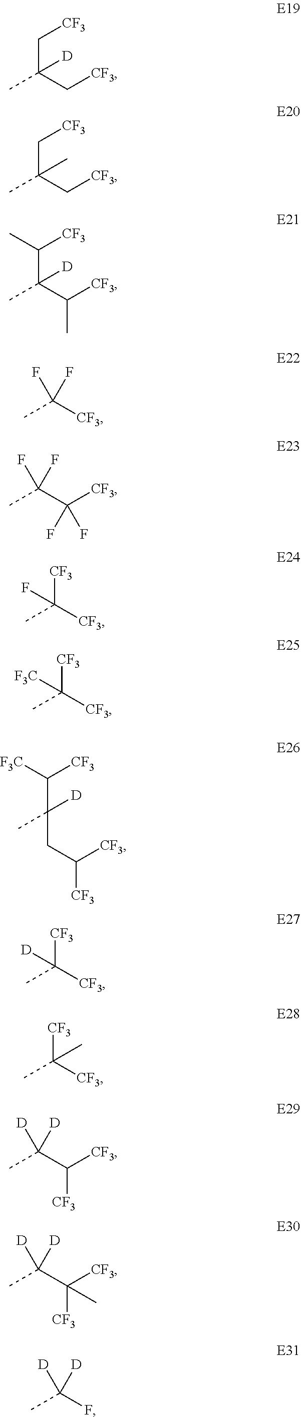

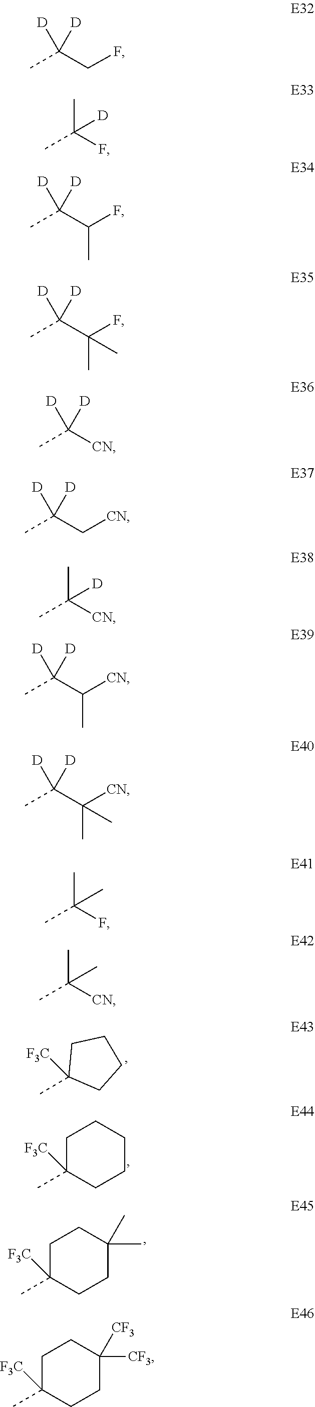

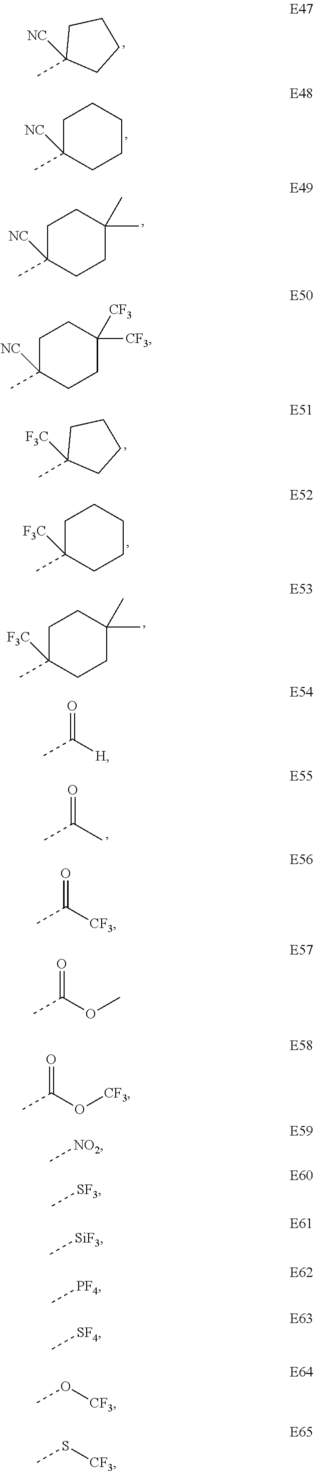

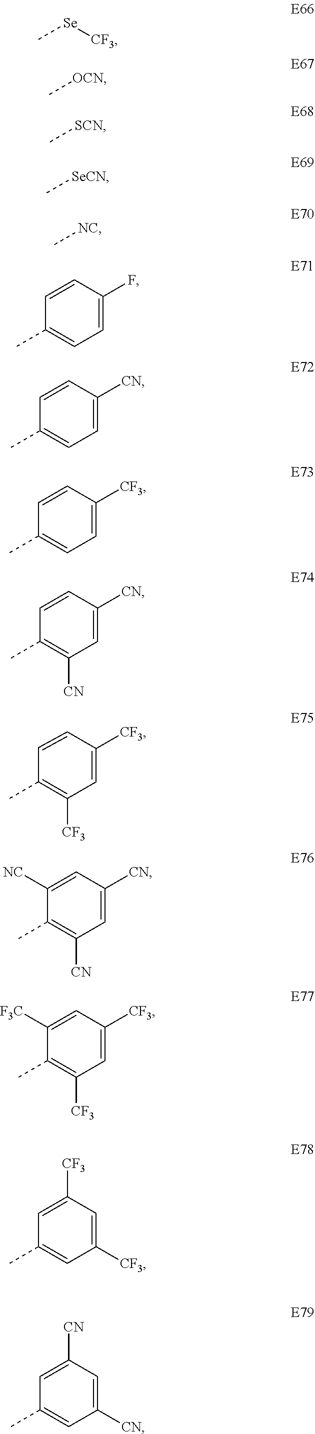

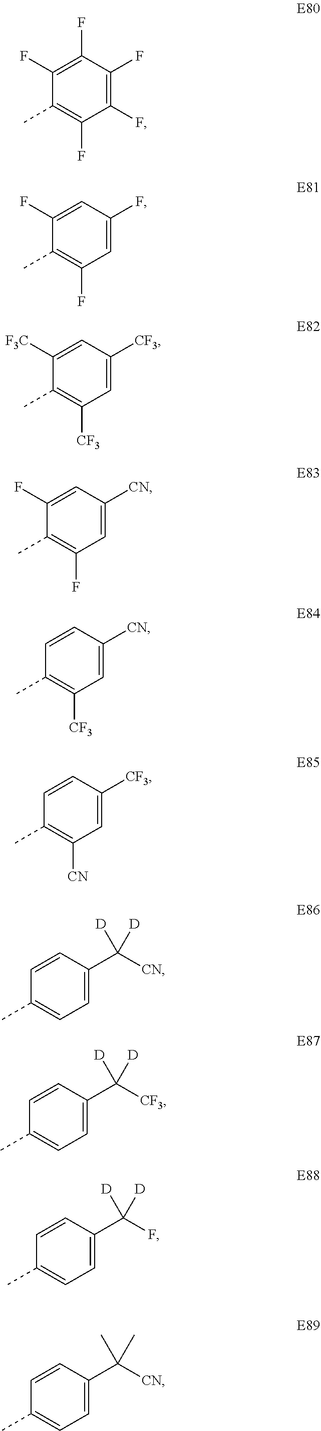

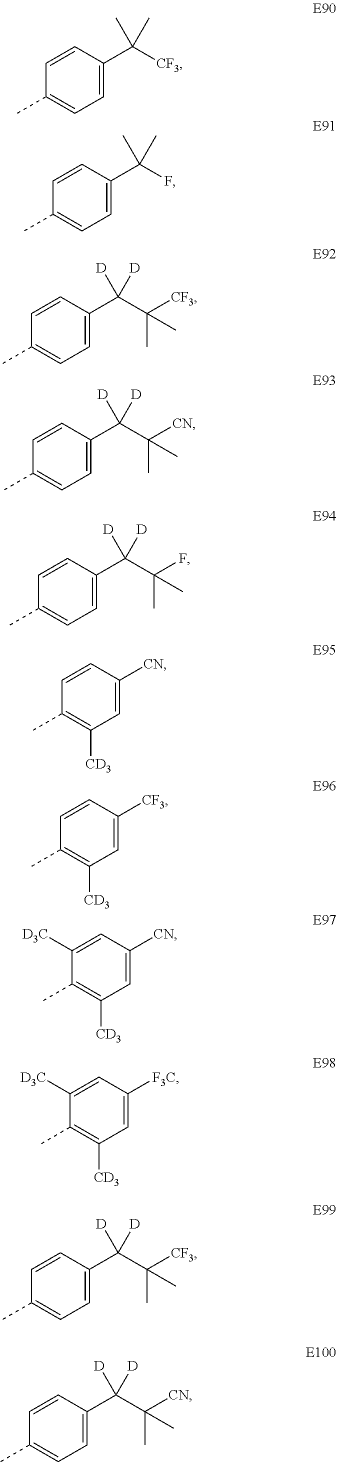

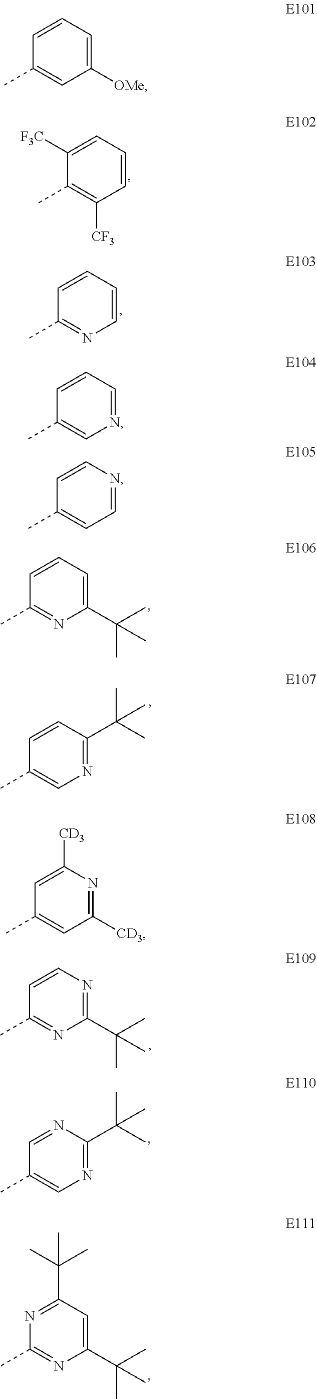

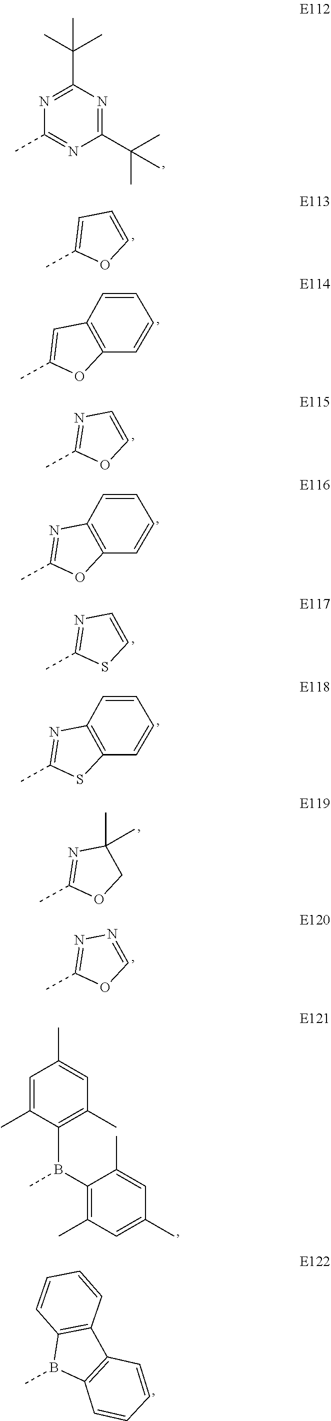

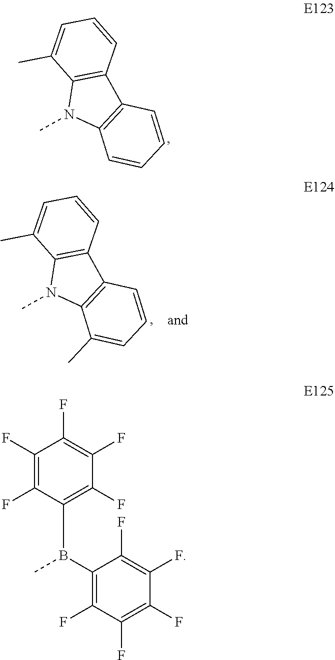

In some embodiments, the compound comprises an electron-withdrawing group selected from the group consisting of the structures of the following EWG3 LIST:

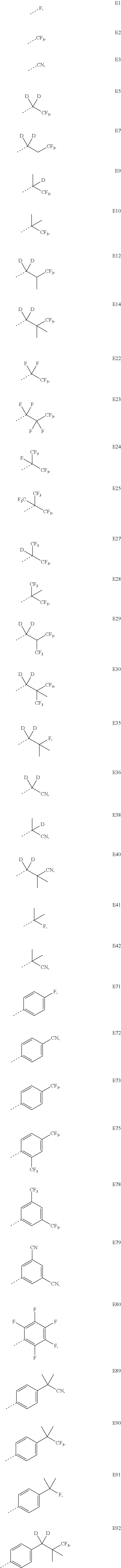

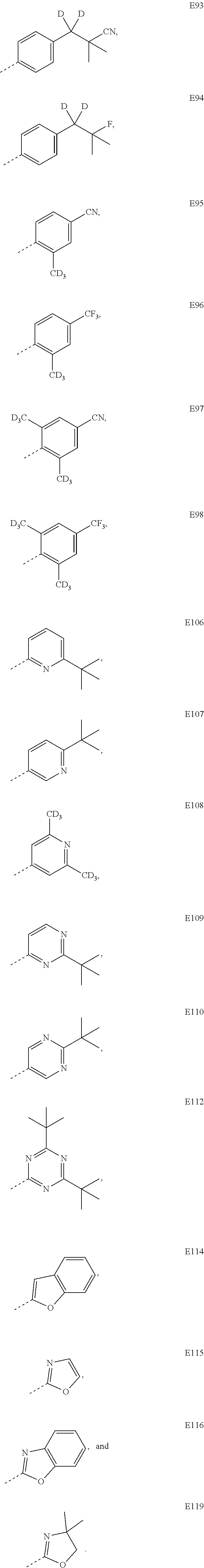

In some embodiments, the compound comprises an electron-withdrawing group selected from the group consisting of the structures of the following EWG4 LIST:

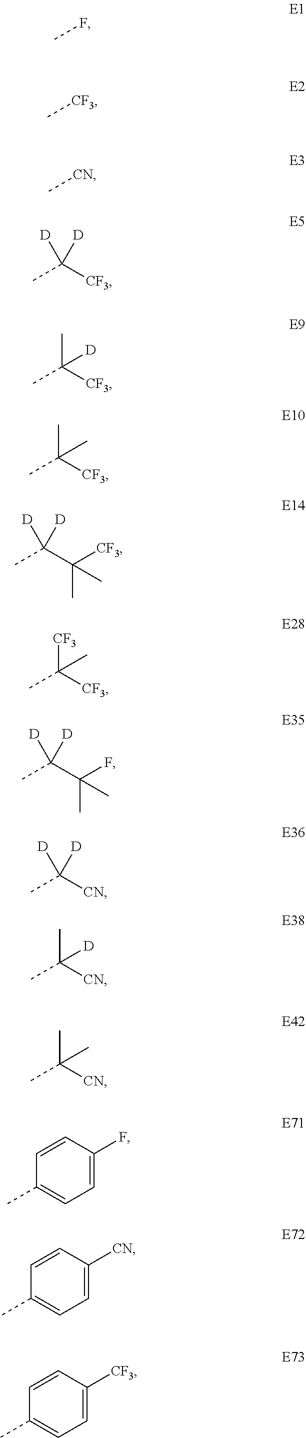

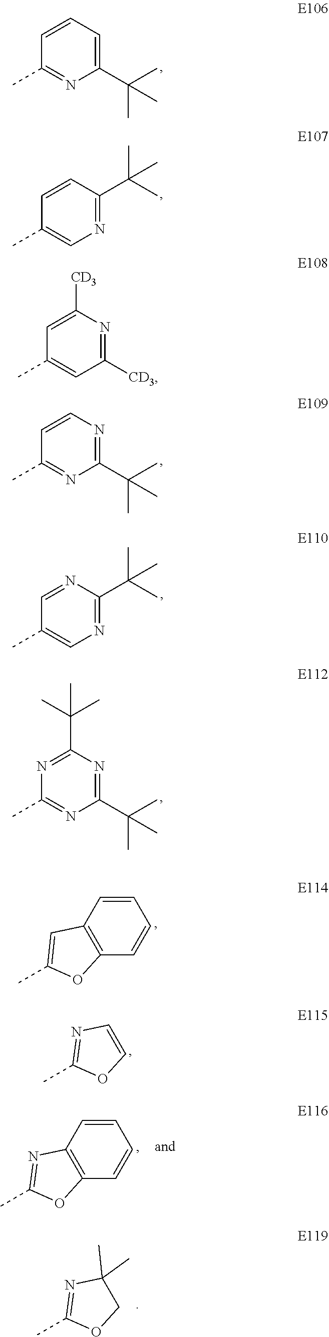

In some embodiments, the compound comprises an electron-withdrawing group that is a π-electron deficient electron-withdrawing group. In some embodiments, the n-electron deficient electron-withdrawing group is selected from the group consisting of the structures of the following Pi-EWG LIST: CN, COCH₃, CHO, COCF₃, COOMe, COOCF₃, NO₂, SF₃, SiF₃, PF₄, SFs, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, BR^{k2}R^{k3}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

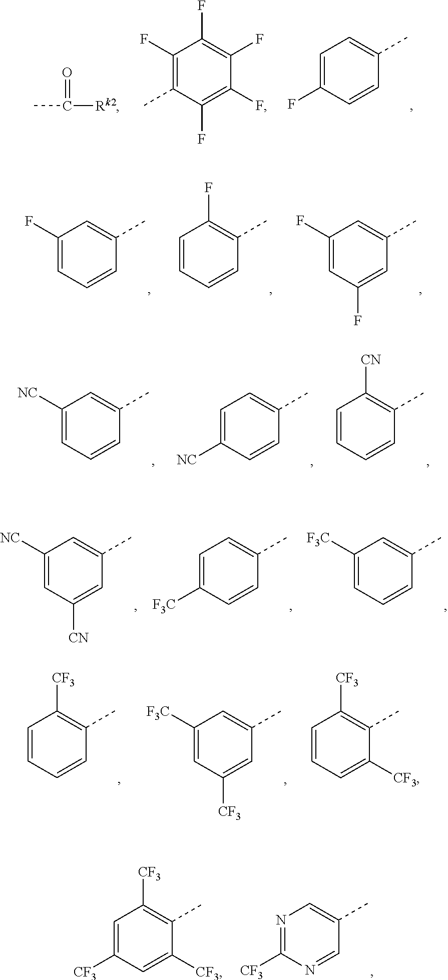

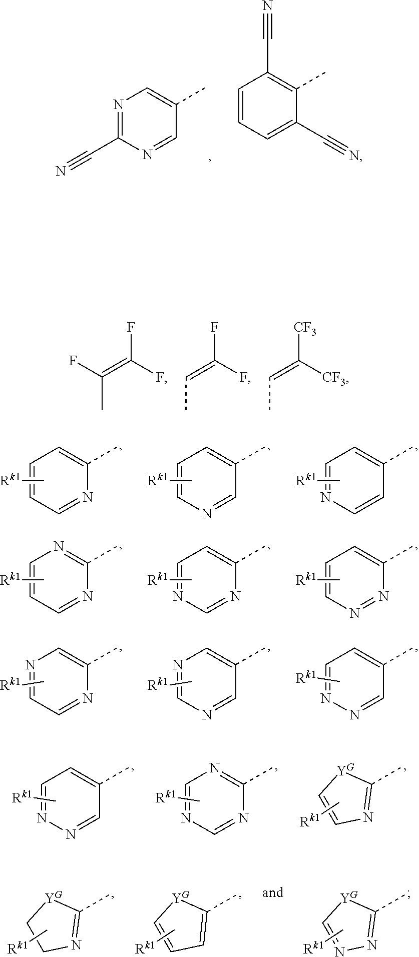

wherein the variables are the same as previously defined.

In some embodiments of the compound of Formula I, at least one of R^{A}, R^{B}, R^{c}, R^{D}, R^{E}, and R^{F} is or comprises an electron-withdrawing group from the EWG1 LIST as defined herein. In some embodiments, at least one of R^{A}, R^{B}, R^{c}, R^{D}, R^{E}, and R^{F} is or comprises an electron-withdrawing group from the EWG2 LIST as defined herein. In some embodiments, at least one of R^{A}, R^{B}, R^{c}, R^{D}, R^{E}, and R^{F} is or comprises an electron-withdrawing group from the EWG3 LIST as defined herein. In some embodiments, at least one of R^{A}, R^{B}, R^{c}, R^{D}, R^{E}, and R^{F} is or comprises an electron-withdrawing group from the EWG4 LIST as defined herein. In some embodiments, at least one of R^{A}, R^{B}, R^{c}, R^{D}, R^{E}, and R^{F} is or comprises an electron-withdrawing group from the Pi-EWG LIST as defined herein.

In some embodiments, at least one R^{A} is or comprises an electron-withdrawing group from the EWG1 LIST as defined herein. In some embodiments, at least one R^{A} is or comprises an electron-withdrawing group from the EWG2 LIST as defined herein. In some embodiments, at least one R^{A} is or comprises an electron-withdrawing group from the EWG3 LIST as defined herein. In some embodiments, at least one R^{A} is or comprises an electron-withdrawing group from the EWG4 LIST as defined herein. In some embodiments, at least one R^{A} is or comprises an electron-withdrawing group from the Pi-EWG LIST as defined herein.

In some embodiments, at least one R^{B} is or comprises an electron-withdrawing group from the EWG1 LIST as defined herein. In some embodiments, at least one R^{B} is or comprises an electron-withdrawing group from the EWG2 LIST as defined herein. In some embodiments, at least one R^{B} is or comprises an electron-withdrawing group from the EWG3 LIST as defined herein. In some embodiments, at least one R^{B} is or comprises an electron-withdrawing group from the EWG4 LIST as defined herein. In some embodiments, at least one R^{B} is or comprises an electron-withdrawing group from the Pi-EWG LIST as defined herein

In some embodiments, at least one R^{c} is or comprises an electron-withdrawing group from the EWG1 LIST as defined herein. In some embodiments, at least one R^{c} is or comprises an electron-withdrawing group from the EWG2 LIST as defined herein. In some embodiments, at least one R^{c} is or comprises an electron-withdrawing group from the EWG3 LIST as defined herein. In some embodiments, at least one R^{c} is or comprises an electron-withdrawing group from the EWG4 LIST as defined herein. In some embodiments, at least one R^{c} is or comprises an electron-withdrawing group from the Pi-EWG LIST as defined herein.

In some embodiments, at least one R^{D} is or comprises an electron-withdrawing group from the EWG1 LIST as defined herein. In some embodiments, at least one R^{D} is or comprises an electron-withdrawing group from the EWG2 LIST as defined herein. In some embodiments, at least one R^{D} is or comprises an electron-withdrawing group from the EWG3 LIST as defined herein. In some embodiments, at least one R^{D} is or comprises an electron-withdrawing group from the EWG4 LIST as defined herein. In some embodiments, at least one R^{D} is or comprises an electron-withdrawing group from the Pi-EWG LIST as defined herein.

In some embodiments, at least one R^{E} is or comprises an electron-withdrawing group from the EWG1 LIST as defined herein. In some embodiments, at least one R^{E} is or comprises an electron-withdrawing group from the EWG2 LIST as defined herein. In some embodiments, at least one R^{E} is or comprises an electron-withdrawing group from the EWG3 LIST as defined herein. In some embodiments, at least one R^{E} is or comprises an electron-withdrawing group from the EWG4 LIST as defined herein. In some embodiments, at least one R^{E} is or comprises an electron-withdrawing group from the Pi-EWG LIST as defined herein.

In some embodiments, at least one R^{F} is or comprises an electron-withdrawing group from the EWG1 LIST as defined herein. In some embodiments, at least one R^{F} is or comprises an electron-withdrawing group from the EWG2 LIST as defined herein. In some embodiments, at least one R^{F} is or comprises an electron-withdrawing group from the EWG3 LIST as defined herein. In some embodiments, at least one R^{F} is or comprises an electron-withdrawing group from the EWG4 LIST as defined herein. In some embodiments, at least one R^{F} is or comprises an electron-withdrawing group from the Pi-EWG LIST as defined herein.

In some embodiments of the compound of Formula I, at least one of R^{A}, R^{B}, R^{c}, R^{D}, R^{E}, or R^{F} is partially or fully deuterated. In some embodiments, at least one R^{A} is partially or fully deuterated. In some embodiments, at least one R^{B}, is partially or fully deuterated. In some embodiments, at least one R^{D} is partially or fully deuterated. In some embodiments, at least one R^{E}, is partially or fully deuterated. In some embodiments, at least one R^{F} is partially or fully deuterated.

In some embodiments, the compound is selected from the group consisting of compounds having the formula of Pt(L_{A′})(Ly):

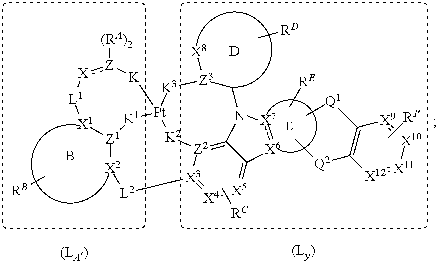

wherein L_{A′} is from the group consisting of the structures shown in the following LIST 4:

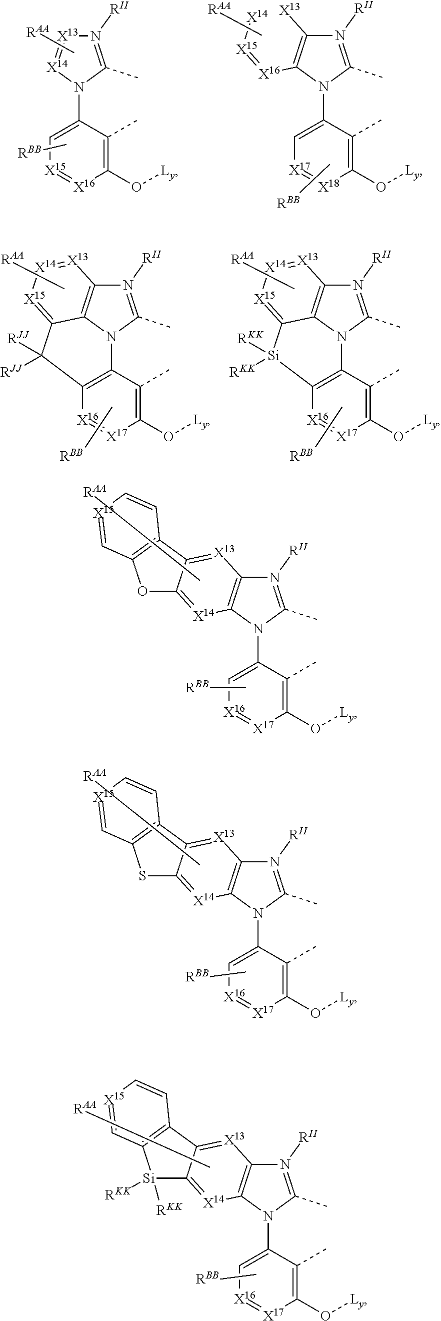

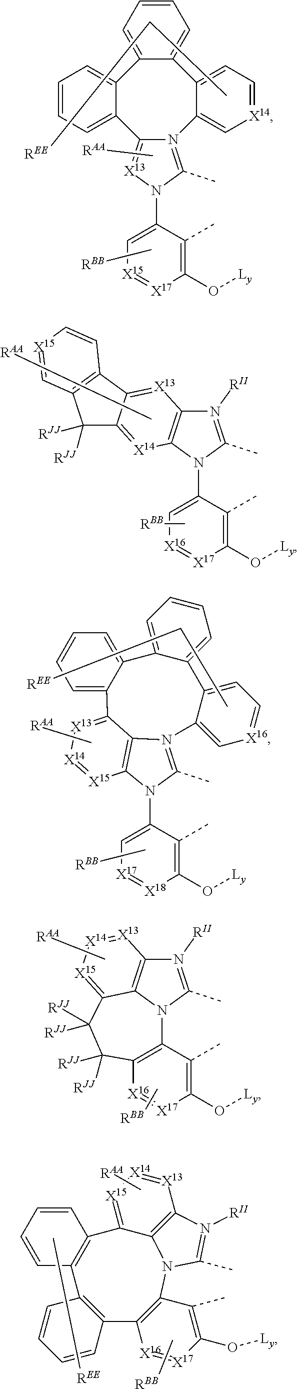

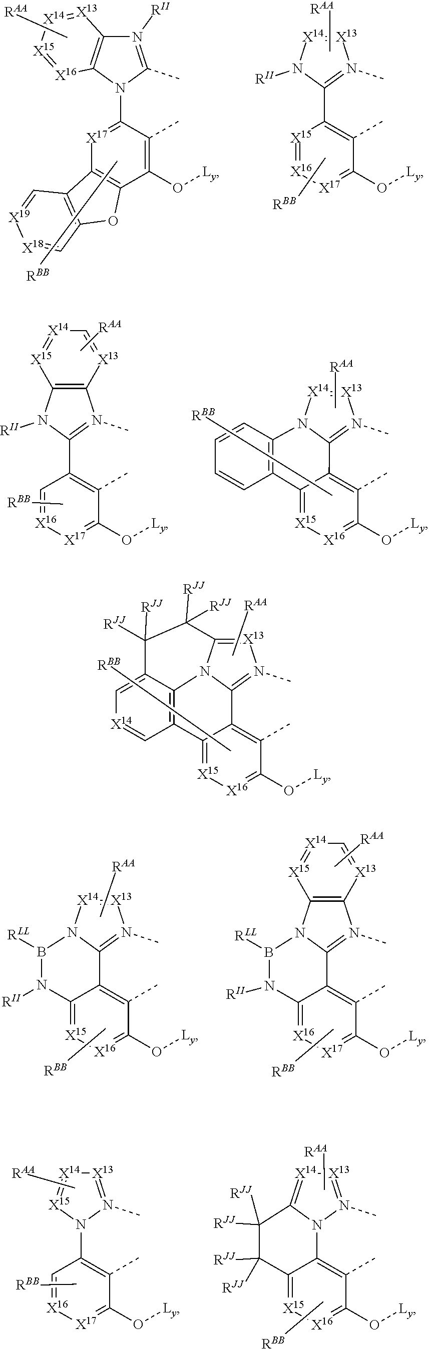

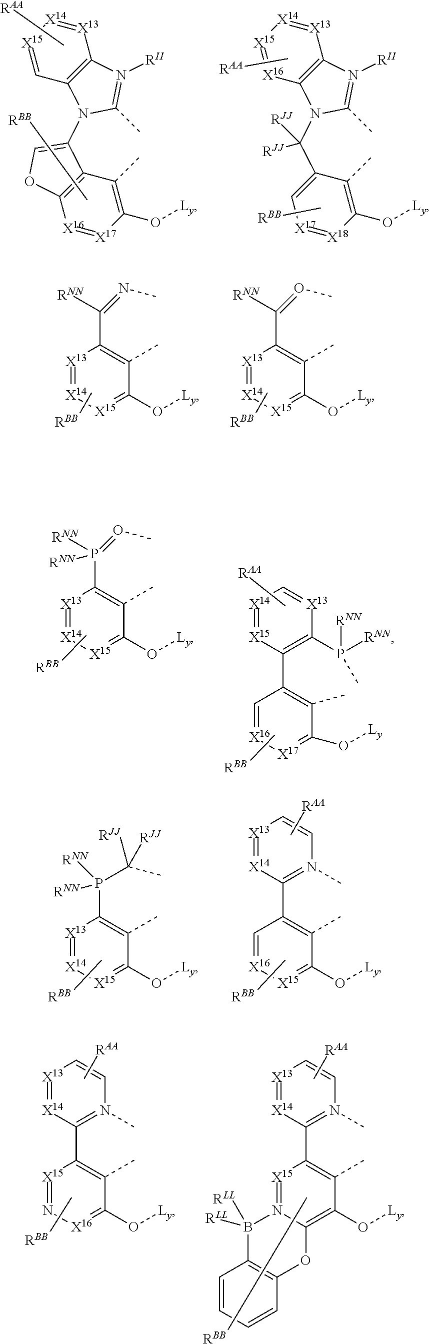

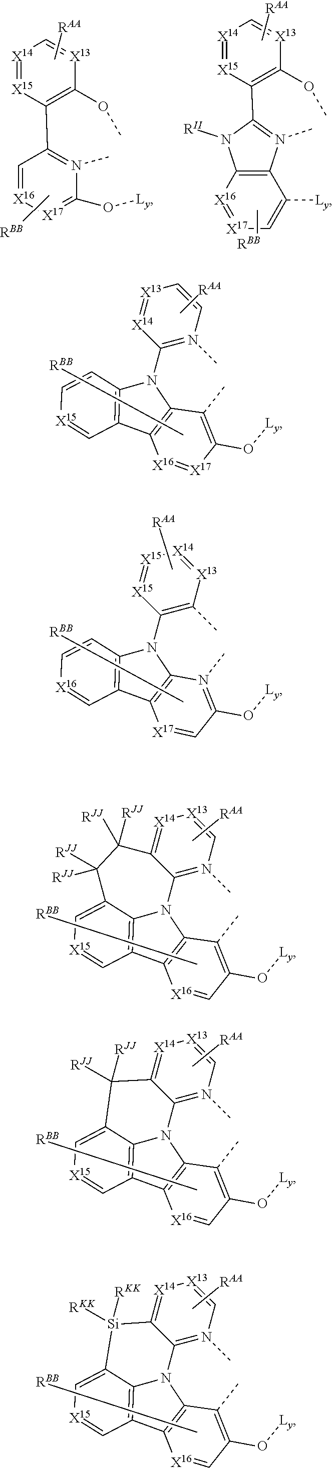

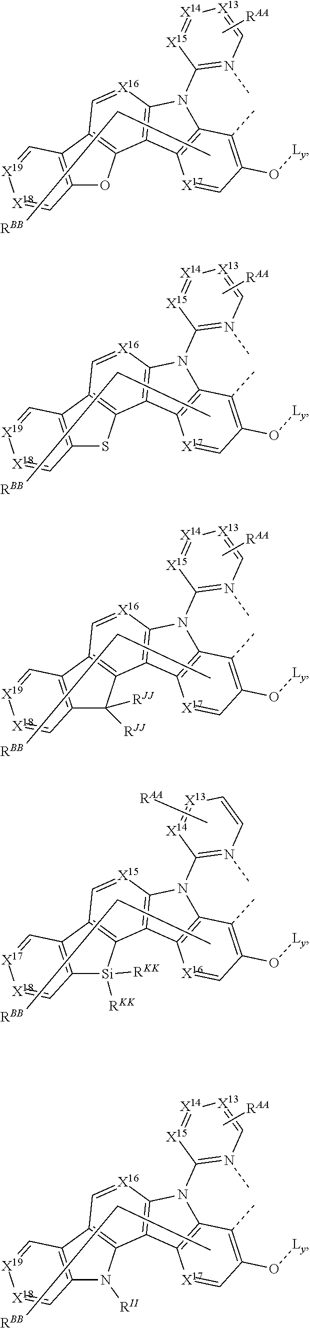

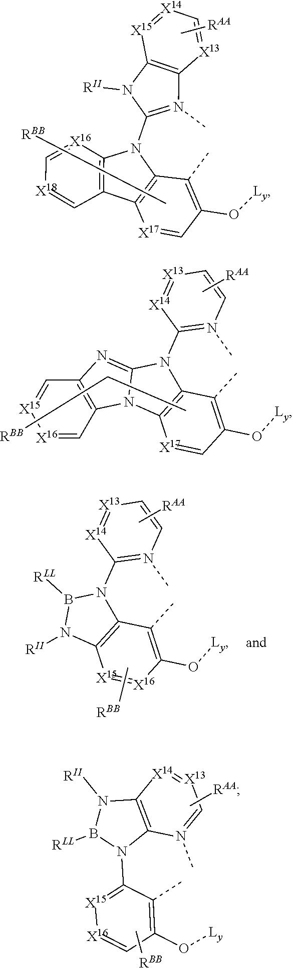

wherein L_{y} is selected from the group consisting of the structures shown in the following LIST 5:

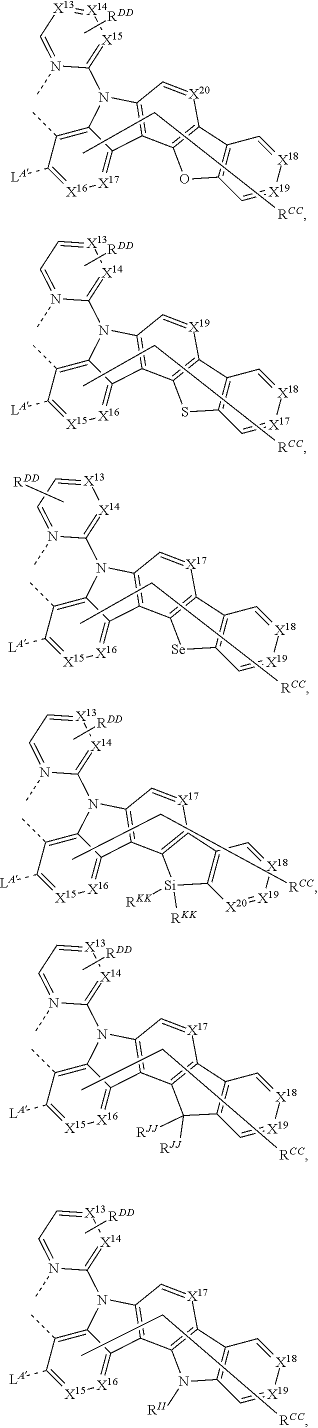

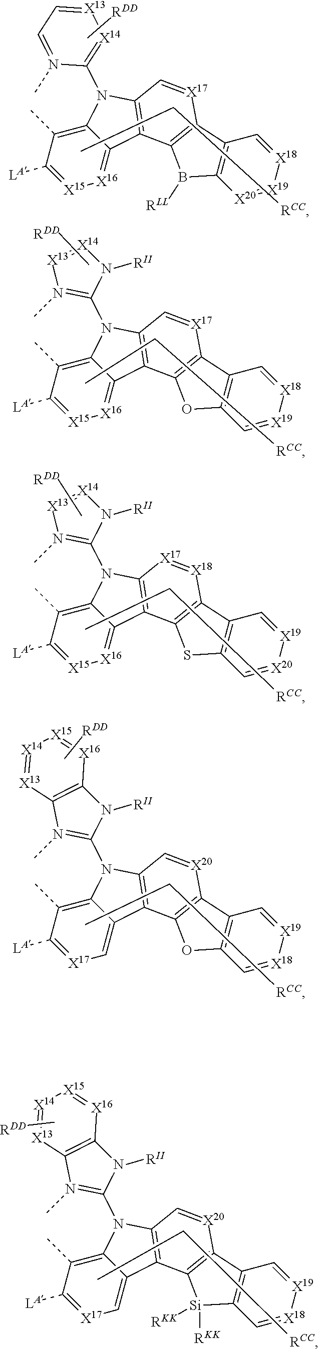

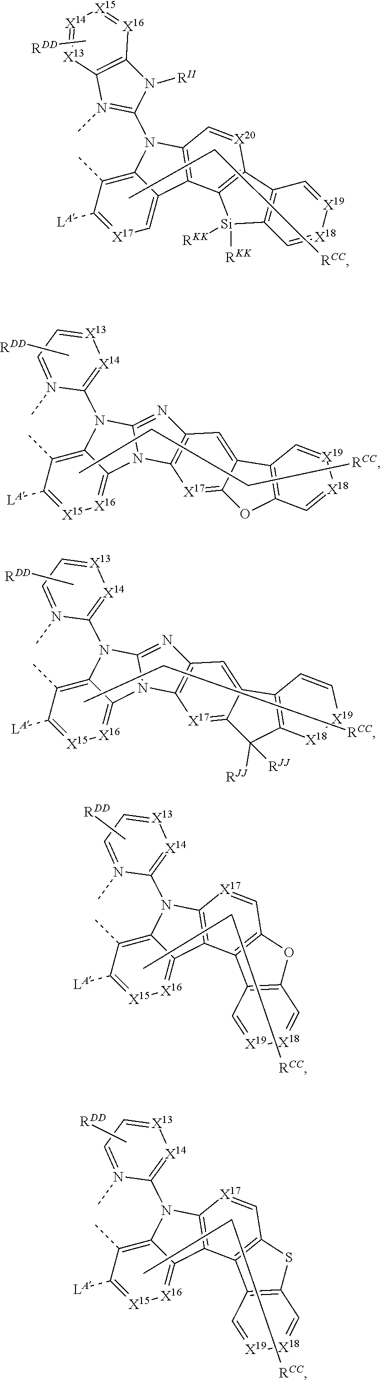

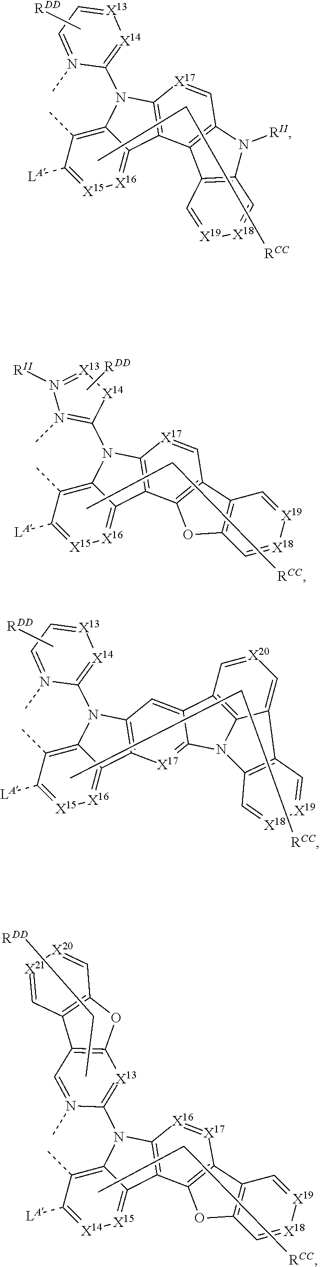

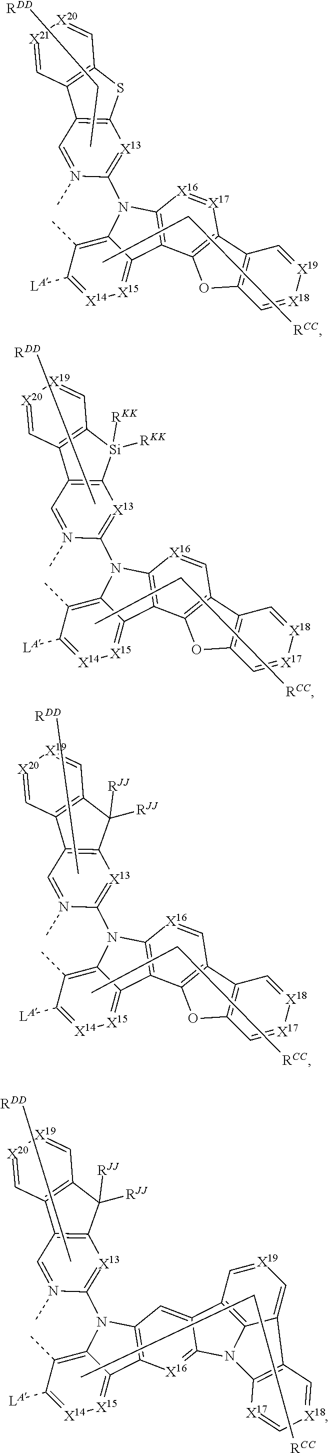

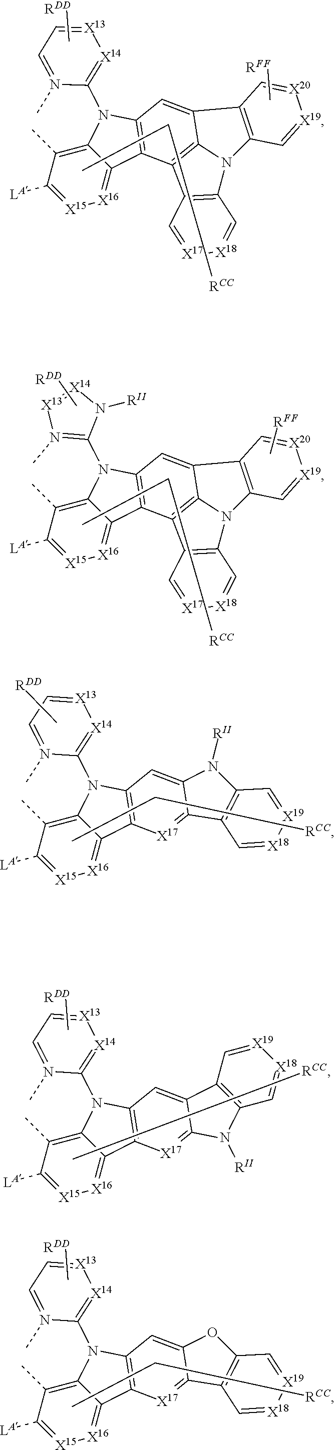

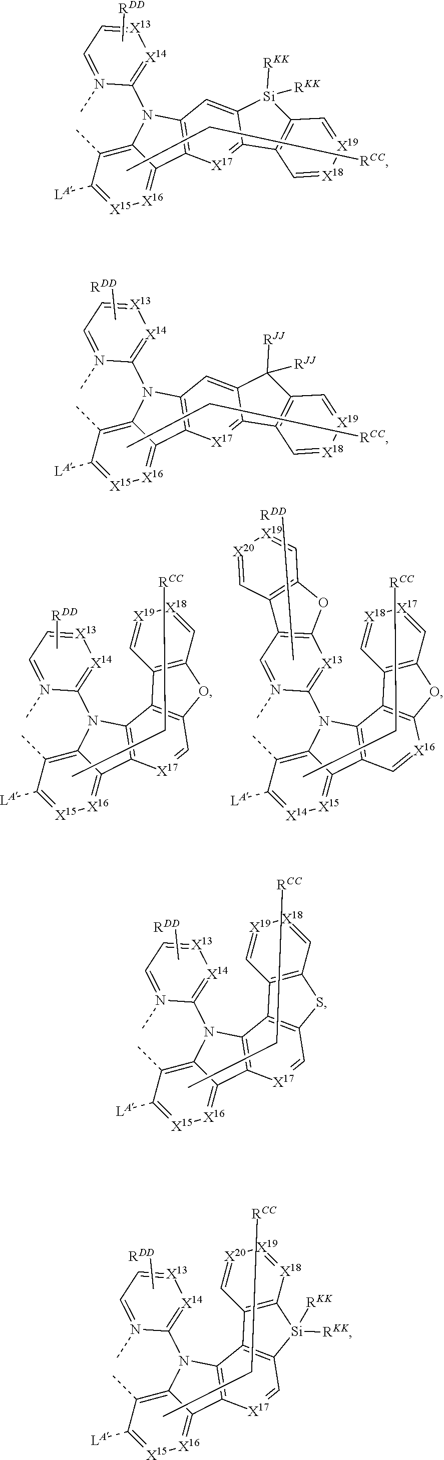

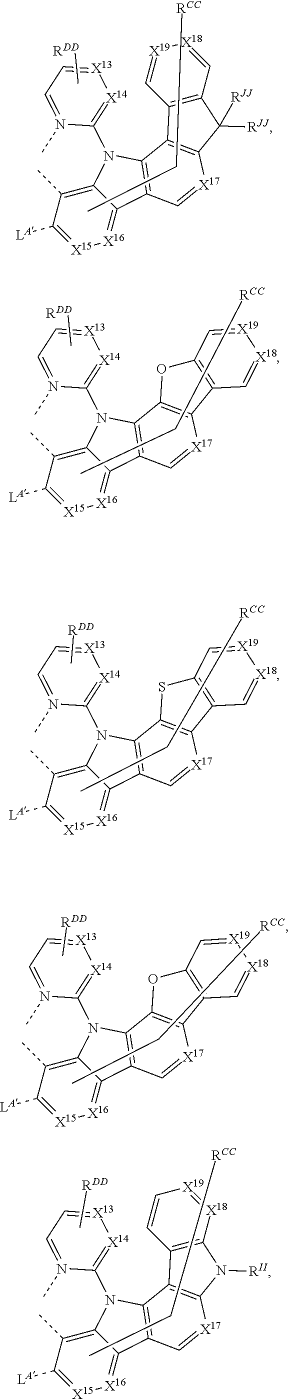

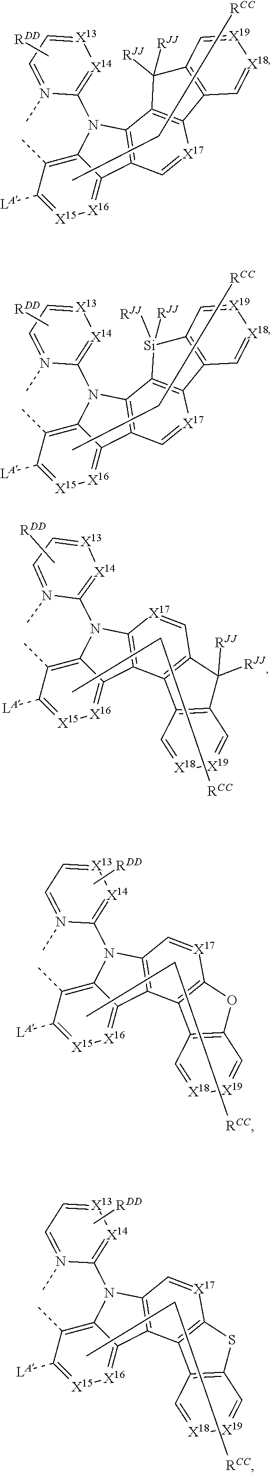

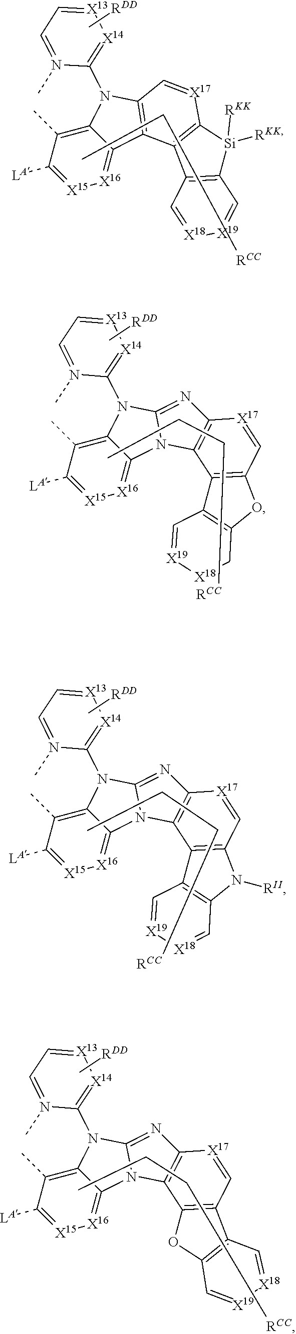

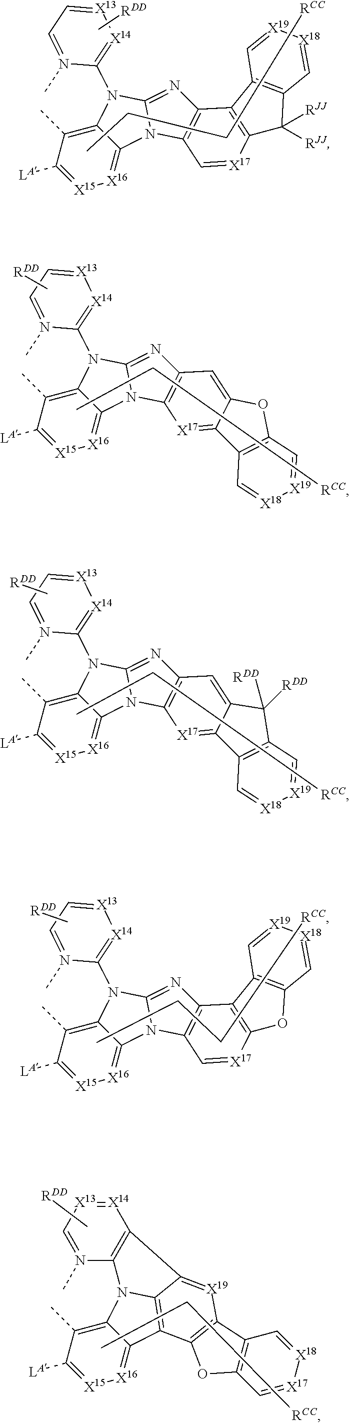

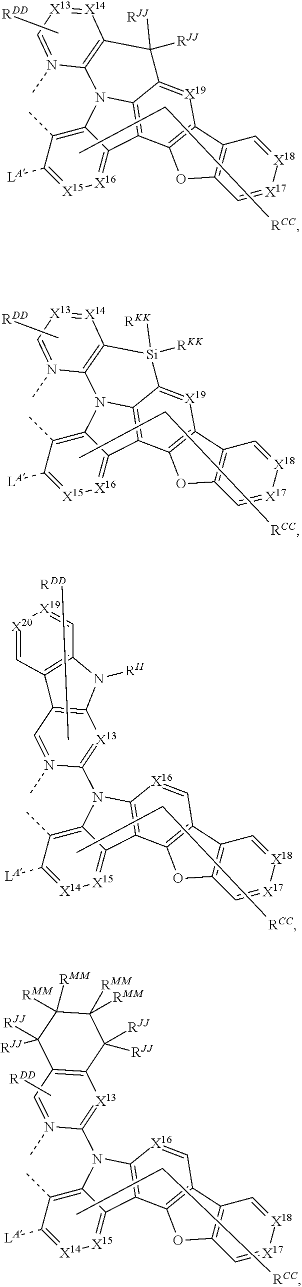

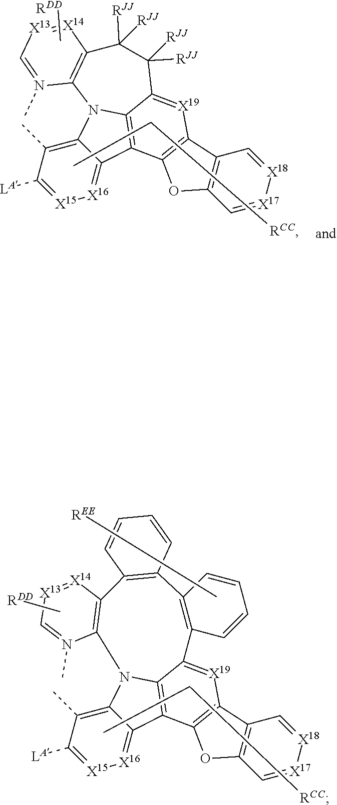

wherein each of X¹³ to X²¹ is independently C or N;
wherein R^{AA}, R^{BB}, R^{CC}, R^{DD}, and R^{EE} each independently represent mono up to the maximum possible substitutions, or no substitutions;
wherein each R^{AA}, R^{BB}, R^{CC}, R^{DD}, R^{EE}, R^{FF}, R^{II}, R^{JJ}, R^{KK}, R^{LL}, R^{MM}, and R^{NN} is independently selected from the group consisting of the structures of the following LIST 6:

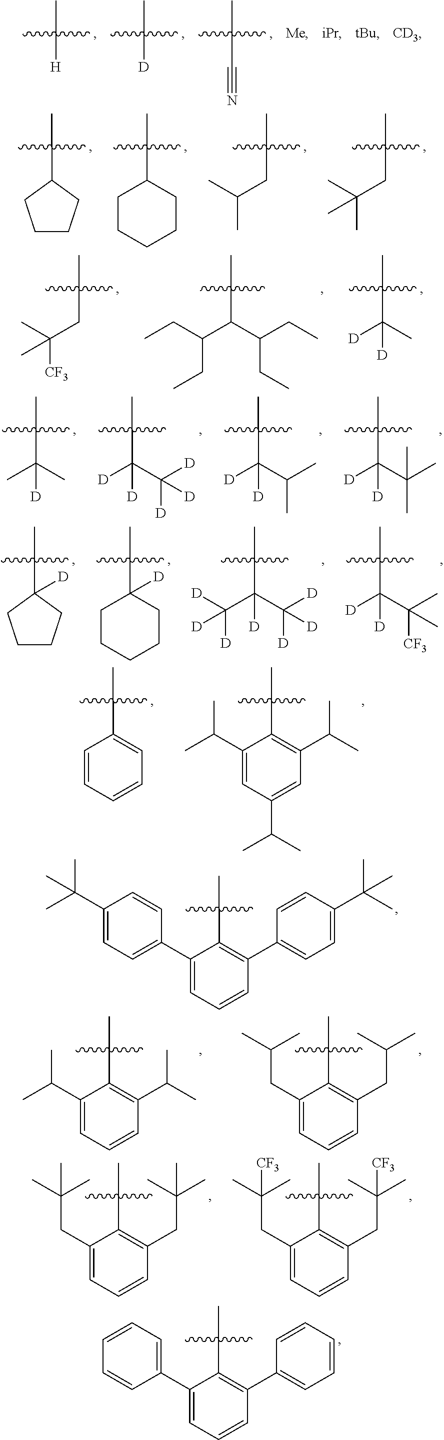

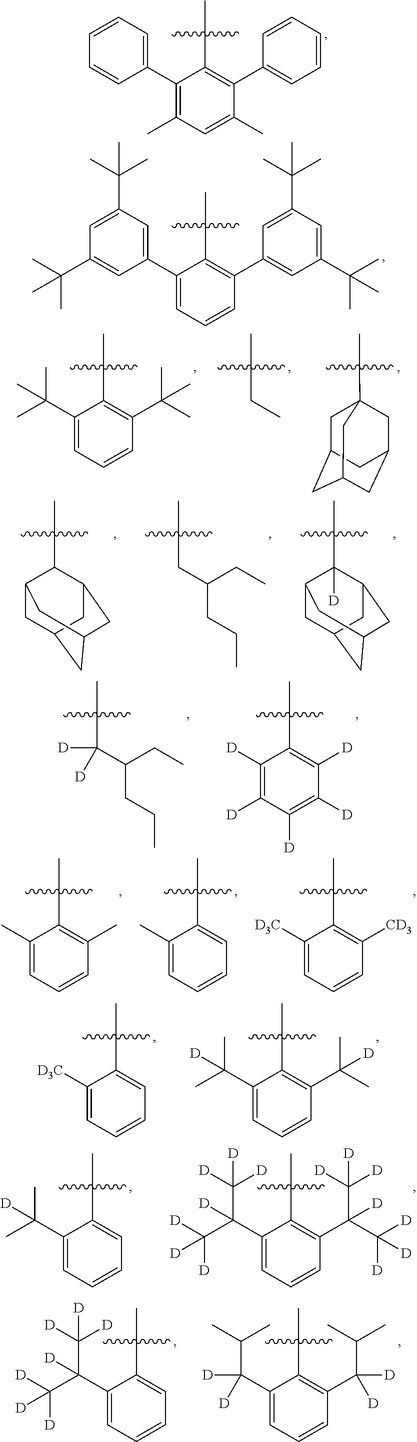

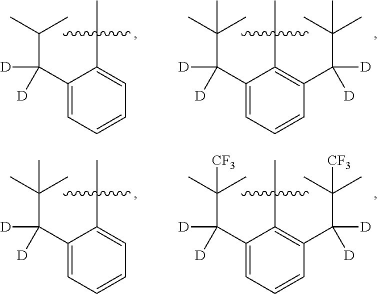 [SMILES: *c1ccccc1C([2H])([2H])C(C)C ; *c1c(C([2H])([2H])C(C)(C)C)cccc1C([2H])([2H])C(C)(C)C ; *c1ccccc1C([2H])([2H])C(C)(C)C ; *c1c(C([2H])([2H])C(C)(C)C(F)(F)F)cccc1C([2H])([2H])C(C)(C)C(F)(F)F]

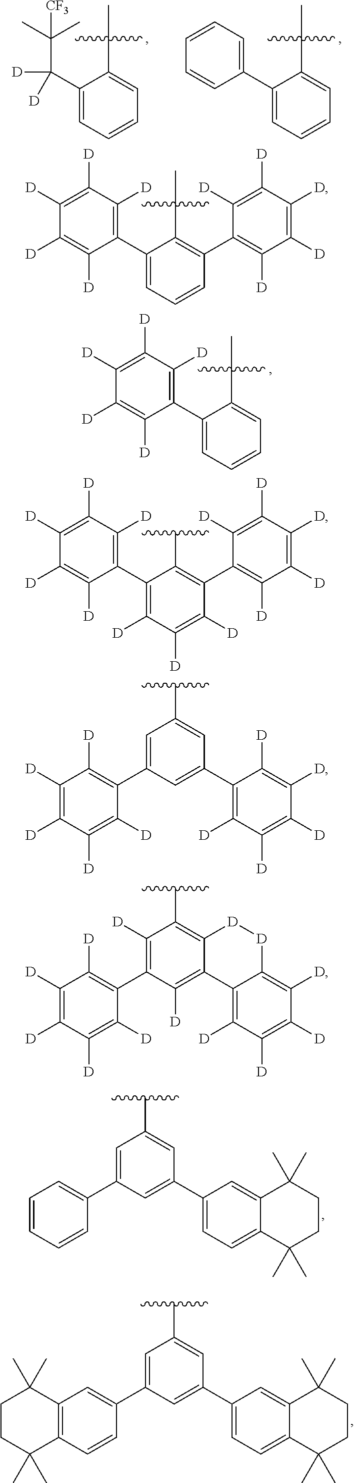

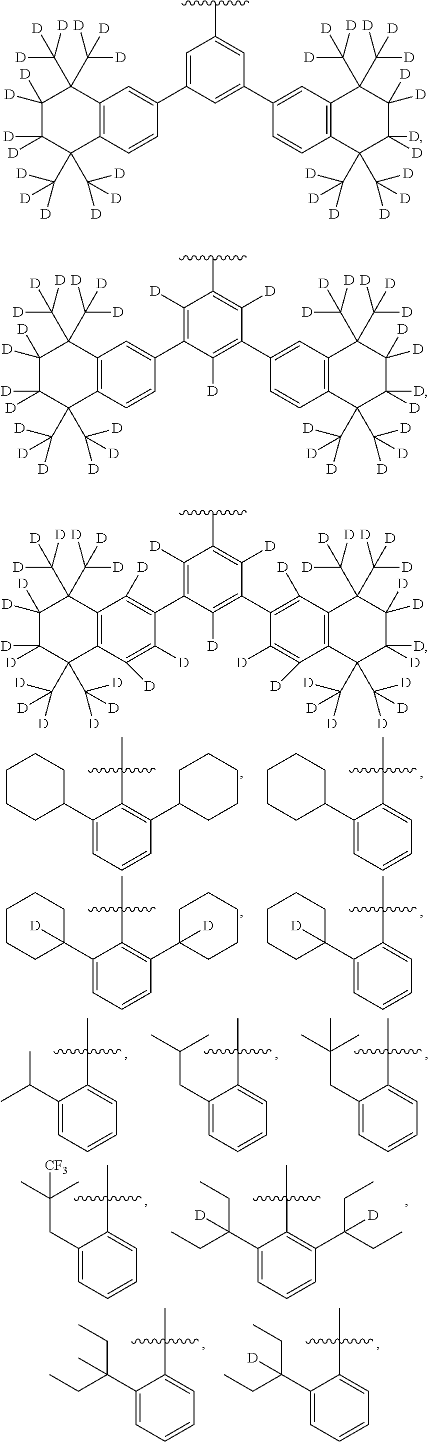

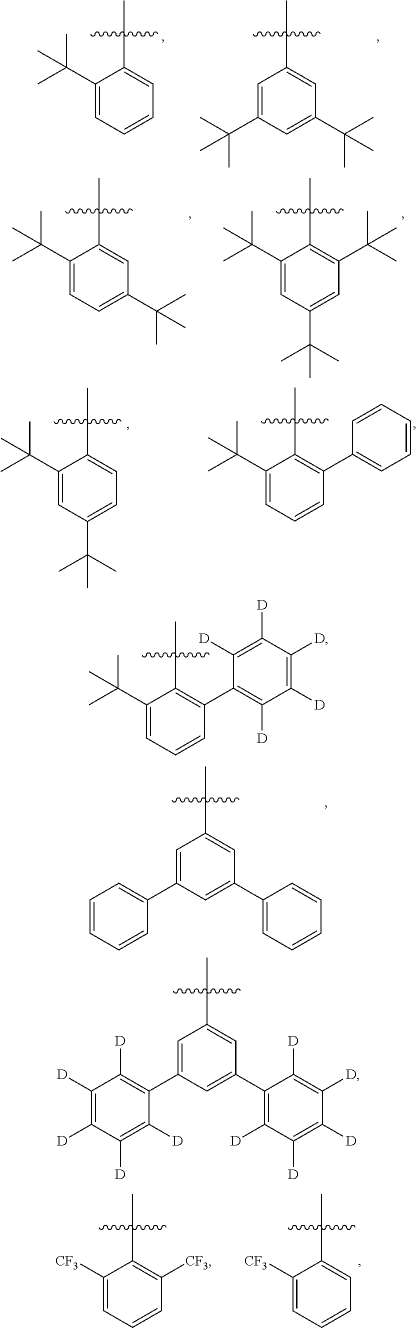

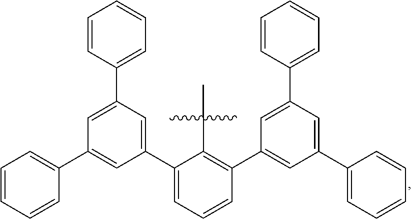 [SMILES: *c1c(-c2cc(-c3ccccc3)cc(-c3ccccc3)c2)cccc1-c1cc(-c2ccccc2)cc(-c2ccccc2)c1]

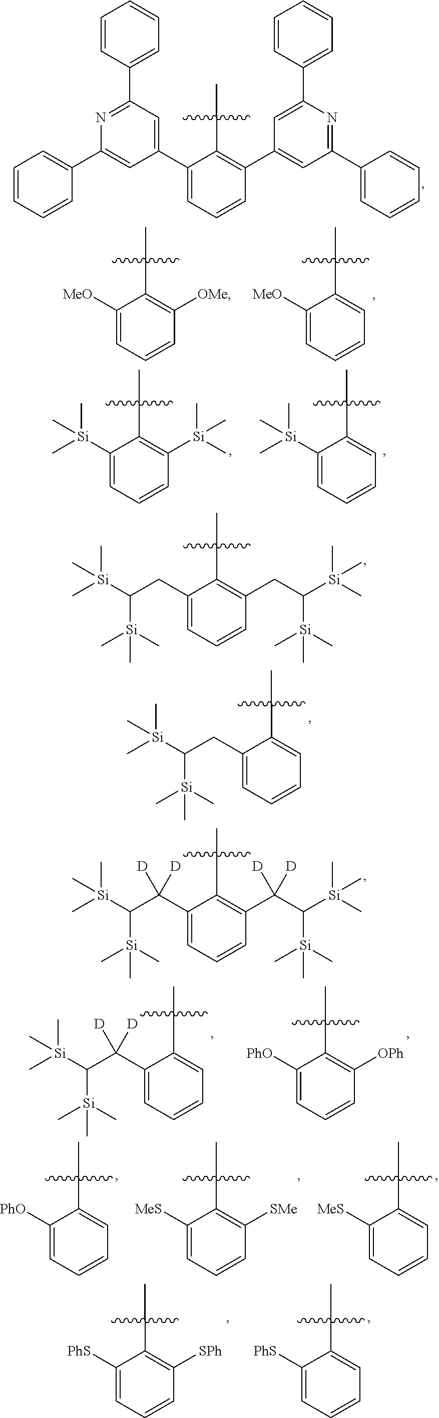

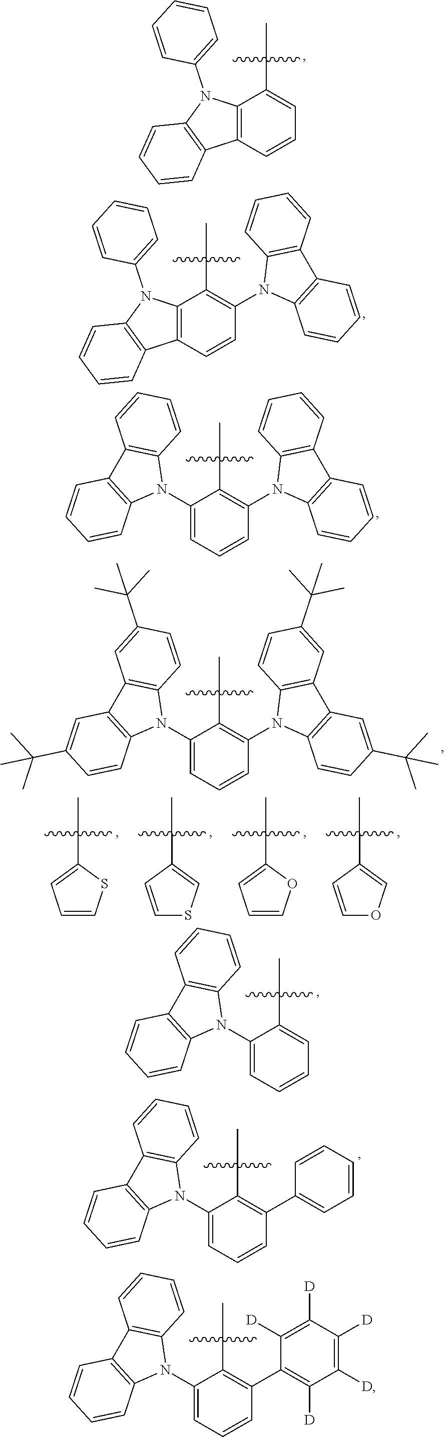

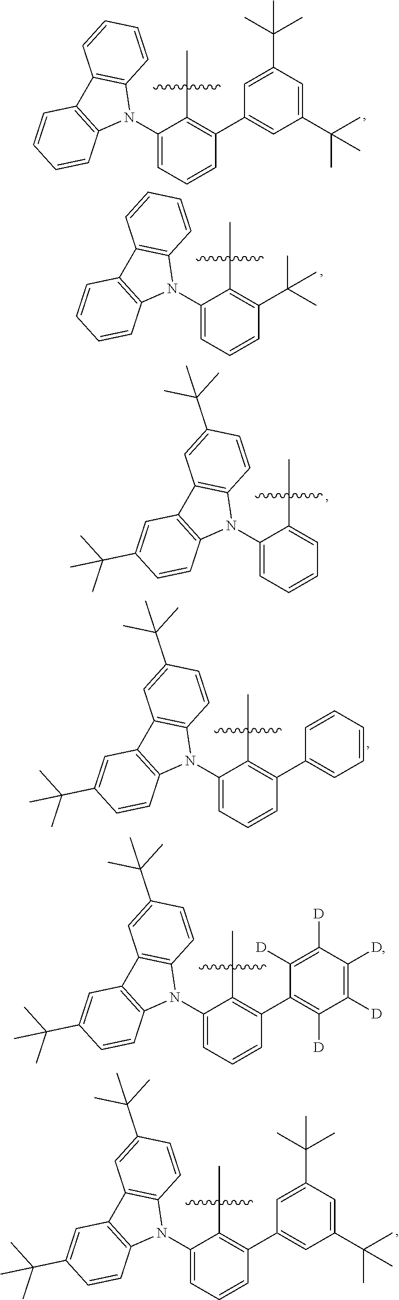

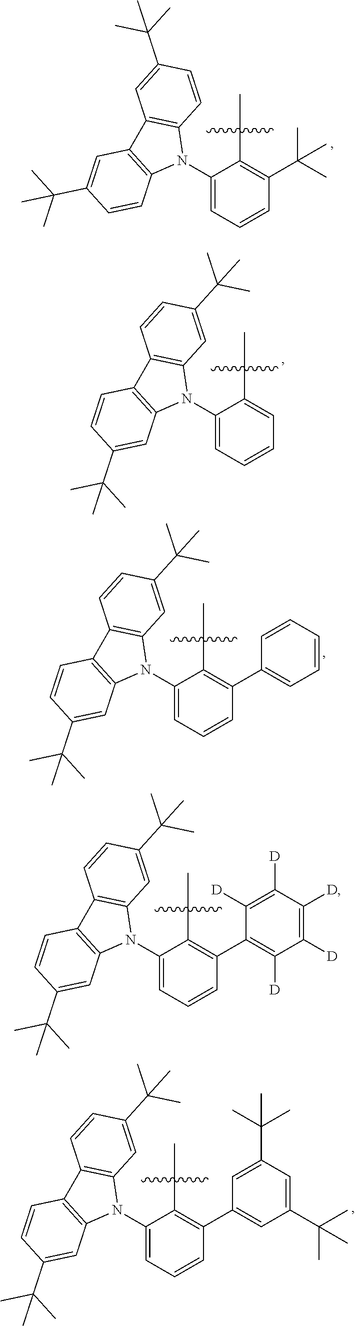

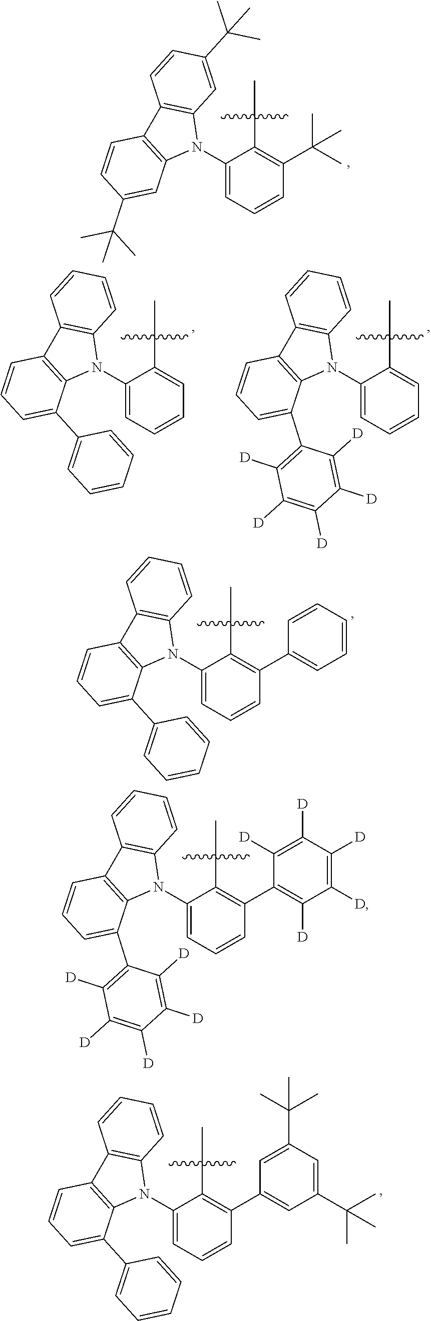

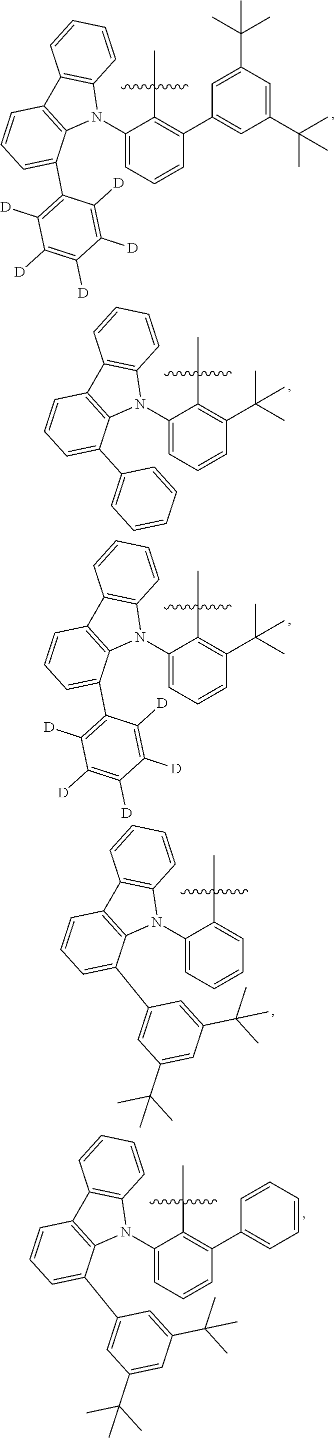

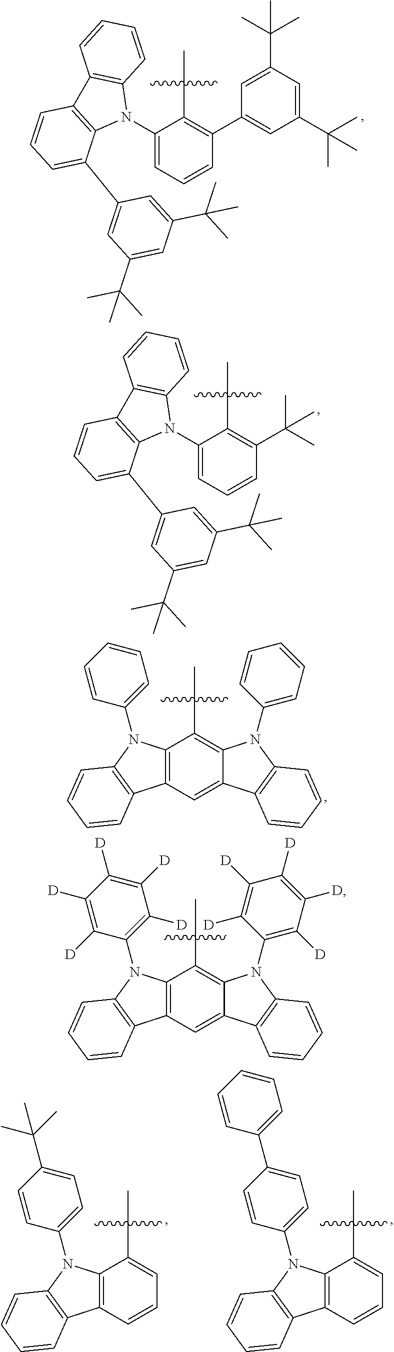

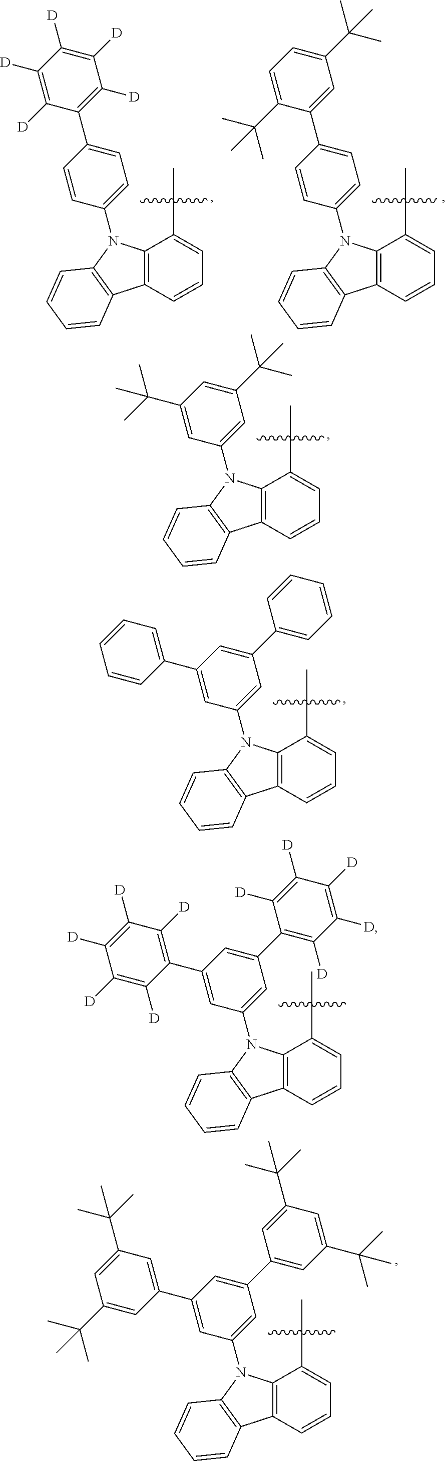

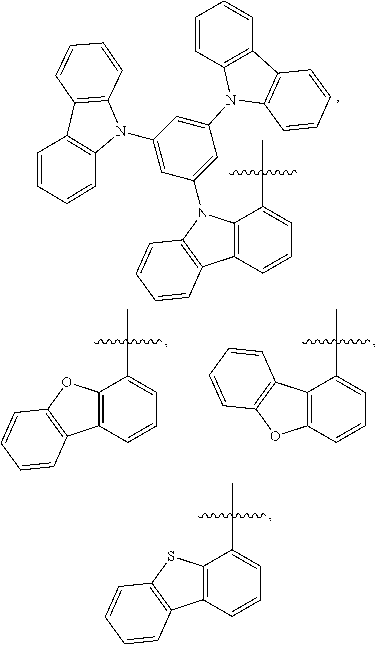 [SMILES: *c1cccc2c3ccccc3n(-c3cc(-n4c5ccccc5c5ccccc54)cc(-n4c5ccccc5c5ccccc54)c3)c12 ; *c1cccc2c1oc1ccccc12 ; *c1cccc2oc3ccccc3c12 ; *c1cccc2c1sc1ccccc12]

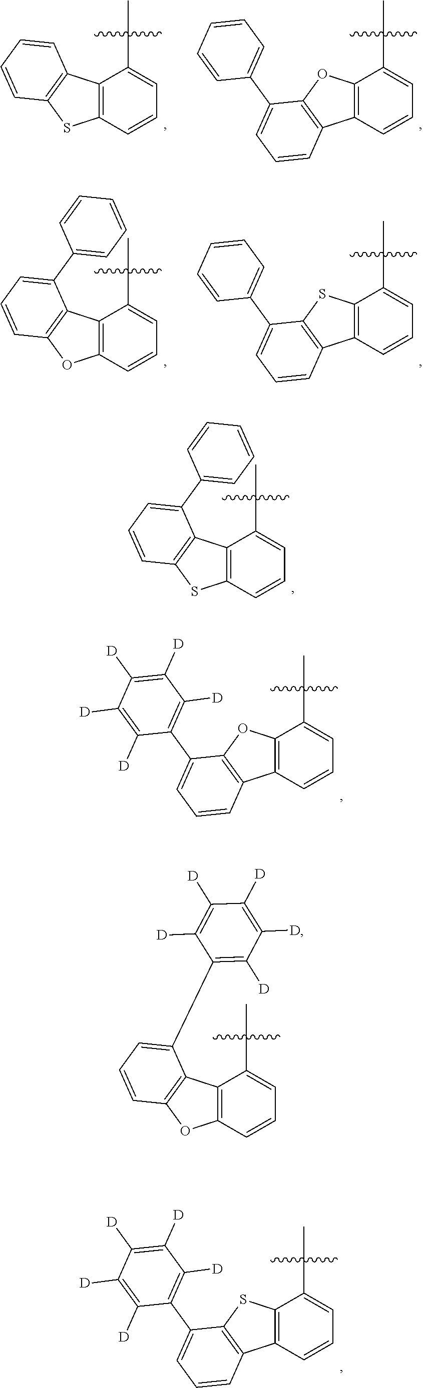

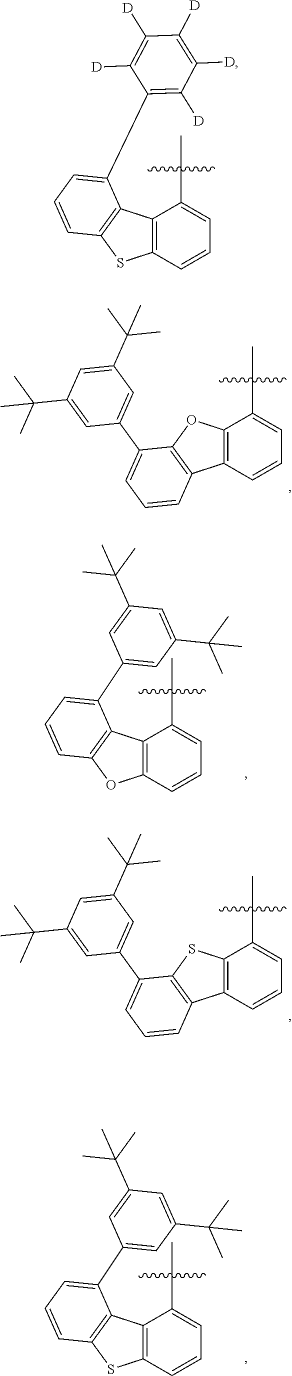

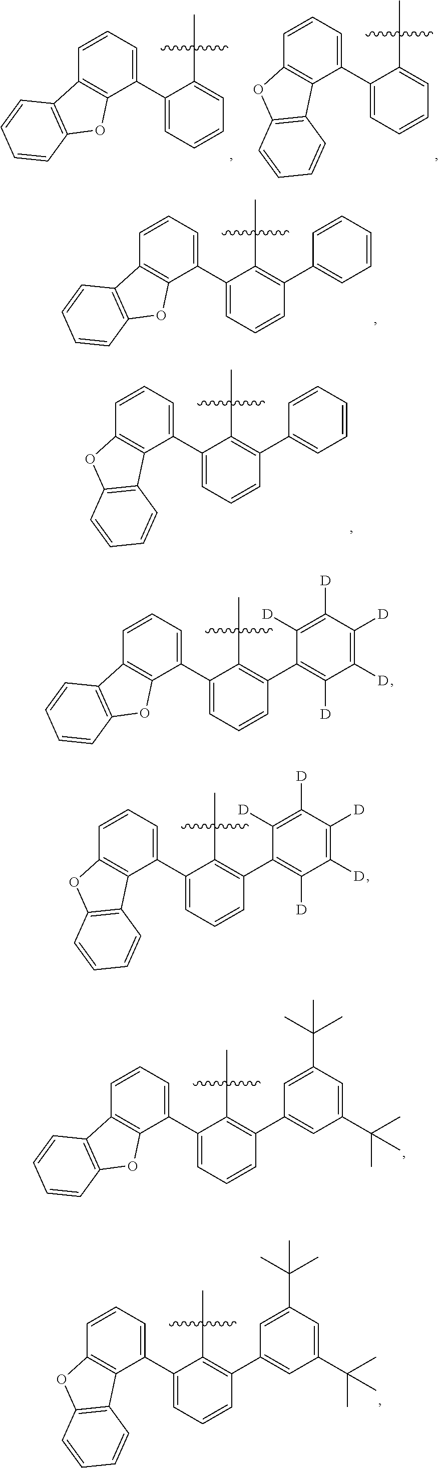

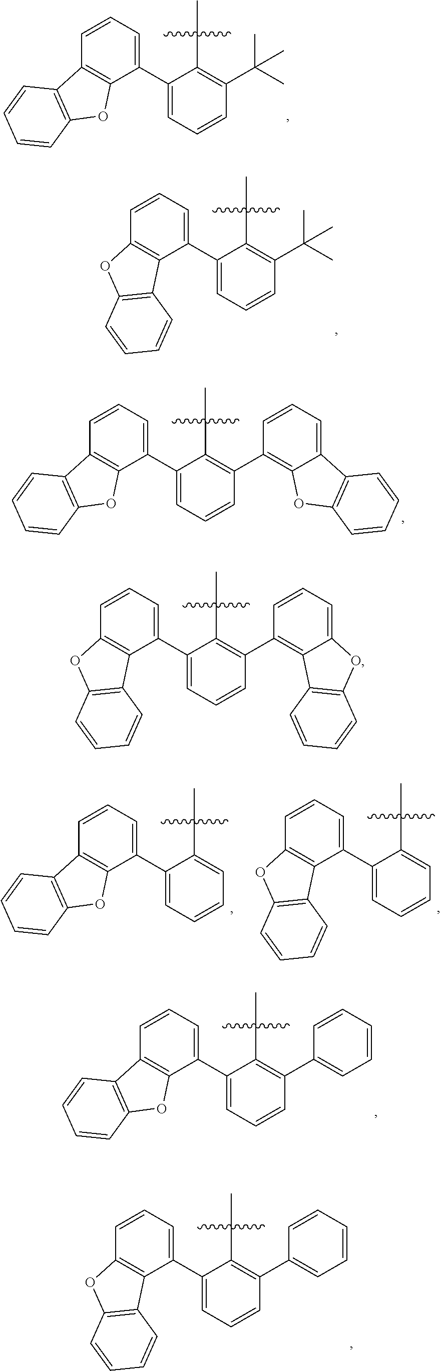

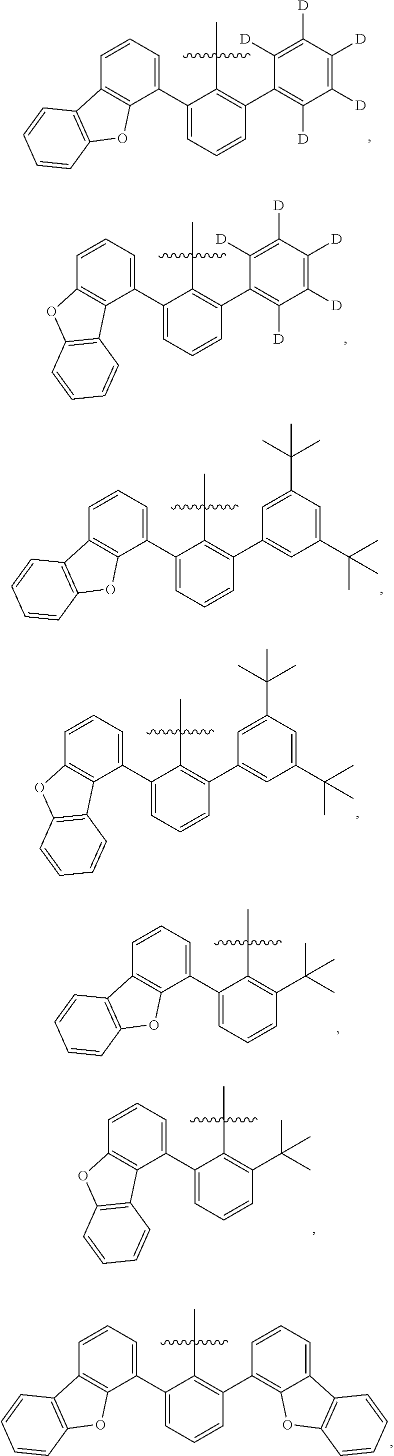

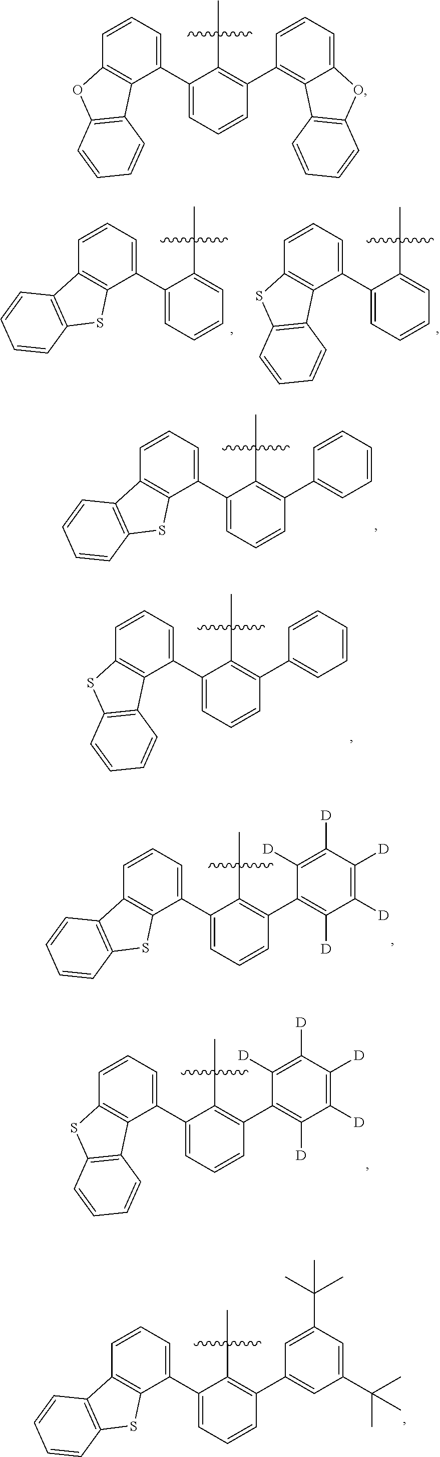

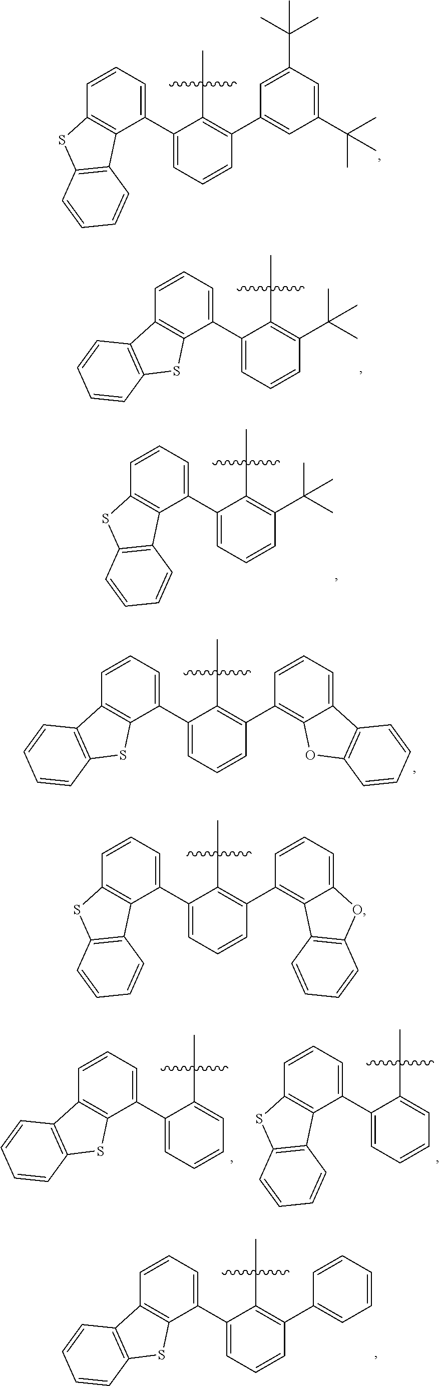

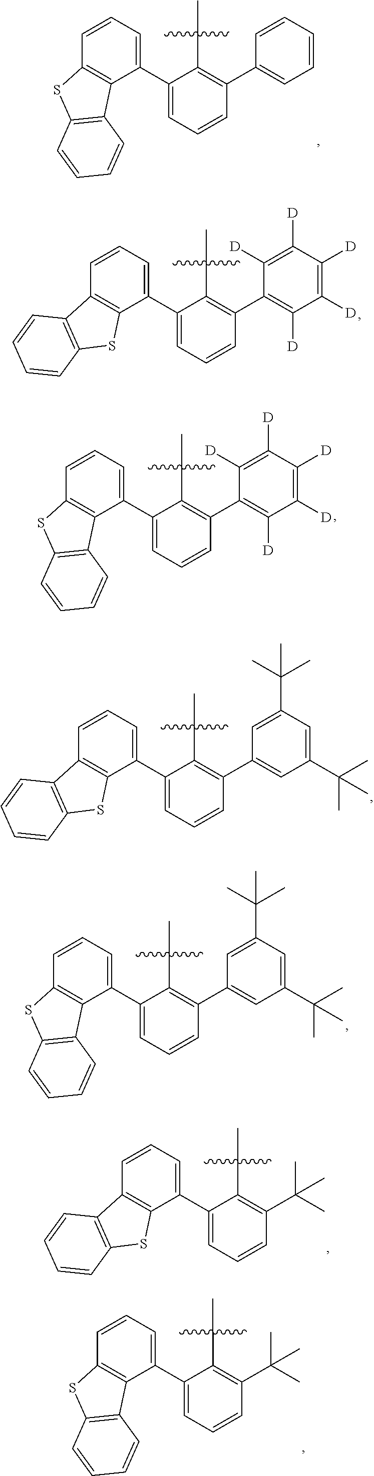

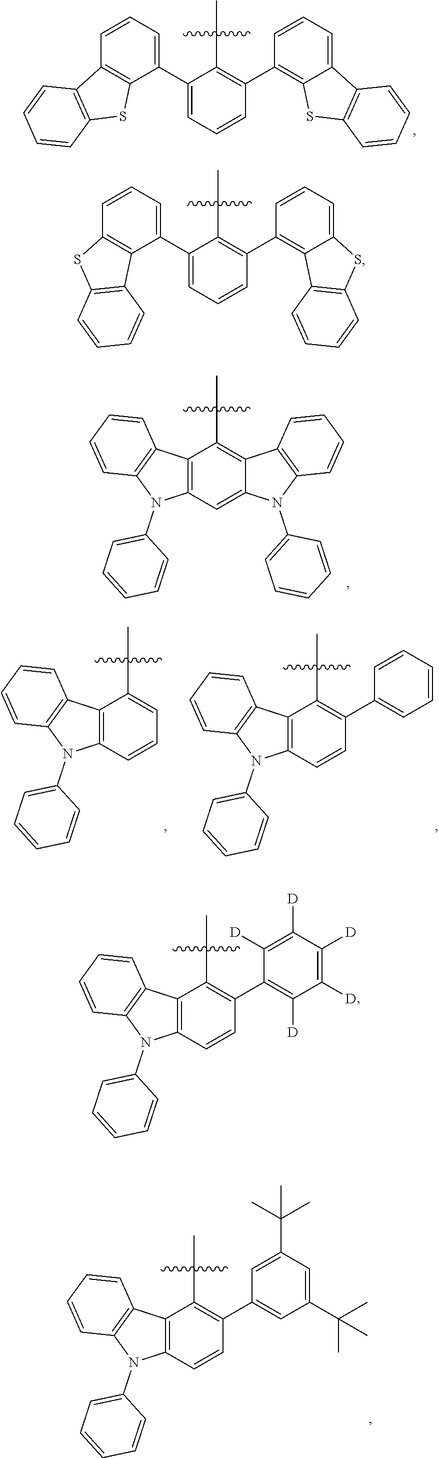

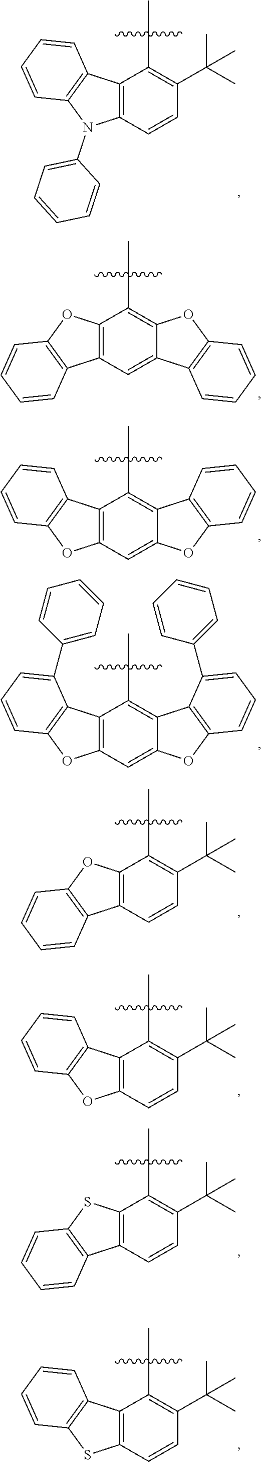

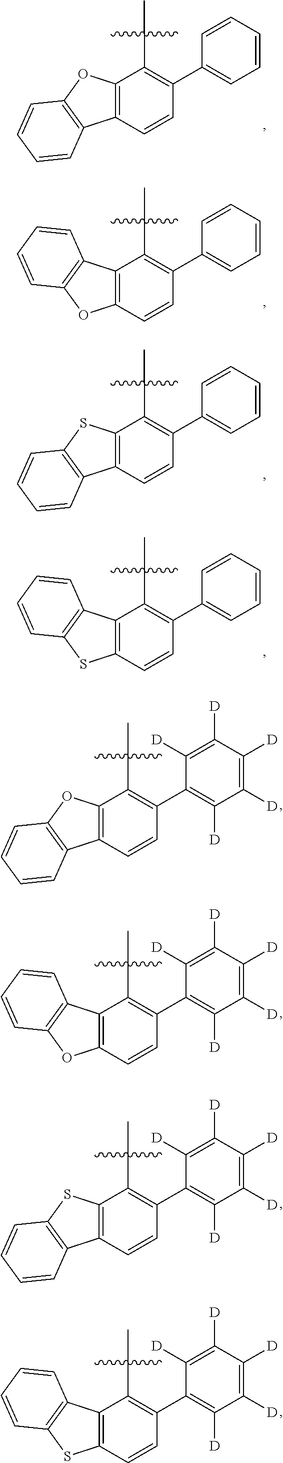

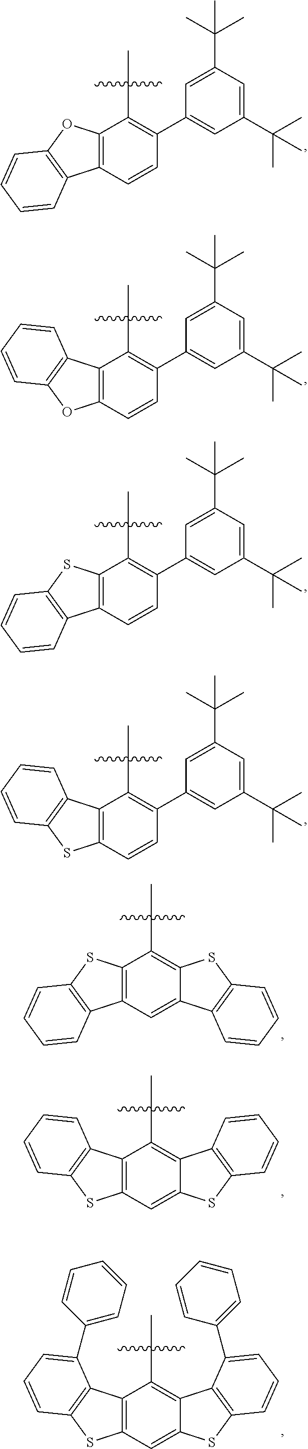

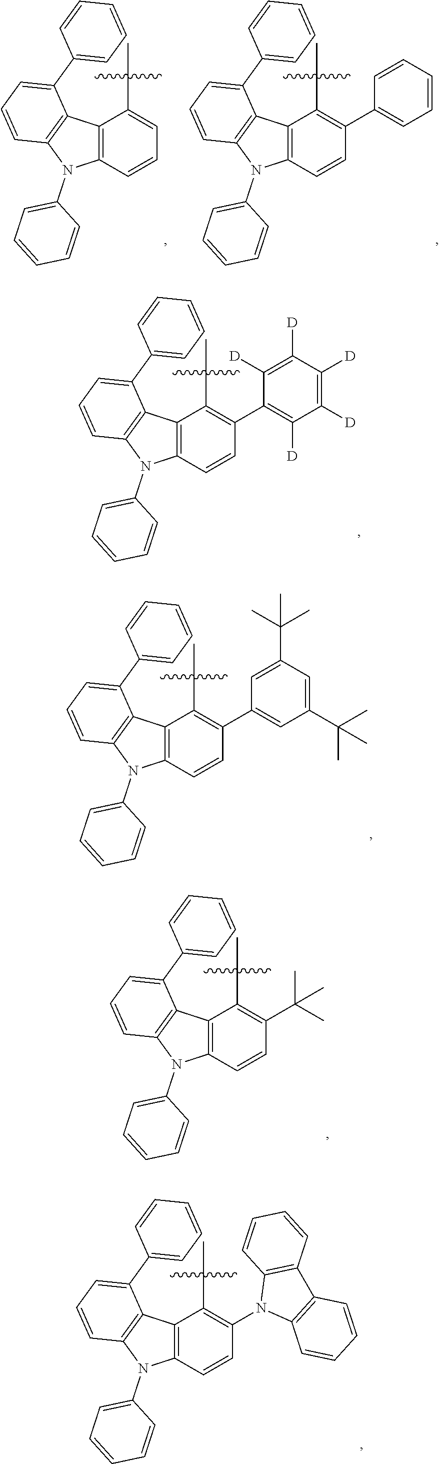

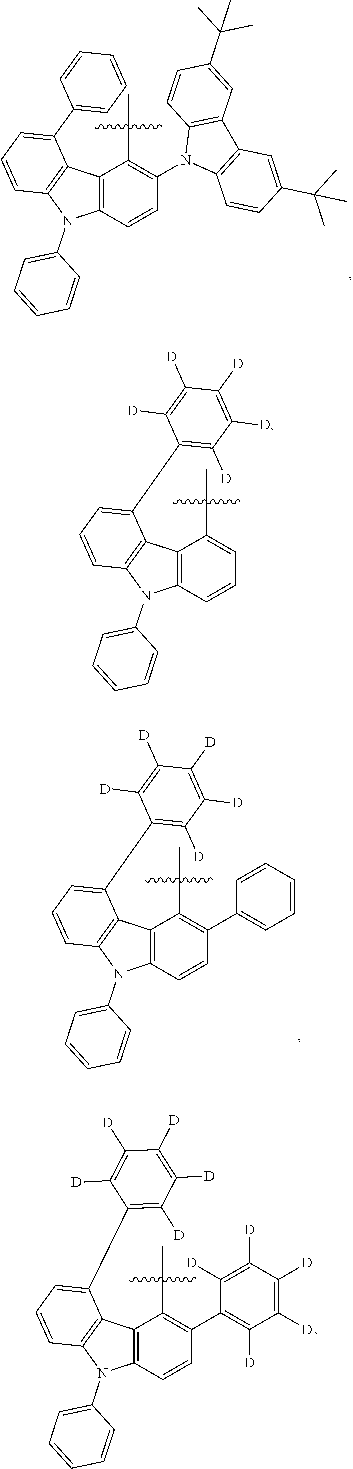

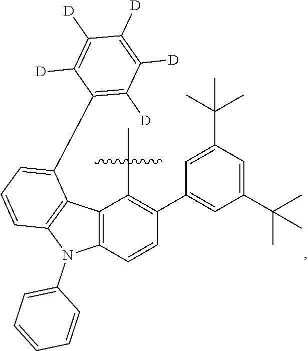 [SMILES: *c1c(-c2cc(C(C)(C)C)cc(C(C)(C)C)c2)ccc2c1c1c(-c3c([2H])c([2H])c([2H])c([2H])c3[2H])cccc1n2-c1ccccc1]

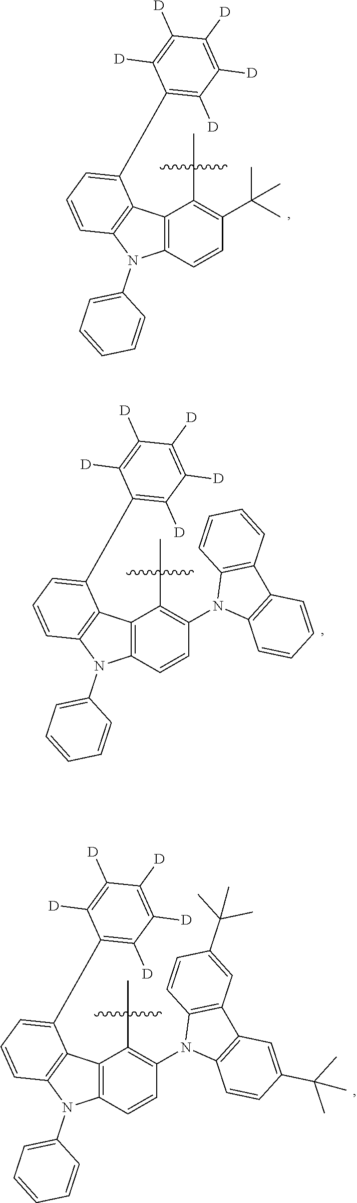 [SMILES: *c1c(C(C)(C)C)ccc2c1c1c(-c3c([2H])c([2H])c([2H])c([2H])c3[2H])cccc1n2-c1ccccc1 ; *c1c(-n2c3ccccc3c3ccccc32)ccc2c1c1c(-c3c([2H])c([2H])c([2H])c([2H])c3[2H])cccc1n2-c1ccccc1 ; *c1c(-n2c3ccc(C(C)(C)C)cc3c3cc(C(C)(C)C)ccc32)ccc2c1c1c(-c3c([2H])c([2H])c([2H])c([2H])c3[2H])cccc1n2-c1ccccc1]

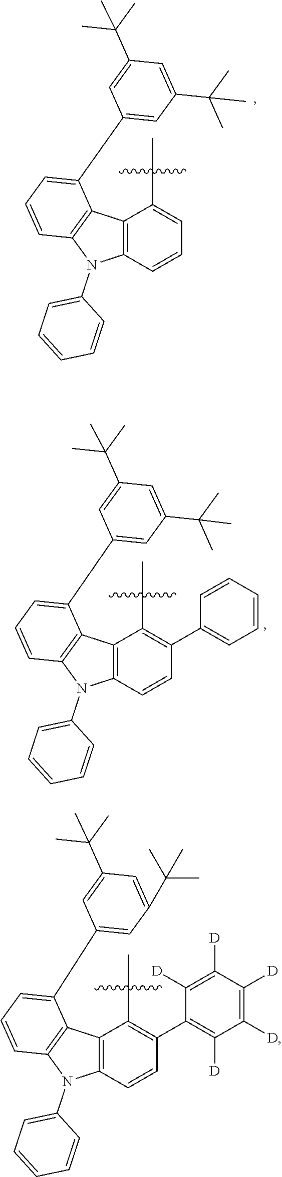

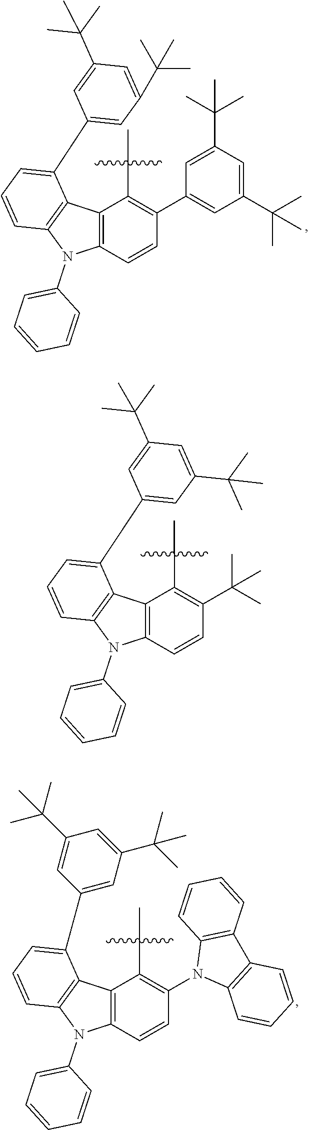

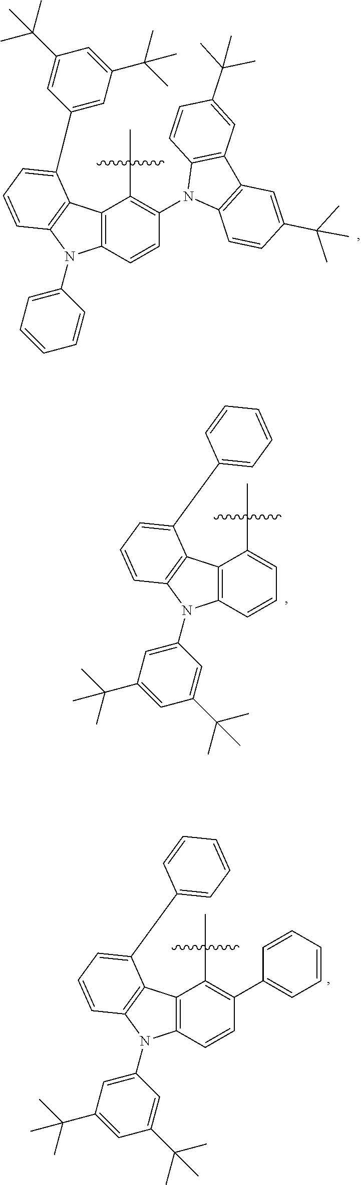

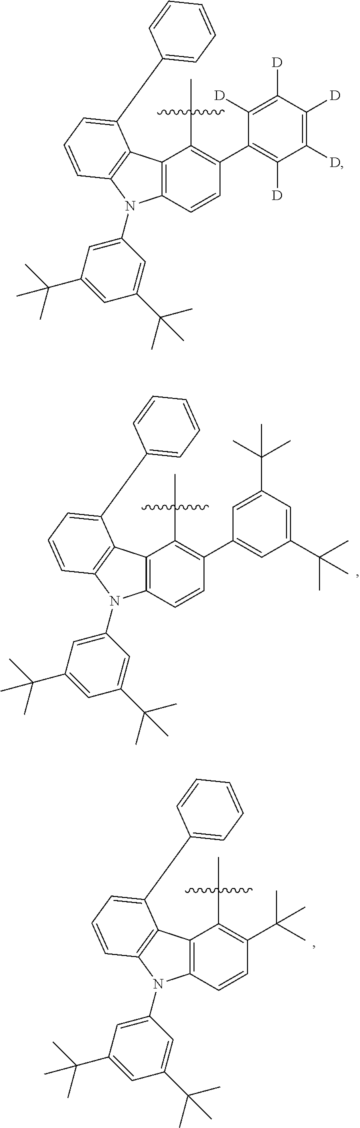

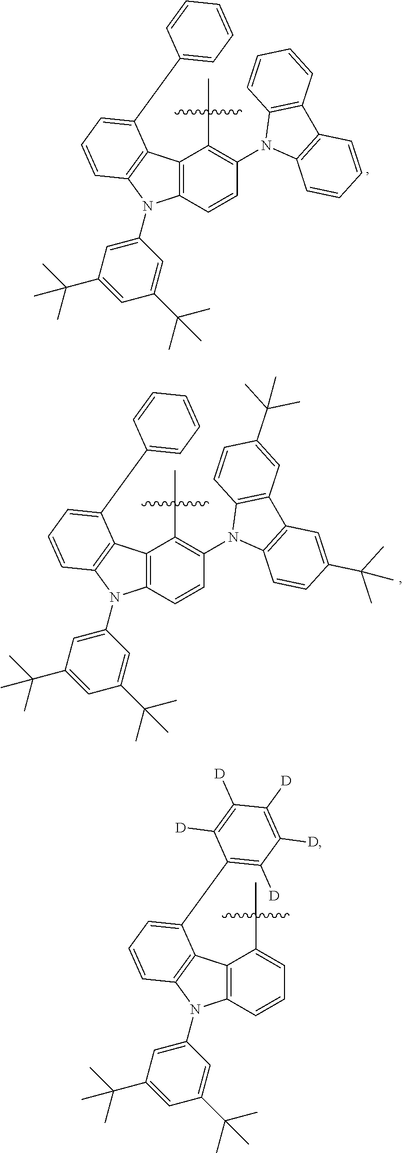

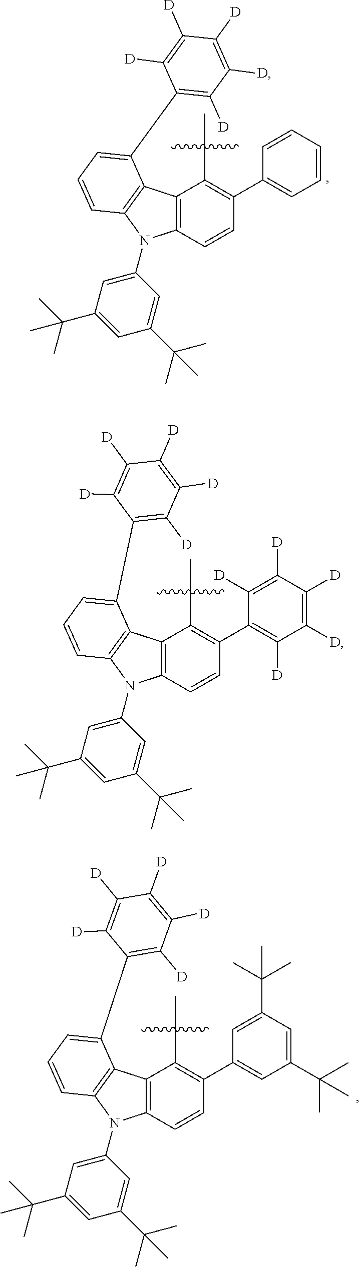

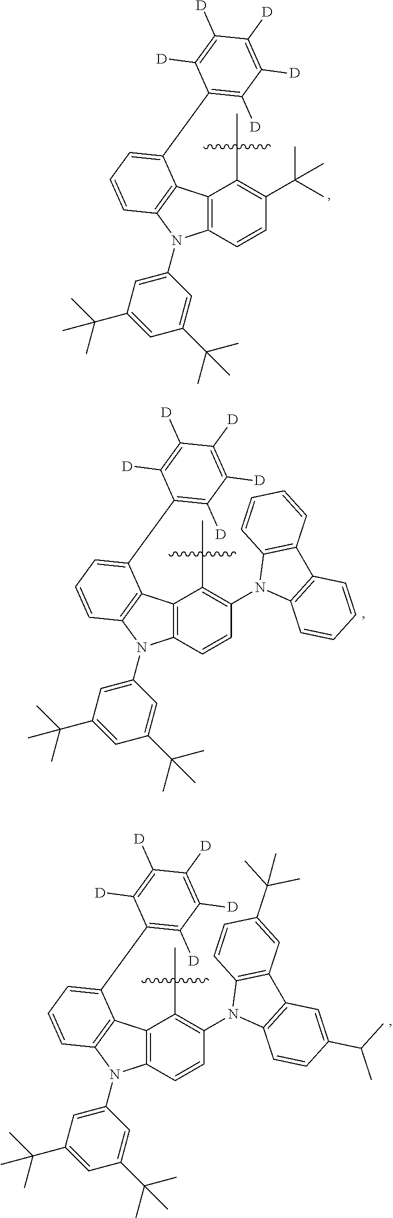

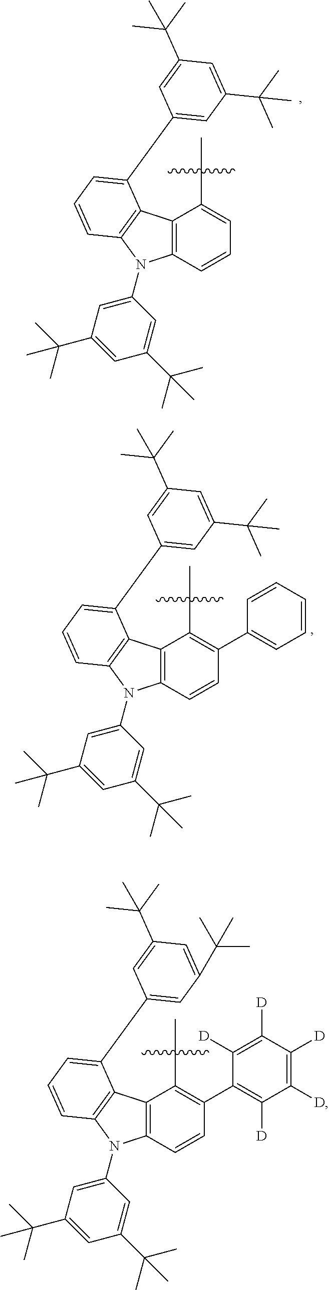

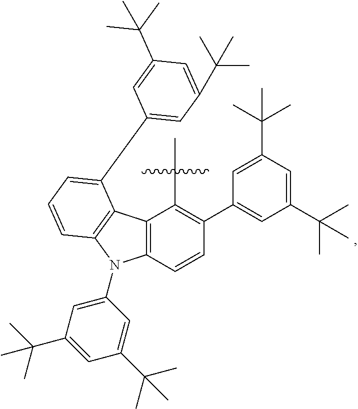 [SMILES: *c1c(-c2cc(C(C)(C)C)cc(C(C)(C)C)c2)ccc2c1c1c(-c3cc(C(C)(C)C)cc(C(C)(C)C)c3)cccc1n2-c1cc(C(C)(C)C)cc(C(C)(C)C)c1]

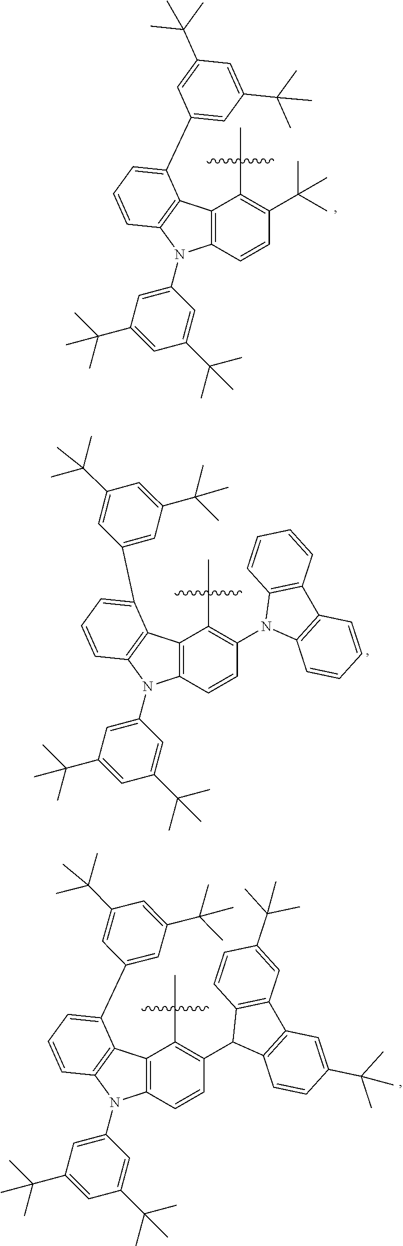

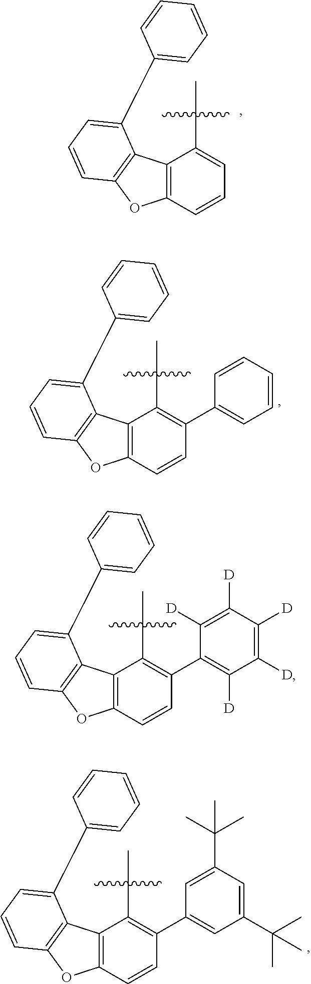

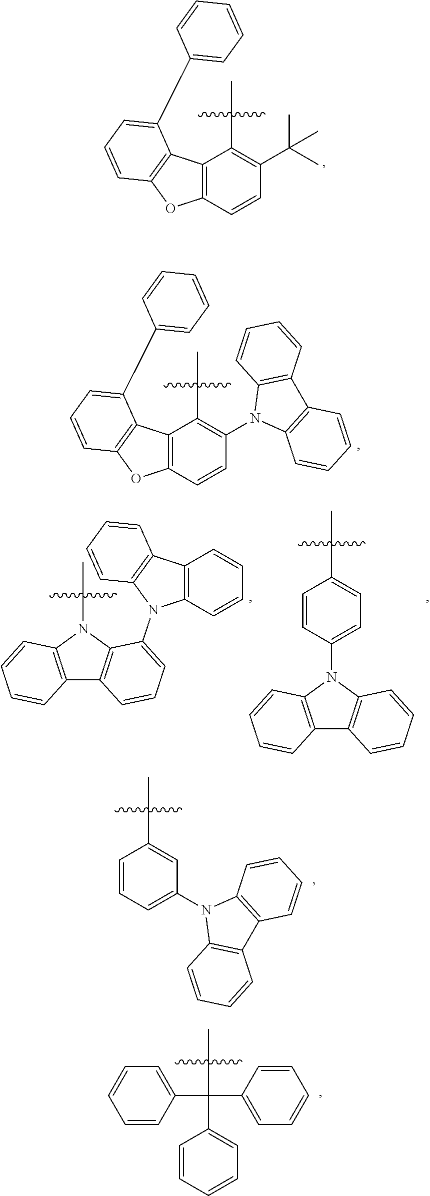

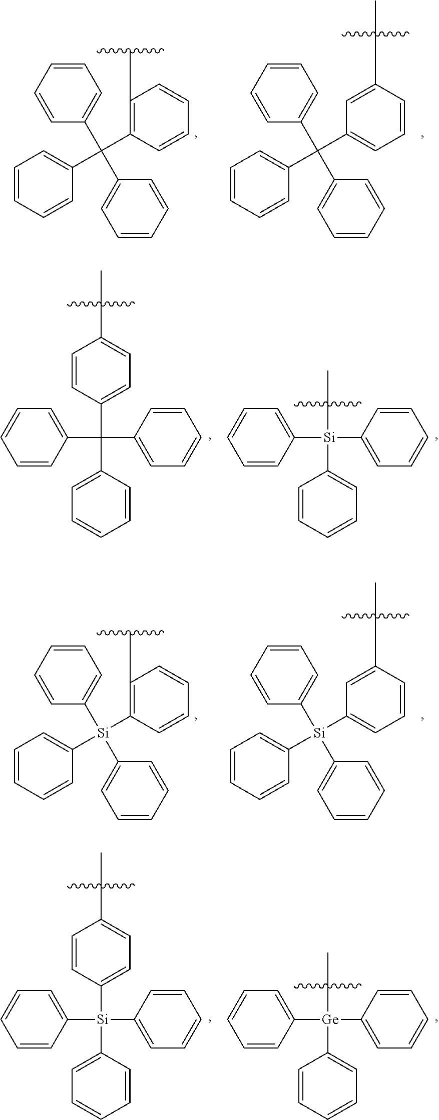

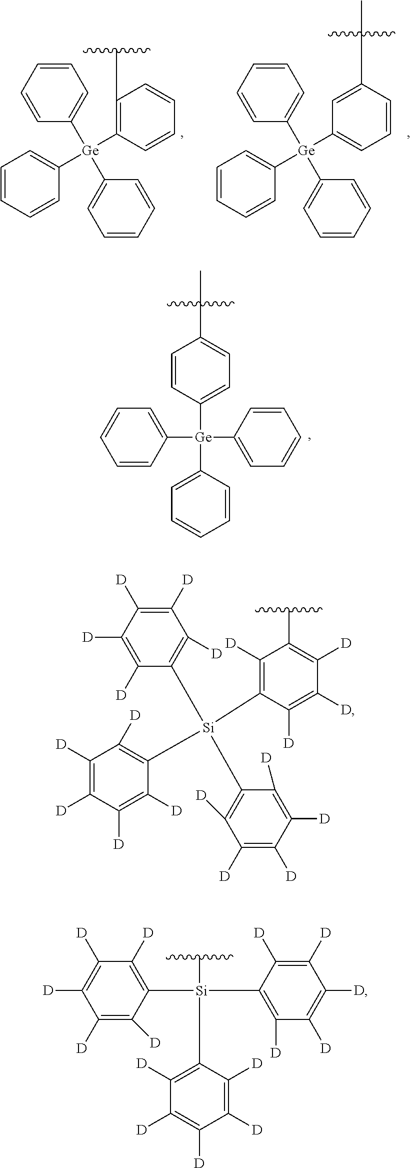

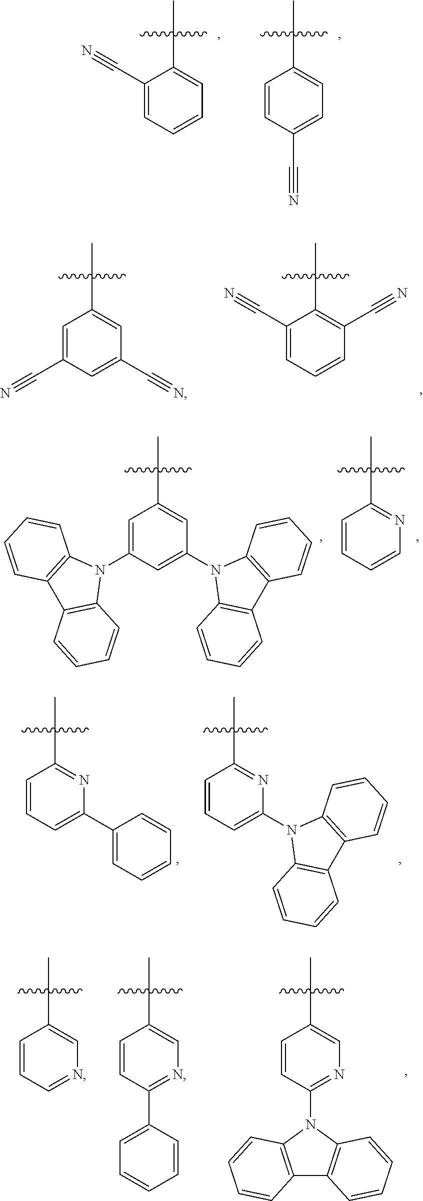

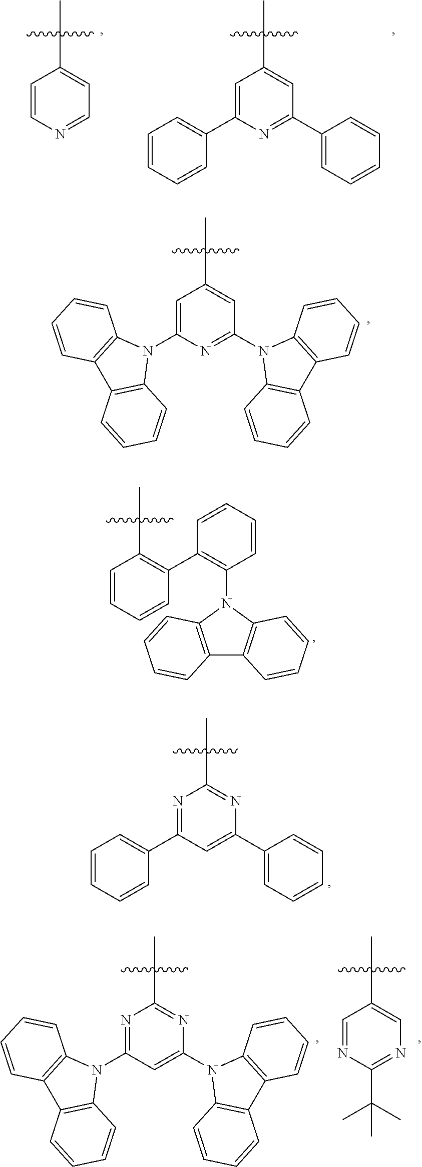

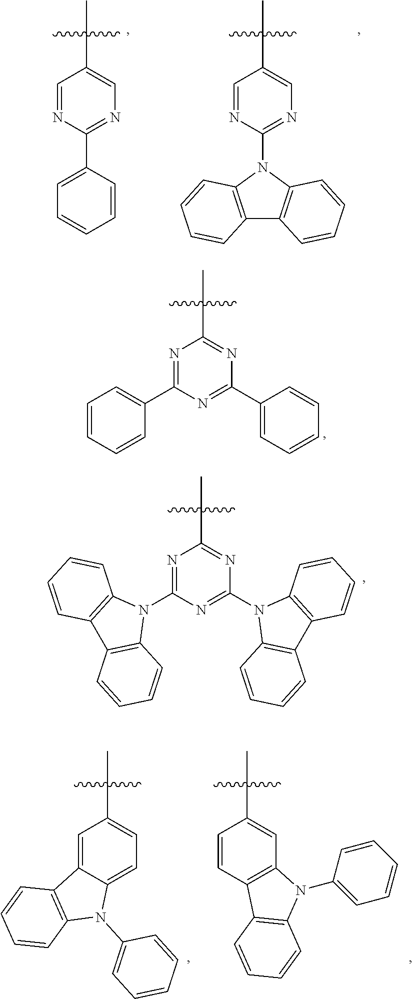 [SMILES: *c1cnc(-c2ccccc2)nc1 ; *c1cnc(-n2c3ccccc3c3ccccc32)nc1 ; *c1nc(-c2ccccc2)nc(-c2ccccc2)n1 ; *c1nc(-n2c3ccccc3c3ccccc32)nc(-n2c3ccccc3c3ccccc32)n1 ; *c1ccc2c(c1)c1ccccc1n2-c1ccccc1 ; *c1ccc2c3ccccc3n(-c3ccccc3)c2c1]

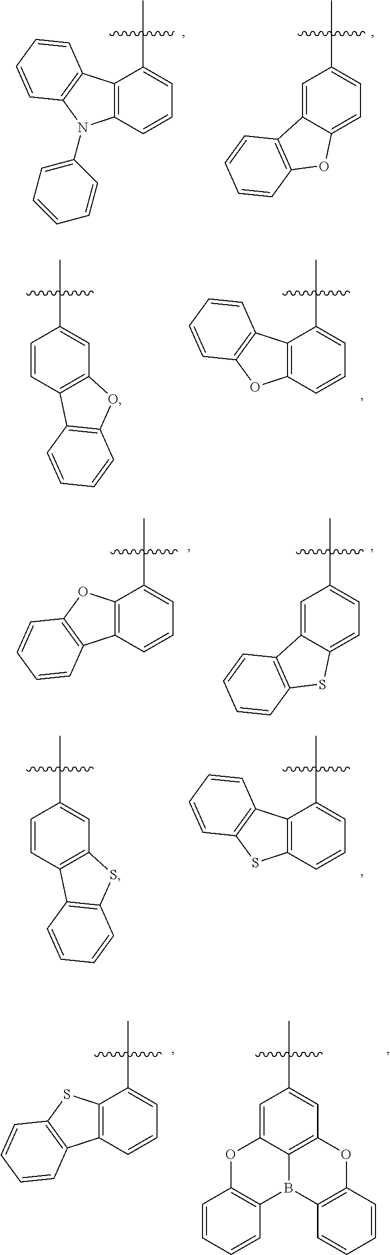

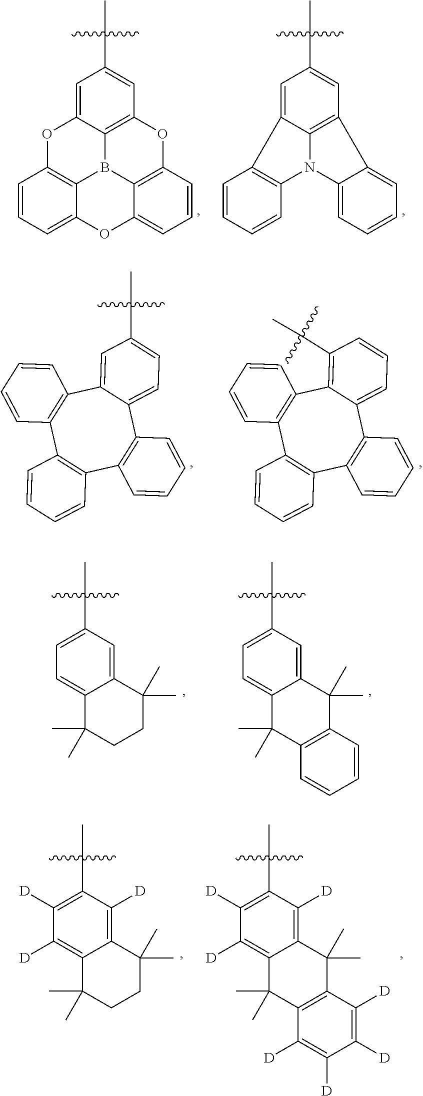

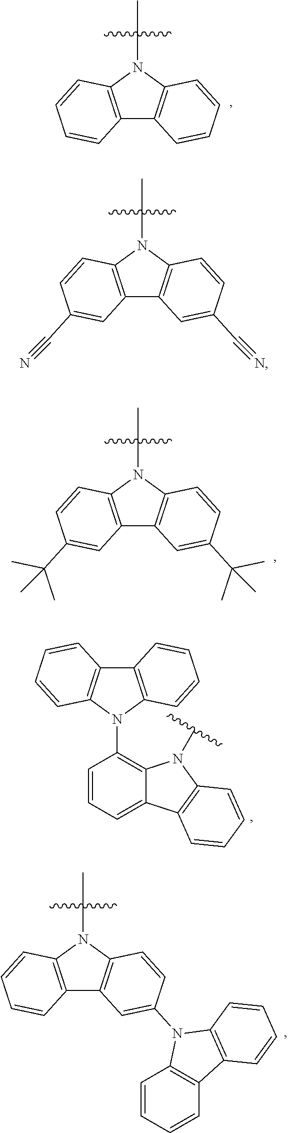 [SMILES: *n1c2ccccc2c2ccccc21 ; *n1c2ccc(C#N)cc2c2cc(C#N)ccc21 ; *n1c2ccc(C(C)(C)C)cc2c2cc(C(C)(C)C)ccc21 ; *n1c2ccccc2c2cccc(-n3c4ccccc4c4ccccc43)c21 ; *n1c2ccccc2c2cc(-n3c4ccccc4c4ccccc43)ccc21]

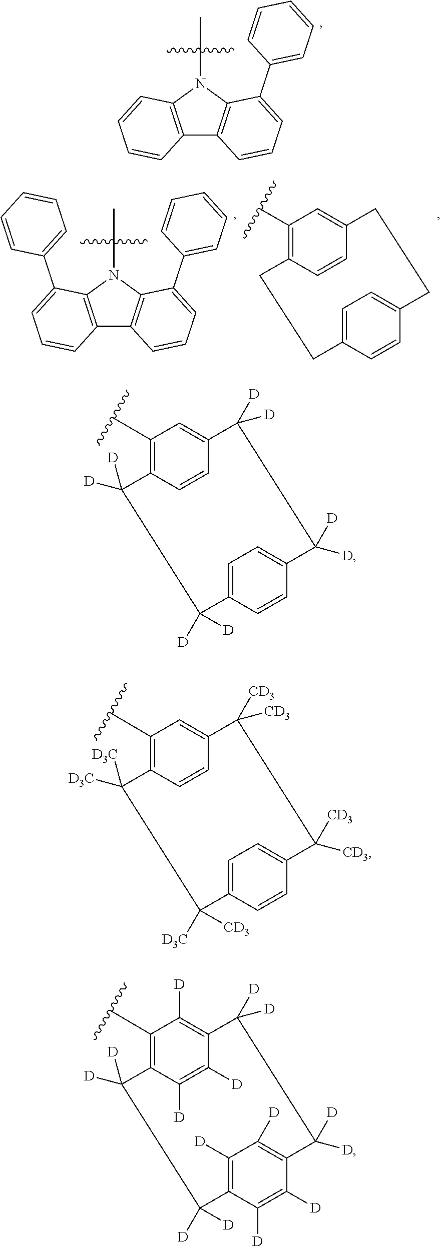

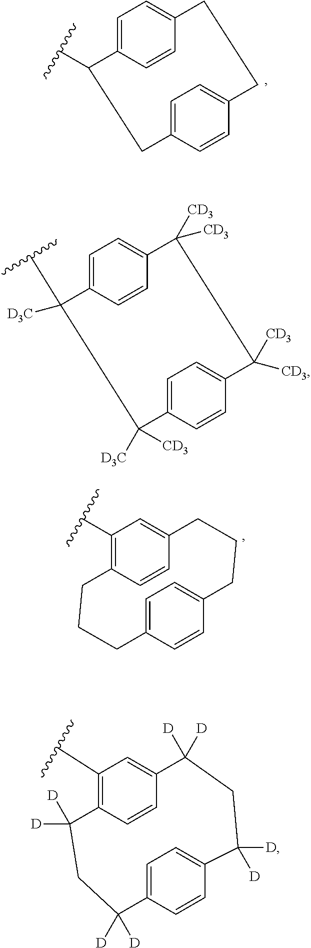

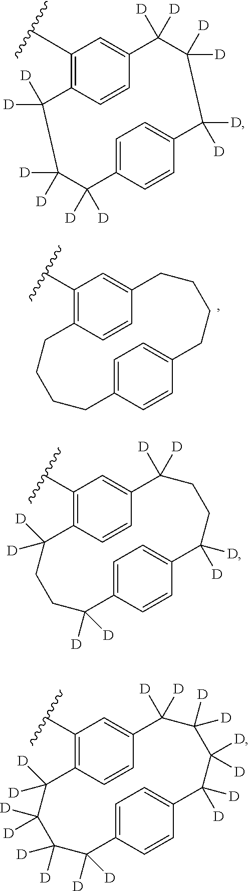

and the structures of LIST 1 defined herein.

What is claimed is:

1. A compound of Formula I, 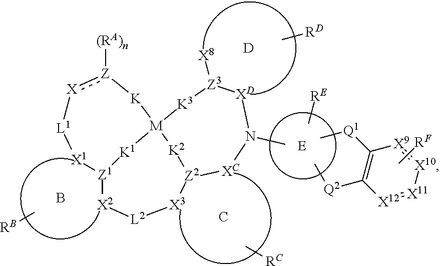
wherein:
M is Pt or Pd;
each of moiety B, moiety C, and moiety D independently represents a monocyclic ring or a polycyclic fused ring system, wherein the monocyclic ring or each ring of the polycyclic fused ring system is independently a 5-membered to 10-membered carbocyclic or heterocyclic ring;
moiety E represents a monocyclic ring or bicyclic fused ring system, wherein the monocyclic ring or each ring of the bicyclic fused ring system is independently a 5-membered to 10-membered carbocyclic or heterocyclic ring;
n is 0, 1, or 2, as needed to fill the valence of Z;
K is selected from the group consisting of a direct bond, O, S, Se, NR, NRR′, and PRR′;
each of K¹ to K³ is independently selected from the group consisting of a direct bond, O, S, N(R^{α}),
P(R^{α}), B(R^{α}), C(R^{α})(R^{β}), and Si(R^{α})(R^{β});
Z is selected from the group consisting of C, N, O, S, B, and P;
n is 0, 1, or 2, as needed to fill the valence of Z;
each of Z¹ to Z³ is independently C or N;
X is selected from the group consisting of CR, CRR′, NR, and PRR′;
each of X^{C}, X^{D}, X¹ to X³ and X⁸ to X¹² is independently C or N;
L¹ is selected from the group consisting of a direct bond, BR, BRR′, NR, PR, P(O)R, O, S, Se, C═O, C═S, C═Se, C═NR′, C═CR′R″, S═O, SO₂, CR, CRR′, SiRR′, GeRR′, alkylene, cycloalkyl, aryl, cycloalkylene, arylene, heteroarylene, and combinations thereof;
L² is selected from the group consisting of absent a bond, a direct bond, BR, BRR′, NR, PR, P(O)R, O, S, Se, C═O, C═S, C═Se, C═NR, C═CRR, S═O, SO₂, CR, CRR′, SiRR′, GeRR′, alkylene, cycloalkyl, aryl, cycloalkylene, arylene, heteroarylene, and combinations thereof, and if L² is absent, at least one R^{A} and at least one R^{D} are bonded or fused to form a ring including M;
each of Q¹ and Q² is independently selected from the group consisting of a direct bond, C, CRR′, SiRR′, O, S, Se, BR, and NR;
each [symbol] independently represents a single or double bond in a Lewis structure;
each of R^{A}, R^{B}, R^{c}, R^{D}, R^{E}, and R^{F} independently represents mono to the maximum allowable substitutions, or no substitution;
each R, R′, R″, R^{α}, R^{β}, R^{A}, R^{B}, R^{c}, R^{D}, and R^{F} is independently a hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents may be joined or fused to form a ring.

2. A compound of claim 1, wherein the compound has a structure of Formula II, 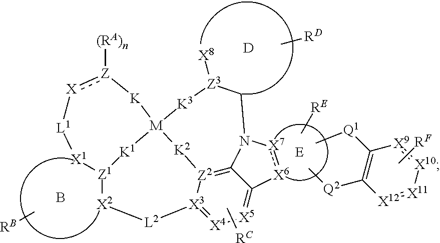
wherein:
each of K¹ to K³ is independently selected from the group consisting of a direct bond, 0, and S;
each of X¹ to X¹² is independently C or N;
each of L¹ and L² is independently selected from the group consisting of a direct bond, BR, BRR′, NR, PR, P(O)R, O, S, Se, C═O, C═S, C═Se, C═NR′, C═CR′R″, S═O, SO₂, CR, CRR′, SiRR′, GeRR′, alkylene, cycloalkyl, aryl, cycloalkylene, arylene, heteroarylene, and combinations thereof;
at least one of the following conditions is true:
(1) the compound comprises at least one deuterium atom;
(2) at least one of K, K¹, K² and K³ is not a direct bond;
(3) X is CR, NR, or PRR′, and R does not join with an R^{A} substituent to form a ring;
(4) L¹ is a direct bond, X is NR, Z is C, and R and R^{A} join to comprise a structure of Formula III, 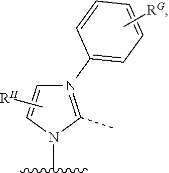
wherein the dashed line represents a direct bond to M, two R^{F} substituents do not join to form a ring, and at least one R^{G} substituent is not hydrogen; and
(5) L¹ is a direct bond, X is NR, Z is C, and R and R^{A} join to comprise a structure of Formula IV, 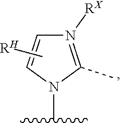
wherein R^{X} has a molecular weight of at least 153 grams/mol or R^{X} and R^{H} are joined to form a ring;
wherein each of R^{G} and R^{H} independently represents mono to the maximum allowable substitution, or no substitution;
each R^{G}, R^{H}, and R^{X} is independently a hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents may be joined or fused to form a ring subject to the above conditions, with the proviso that the compound does not comprise

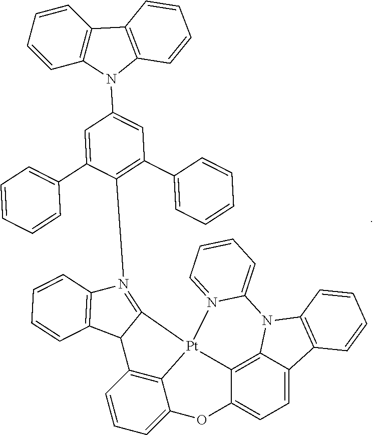

3. The compound of claim 1, wherein each R, R′, R^{A}, R^{B}, R^{c}, R^{D}, R^{F}, R^{G}, R^{H}, and R^{X} is independently a hydrogen or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

4. The compound of claim 1, wherein L¹ is a direct bond, X is NR, Z is C, and R and R^{A} join to comprise a structure of Formula II or Formula III, and R^{A} comprises D.

5. The compound of claim 1, wherein L¹ is a direct bond, X is NR, Z is C, and R and one R^{A} join to comprise a structure of Formula III, and R^{X} comprises an N-bound ortho-biphenyl moiety.

6. The compound of claim 1, wherein moiety B is selected from the group consisting of benzene, pyridine, pyrimidine, pyridazine, pyrazine, triazine, imidazole, imidazole derived carbene, pyrazole, pyrrole, oxazole, furan, thiophene, thiazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene; and/or, wherein moiety B is selected from the group consisting of benzene, pyridine, pyrimidine, pyridazine, pyrazine, triazine, imidazole, imidazole derived carbene, pyrazole, pyrrole, oxazole, furan, thiophene, thiazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene; and/or wherein moiety E is selected from the group consisting of benzene, pyridine, pyrimidine, pyridazine, pyrazine, triazine, imidazole, pyrazole, pyrrole, oxazole, furan, thiophene, thiazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, and aza-benzimidazole; and/or wherein K is a direct bond, O or S.

7. The compound of claim 1, wherein at least one of X¹ to X¹² is N or wherein each of X¹ to X¹² is C; and/or wherein L¹ is a direct bond, O, BR, NR, or PR; and/or wherein L² is a direct bond, O, BR, NR, SiRR′, or CRR′; and/or wherein one of Q¹ and Q² is a direct bond, O, S, or NR.

8. The compound of claim 1, wherein the compound comprises at least one deuterium atom.

9. The compound of claim 1, wherein at least one of K, K¹, K² and K³ is not a direct bond.

10. The compound of claim 1, wherein X is CR, NR, or PRR′, and R^{A} does not join with R or R′ to form a ring.

11. The compound of claim 2, wherein X is NR, Z is C, and R and R^{A} join to comprise a structure of Formula III, 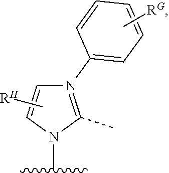
wherein the dashed line represents a direct bond to M; wherein L¹ is a direct bond; two R^{F} substituents do not join to form a ring; and at least one R^{G} substituent is not hydrogen; and/or wherein at least one R^{H} is not hydrogen; and/or wherein two R^{H} are joined to form a ring.

12. The compound of claim 2, wherein X is NR, Z is C, and R and R^{A} join to comprise a structure of Formula IV, 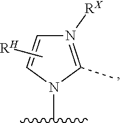
wherein R^{X} has a molecular weight of at least 153 grams/mol or R^{X} and R^{H} are joined to form a ring; and/or wherein L¹ is a direct bond; and/or wherein at least one R^{H} is not H; and/or wherein two R^{H} are joined to form a ring.

13. The compound of claim 12, wherein R″ has a structure selected from the group consisting of: 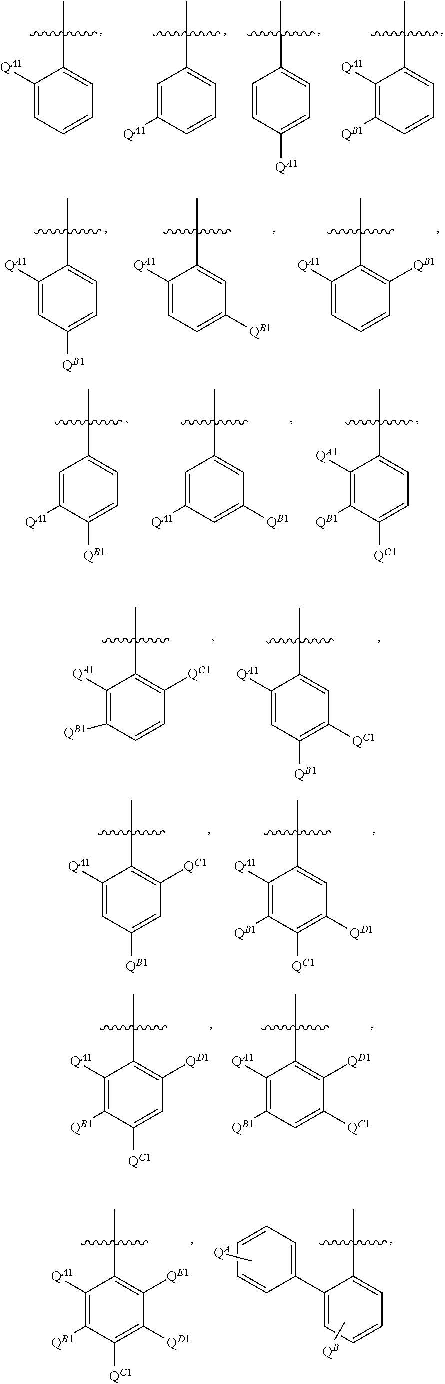 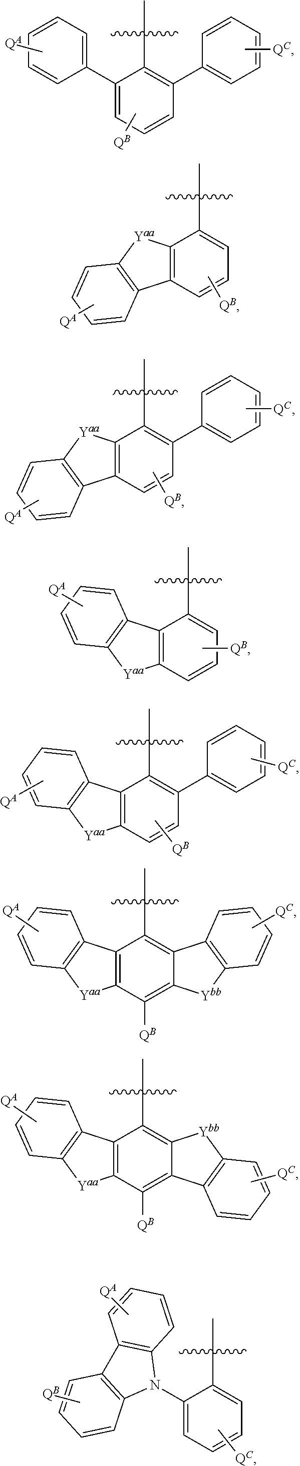 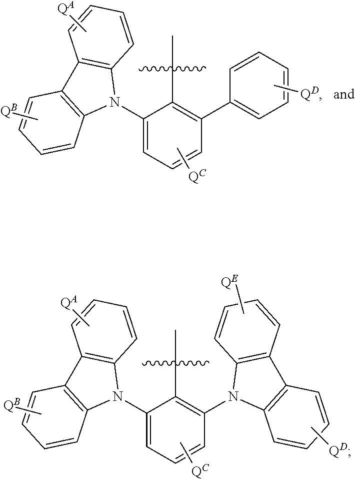
wherein each of Q^{A}, Q^{B}, Q^{C}, Q^{D}, and Q^{E} independently represents mono to the maximum allowable substitutions, or no substitutions;
wherein each Q^{A}, Q^{B}, Q^{C}, Q^{D}, Q^{E}, Q^{A1}, Q^{B1}, Q^{C1}, Q^{D1} and Q^{E1} is independently a hydrogen or a substituent selected from the group consisting of alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
each Y^{aa} and Y^{bb} is independently selected from the group consisting of a direct bond, BR, BRR′, NR, PR, O, S, Se, C═O, C═S, C═Se, C═NR, C═CRR′, S═O, SO₂, CR, CRR′, SiRR′, GeRR′, alkyl, cycloalkyl, aryl, heteroaryl, and combinations thereof; and
any two substituents can be joined or fused to form a ring.

14. The compound of claim 1, wherein the compound is selected from the group consisting of compounds having the formula of Pt(L_{A′})(Ly): 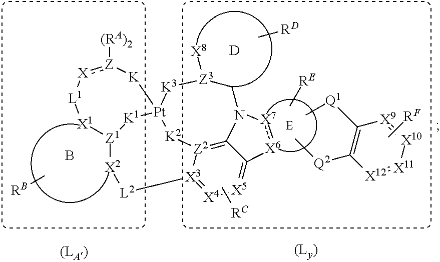
wherein L_{A′} is selected from the group consisting of: 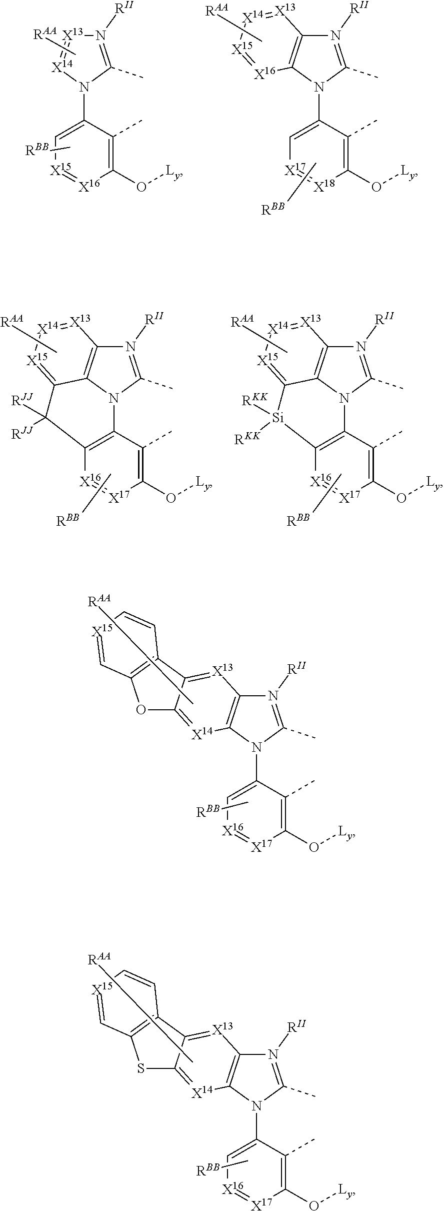 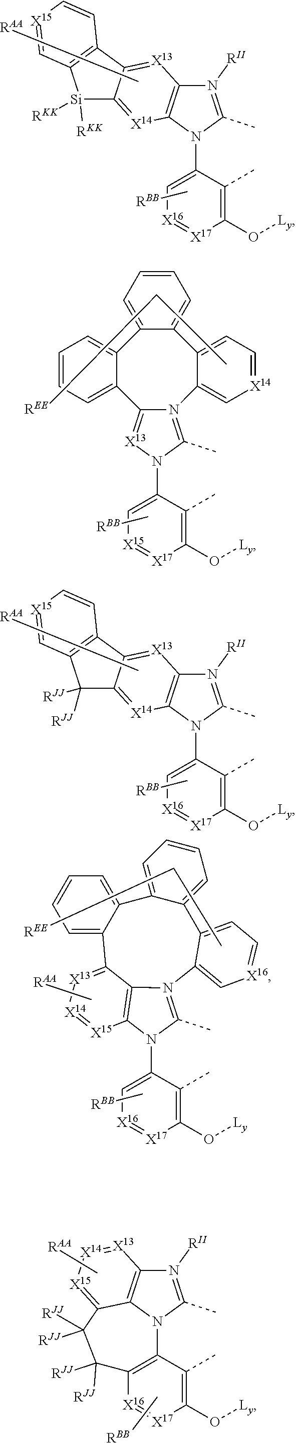 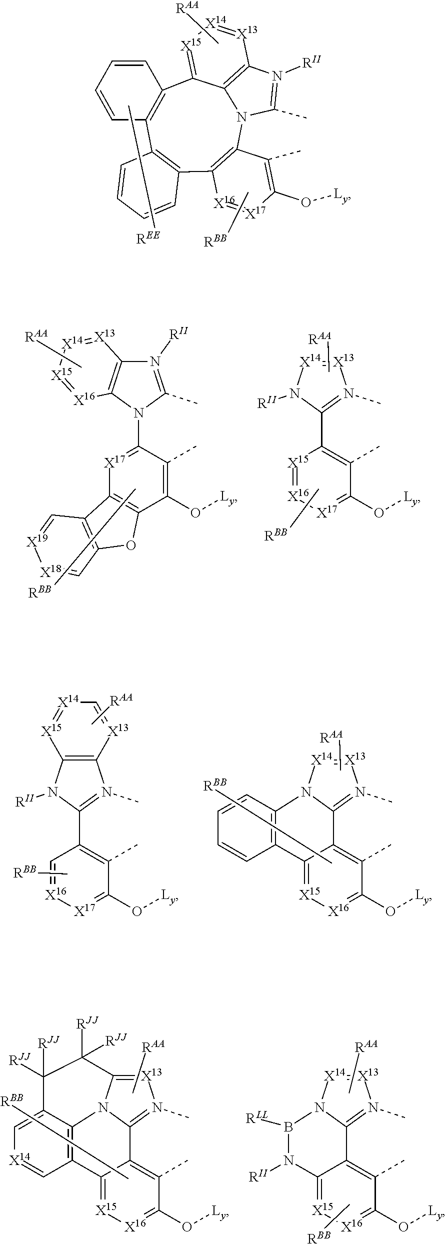 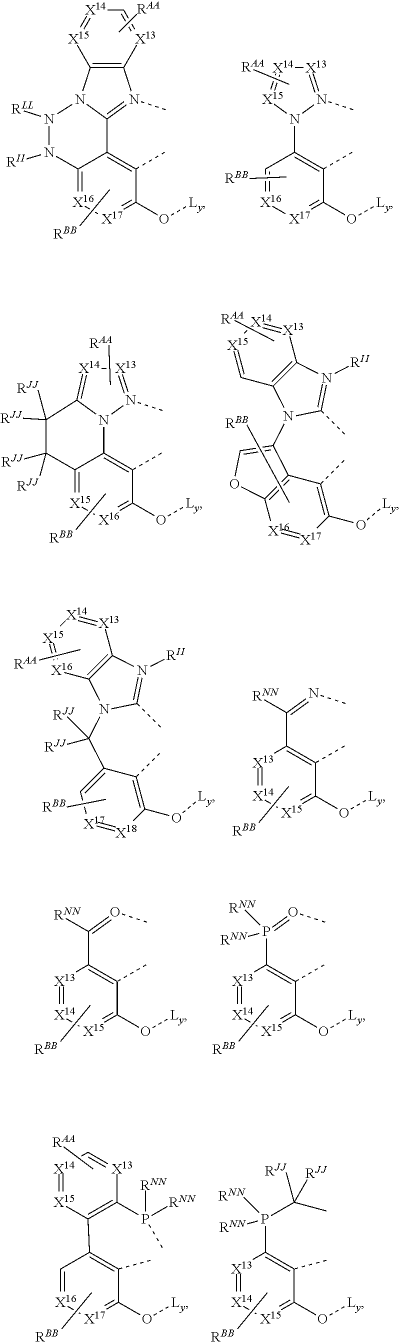 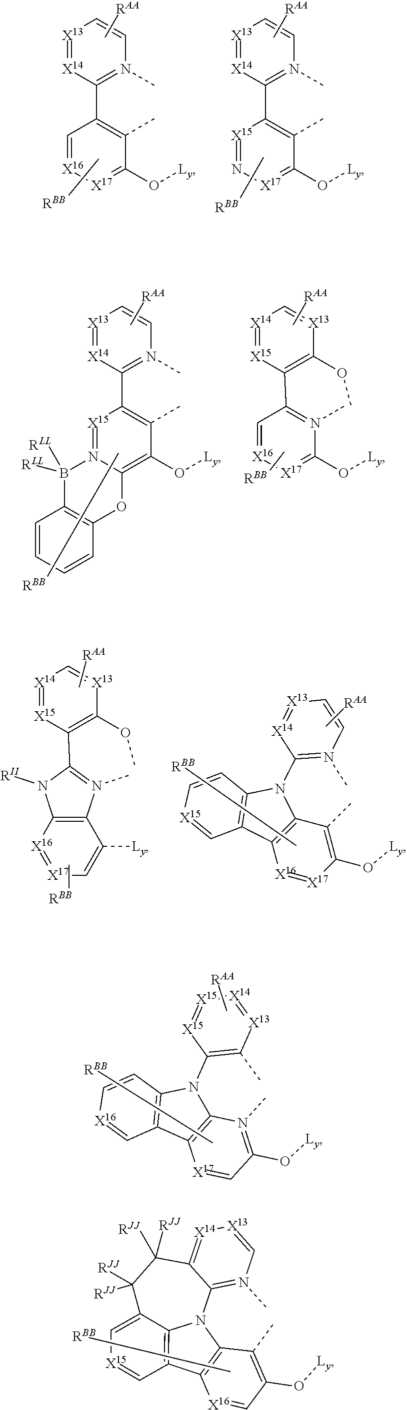 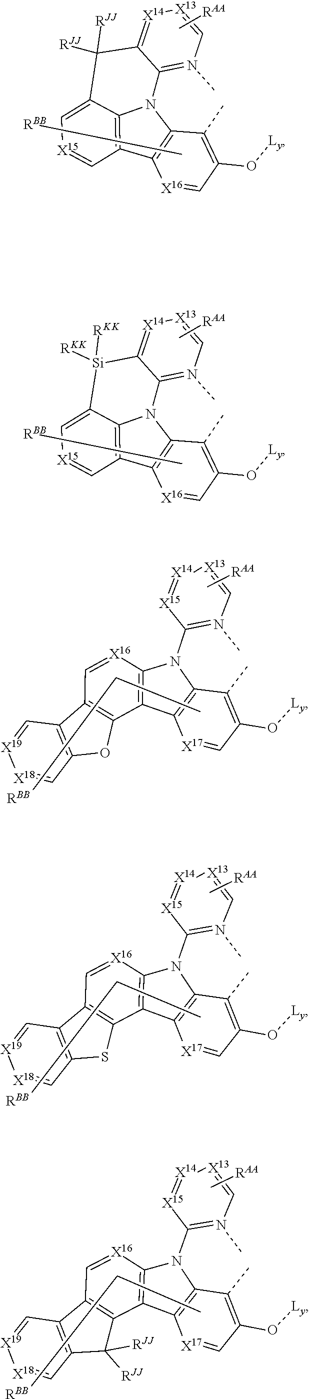 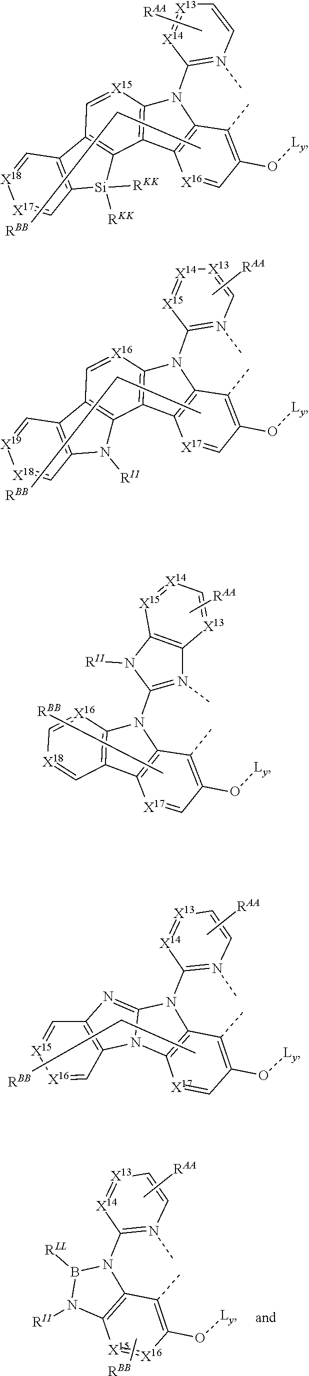 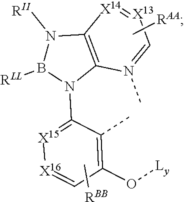
wherein L_{y} is selected from the group consisting of: 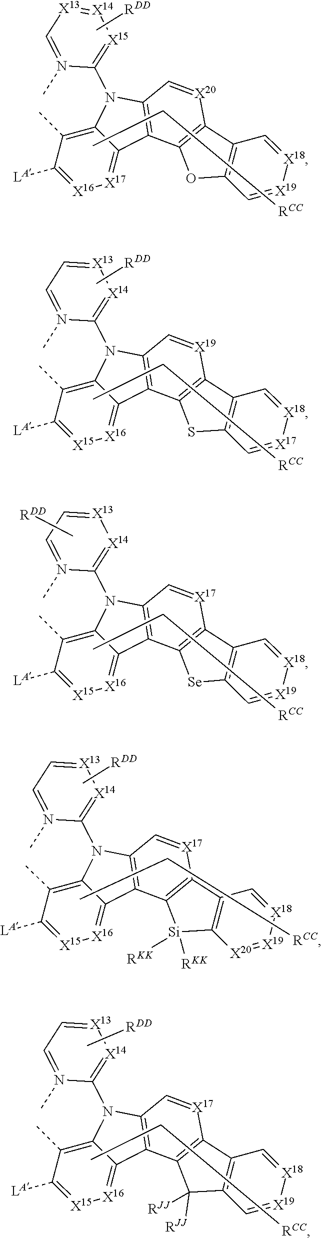 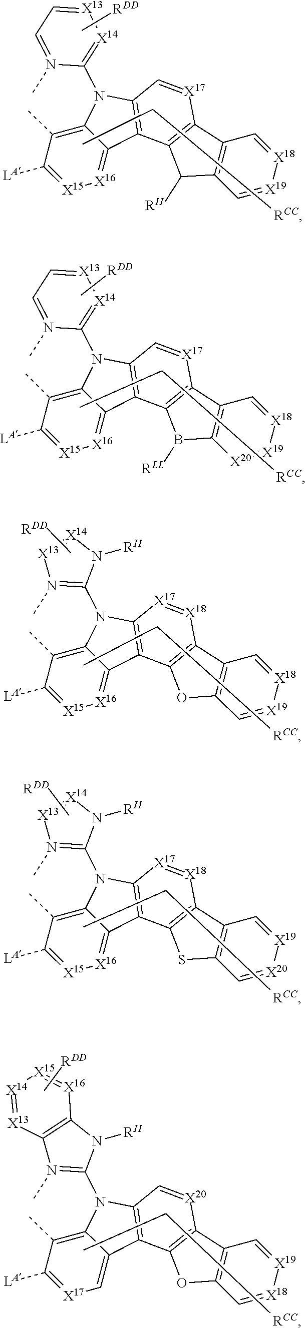 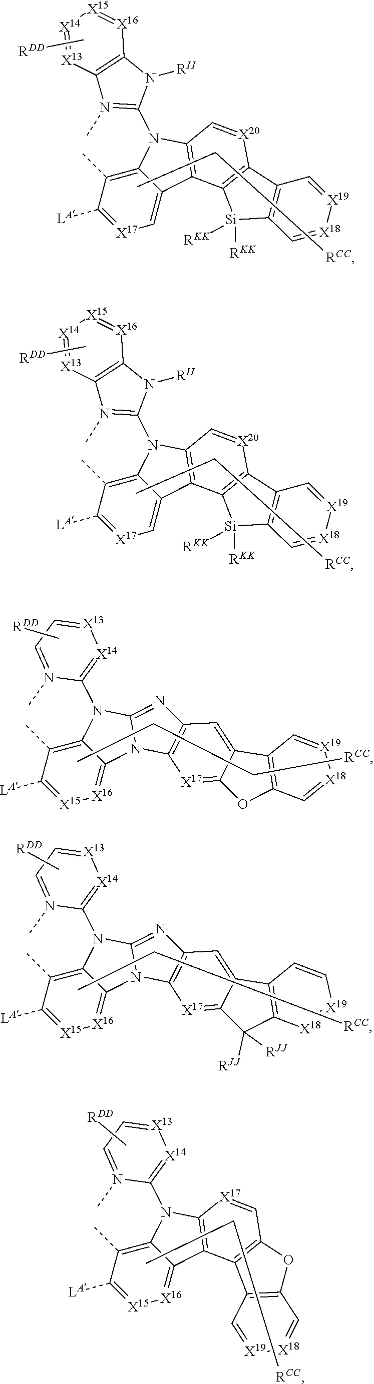 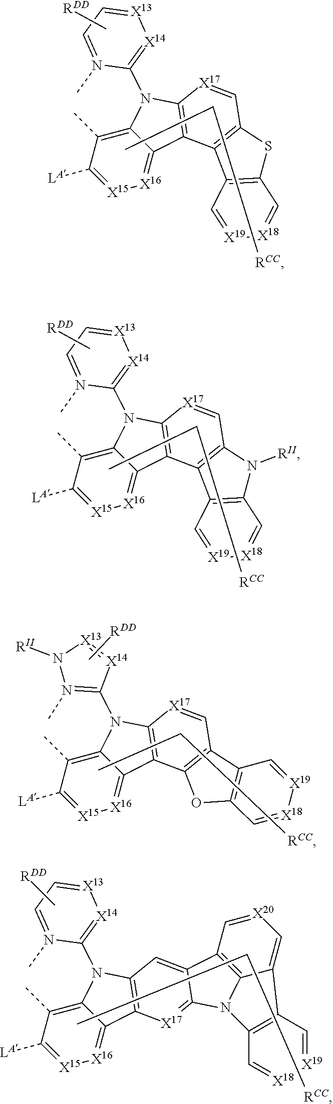 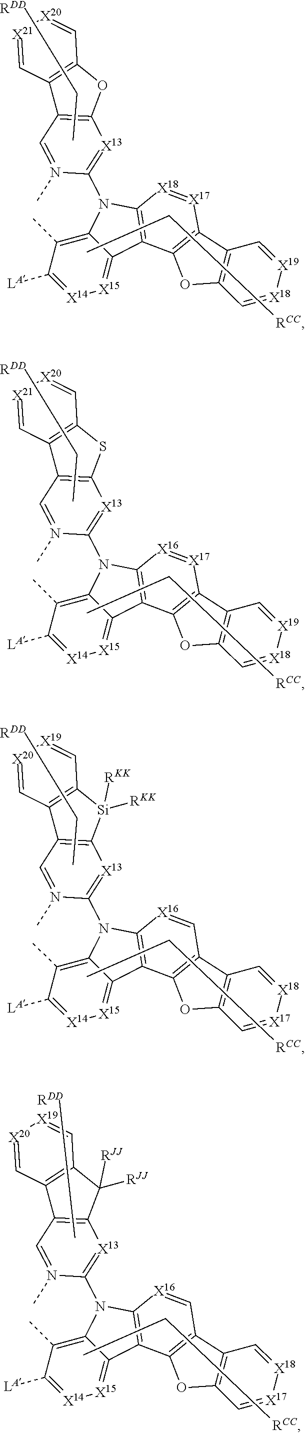 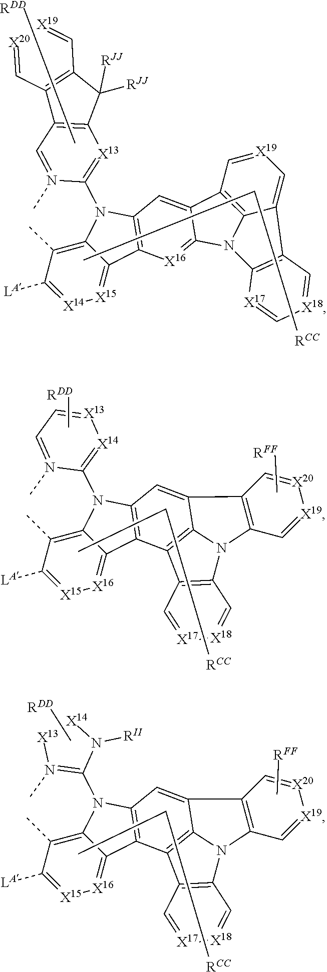 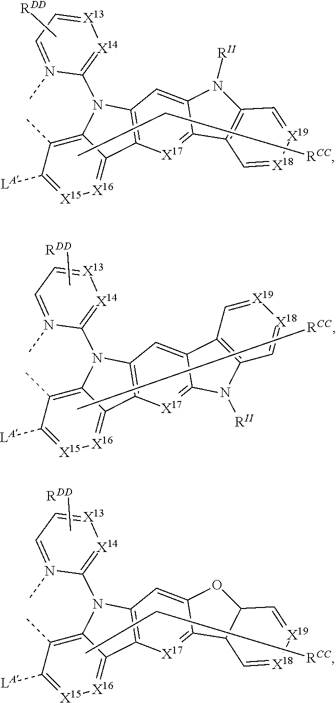 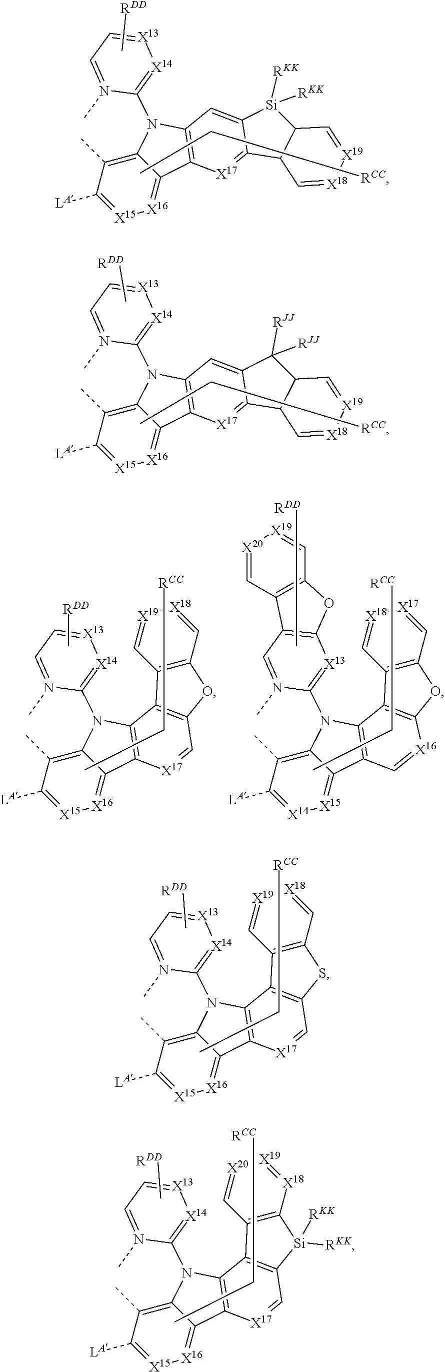 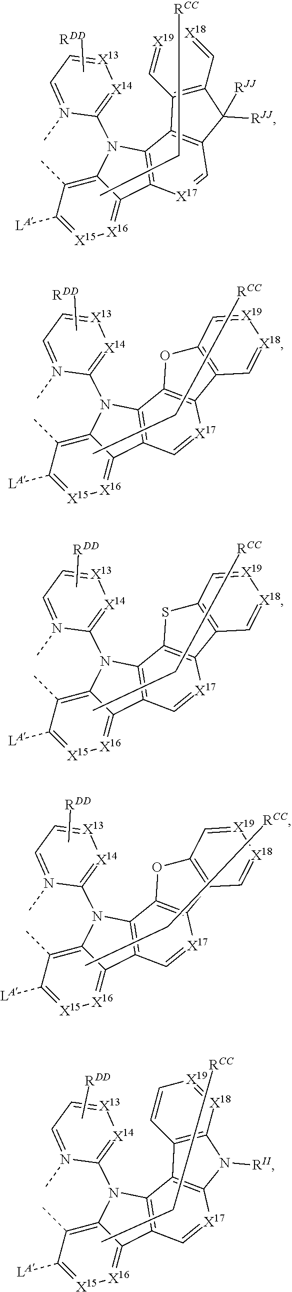 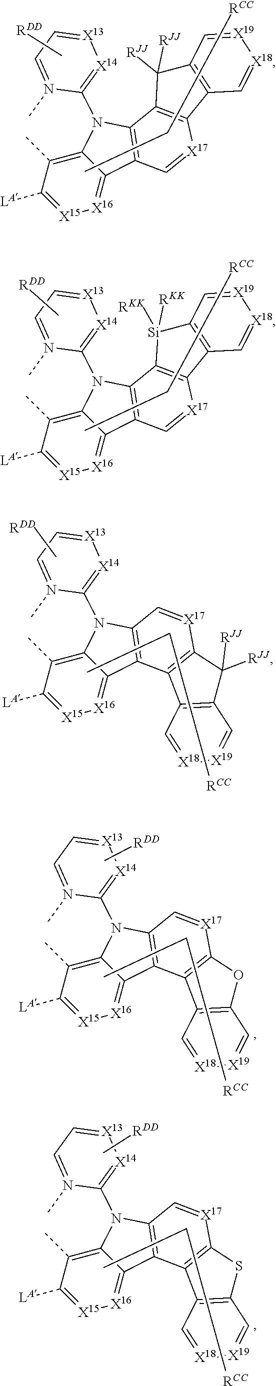 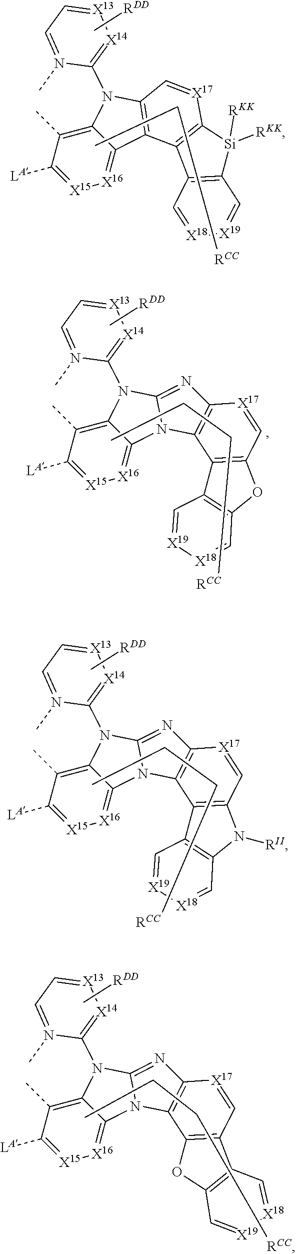 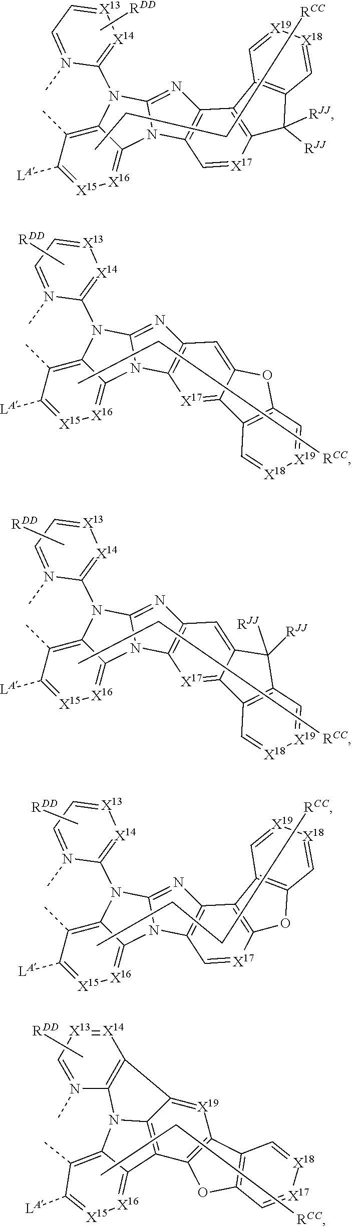 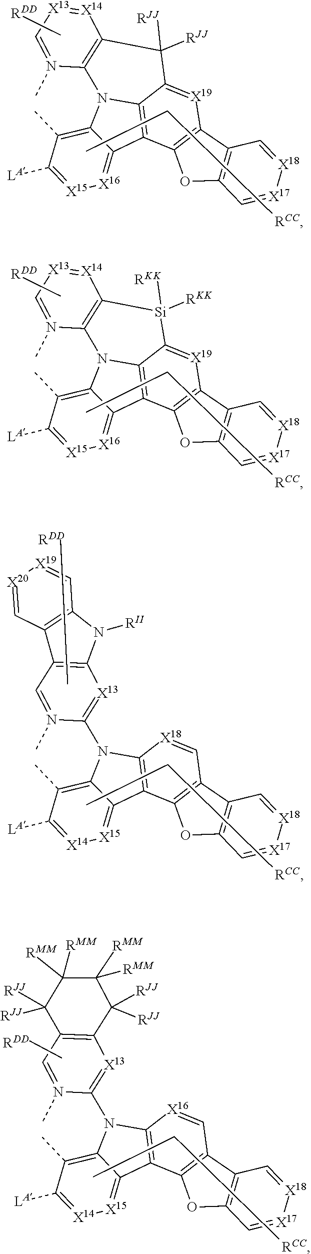 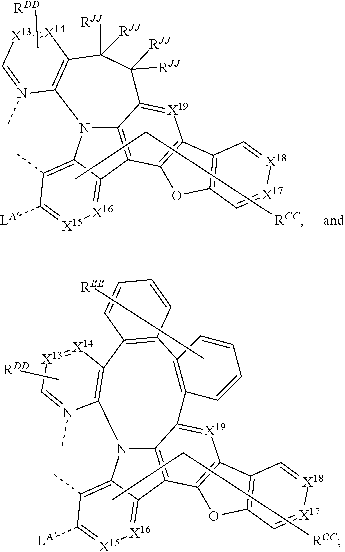
wherein each of X¹³ to X²¹ is independently C or N;
wherein R^{AA}, R^{BB}, R^{CC}, R^{DD}, and R^{EE} each independently represent mono up to the maximum possible substitutions, or no substitutions;
wherein each R^{AA}, R^{BB}, R^{CC}, R^{DD}, R^{EE}, R^{FF}, R^{II}, R^{JJ}, R^{KK}, R^{LL}, R^{MM}, and R^{NN} is independently selected from the group consisting of: 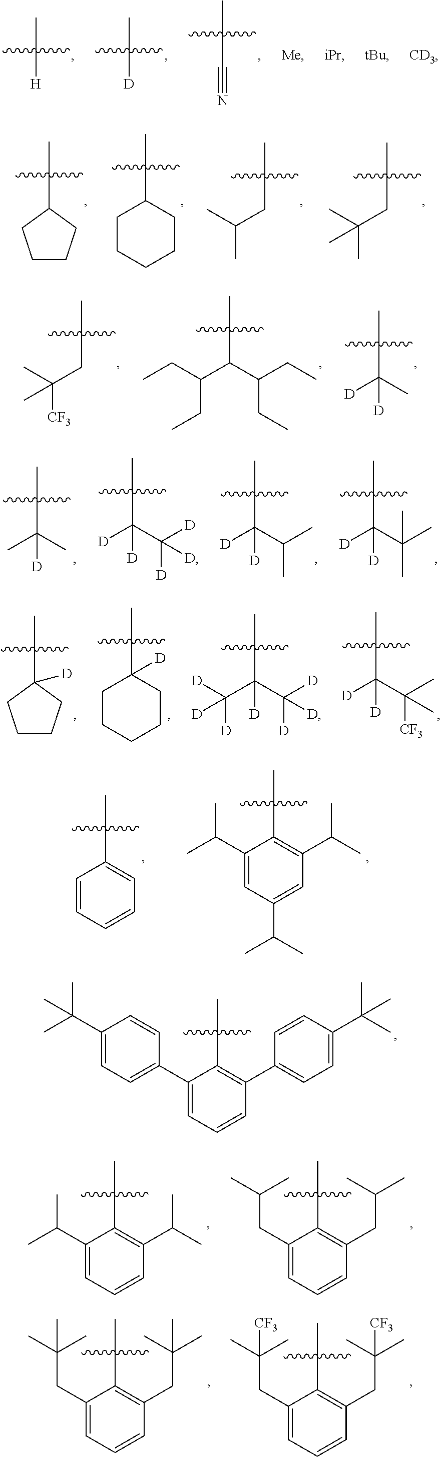 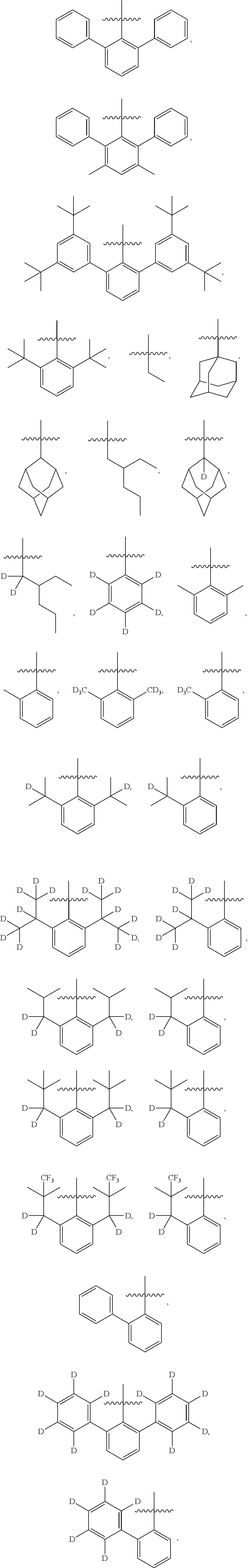 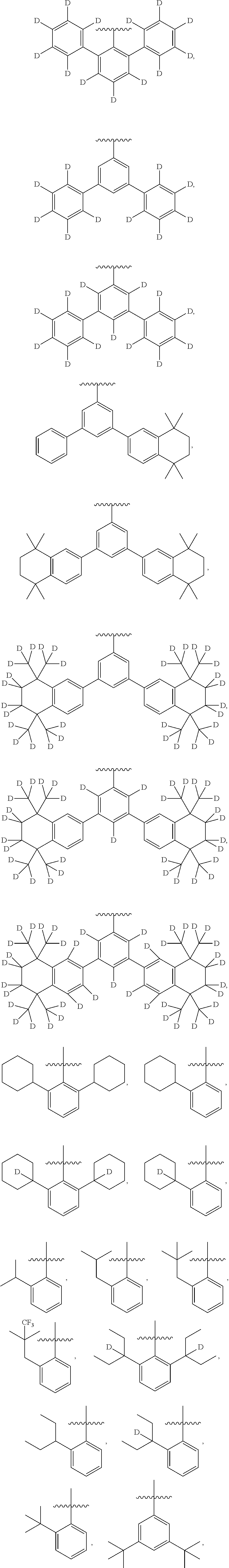 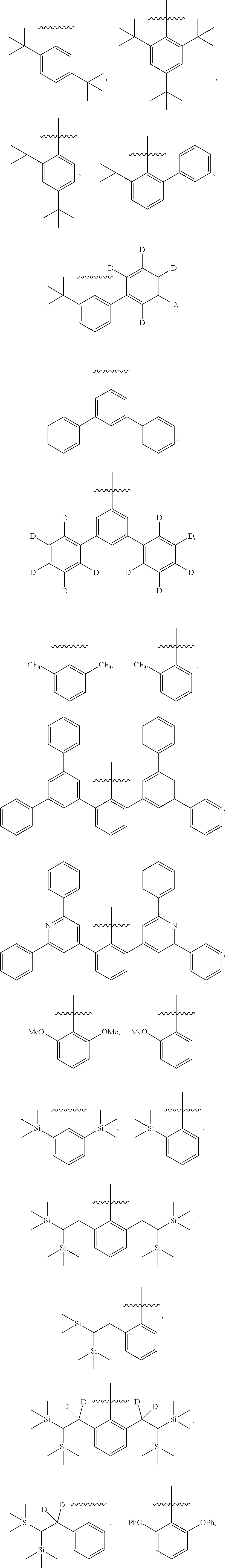 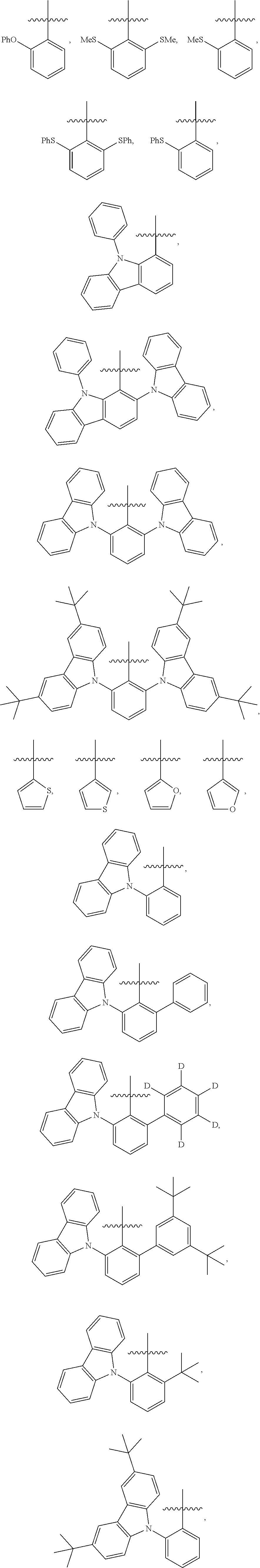 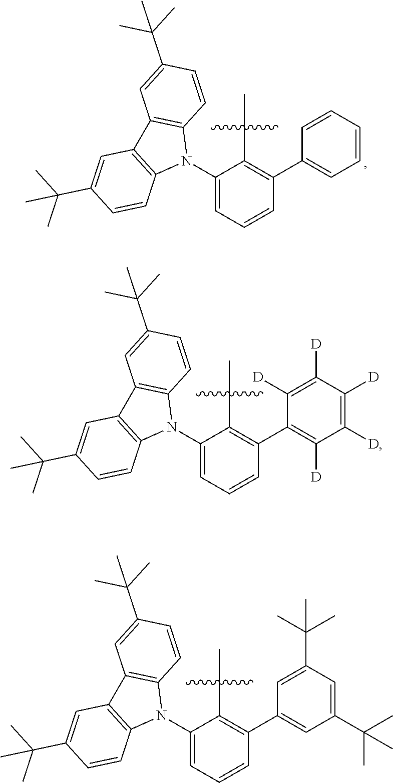 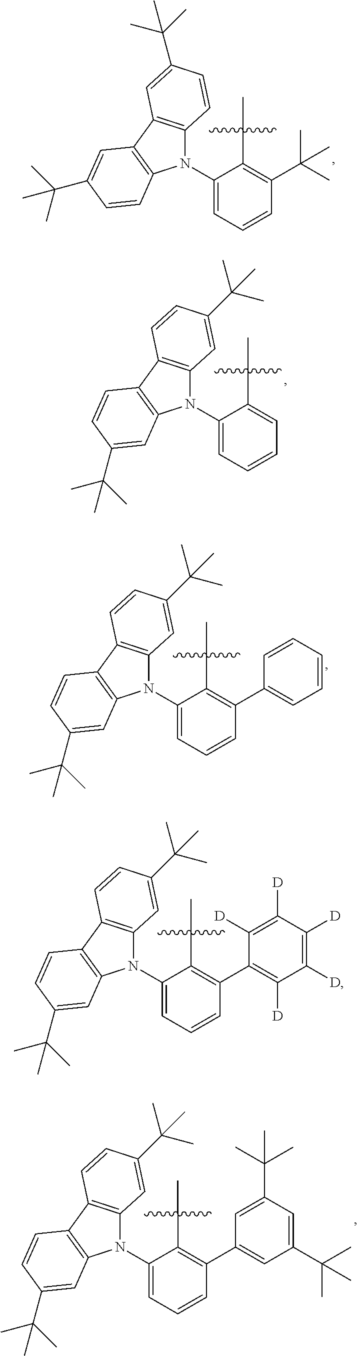 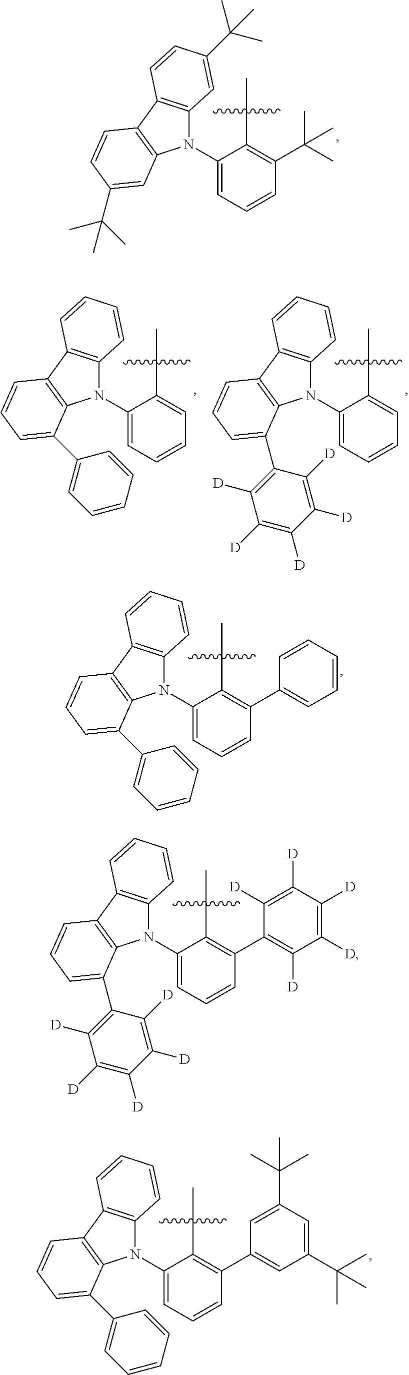 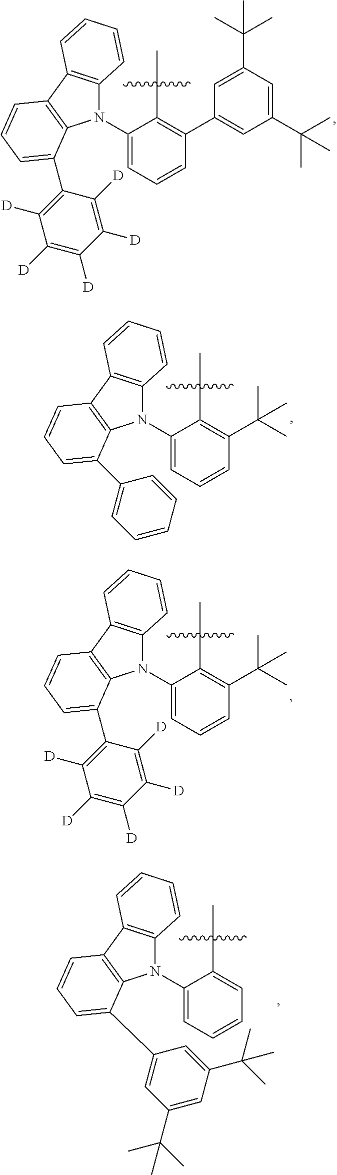 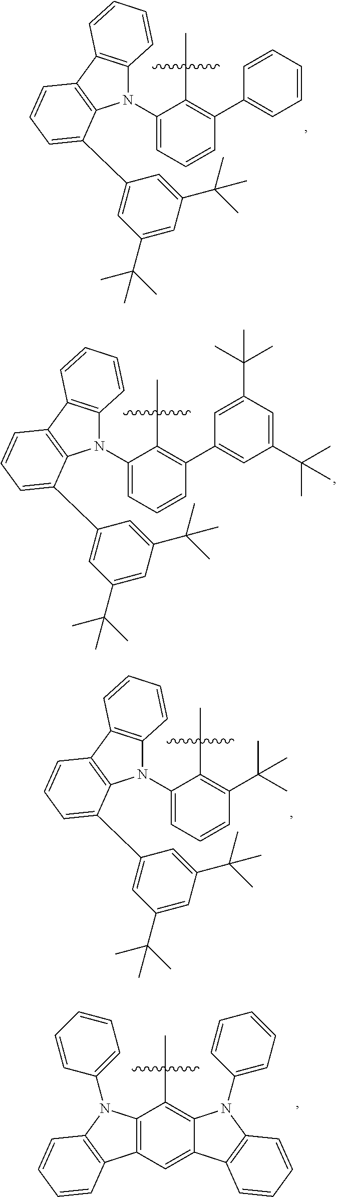 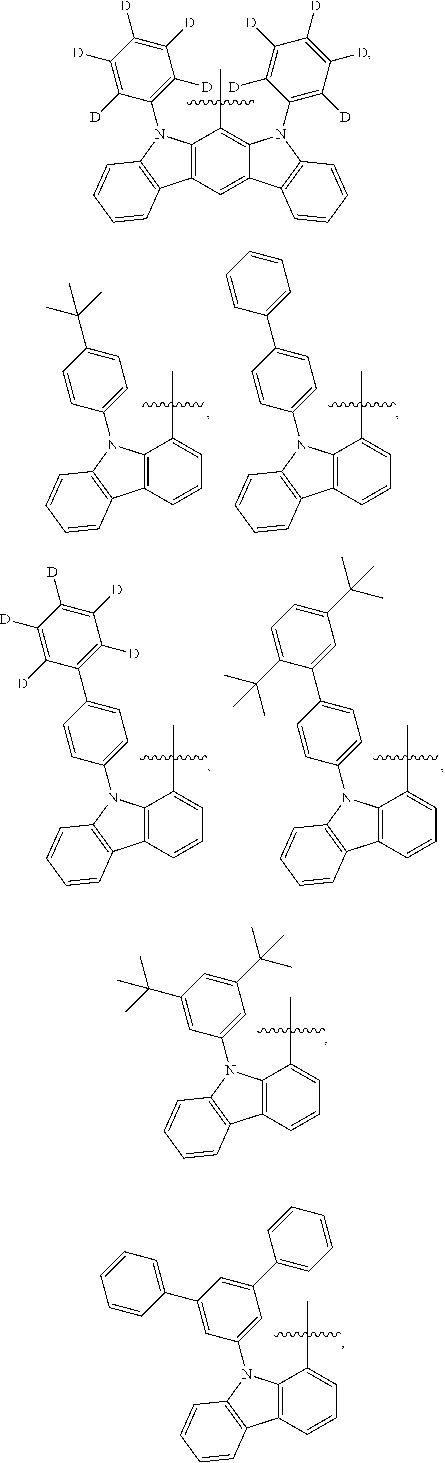 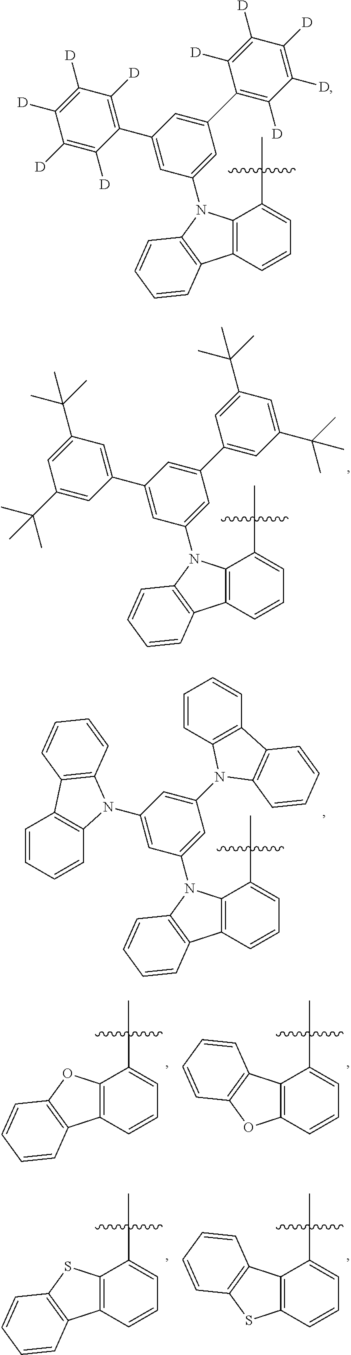 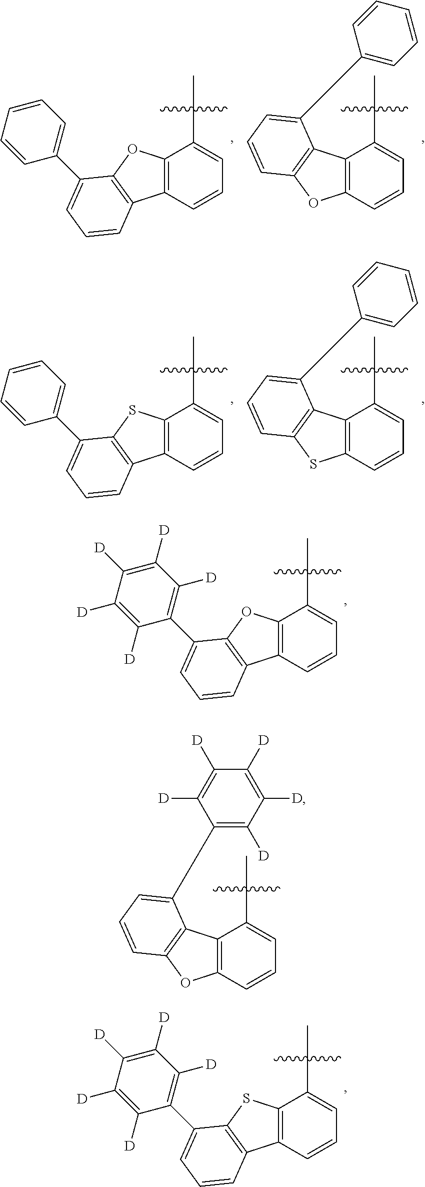 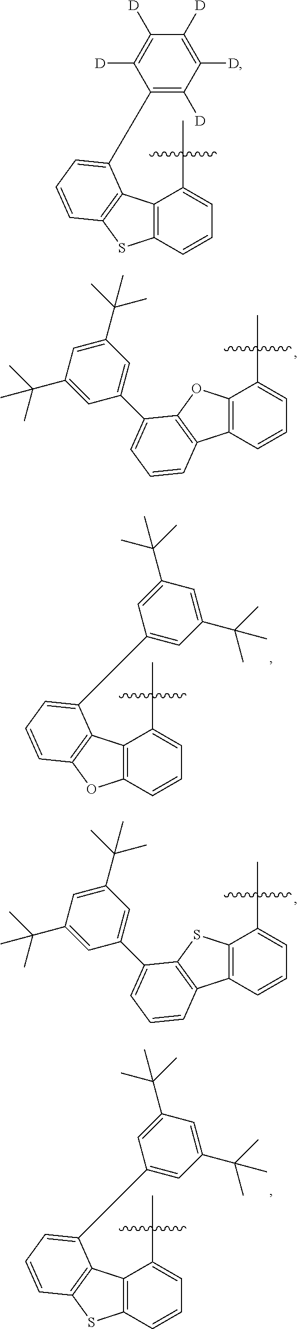 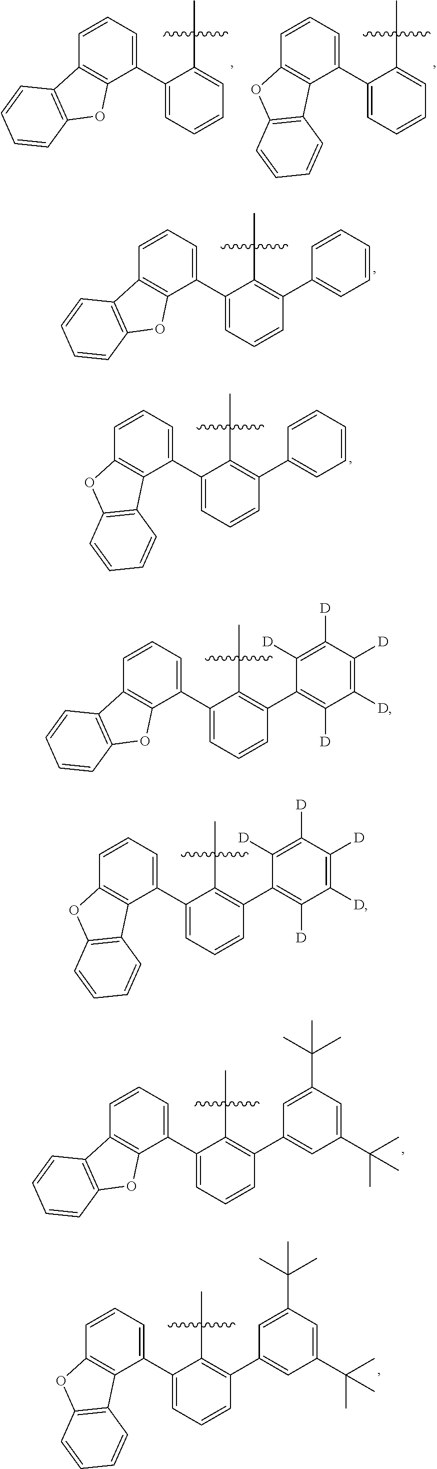 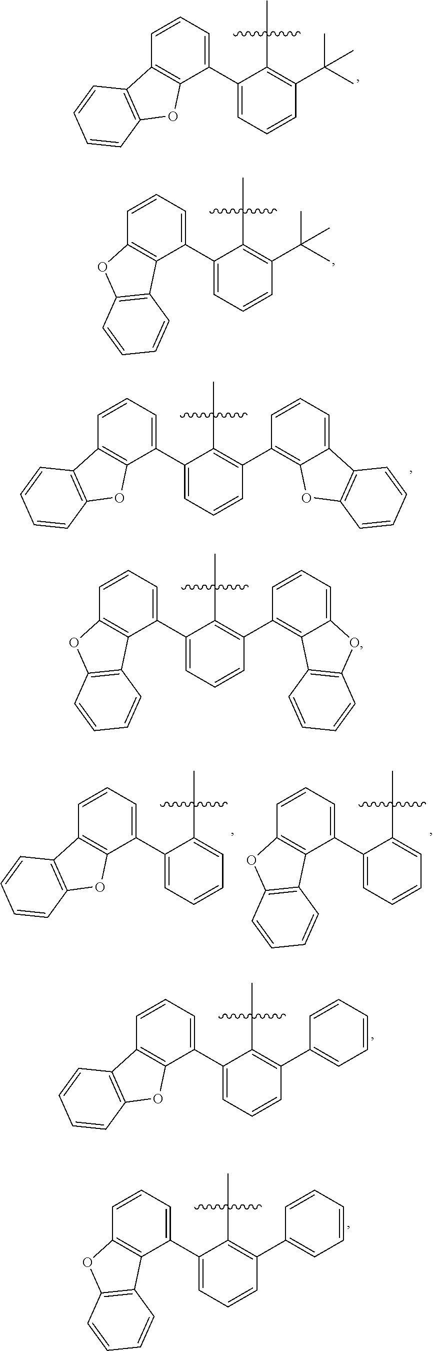 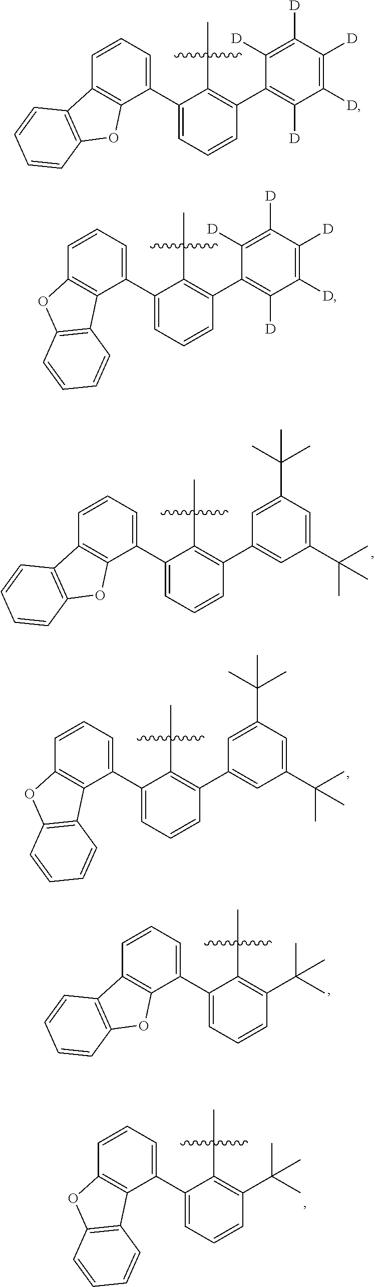 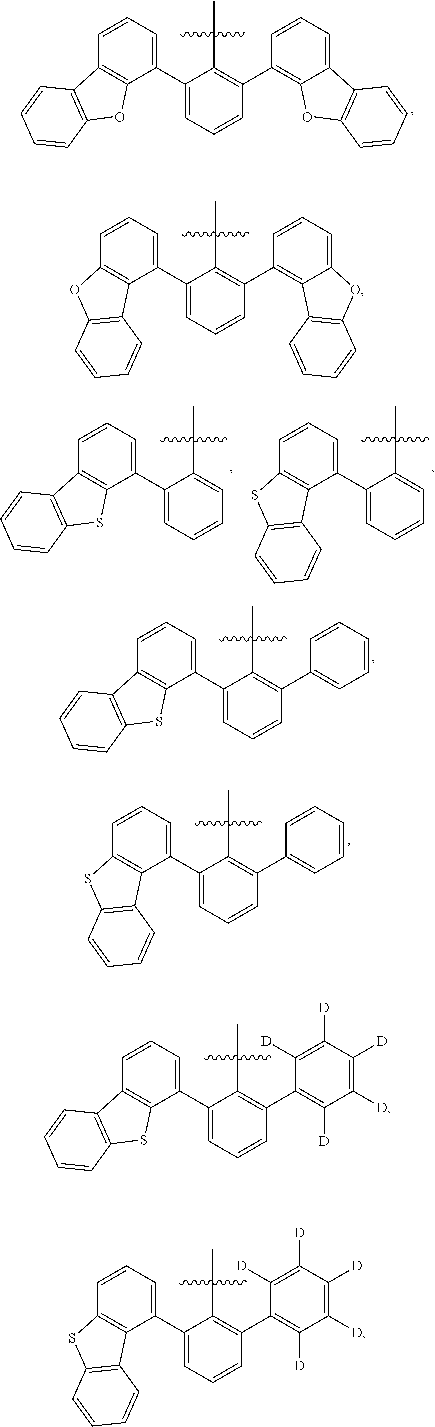 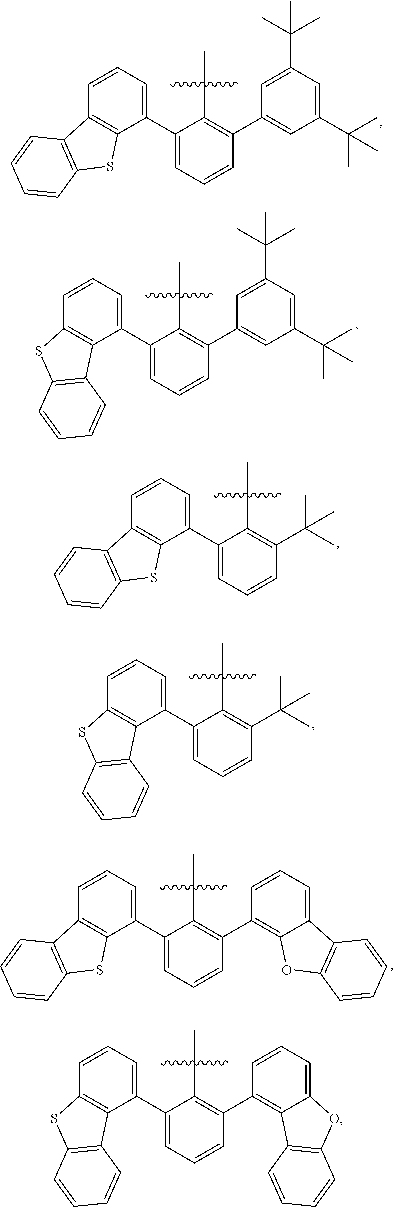 [SMILES: *c1c(-c2cc(C(C)(C)C)cc(C(C)(C)C)c2)cccc1-c1cccc2c1sc1ccccc12 ; *c1c(-c2cc(C(C)(C)C)cc(C(C)(C)C)c2)cccc1-c1cccc2sc3ccccc3c12 ; *c1c(-c2cccc3c2sc2ccccc23)cccc1C(C)(C)C ; *c1c(-c2cccc3sc4ccccc4c23)cccc1C(C)(C)C ; *c1c(-c2cccc3c2oc2ccccc23)cccc1-c1cccc2c1sc1ccccc12 ; *c1c(-c2cccc3oc4ccccc4c23)cccc1-c1cccc2sc3ccccc3c12] 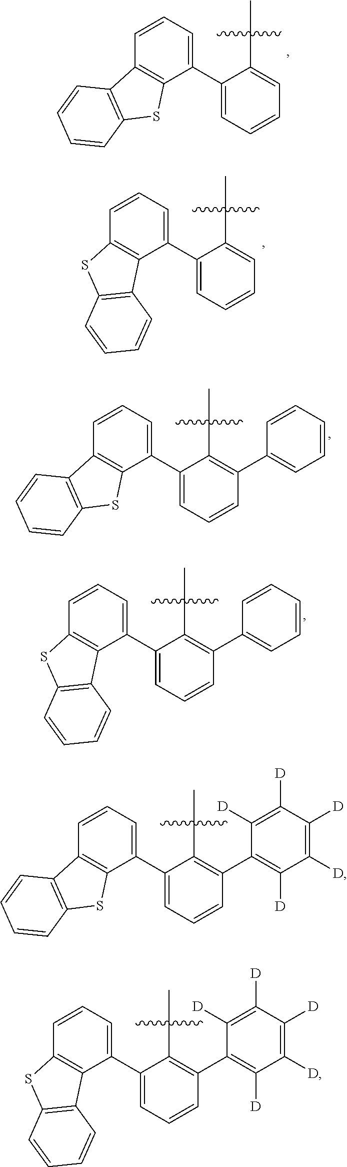 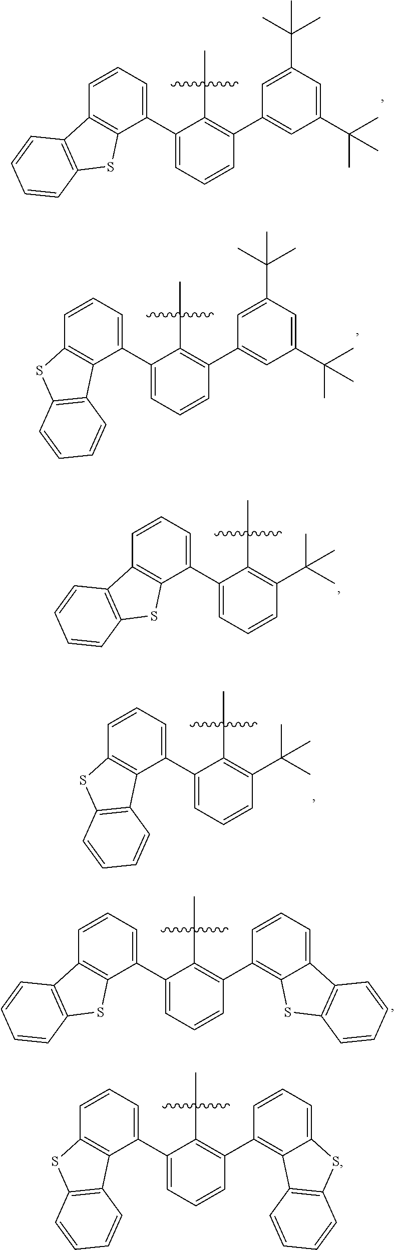 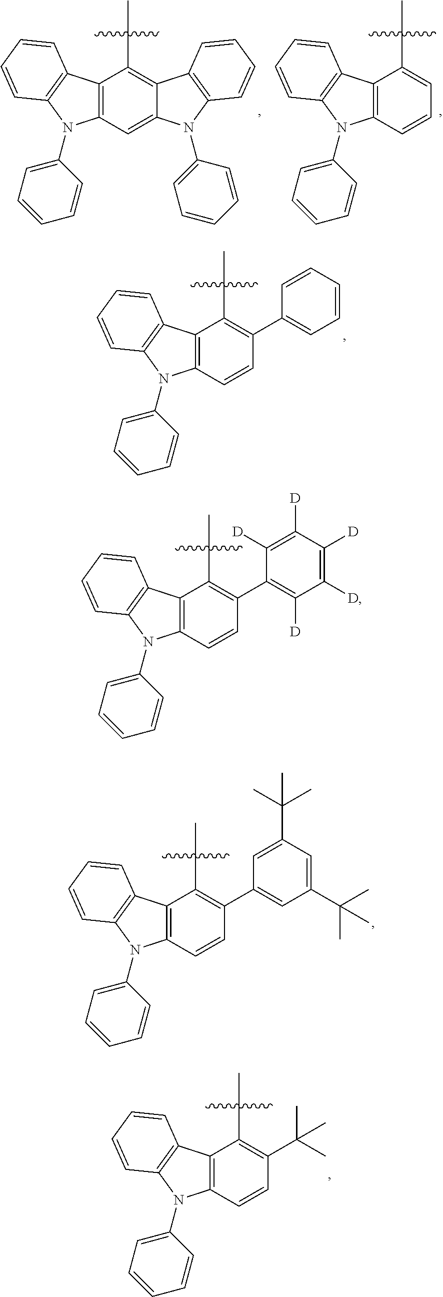 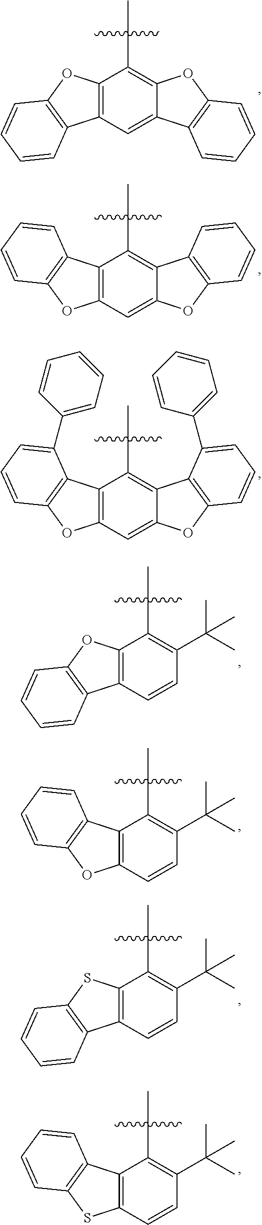 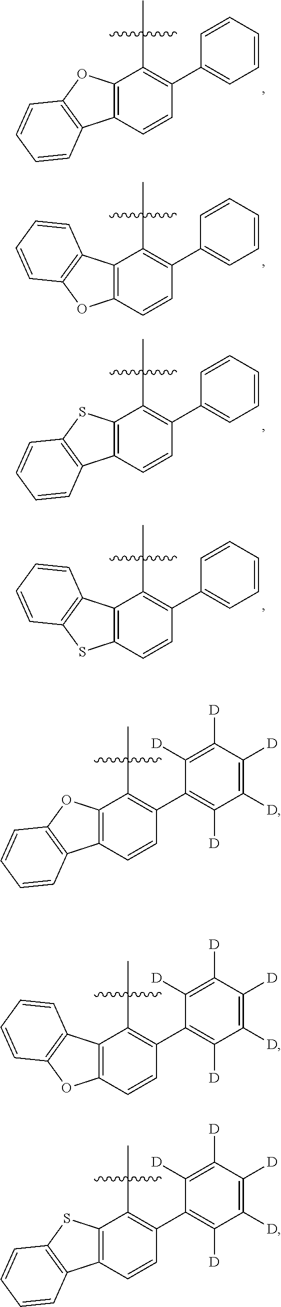 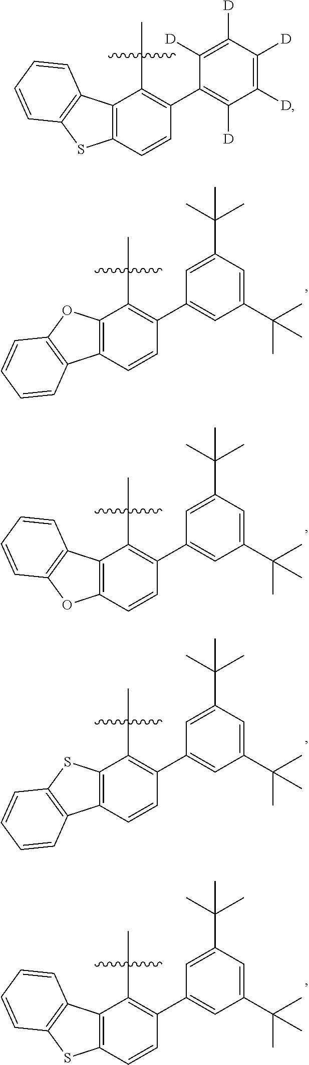 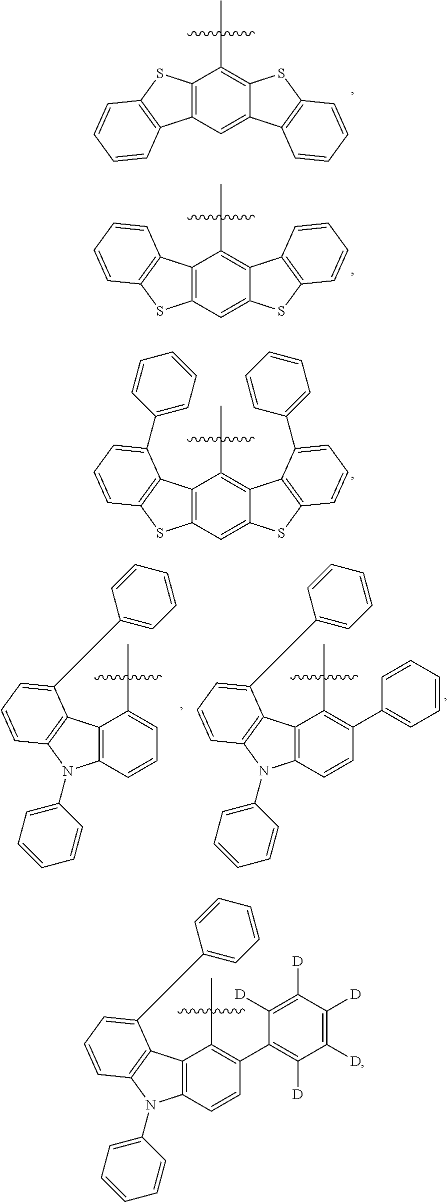 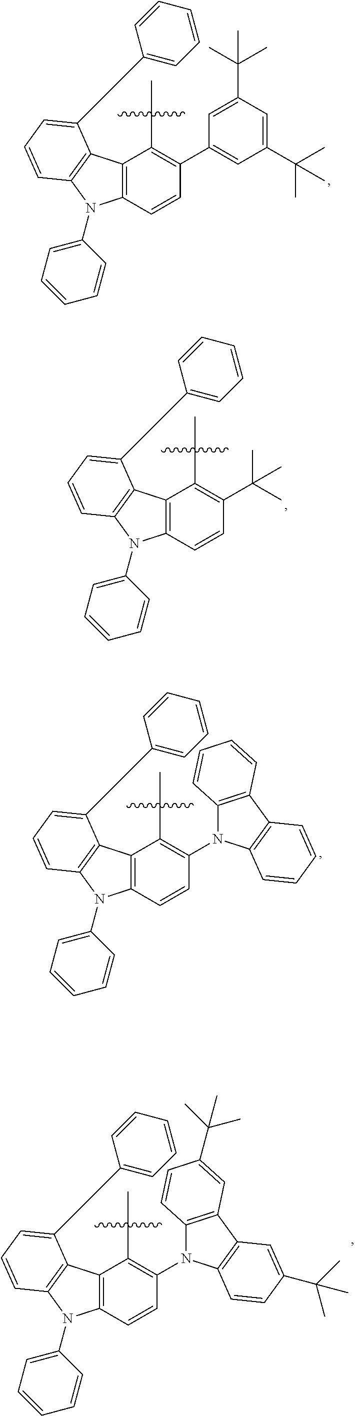 [SMILES: *c1c(-c2cc(C(C)(C)C)cc(C(C)(C)C)c2)ccc2c1c1c(-c3ccccc3)cccc1n2-c1ccccc1 ; *c1c(C(C)(C)C)ccc2c1c1c(-c3ccccc3)cccc1n2-c1ccccc1 ; *c1c(-n2c3ccccc3c3ccccc32)ccc2c1c1c(-c3ccccc3)cccc1n2-c1ccccc1 ; *c1c(-n2c3ccc(C(C)(C)C)cc3c3cc(C(C)(C)C)ccc32)ccc2c1c1c(-c3ccccc3)cccc1n2-c1ccccc1] 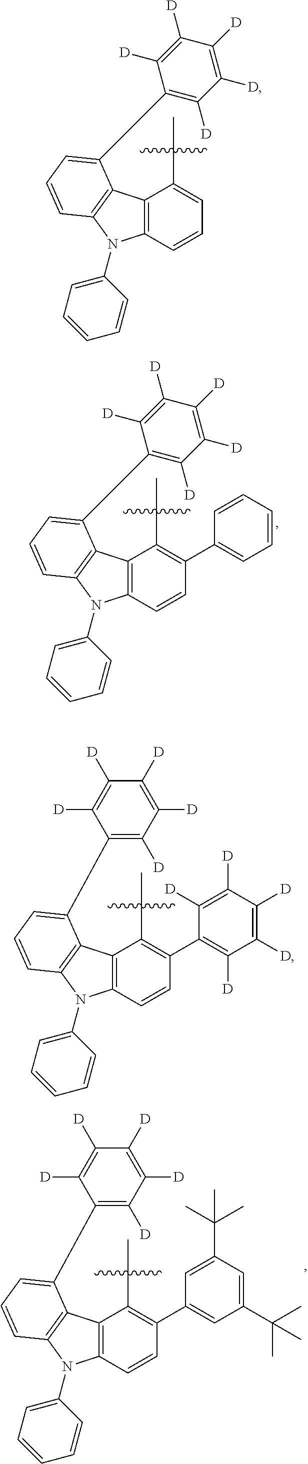 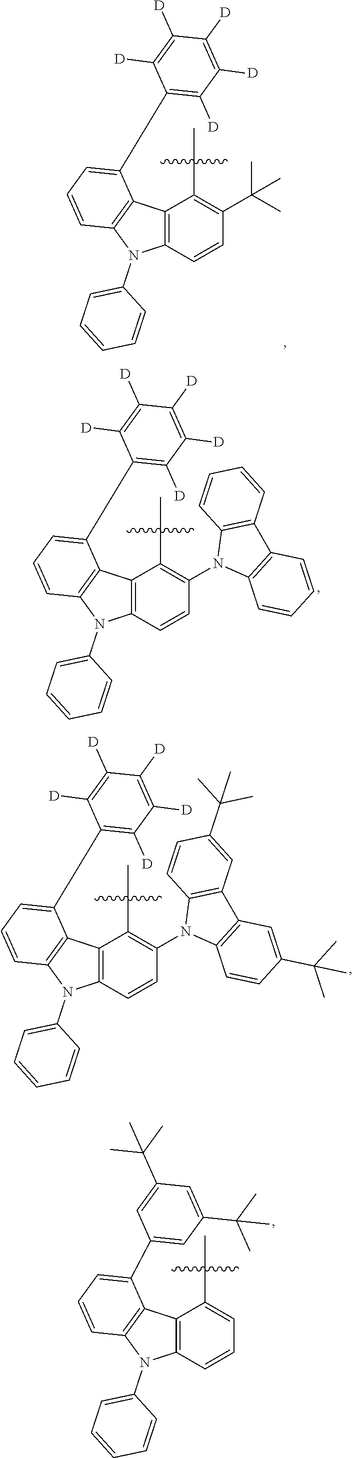 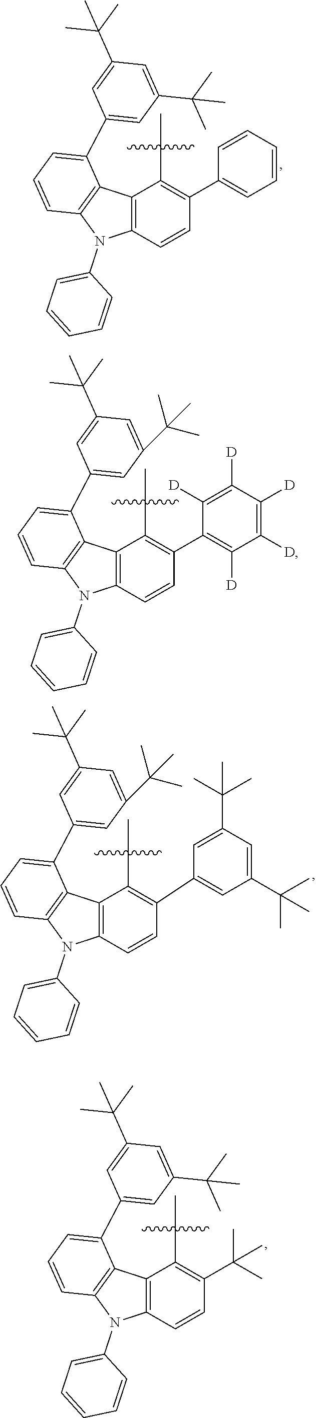 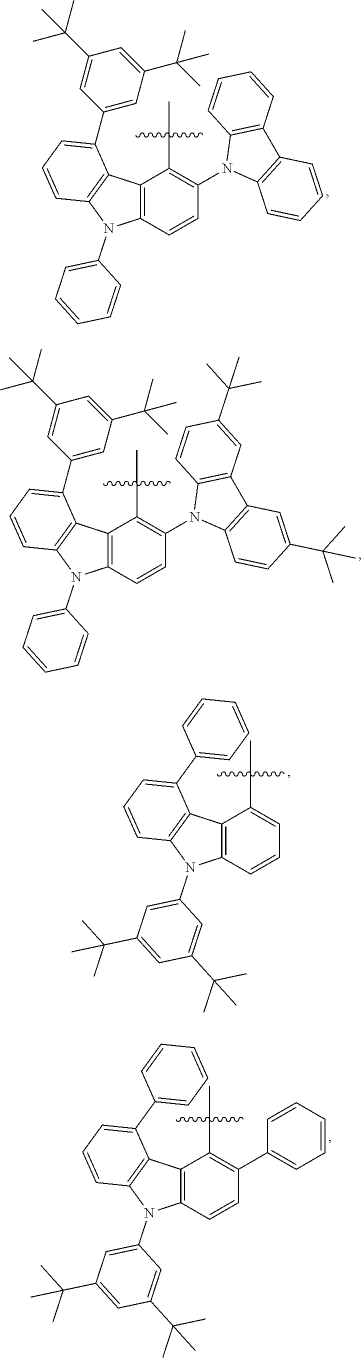 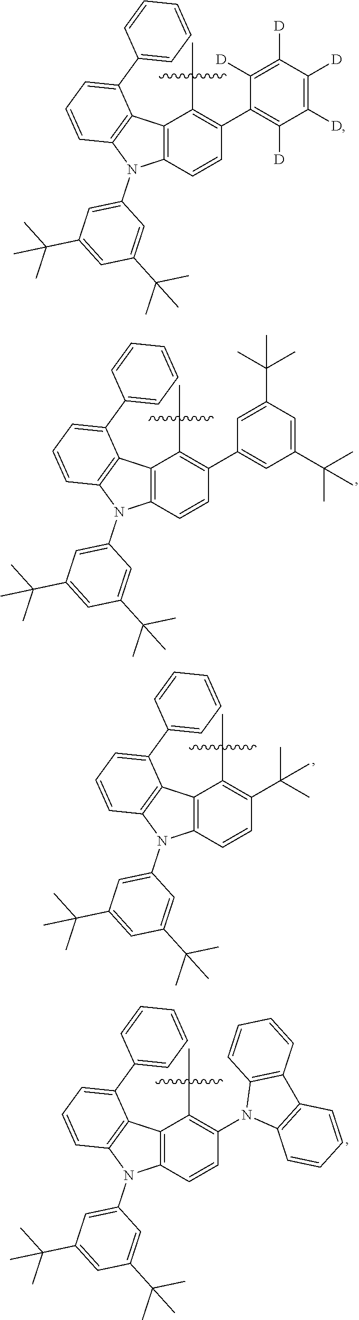 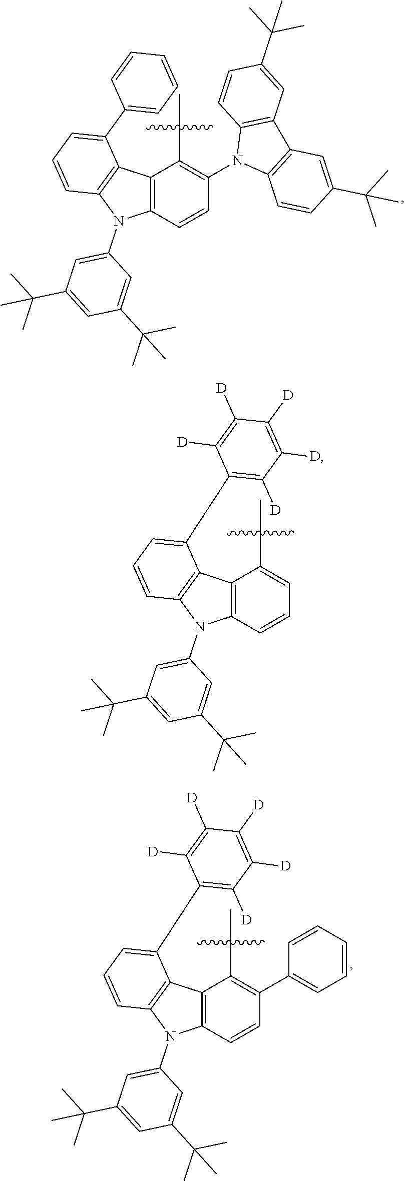 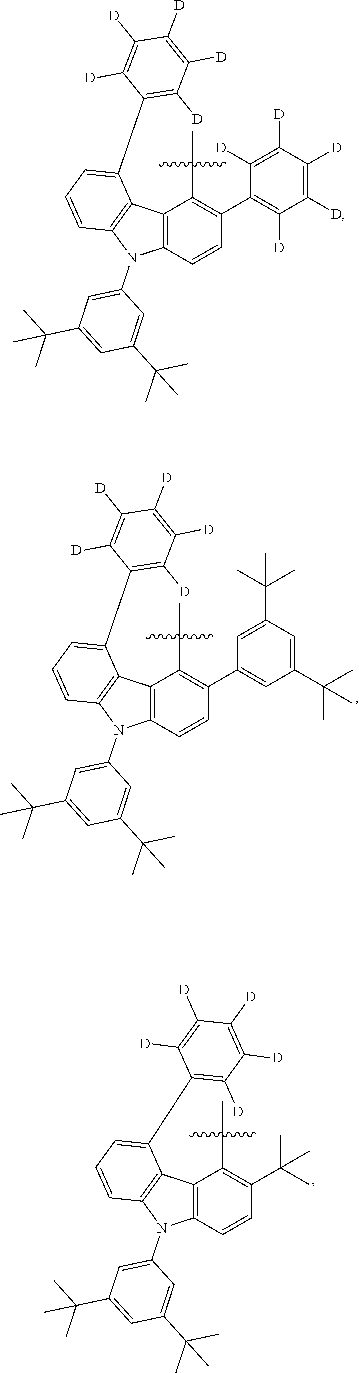 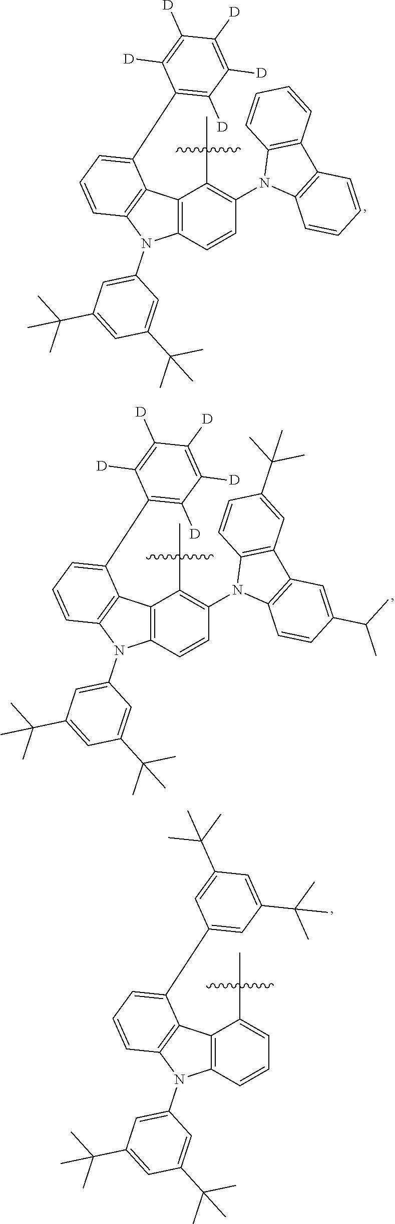 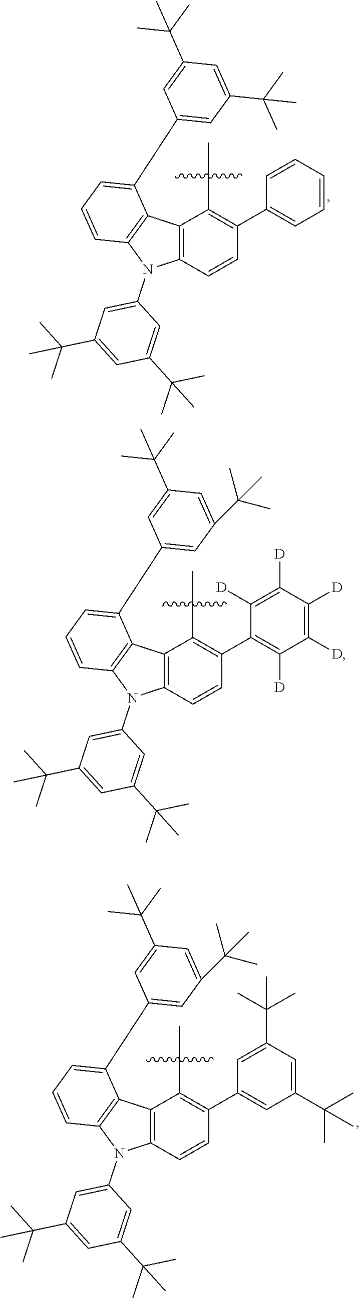 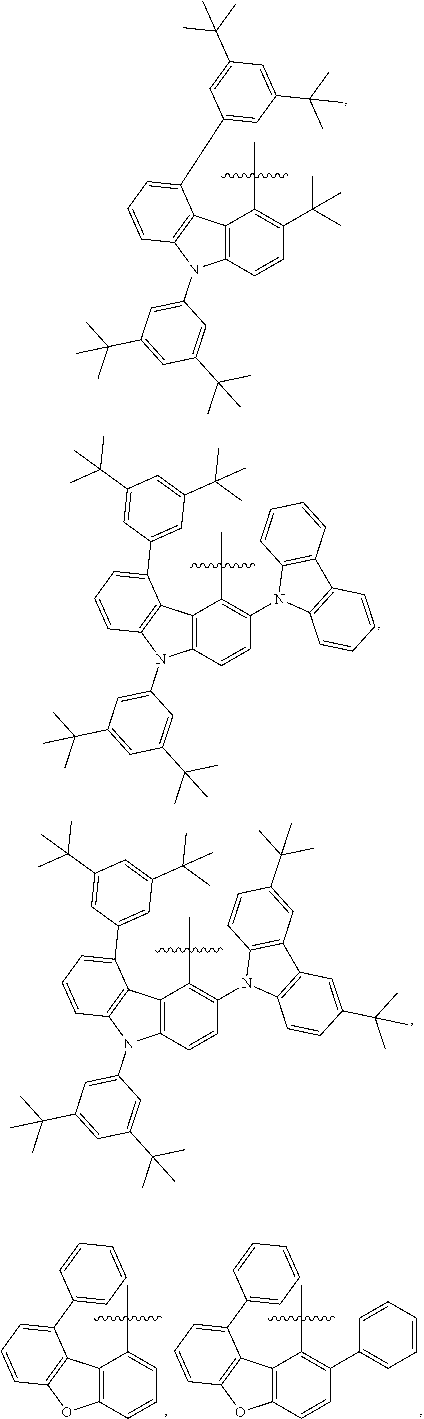 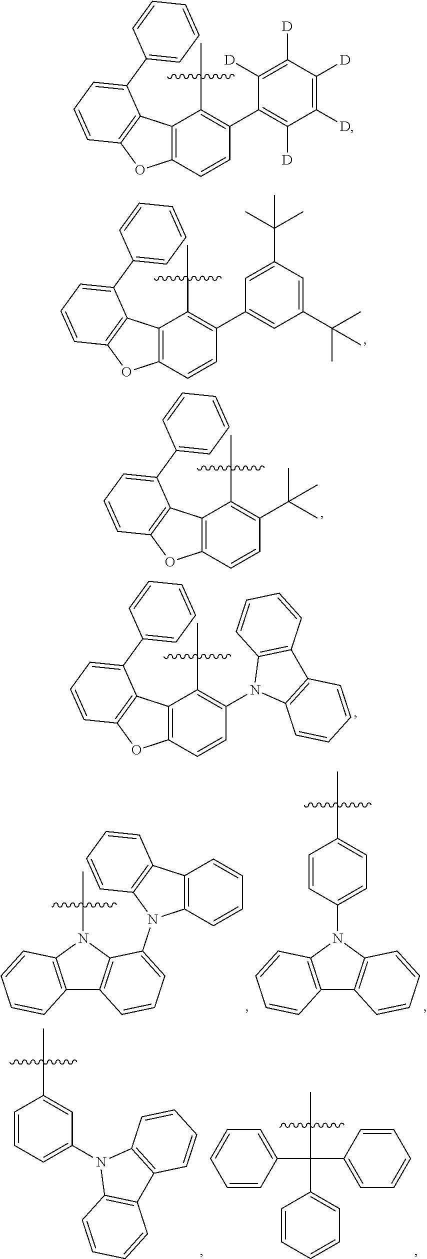 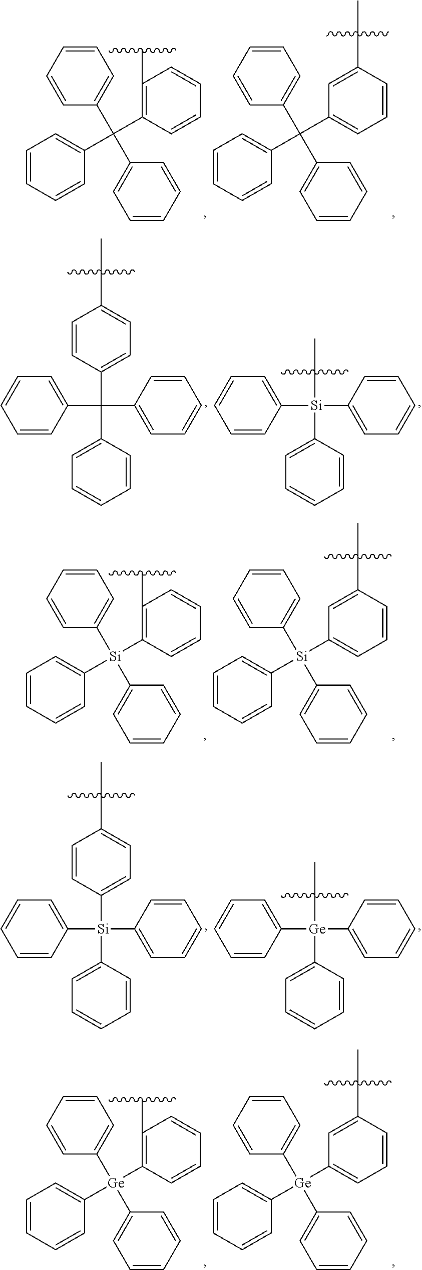 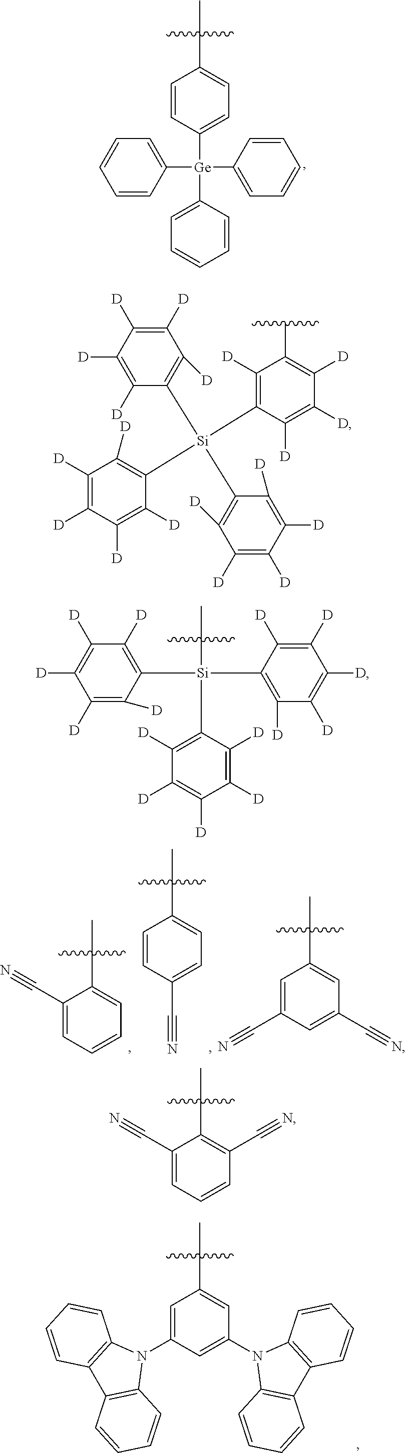 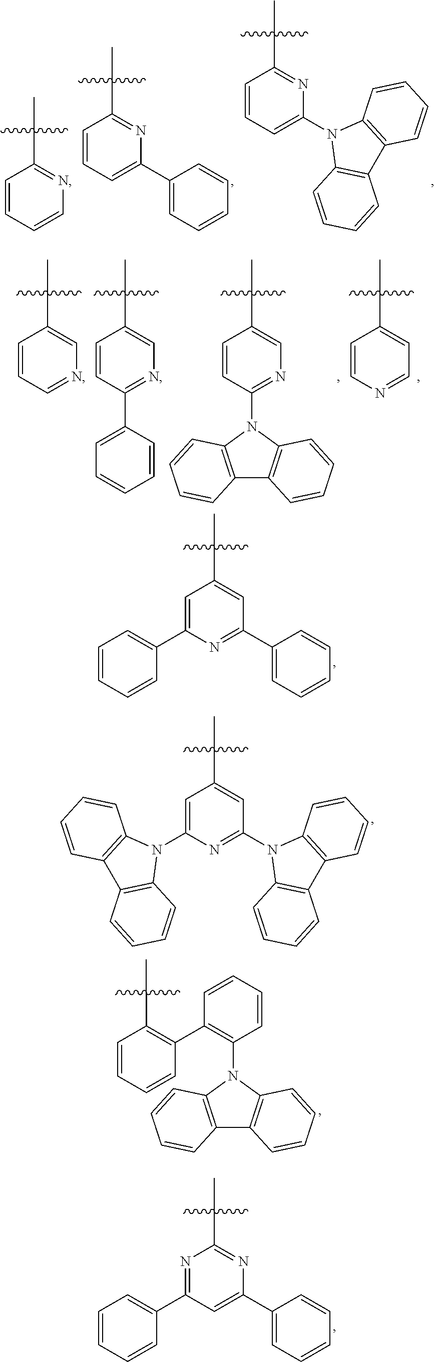 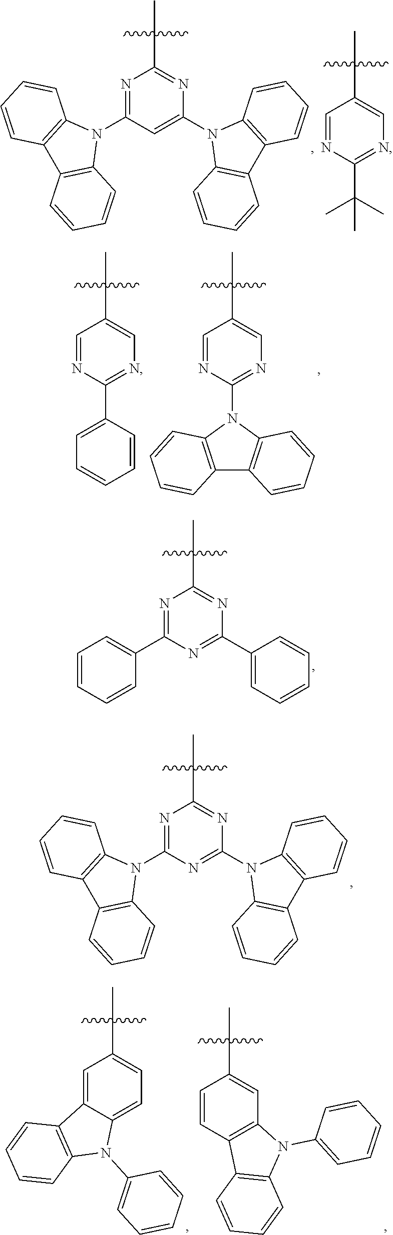 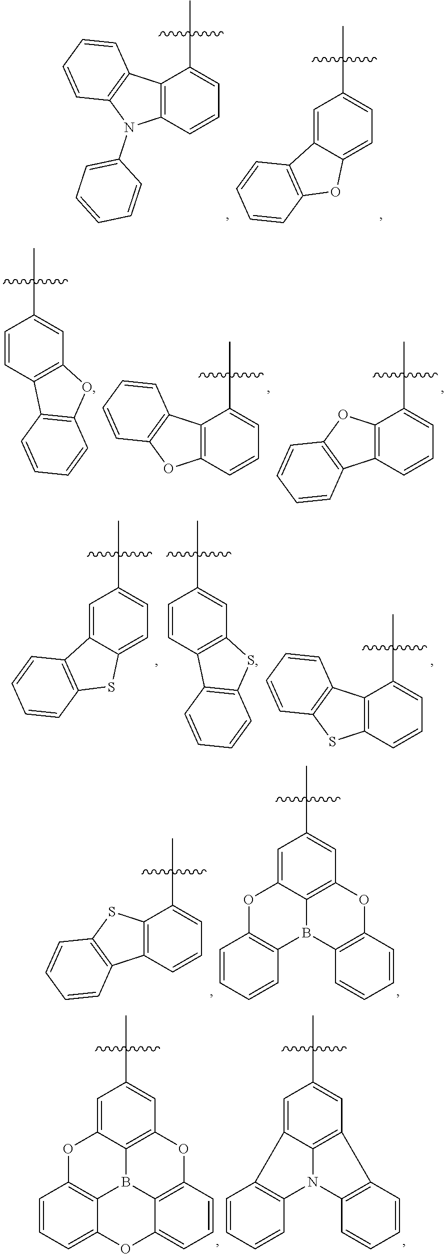 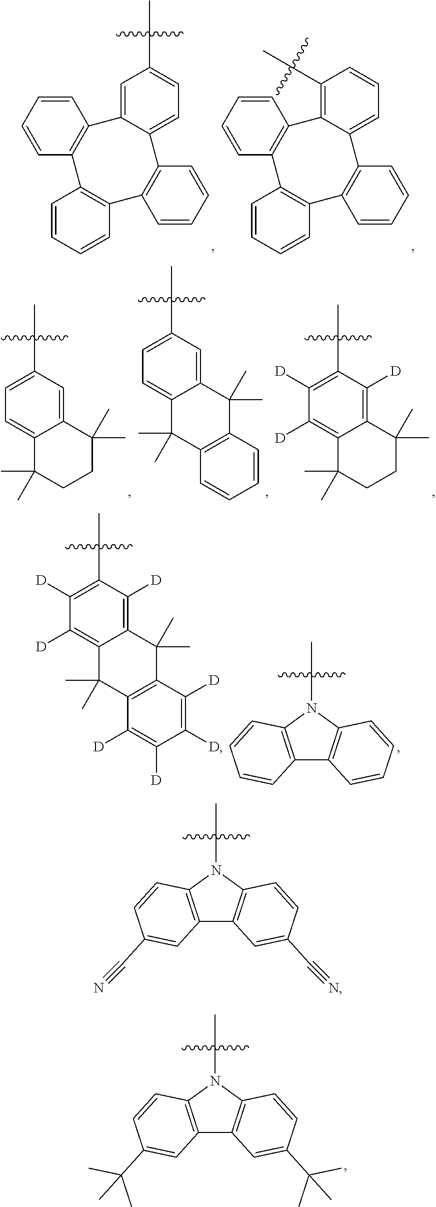 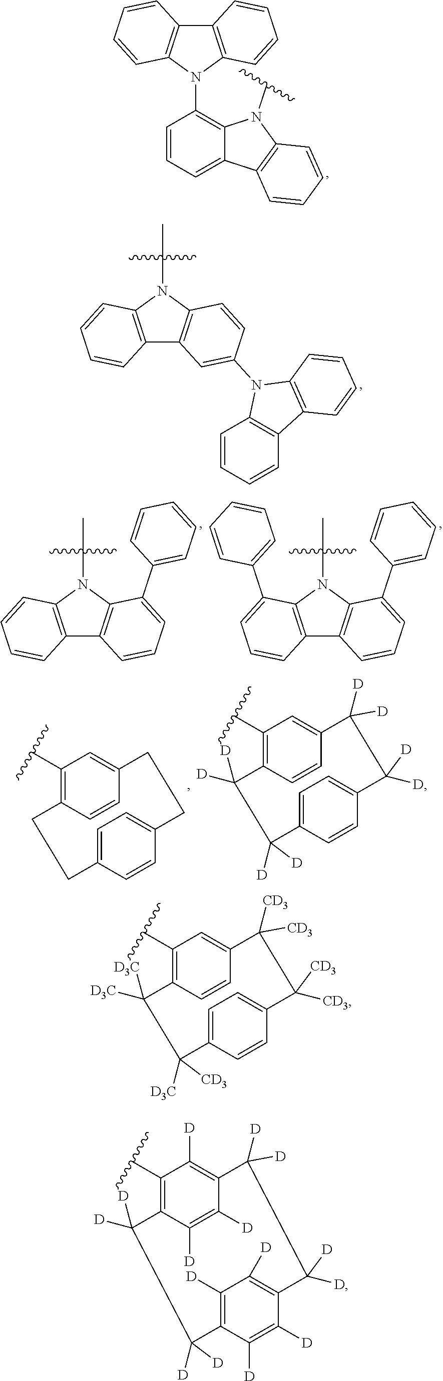 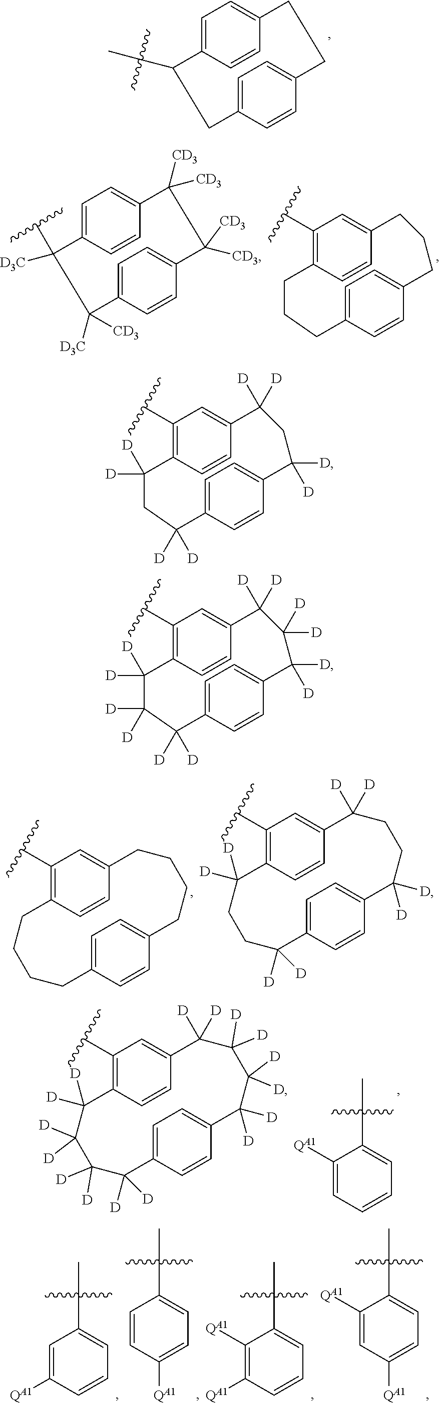 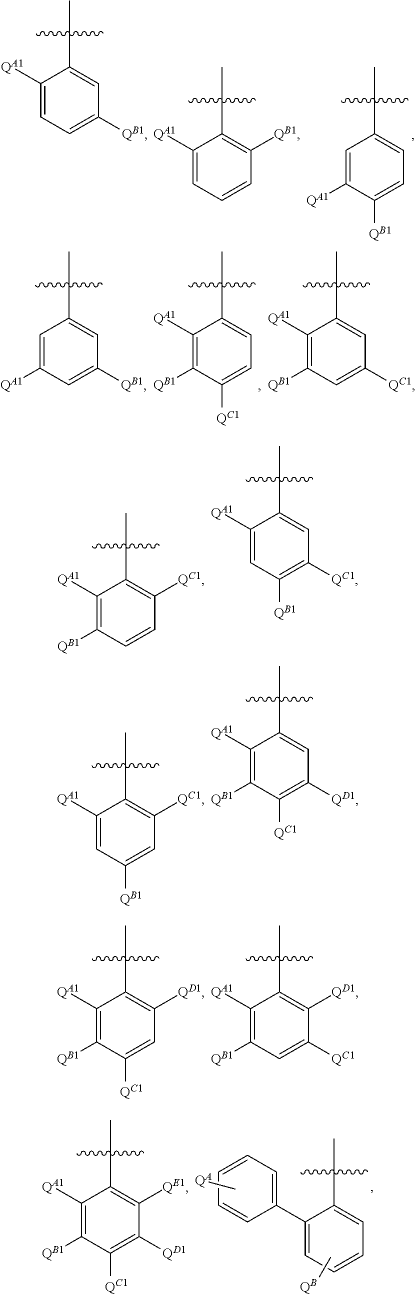 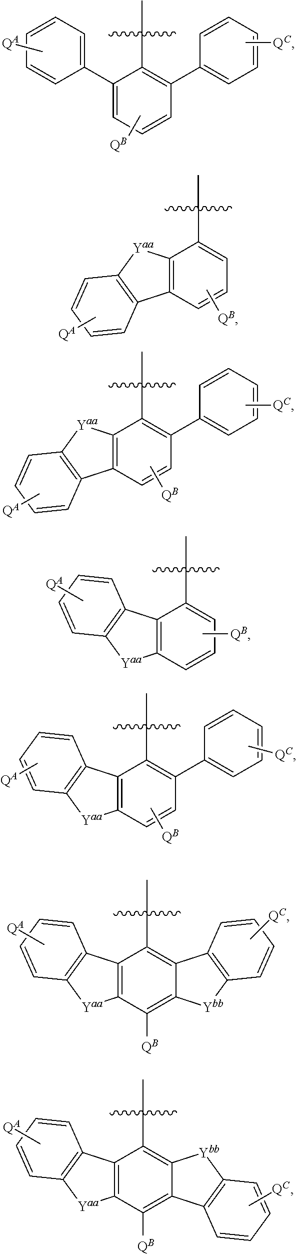 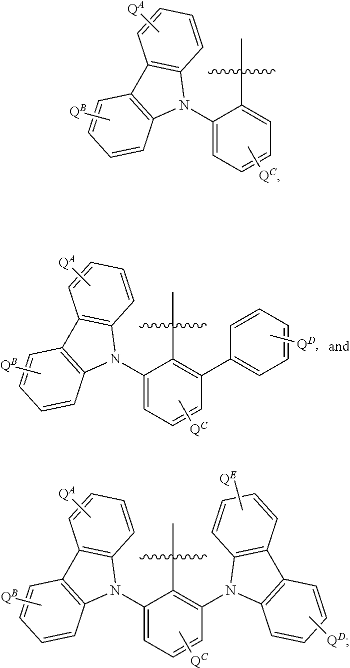
wherein each of Q^{A}, Q^{B}, Q^{C}, Q^{D}, and Q^{E} independently represents mono to the maximum allowable substitutions, or no substitutions;
wherein each Q^{A}, Q^{B}, Q^{C}, Q^{D}, Q^{E}, Q^{A1}, Q^{B1}, Q^{C1}, Q^{D1} and Q^{E1} is independently a hydrogen or a substituent selected from the group consisting of the General Substituents defined herein;
each Y^{aa} and Y^{bb} is independently selected from the group consisting of a direct bond, BR, BRR′, NR, PR, O, S, Se, C═O, C═S, C═Se, C═NR, C═CRR′, S═O, SO₂, CR, CRR′, SiRR′, GeRR′, alkyl, cycloalkyl, aryl, heteroaryl, and combinations thereof; and
any two substituents can be joined or fused to form a ring.

15. The compound of claim 1, wherein the compound is selected from the group consisting of the compounds having the formula of Pt(L_{A′})(Ly): 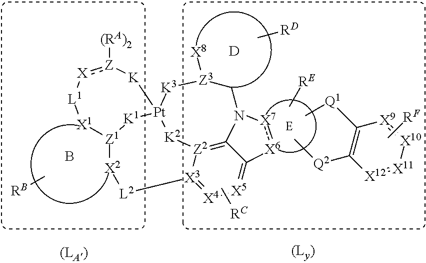
wherein L_{A′} is selected from the group consisting of structures L_{A′}1-(Ri)(Rj)(Rk)(Rl) to L_{A′}63-(Rj)(Rk)(Ru), wherein each of i, j, k, l, m, s, t, u, and v is independently an integer from 1 to 135, and L_{A′}1-(R1)(R1)(R1)(R1) to L_{A′}63-(R135)(R135)(R135) have the structures defined as follows:

| | |
|---|---|
| L_{A′}1-(Ri)(Rj)(Rk)(Rl), wherein L_{A′}1- (R1)(R1)(R1)(R1) to L_{A′}1- (R135)(R135)(R135)(R135) have the structure | 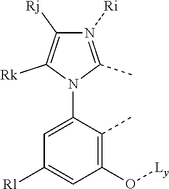 |
| L_{A′}2-(Ri)(Rj)(Rk), wherein L_{A′}2-(R1)(R1)(R1) to L_{A′}2- (R135)(R135)(R135) have the structure | 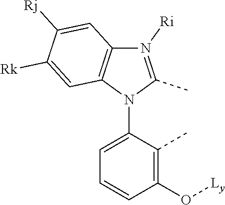 |
| L_{A′}3-(Ri)(Rj)(Rt), wherein L_{A′}3-(R1)(R1)(R1) to L_{A′}3- (R135)(R135)(R135) have the structure | 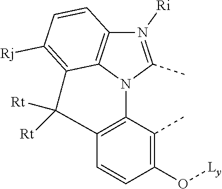 |
| L_{A′}4-(Ri)(Rj)(Rs), wherein L_{A′}4-(R1)(R1)(R1) to L_{A′}4- (R135)(R135)(R135) have the structure | 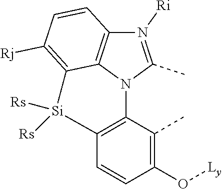 |
| L_{A′}5-(Ri)(Rj)(Rk), wherein L_{A′}5-(R1)(R1)(R1) to L_{A′}5- (R135)(R135)(R135) have the structure | 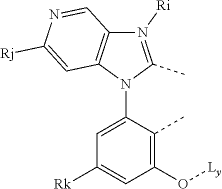 |
| L_{A′}6-(Ri)(Rj)(Rk), wherein L_{A′}6-(R1)(R1)(R1) to L_{A′}6- (R135)(R135)(R135) have the structure | 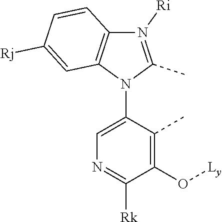 |
| L_{A′}7-(Ri)(Rj)(Rk), wherein L_{A′}7-(R1)(R1)(R1) to L_{A′}7- (R135)(R135)(R135) have the structure | 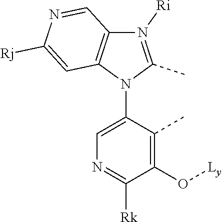 |
| L_{A′}8-(Ri)(Rj)(Rk)(Rl), wherein L_{A′}8- (R1)(R1)(R1)(R1) to L_{A′}8- (R135)(R135)(R135)(R135) have the structure | 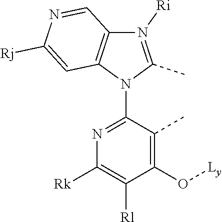 |
| L_{A′}9-(Ri)(Rj)(Rk), wherein L_{A′}9-(R1)(R1)(R1) to L_{A′}9- (R135)(R135)(R135) have the structure | 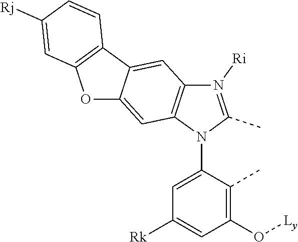 |
| L_{A′}10-(Ri)(Rj)(Rk), wherein L_{A′}10- (R1)(R1)(R1) to L_{A′}10- (R135)(R135)(R135) have the structure | 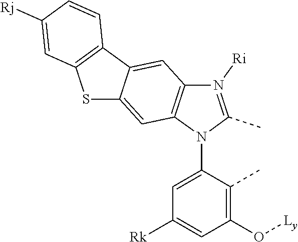 |
| L_{A′}11-(Ri)(Rj)(Rs), wherein L_{A′}11- (R1)(R1)(R1) to L_{A′}11- (R135)(R135)(R135) have the structure | 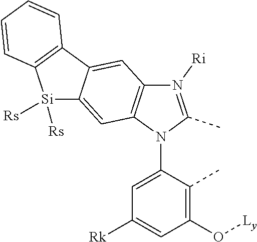 |
| L_{A′}12-(Ri)(Rj)(Rk)(Rt), wherein L_{A′}12- (R1)(R1)(R1)(R1) to L_{A′}12- (R135)(R135)(R135)(R135) have the structure | 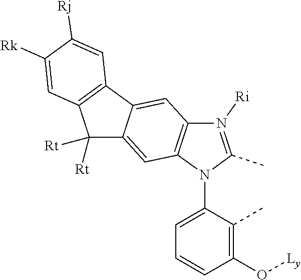 |
| L_{A′}13-(Ri)(Rj)(Rk), wherein L_{A′}12- (R1)(R1)(R1) to L_{A′}12- (R135)(R135)(R135) have the structure | 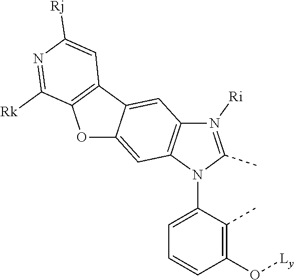 |
| L_{A′}14-(Ri)(Rj)(Rk), wherein L_{A′}14- (R1)(R1)(R1) to L_{A′}14- (R135)(R135)(R135) have the structure | 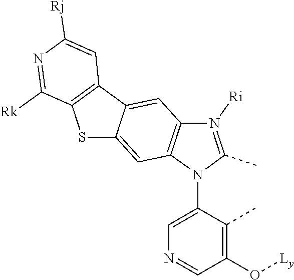 |
| L_{A′}15-(Ri)(Rj)(Rs), wherein L_{A′}15- (R1)(R1)(R1) to L_{A′}15- (R135)(R135)(R135) have the structure | 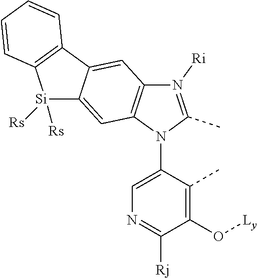 |
| L_{A′}16-(Rj)(Rk)(Rl)(Rm), wherein L_{A′}16- (R1)(R1)(R1)(R1) to L_{A′}16- (R135)(R135)(R135)(R135) have the structure | 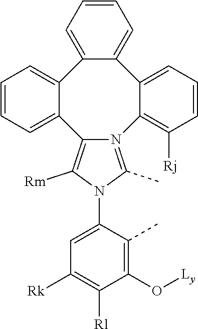 |
| L_{A′}17-(Rj)(Rk)(Rl)(Rm), wherein L_{A′}17- (R1)(R1)(R1)(R1) to L_{A′}17- (R135)(R135)(R135)(R135) have the structure | 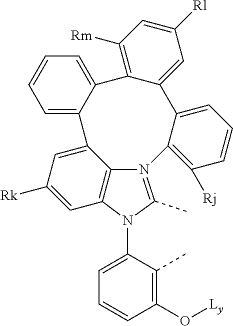 |
| L_{A′}18-(Rj)(Rj)(Rt), wherein L_{A′}18- (R1)(R1)(R1) to L_{A′}18- (R135)(R135)(R135) have the structure | 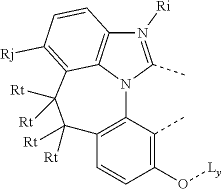 |
| L_{A′}19-(Ri)(Rj)(Rk), wherein L_{A′}19- (R1)(R1)(R1) to L_{A′}19- (R135)(R135)(R135) have the structure | 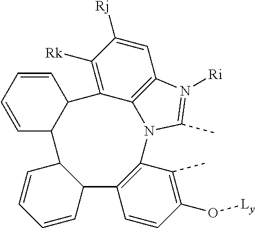 |
| L_{A′}20-(Rj)(Rk)(Rl)(Rm), wherein L_{A′}20- (R1)(R1)(R1)(R1) to L_{A′}20- (R135)(R135)(R135)(R135) have the structure | 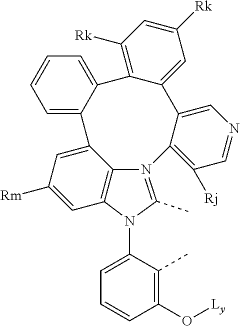 |
| L_{A′}21-(Rj)(Rk)(Rl)(Rm), wherein L_{A′}21- (R1)(R1)(R1)(R1) to L_{A′}21- (R135)(R135)(R135)(R135) have the structure | 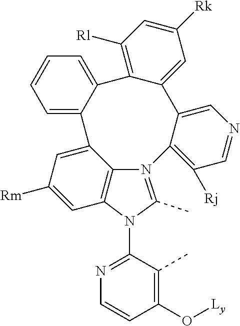 |
| L_{A′}22-(Ri)(Rj)(Rk), wherein L_{A′}22- (R1)(R1)(R1) to L_{A′}22- (R135)(R135)(R135) have the structure | 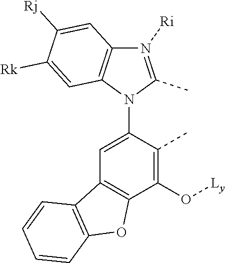 |
| L_{A′}23-(Ri)(Rj)(Rk), wherein L_{A′}23- (R1)(R1)(R1) to L_{A′}23- (R135)(R135)(R135) have the structure | 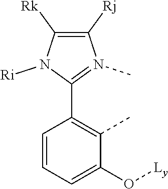 |
| L_{A′}24-(Ri)(Rj)(Rk), wherein L_{A′}24- (R1)(R1)(R1) to L_{A′}24- (R135)(R135)(R135) have the structure | 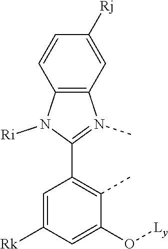 |
| L_{A′}25-(Rj)(Rk)(Rl), wherein L_{A′}25- (R1)(R1)(R1) to L_{A′}25- (R135)(R135)(R135) have the structure | 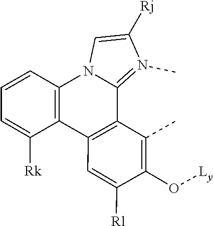 |
| L_{A′}26-(Ri)(Rj)(Rk), wherein L_{A′}26- (R1)(R1)(R1) to L_{A′}26- (R135)(R135)(R135) have the structure | 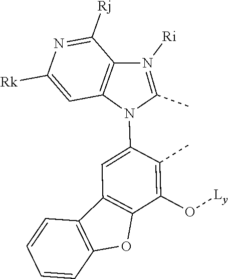 |
| L_{A′}27-(Rj)(Rj)(Rk)(Rv), wherein L_{A′}27- (R1)(R1)(R1)(R1) to L_{A′}27- (R135)(R135)(R135)(R135) have the structure | 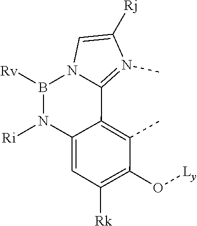 |
| L_{A′}28-(Rj)(Rk)(Rl), wherein L_{A′}28- (R1)(R1)(R1) to L_{A′}28- (R135)(R135)(R135) have the structure | 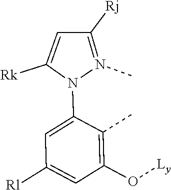 |
| L_{A′}29-(Ri)(Rj)(Rk)(Rl), wherein L_{A′}29- (R1)(R1)(R1)(R1) to L_{A′}29- (R135)(R135)(R135)(R135) have the structure | 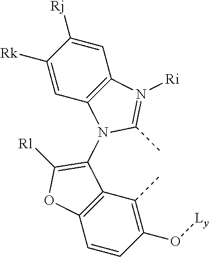 |
| L_{A′}30-(Rj)(Rk)(Rl), wherein L_{A′}30- (R1)(R1)(R1) to L_{A′}30- (R135)(R135)(R135) have the structure | 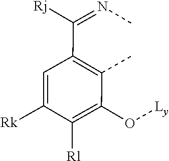 |
| L_{A′}31-(Rj)(Rk)(Rl), wherein L_{A′}31- (R1)(R1)(R1) to L_{A′}31- (R135)(R135)(R135) have the structure | 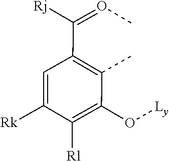 |
| L_{A′}32-(Rj)(Rk)(Rl), wherein L_{A′}32- (R1)(R1)(R1) to L_{A′}32- (R135)(R135)(R135) have the structure | 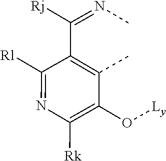 |
| L_{A′}33-(Rj)(Rk)(Ru)(Rt), wherein L_{A′}33- (R1)(R1)(R1)(R1) to L_{A′}33- (R135)(R135)(R135)(R135) have the structure | 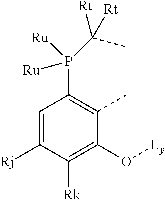 |
| L_{A′}34-(Rj)(Rk)(Rl)(Rm), wherein L_{A′}34- (R1)(R1)(R1)(R1) to L_{A′}34- (R135)(R135)(R135)(R135) have the structure | 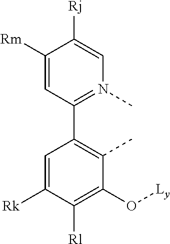 |
| L_{A′}35-(Rj)(Rk)(Ru), wherein L_{A′}35- (R1)(R1)(R1) to L_{A′}35- (R135)(R135)(R135) have the structure | 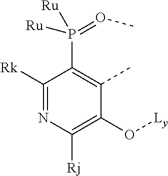 |
| L_{A′}36-(Rj)(Rk)(Ru), wherein L_{A′}36- (R1)(R1)(R1) to L_{A′}36- (R135)(R135)(R135) have the structure | 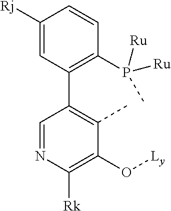 |
| L_{A′}37-(Rj)(Rk)(Rl), wherein L_{A′}37- (R1)(R1)(R1) to L_{A′}37- (R135)(R135)(R135) have the structure | 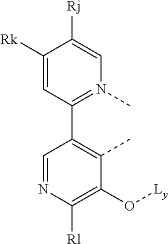 |
| L_{A′}38-(Rj)(Rk)(Rv), wherein L_{A′}38- (R1)(R1)(R1) to L_{A′}38- (R135)(R135)(R135) have the structure | 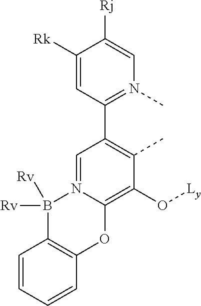 |
| L_{A′}39-(Rj)(Rk)(Rl), wherein L_{A′}39- (R1)(R1)(R1) to L_{A′}39- (R135)(R135)(R135) have the structure | 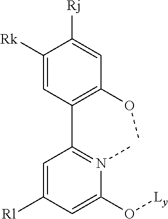 |
| L_{A′}40-(Ri)(Rj)(Rk), wherein L_{A′}40- (R1)(R1)(R1) to L_{A′}40- (R135)(R135)(R135) have the structure | 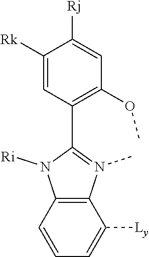 |
| L_{A′}41-(Rj)(Rk)(Rl)(Rm), wherein L_{A′}41- (R1)(R1)(R1)(R1) to L_{A′}41- (R135)(R135)(R135)(R135) have the structure | 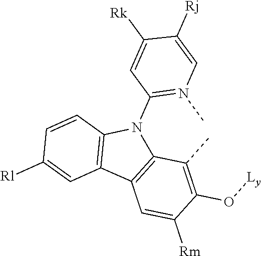 |
| L_{A′}42-(Rj)(Rk)(Rl)(Rm), wherein L_{A′}42- (R1)(R1)(R1)(R1) to L_{A′}42- (R135)(R135)(R135)(R135) have the structure | 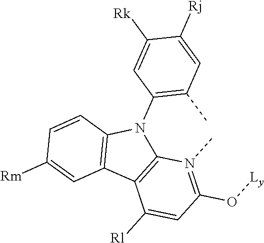 |
| L_{A′}43-(Rj)(Rk)(Rl)(Rt), wherein L_{A′}43- (R1)(R1)(R1)(R1) to L_{A′}43- (R135)(R135)(R135)(R135) have the structure | 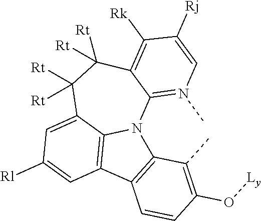 |
| L_{A′}44-(Rj)(Rk)(Rl)(Rt), wherein L_{A′}44- (R1)(R1)(R1)(R1) to L_{A′}44- (R135)(R135)(R135)(R135) have the structure | 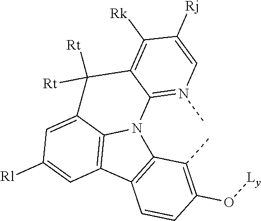 |
| L_{A′}45-(Rj)(Rk)(Rl)(Rm)(Rs), wherein L_{A′}45- (R1)(R1)(R1)(R1)(R1) to L_{A′}45- (R135)(R135)(R135)(R135) (R135) have the structure | 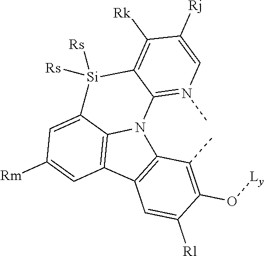 |
| L_{A′}46-(Rj)(Rk)(Rl), wherein L_{A′}46- (R1)(R1)(R1) to L_{A′}46- (R135)(R135)(R135) have the structure | 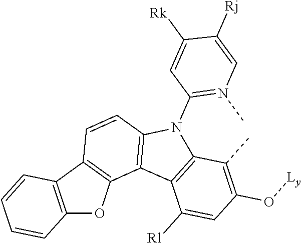 |
| L_{A′}47-(Rj)(Rk)(Rl), wherein L_{A′}47- (R1)(R1)(R1) to L_{A′}47- (R135)(R135)(R135) have the structure | 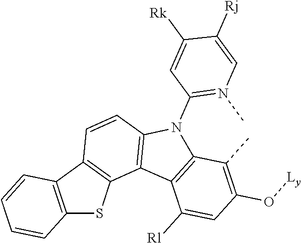 |
| L_{A′}48-(Rj)(Rk)(Rl)(Rt), wherein L_{A′}48- (R1)(R1)(R1)(R1) to L_{A′}48- (R135)(R135)(R135)(R135) have the structure | 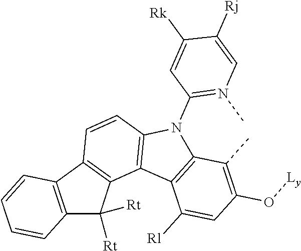 |
| L_{A′}49-(Rj)(Rk)(Rl), wherein L_{A′}49- (R1)(R1)(R1) to L_{A′}49- (R135)(R135)(R135) have the structure | 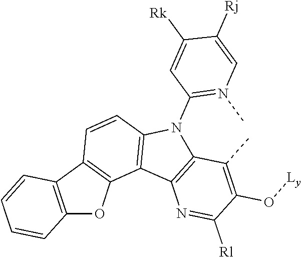 |
| L_{A′}50-(Rj)(Rk)(Rl)(Rs), wherein L_{A′}50- (R1)(R1)(R1)(R1) to L_{A′}50- (R135)(R135)(R135)(R135) have the structure | 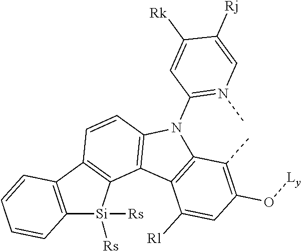 |
| L_{A′}51-(Ri)(Rj)(Rk), wherein L_{A′}51- (R1)(R1)(R1) to L_{A′}51- (R135)(R135)(R135) have the structure | 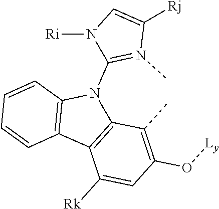 |
| L_{A′}52-(Ri)(Rj)(Rk), wherein L_{A′}52- (R1)(R1)(R1) to L_{A′}52- (R135)(R135)(R135) have the structure | 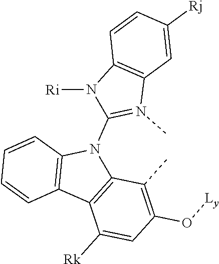 |
| L_{A′}53-(Rj)(Rk)(Rs), wherein L_{A′}53- (R1)(R1)(R1) to L_{A′}53- (R135)(R135)(R135) have the structure | 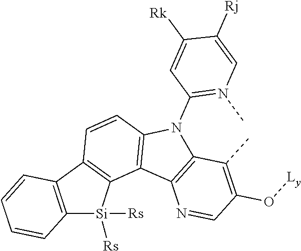 |
| L_{A′}54-(Rj)(Rk)(Rl), wherein L_{A′}54- (R1)(R1)(R1) to L_{A′}54- (R135)(R135)(R135) have the structure | 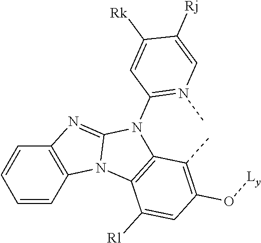 |
| L_{A′}55-(Ri)(Rj)(Rk)(Rv), wherein L_{A′}55- (R1)(R1)(R1)(R1) to L_{A′}55- (R135)(R135)(R135)(R135) have the structure | 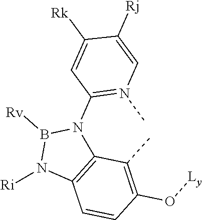 |
| L_{A′}56-(Ri)(Rj)(Rk)(Rv), wherein L_{A′}56- (R1)(R1)(R1)(R1) to L_{A′}56- (R135)(R135)(R135)(R135) have the structure | 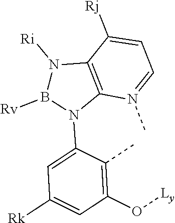 |
| L_{A′}57-(Ri)(Rj)(Rk), wherein L_{A′}57- (R1)(R1)(R1) to L_{A′}57- (R135)(R135)(R135) have the structure | 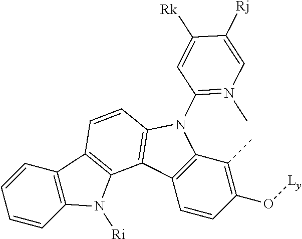 |
| L_{A′}58-(Rj)(Rk)(Rl)(Rt), wherein L_{A′}58- (R1)(R1)(R1)(R1) to L_{A′}58- (R135)(R135)(R135)(R135) have the structure | 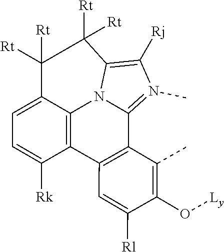 |
| L_{A′}59-(Ri)(Rj)(Rk)(Rv), wherein L_{A′}59- (R1)(R1)(R1)(R1) to L_{A′}59- (R135)(R135)(R135)(R135) have the structure | 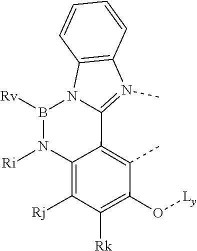 |
| L_{A′}60-(Rj)(Rk)(Rt), wherein L_{A′}60- (R1)(R1)(R1) to L_{A′}60- (R135)(R135)(R135) have the structure | 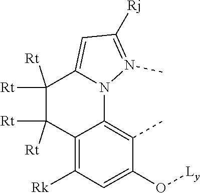 |
| L_{A′}61-(Ri)(Rj)(Rk)(Rt), wherein L_{A′}61- (R1)(R1)(R1)(R1) to L_{A′}61- (R135)(R135)(R135)(R135) have the structure | 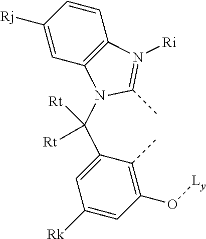 |
| L_{A′}62-(Rj)(Rk)(Rl), wherein L_{A′}62- (R1)(R1)(R1) to L_{A′}62- (R135)(R135)(R135) have the structure | 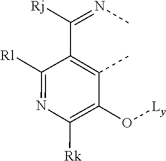 |
| L_{A′}63-(Rj)(Rk)(Ru), wherein L_{A′}63- (R1)(R1)(R1) to L_{A′}63- (R135)(R135)(R135) have the structure | 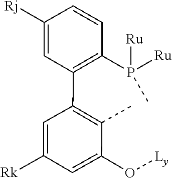 |

wherein L_{y} is selected from the group consisting of structures L_{y}1-(Rj)(Rk)(Rl)(Rm) to L_{y}74-(Rj)(Rk)(Rl)(Rm), wherein each of l, j, k, l, m, s, t, v, and w is independently an integer from 1 to 135, and L_{y}1-(R1)(R1)(R1)(R1) to L_{y}74-(R135)(R135)(R135)(R135) have the following structures:

| | |
|---|---|
| L_{y}1-(Rj)(Rk)(Rl)(Rm), wherein L_{y}1- (R1)(R1)(R1)(R1) to L_{y}1- (R135)(R135)(R135) (R135) have the structure | 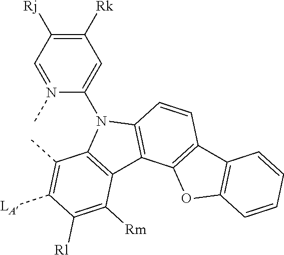 |
| L_{y}2-(Rj)(Rk)(Rl)(Rm), wherein L_{y}2- (R1)(R1)(R1)(R1) to L_{y}2- (R135)(R135)(R135) (R135) have the structure | 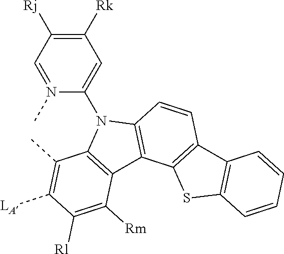 |
| L_{y}3-(Rj)(Rk)(Rl)(Rm), wherein L_{y}3- (R1)(R1)(R1)(R1) to L_{y}3- (R135)(R135)(R135) (R135) have the structure | 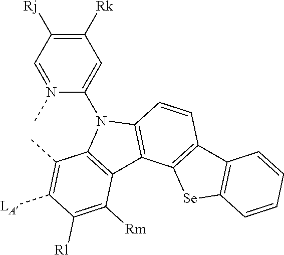 |
| L_{y}4-(Rj)(Rk)(Rl), wherein L_{y}4- (R1)(R1)(R1) to L_{y}4- (R135)(R135)(R135) have the structure | 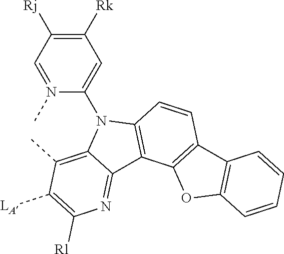 |
| L_{y}5-(Rj)(Rk)(Rl), wherein L_{y}5- (R1)(R1)(R1) to L_{y}5- (R135)(R135)(R135) have the structure | 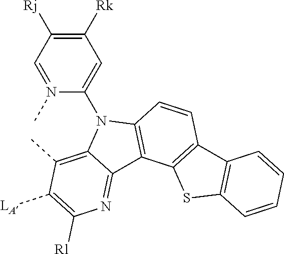 |
| L_{y}6-(Rj)(Rk)(Rl), wherein L_{y}6- (R1)(R1)(R1) to L_{y}6- (R135)(R135)(R135) have the structure | 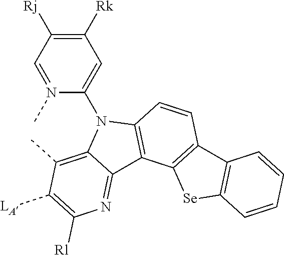 |
| L_{y}7-(Rj)(Rk)(Rl)(Rs), wherein L_{y}7- (R1)(R1)(R1)(R1) to L_{y}7- (R135)(R135)(R135) (R135) have the structure | 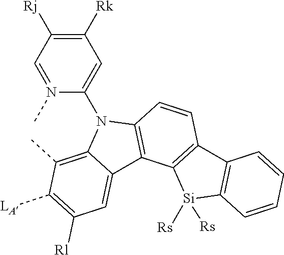 |
| L_{y}8-(Rj)(Rk)(Rl)(Rt), wherein L_{y}8- (R1)(R1)(R1)(R1) to L_{y}8- (R135)(R135)(R135) (R135) have the structure | 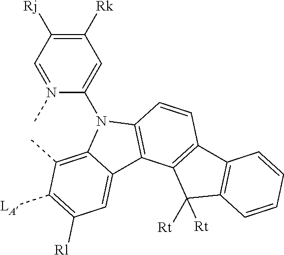 |
| L_{y}9-(Rj)(Rj)(Rk)(Rl), wherein L_{y}9- (R1)(R1)(R1)(R1) to L_{y}9- (R135)(R135)(R135) (R135) have the structure | 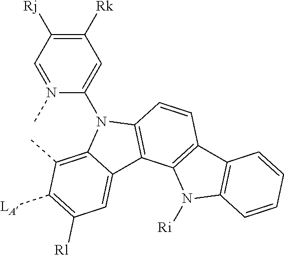 |
| L_{y}10-(Rj)(Rk)(Rs), wherein L_{y}10- (R1)(R1)(R1) to L_{y}10- (R135)(R135)(R135) have the structure | 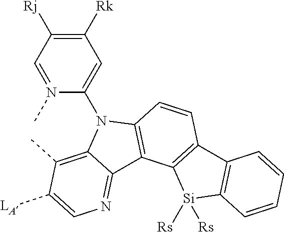 |
| L_{y}11-(Rj)(Rk)(Rt), wherein L_{y}11- (R1)(R1)(R1) to L_{y}11- (R135)(R135)(R135) have the structure | 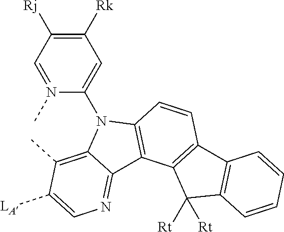 |
| L_{y}12-(Ri)(Rj)(Rk), wherein L_{y}12- (R1)(R1)(R1) to L_{y}12- (R135)(R135)(R135) have the structure | 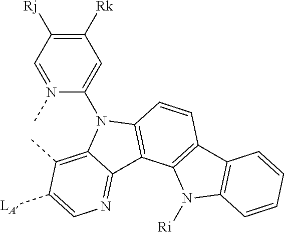 |
| L_{y}13-(Rj)(Rk)(Rv), wherein L_{y}13- (R1)(R1)(R1) to L_{y}13- (R135)(R135)(R135) have the structure | 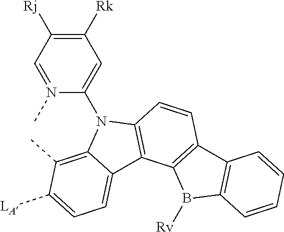 |
| L_{y}14- (Ri)(Rj)(Rk)(Rl)(Rm), wherein L_{y}14- (R1)(R1)(R1)(R1)(R1) to L_{y}14- (R135)(R135)(R135) (R135)(R135) have the structure | 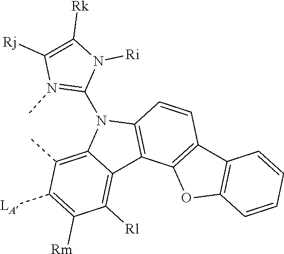 |
| L_{y}15- (Ri)(Rj)(Rk)(Rl)(Rm), wherein L_{y}15- (R1)(R1)(R1)(R1)(R1) to L_{y}15- (R135)(R135)(R135) (R135)(R135) have the structure | 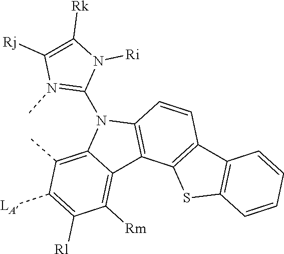 |
| L_{y}16-(Rj)(Rk)(Rl), wherein L_{y}16- (R1)(R1)(R1) to L_{y}16- (R135)(R135)(R135) have the structure | 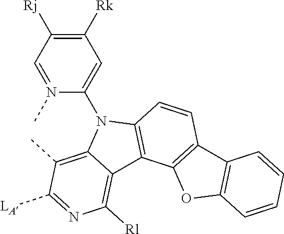 |
| L_{y}17-(Rj)(Rk)(Rl)(Rv), wherein L_{y}17- (R1)(R1)(R1) to L_{y}17- (R135)(R135)(R135) have the structure | 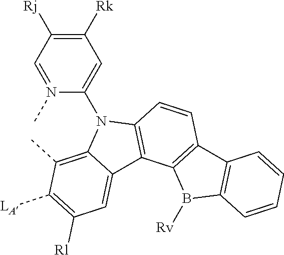 |
| L_{y}18-(Rj)(Rk)(Rl)(Rm), wherein L_{y}18- (R1)(R1)(R1) to L_{y}18- (R135)(R135)(R135) have the structure | 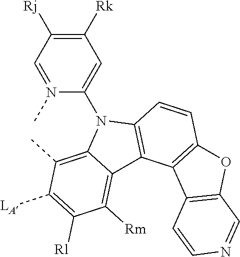 |
| L_{y}19-(Ri)(Rj)(Rk)(Rl), wherein L_{y}19- (R1)(R1)(R1) to L_{y}19- (R135)(R135)(R135) have the structure | 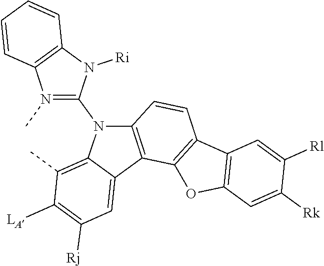 |
| L_{y}20-(Ri)(Rj)(Rk)(Rs), wherein L_{y}20- (R1)(R1)(R1) to L_{y}20- (R135)(R135)(R135) have the structure | 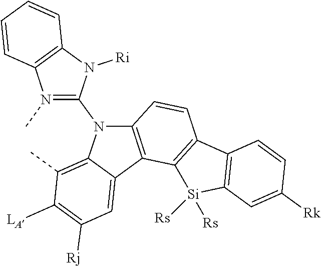 |
| L_{y}21-(Rj)(Rk)(Rl), wherein L_{y}21- (R1)(R1)(R1) to L_{y}21- (R135)(R135)(R135) have the structure | 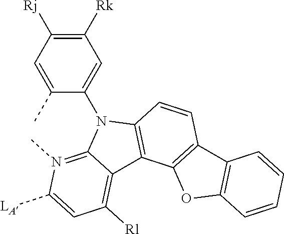 |
| L_{y}22-(Rj)(Rk)(Rl), wherein L_{y}22- (R1)(R1)(R1) to L_{y}22- (R135)(R135)(R135) have the structure | 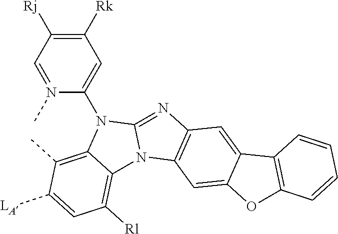 |
| L_{y}23-(Rj)(Rk)(Rl)(Rt), wherein L_{y}23- (R1)(R1)(R1)(R1) to L_{y}23- (R135)(R135)(R135) (R135) have the structure | 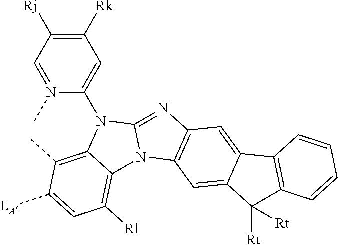 |
| L_{y}24-(Rj)(Rk)(Rl)(Rm), wherein L_{y}24- (R1)(R1)(R1)(R1) to L_{y}24- (R135)(R135)(R135) (R135) have the structure | 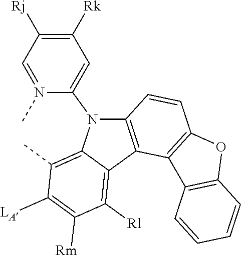 |
| L_{y}25-(Rj)(Rk)(Rl)(Rm), wherein L_{y}25- (R1)(R1)(R1)(R1) to L_{y}25- (R135)(R135)(R135) (R135) have the structure | 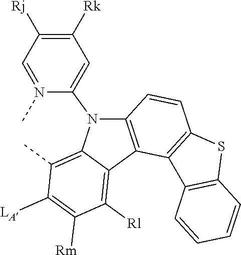 |
| L_{y}26-(Ri)(Rj)(Rk)(Rl), wherein L_{y}26- (R1)(R1)(R1)(R1) to L_{y}26- (R135)(R135)(R135) (R135) have the structure | 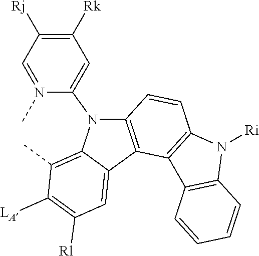 |
| L_{y}27-(Ri)(Rj)(Rk)(Rl), wherein L_{y}27- (R1)(R1)(R1)(R1) to L_{y}27- (R135)(R135)(R135) (R135) have the structure | 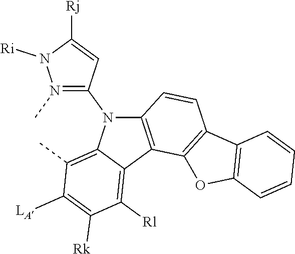 |
| L_{y}28-(Rj)(Rk)(Rl)(Rm), wherein L_{y}28- (R1)(R1)(R1)(R1) to L_{y}28- (R135)(R135)(R135) (R135) have the structure | 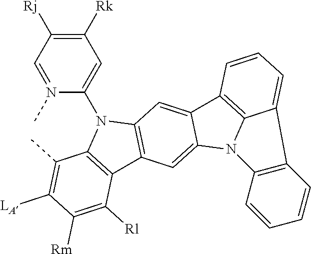 |
| L_{y}29-(Rj)(Rk)(Rl), wherein L_{y}29- (R1)(R1)(R1) to L_{y}29- (R135)(R135)(R135) have the structure | 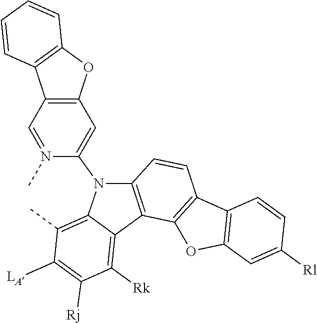 |
| L_{y}30-(Rj)(Rk)(Rl), wherein L_{y}30- (R1)(R1)(R1) to L_{y}30- (R135)(R135)(R135) have the structure | 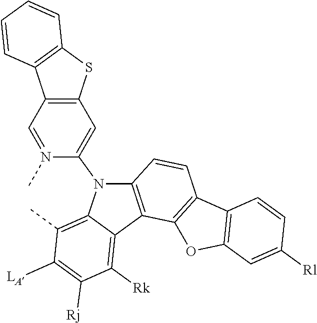 |
| L_{y}31-(Rj)(Rk)(Rl), wherein L_{y}31- (R1)(R1)(R1) to L_{y}31- (R135)(R135)(R135) have the structure | 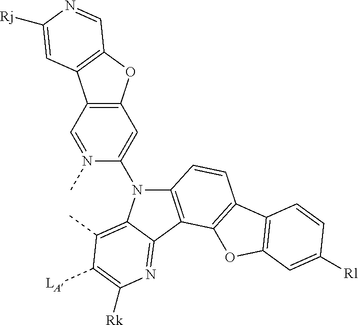 |
| L_{y}32-(Rj)(Rk)(Rl), wherein L_{y}32- (R1)(R1)(R1) to L_{y}32- (R135)(R135)(R135) have the structure | 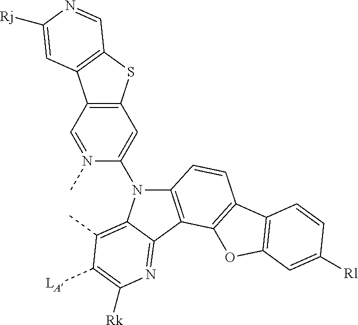 |
| L_{y}33-(Ri)(Rj)(Rk)(Rl), wherein L_{y}33- (R1)(R1)(R1)(R1) to L_{y}33- (R135)(R135)(R135) (R135) have the structure | 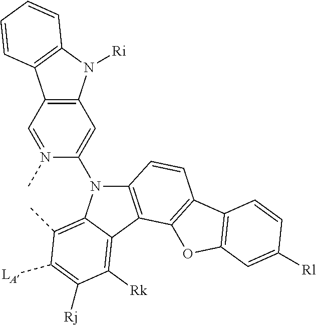 |
| L_{y}34-(Rj)(Rk)(Rs), wherein L_{y}34- (R1)(R1)(R1) to L_{y}34- (R135)(R135)(R135) have the structure | 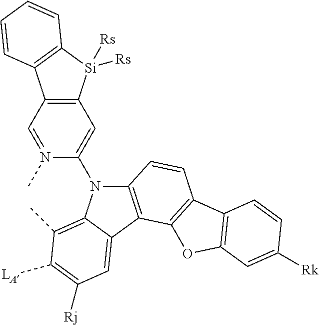 |
| L_{y}35-(Rj)(Rk)(Rt), wherein L_{y}35- (R1)(R1)(R1) to L_{y}35- (R135)(R135)(R135) have the structure | 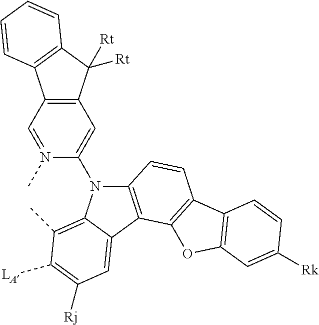 |
| L_{y}36-(Rj)(Rk)(Rt), wherein L_{y}36- (R1)(R1)(R1) to L_{y}36- (R135)(R135)(R135) have the structure | 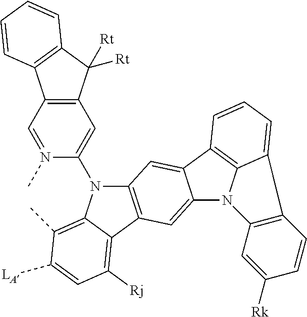 |
| L_{y}37-(Ri)(Rj)(Rk), wherein L_{y}37- (R1)(R1)(R1) to L_{y}37- (R135)(R135)(R135) have the structure | 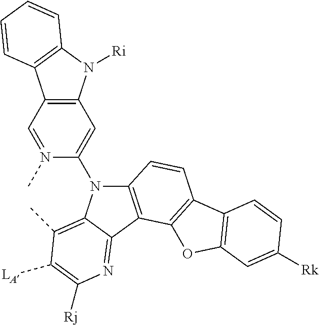 |
| L_{y}38-(Ri)(Rj)(Rk)(Rl), wherein L_{y}38- (R1)(R1)(R1)(R1) to L_{y}38- (R135)(R135)(R135) (R135) have the structure | 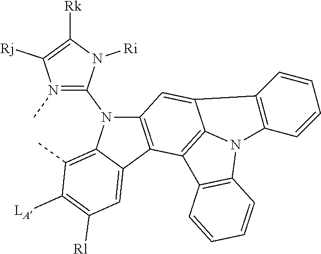 |
| L_{y}39-(Ri)(Rj)(Rk)(Rl), wherein L_{y}39- (R1)(R1)(R1)(R1) to L_{y}39- (R135)(R135)(R135) (R135) have the structure | 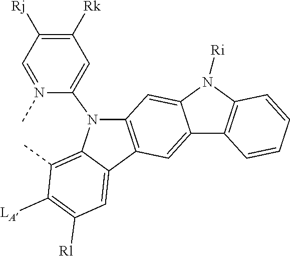 |
| L_{y}40-(Ri)(Rj)(Rk)(Rl), wherein L_{y}40- (R1)(R1)(R1)(R1) to L_{y}40- (R135)(R135)(R135) (R135) have the structure | 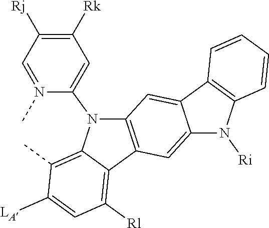 |
| L_{y}41-(Rj)(Rk)(Rl)(Rm), wherein L_{y}41- (R1)(R1)(R1)(R1) to L_{y}41- (R135)(R135)(R135) (R135) have the structure | 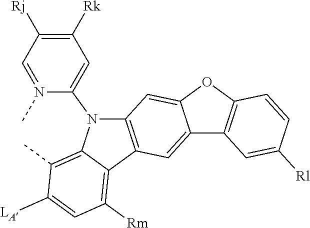 |
| L_{y}42-(Rj)(Rk)(Rl)(Rs), wherein L_{y}42- (R1)(R1)(R1)(R1) to L_{y}42- (R135)(R135)(R135) (R135) have the structure | 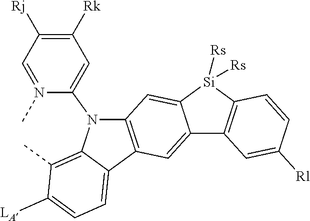 |
| L_{y}43-(Rj)(Rk)(Rl), wherein L_{y}43- (R1)(R1)(R1) to L_{y}43- (R135)(R135)(R135) have the structure | 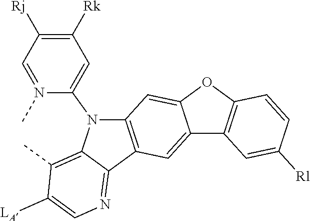 |
| L_{y}44-(Rj)(Rk)(Rl)(Rt), wherein L_{y}44- (R1)(R1)(R1)(R1) to L_{y}44- (R135)(R135)(R135) (R135) have the structure | 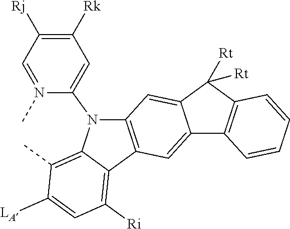 |
| L_{y}45-(Rj)(Rk)(Rl), wherein L_{y}45- (R1)(R1)(R1) to L_{y}45- (R135)(R135)(R135) have the structure | 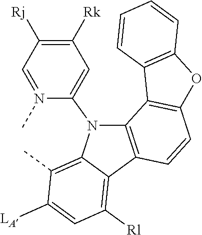 |
| L_{y}46-(Rj)(Rk)(Rl), wherein L_{y}46- (R1)(R1)(R1) to L_{y}46- (R135)(R135)(R135) have the structure | 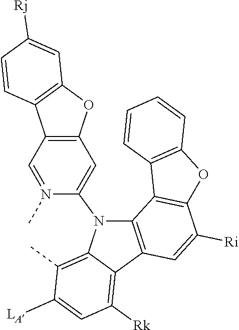 |
| L_{y}47-(Rj)(Rk)(Rl), wherein L_{y}47- (R1)(R1)(R1) to L_{y}47- (R135)(R135)(R135) have the structure | 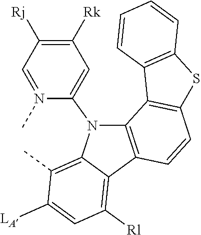 |
| L_{y}48-(Rj)(Rk)(Rl)(Rs), wherein L_{y}48- (R1)(R1)(R1)(R1) to L_{y}48- (R135)(R135)(R135) (R135) have the structure | 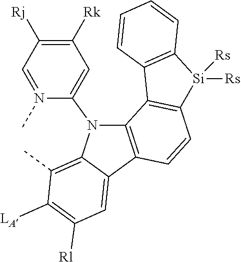 |
| L_{y}49-(Rj)(Rk)(Rl)(Rt), wherein L_{y}49- (R1)(R1)(R1)(R1) to L_{y}49- (R135)(R135)(R135) (R135) have the structure | 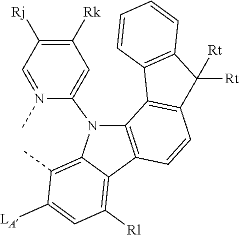 |
| L_{y}50-(Rj)(Rk)(Rl), wherein L_{y}50- (R1)(R1)(R1) to L_{y}50- (R135)(R135)(R135) have the structure | 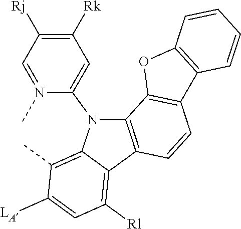 |
| L_{y}51-(Rj)(Rk)(Rl), wherein L_{y}51- (R1)(R1)(R1) to L_{y}51- (R135)(R135)(R135) have the structure | 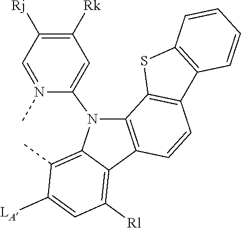 |
| L_{y}52-(Rj)(Rk)(Rl), wherein L_{y}52- (R1)(R1)(R1) to L_{y}52- (R135)(R135)(R135) have the structure | 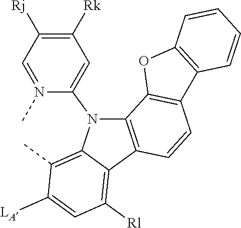 |
| L_{y}53-(Rl)(Rj)(Rk)(Rl), wherein L_{y}53- (R1)(R1)(R1)(R1) to L_{y}53- (R135)(R135)(R135) (R135) have the structure | 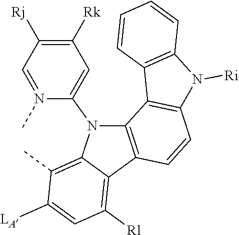 |
| L_{y}54-(Rj)(Rk)(Rl)(Rt), wherein L_{y}54- (R1)(R1)(R1)(R1) to L_{y}54- (R135)(R135)(R135) (R135) have the structure | 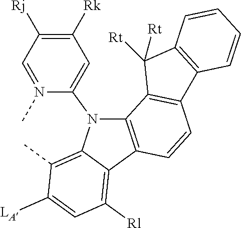 |
| L_{y}55-(Rj)(Rk)(Rl)(Rs), wherein L_{y}55- (R1)(R1)(R1)(R1) to L_{y}55- (R135)(R135)(R135) (R135) have the structure | 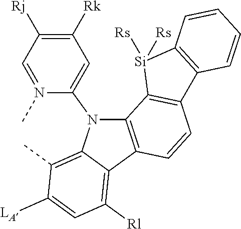 |
| L_{y}56-(Rj)(Rk)(Rl)(Rt), wherein L_{y}56- (R1)(R1)(R1)(R1) to L_{y}56- (R135)(R135)(R135) (R135) have the structure | 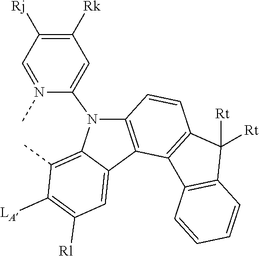 |
| L_{y}57-(Rj)(Rk)(Rl), wherein L_{y}57- (R1)(R1)(R1) to L_{y}7- (R135)(R135)(R135) have the structure | 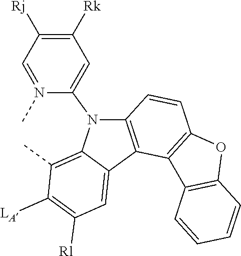 |
| L_{y}58-(Rj)(Rk)(Rl), wherein L_{y}58- (R1)(R1)(R1) to L_{y}58- (R135)(R135)(R135) have the structure | 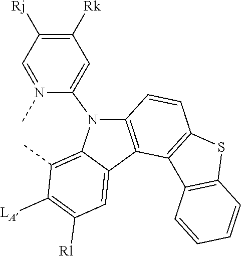 |
| L_{y}59-(Rj)(Rk)(Rl)(Rs), wherein L_{y}59- (R1)(R1)(R1)(R1) to L_{y}59- (R135)(R135)(R135) (R135) have the structure | 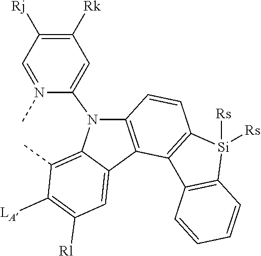 |
| L_{y}60-(Rj)(Rk)(Rl), wherein L_{y}60- (R1)(R1)(R1) to L_{y}60- (R135)(R135)(R135) have the structure | 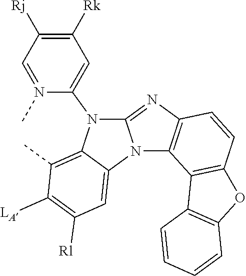 |
| L_{y}61-(Ri)(Rj)(Rk)(Rl), wherein L_{y}61- (R1)(R1)(R1)(R1) to L_{y}61- (R135)(R135)(R135) (R135) have the structure | 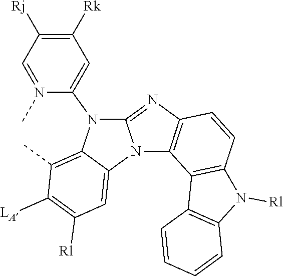 |
| L_{y}62-(Rj)(Rk)(Rl), wherein L_{y}62- (R1)(R1)(R1) to L_{y}62- (R135)(R135)(R135) have the structure | 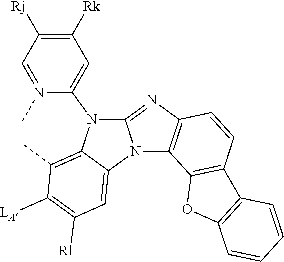 |
| L_{y}63-(Rj)(Rk)(Rl)(Rt), wherein L_{y}63- (R1)(R1)(R1)(R1) to L_{y}63- (R135)(R135)(R135) (R135) have the structure | 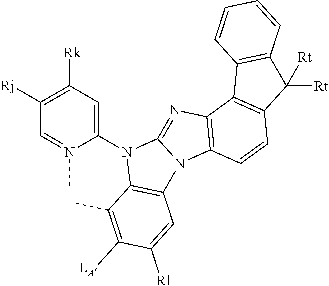 |
| L_{y}64-(Rj)(Rk)(Rl), wherein L_{y}64- (R1)(R1)(R1) to L_{y}64- (R135)(R135)(R135) have the structure | 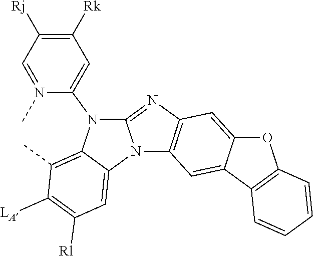 |
| L_{y}65-(Rj)(Rk)(Rl)(Rt), wherein L_{y}65- (R1)(R1)(R1)(R1) to L_{y}65- (R135)(R135)(R135) (R135) have the structure | 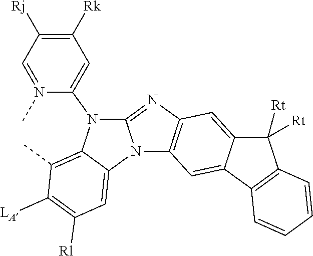 |
| L_{y}66-(Rj)(Rk)(Rl)(Rm), wherein L_{y}66- (R1)(R1)(R1)(R1) to L_{y}66- (R135)(R135)(R135) (R135) have the structure | 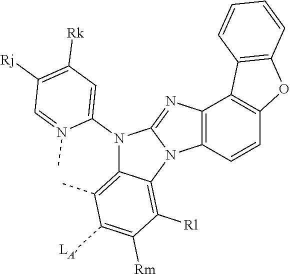 |
| L_{y}67-(Rj)(Rk)(Rl)(Rm), wherein L_{y}67- (R1)(R1)(R1)(R1) to L_{y}67- (R135)(R135)(R135) (R135) have the structure | 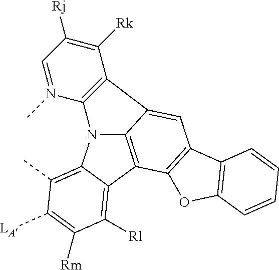 |
| L_{y}68-(Rj)(Rk)(Rl)(Rt), wherein L_{y}68- (R1)(R1)(R1)(R1) to L_{y}68- (R135)(R135)(R135) (R135) have the structure | 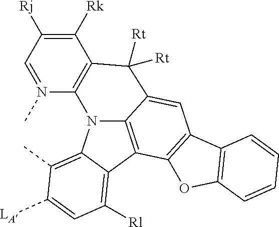 |
| L_{y}69-(Rj)(Rk)(Rl)(Rs), wherein L_{y}69- (R1)(R1)(R1)(R1) to L_{y}69- (R135)(R135)(R135) (R135) have the structure | 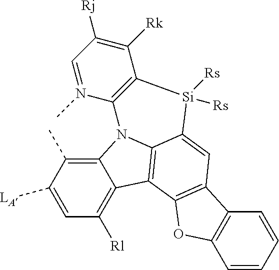 |
| L_{y}70-(Ri)(Rj)(Rk)(Rl), wherein L_{y}70- (R1)(R1)(R1)(R1) to L_{y}70- (R135)(R135)(R135) (R135) have the structure | 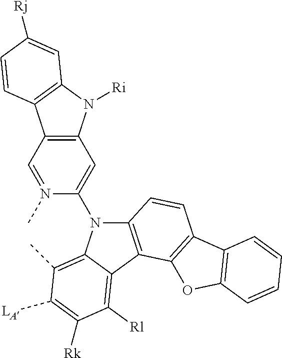 |
| L_{y}71-(Rj)(Rk)(Rt)(Rw), wherein L_{y}71- (R1)(R1)(R1)(R1) to L_{y}71- (R135)(R135)(R135) (R135) have the structure | 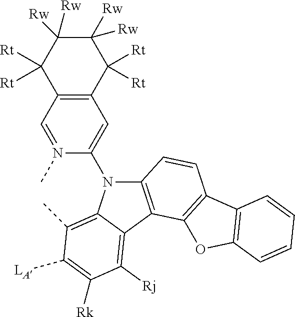 |
| L_{y}72-(Rj)(Rk)(Rl)(Rt), wherein L_{y}72- (R1)(R1)(R1)(R1) to L_{y}72- (R135)(R135)(R135) (R135) have the structure | 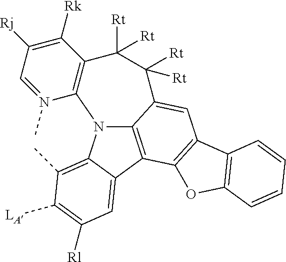 |
| L_{y}73-(Rj)(Rk)(Rl), wherein L_{y}73- (R1)(R1)(R1) to L_{y}73- (R135)(R135)(R135) have the structure | 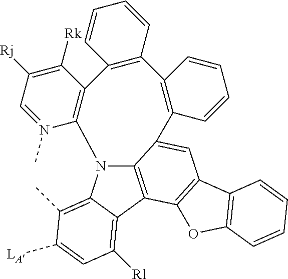 |
| L_{y}74-(Rj)(Rk)(Rl)(Rm), wherein L_{y}74- (R1)(R1)(R1)(R1) to L_{y}74- (R135)(R135)(R135) (R135) have the structure | 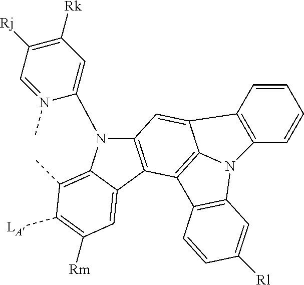 |

wherein R1 to R135 have the following structures:

| | Structure |
|---|---|
| R1 | 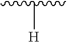 [SMILES: *[H]] |
| R2 | 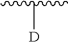 [SMILES: *[2H]] |
| R3 | 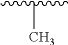 |
| R4 | 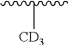 [SMILES: *C([2H])([2H])[2H]] |
| R5 | 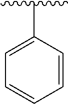 [SMILES: *c1ccccc1] |
| R6 | 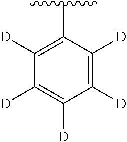 [SMILES: *c1c([2H])c([2H])c([2H])c([2H])c1[2H]] |
| R7 | 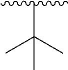 [SMILES: *C(C)(C)C] |
| R8 | 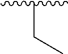 [SMILES: *CC] |
| R9 | 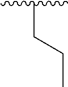 [SMILES: *CCC] |
| R10 | 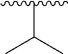 [SMILES: *C(C)C] |
| R11 | 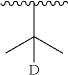 [SMILES: *C([2H])(C)C] |
| R12 | 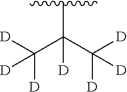 [SMILES: *C([2H])(C([2H])([2H])[2H])C([2H])([2H])[2H]] |
| R13 | 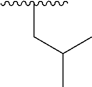 [SMILES: *CC(C)C] |
| R14 | 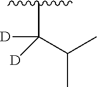 [SMILES: *C([2H])([2H])C(C)C] |
| R15 | 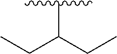 [SMILES: *C(CC)CC] |
| R16 | 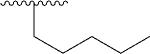 [SMILES: *CCCCC] |
| R17 | 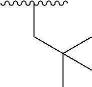 [SMILES: *CC(C)(C)C] |
| R18 | 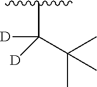 [SMILES: *C([2H])([2H])C(C)(C)C] |
| R19 | 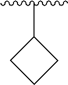 [SMILES: *C1CCC1] |
| R20 | 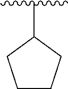 [SMILES: *C1CCCC1] |
| R21 | 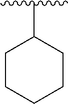 [SMILES: *C1CCCCC1] |
| R22 | 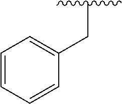 [SMILES: *Cc1ccccc1] |
| R23 | 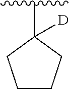 [SMILES: *C1([2H])CCCC1] |
| R24 | 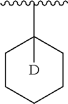 |
| R25 | 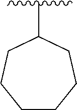 [SMILES: *C1CCCCCC1] |
| R26 | 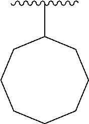 [SMILES: *C1CCCCCCC1] |
| R27 | 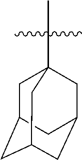 [SMILES: *C12CC3CC(CC(C3)C1)C2] |
| R28 | 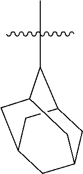 [SMILES: *C1C2CC3CC(C2)CC1C3] |
| R29 | 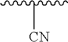 [SMILES: *C#N] |
| R30 | 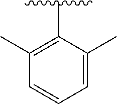 |
| R31 | 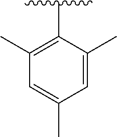 |
| R32 | 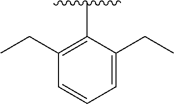 [SMILES: *c1c(CC)cccc1CC] |
| R33 | 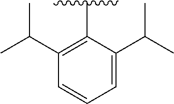 [SMILES: *c1c(C(C)C)cccc1C(C)C] |
| R34 | 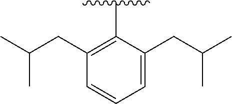 [SMILES: *c1c(CC(C)C)cccc1CC(C)C] |
| R35 | 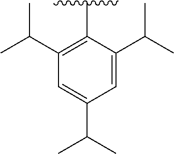 [SMILES: *c1c(C(C)C)cc(C(C)C)cc1C(C)C] |
| R36 | 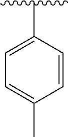 [SMILES: *c1ccc(C)cc1] |
| R37 | 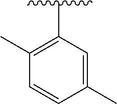 |
| R38 | 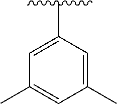 |
| R39 | 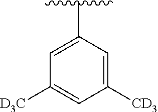 [SMILES: *c1cc(C([2H])([2H])[2H])cc(C([2H])([2H])[2H])c1] |
| R40 | 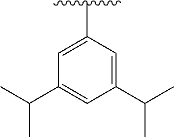 [SMILES: *c1cc(C(C)C)cc(C(C)C)c1] |
| R41 | 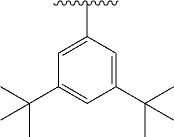 [SMILES: *c1cc(C(C)(C)C)cc(C(C)(C)C)c1] |
| R42 | 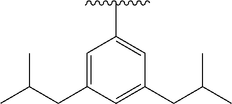 [SMILES: *c1cc(CC(C)C)cc(CC(C)C)c1] |
| R43 | 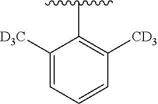 [SMILES: *c1c(C([2H])([2H])[2H])cccc1C([2H])([2H])[2H]] |
| R44 | 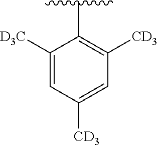 [SMILES: *c1c(C([2H])([2H])[2H])cc(C([2H])([2H])[2H])cc1C([2H])([2H])[2H]] |
| R45 | 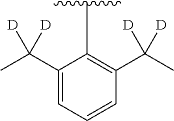 [SMILES: *c1c(C([2H])([2H])C)cccc1C([2H])([2H])C] |
| R46 | 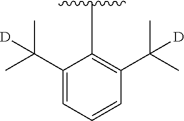 [SMILES: *c1c(C([2H])(C)C)cccc1C([2H])(C)C] |
| R47 | 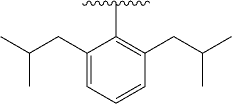 [SMILES: *c1c(CC(C)C)cccc1CC(C)C] |
| R48 | 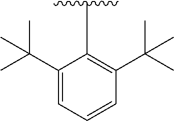 [SMILES: *c1c(C(C)(C)C)cccc1C(C)(C)C] |
| R49 | 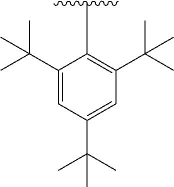 [SMILES: *c1c(C(C)(C)C)cc(C(C)(C)C)cc1C(C)(C)C] |
| R50 | 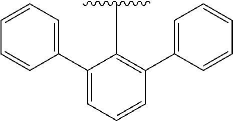 [SMILES: *c1c(-c2ccccc2)cccc1-c1ccccc1] |
| R51 | 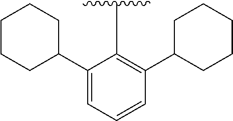 [SMILES: *c1c(C2CCCCC2)cccc1C1CCCCC1] |
| R52 | 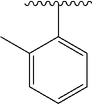 [SMILES: *c1ccccc1C] |
| R53 | 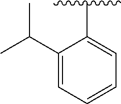 [SMILES: *c1ccccc1C(C)C] |
| R54 | 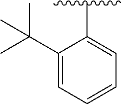 [SMILES: *c1ccccc1C(C)(C)C] |
| R55 | 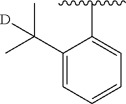 [SMILES: *c1ccccc1C([2H])(C)C] |
| R56 | 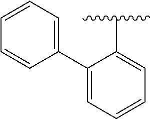 [SMILES: *c1ccccc1-c1ccccc1] |
| R57 | 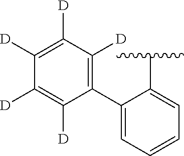 [SMILES: *c1ccccc1-c1c([2H])c([2H])c([2H])c([2H])c1[2H]] |
| R58 | 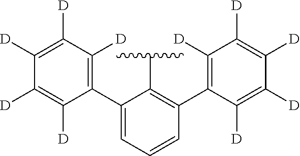 [SMILES: *c1c(-c2c([2H])c([2H])c([2H])c([2H])c2[2H])cccc1-c1c([2H])c([2H])c([2H])c([2H])c1[2H]] |
| R59 | 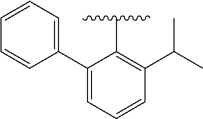 [SMILES: *c1c(-c2ccccc2)cccc1C(C)C] |
| R60 | 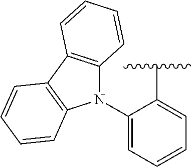 [SMILES: *c1ccccc1-n1c2ccccc2c2ccccc21] |
| R61 | 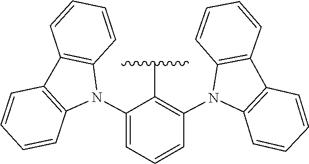 [SMILES: *c1c(-n2c3ccccc3c3ccccc32)cccc1-n1c2ccccc2c2ccccc21] |
| R62 | 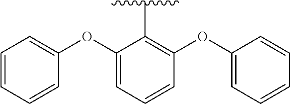 [SMILES: *c1c(Oc2ccccc2)cccc1Oc1ccccc1] |
| R63 | 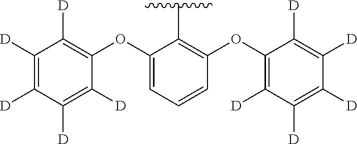 [SMILES: *c1c(Oc2c([2H])c([2H])c([2H])c([2H])c2[2H])cccc1Oc1c([2H])c([2H])c([2H])c([2H])c1[2H]] |
| R64 | 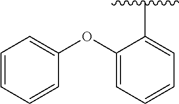 [SMILES: *c1ccccc1Oc1ccccc1] |
| R65 | 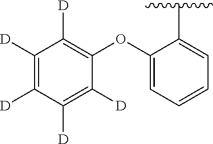 [SMILES: *c1ccccc1Oc1c([2H])c([2H])c([2H])c([2H])c1[2H]] |
| R66 | 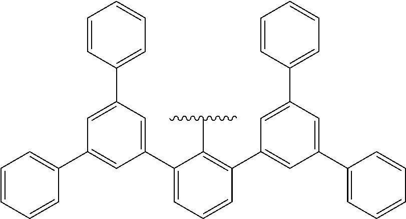 [SMILES: *c1c(-c2cc(-c3ccccc3)cc(-c3ccccc3)c2)cccc1-c1cc(-c2ccccc2)cc(-c2ccccc2)c1] |
| R67 | 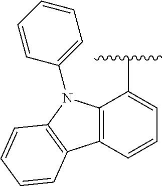 [SMILES: *c1cccc2c3ccccc3n(-c3ccccc3)c12] |
| R68 | 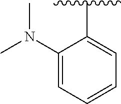 [SMILES: *c1ccccc1N(C)C] |
| R69 | 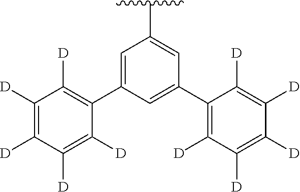 [SMILES: *c1cc(-c2c([2H])c([2H])c([2H])c([2H])c2[2H])cc(-c2c([2H])c([2H])c([2H])c([2H])c2[2H])c1] |
| R70 | 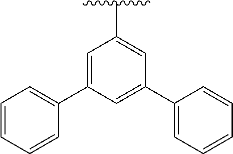 [SMILES: *c1cc(-c2ccccc2)cc(-c2ccccc2)c1] |
| R71 | 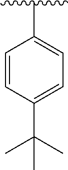 [SMILES: *c1ccc(C(C)(C)C)cc1] |
| R72 | 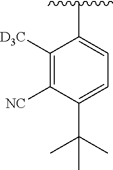 [SMILES: *c1ccc(C(C)(C)C)c(C#N)c1C([2H])([2H])[2H]] |
| R73 | 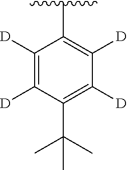 [SMILES: *c1c([2H])c([2H])c(C(C)(C)C)c([2H])c1[2H]] |
| R74 | 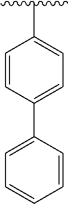 [SMILES: *c1ccc(-c2ccccc2)cc1] |
| R75 | 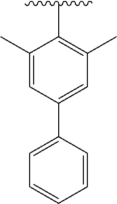 |
| R76 | 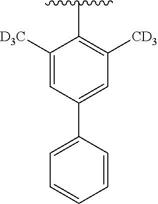 [SMILES: *c1c(C([2H])([2H])[2H])cc(-c2ccccc2)cc1C([2H])([2H])[2H]] |
| R77 | 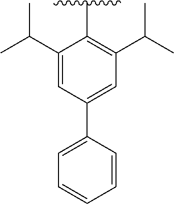 [SMILES: *c1c(C(C)C)cc(-c2ccccc2)cc1C(C)C] |
| R78 | 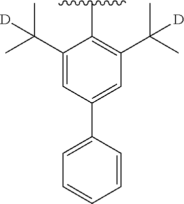 [SMILES: *c1c(C([2H])(C)C)cc(-c2ccccc2)cc1C([2H])(C)C] |
| R79 | 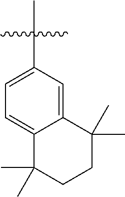 |
| R80 | 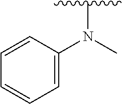 [SMILES: *N(C)c1ccccc1] |
| R81 | 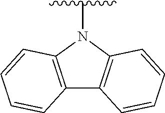 [SMILES: *n1c2ccccc2c2ccccc21] |
| R82 | 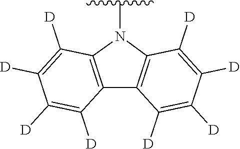 [SMILES: *n1c2c([2H])c([2H])c([2H])c([2H])c2c2c([2H])c([2H])c([2H])c([2H])c21] |
| R83 | 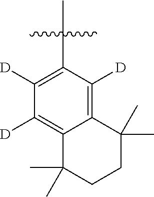 [SMILES: *c1c([2H])c([2H])c2c(c1[2H])C(C)(C)CCC2(C)C] |
| R84 | 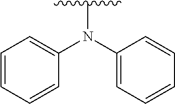 [SMILES: *N(c1ccccc1)c1ccccc1] |
| R85 | 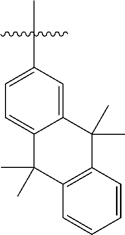 |
| R86 | 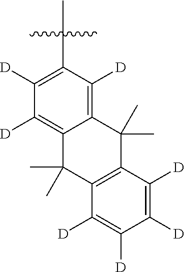 [SMILES: *c1c([2H])c([2H])c2c(c1[2H])C(C)(C)c1c([2H])c([2H])c([2H])c([2H])c1C2(C)C] |
| R87 | 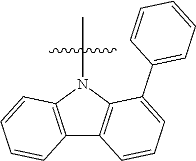 [SMILES: *n1c2ccccc2c2cccc(-c3ccccc3)c21] |
| R88 | 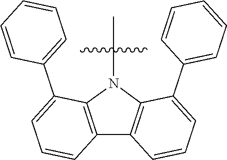 [SMILES: *n1c2c(-c3ccccc3)cccc2c2cccc(-c3ccccc3)c21] |
| R89 | 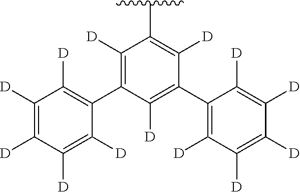 [SMILES: *c1c([2H])c(-c2c([2H])c([2H])c([2H])c([2H])c2[2H])c([2H])c(-c2c([2H])c([2H])c([2H])c([2H])c2[2H])c1[2H]] |
| R90 | 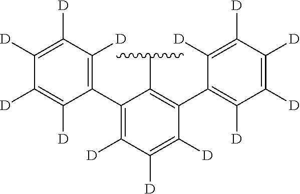 [SMILES: *c1c(-c2c([2H])c([2H])c([2H])c([2H])c2[2H])c([2H])c([2H])c([2H])c1-c1c([2H])c([2H])c([2H])c([2H])c1[2H]] |
| R91 | 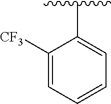 [SMILES: *c1ccccc1C(F)(F)F] |
| R92 | 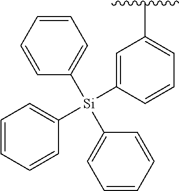 [SMILES: *c1cccc([Si](c2ccccc2)(c2ccccc2)c2ccccc2)c1] |
| R93 | 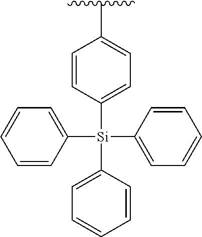 [SMILES: *c1ccc([Si](c2ccccc2)(c2ccccc2)c2ccccc2)cc1] |
| R94 | 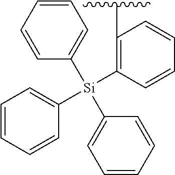 [SMILES: *c1ccccc1[Si](c1ccccc1)(c1ccccc1)c1ccccc1] |
| R95 | 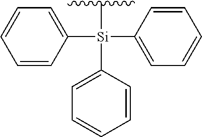 [SMILES: *[Si](c1ccccc1)(c1ccccc1)c1ccccc1] |
| R96 | 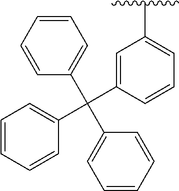 [SMILES: *c1cccc(C(c2ccccc2)(c2ccccc2)c2ccccc2)c1] |
| R97 | 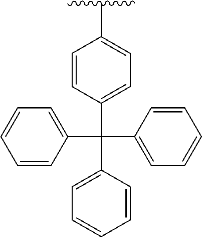 [SMILES: *c1ccc(C(c2ccccc2)(c2ccccc2)c2ccccc2)cc1] |
| R98 | 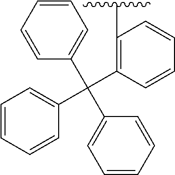 [SMILES: *c1ccccc1C(c1ccccc1)(c1ccccc1)c1ccccc1] |
| R99 | 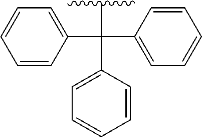 [SMILES: *C(c1ccccc1)(c1ccccc1)c1ccccc1] |
| R100 | 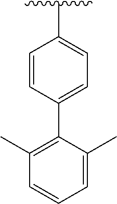 |
| R101 | 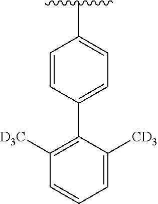 [SMILES: *c1ccc(-c2c(C([2H])([2H])[2H])cccc2C([2H])([2H])[2H])cc1] |
| R102 | 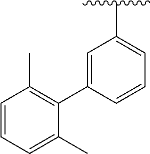 [SMILES: *c1cccc(-c2c(C)cccc2C)c1] |
| R103 | 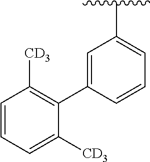 [SMILES: *c1cccc(-c2c(C([2H])([2H])[2H])cccc2C([2H])([2H])[2H])c1] |
| R104 | 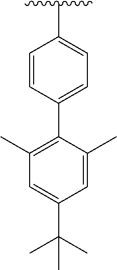 |
| R105 | 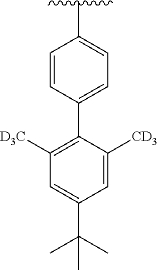 [SMILES: *c1ccc(-c2c(C([2H])([2H])[2H])cc(C(C)(C)C)cc2C([2H])([2H])[2H])cc1] |
| R106 | 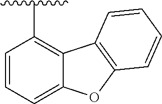 [SMILES: *c1cccc2oc3ccccc3c12] |
| R107 | 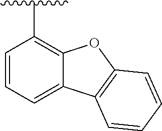 [SMILES: *c1cccc2c1oc1ccccc12] |
| R108 | 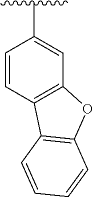 [SMILES: *c1ccc2c(c1)oc1ccccc12] |
| R109 | 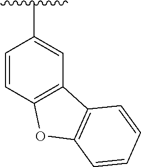 [SMILES: *c1ccc2oc3ccccc3c2c1] |
| R110 | 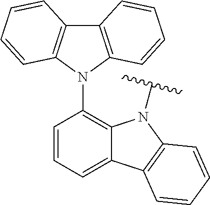 [SMILES: *n1c2ccccc2c2cccc(-n3c4ccccc4c4ccccc43)c21] |
| R111 | 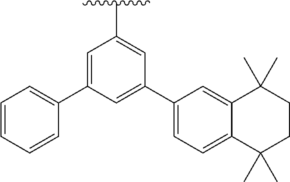 [SMILES: *c1cc(-c2ccccc2)cc(-c2ccc3c(c2)C(C)(C)CCC3(C)C)c1] |
| R112 | 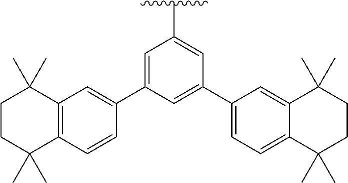 [SMILES: *c1cc(-c2ccc3c(c2)C(C)(C)CCC3(C)C)cc(-c2ccc3c(c2)C(C)(C)CCC3(C)C)c1] |
| R113 | 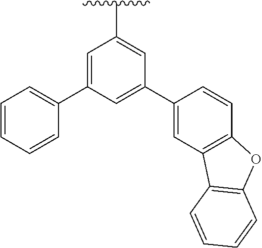 [SMILES: *c1cc(-c2ccccc2)cc(-c2ccc3oc4ccccc4c3c2)c1] |
| R114 | 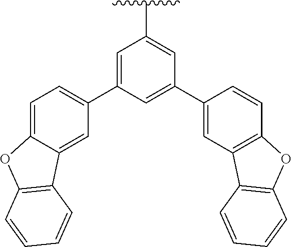 [SMILES: *c1cc(-c2ccc3oc4ccccc4c3c2)cc(-c2ccc3oc4ccccc4c3c2)c1] |
| R115 | 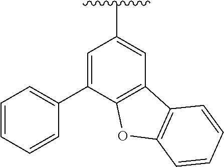 [SMILES: *c1cc(-c2ccccc2)c2oc3ccccc3c2c1] |
| R116 | 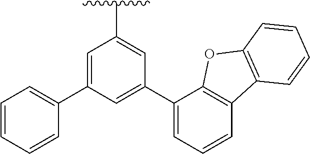 [SMILES: *c1cc(-c2ccccc2)cc(-c2cccc3c2oc2ccccc23)c1] |
| R117 | 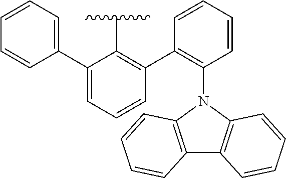 [SMILES: *c1c(-c2ccccc2)cccc1-c1ccccc1-n1c2ccccc2c2ccccc21] |
| R118 | 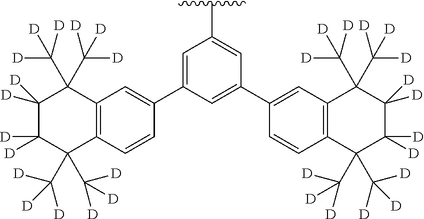 [SMILES: *c1cc(-c2ccc3c(c2)C(C([2H])([2H])[2H])(C([2H])([2H])[2H])C([2H])([2H])C([2H])([2H])C3(C([2H])([2H])[2H])C([2H])([2H])[2H])cc(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c1] |
| R119 | 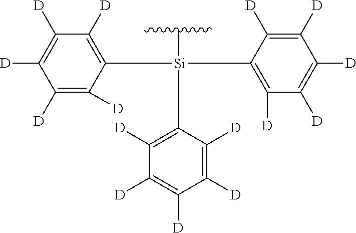 [SMILES: *[Si](c1c([2H])c([2H])c([2H])c([2H])c1[2H])(c1c([2H])c([2H])c([2H])c([2H])c1[2H])c1c([2H])c([2H])c([2H])c([2H])c1[2H]] |
| R120 | 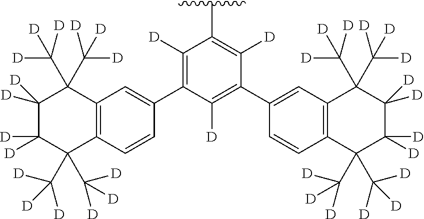 [SMILES: *c1c([2H])c(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c([2H])c(-c2ccc3c(c2)C(C([2H])([2H])[2H])(C([2H])([2H])[2H])C([2H])([2H])C([2H])([2H])C3(C([2H])([2H])[2H])C([2H])([2H])[2H])c1[2H]] |
| R121 | 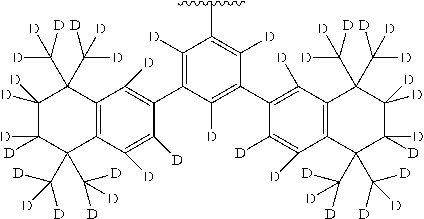 [SMILES: *c1c([2H])c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])c([2H])c(-c2c([2H])c([2H])c3c(c2[2H])C(C([2H])([2H])[2H])(C([2H])([2H])[2H])C([2H])([2H])C([2H])([2H])C3(C([2H])([2H])[2H])C([2H])([2H])[2H])c1[2H]] |
| R122 | 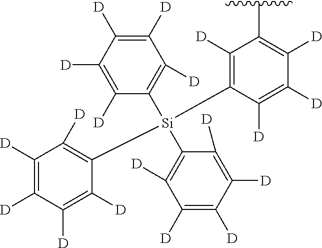 [SMILES: *c1c([2H])c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c1[2H]] |
| R123 | 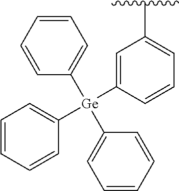 |
| R124 | 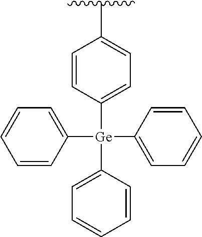 |
| R125 | 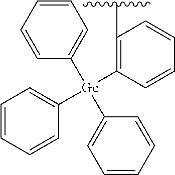 |
| R126 | 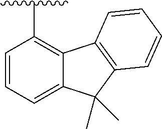 [SMILES: *c1cccc2c1-c1ccccc1C2(C)C] |
| R127 | 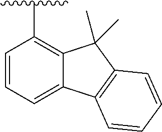 [SMILES: *c1cccc2c1C(C)(C)c1ccccc1-2] |
| R128 | 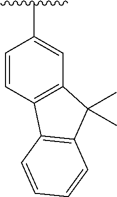 [SMILES: *c1ccc2c(c1)C(C)(C)c1ccccc1-2] |
| R129 | 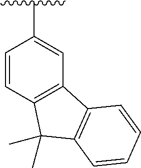 [SMILES: *c1ccc2c(c1)-c1ccccc1C2(C)C] |
| R130 | 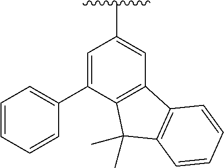 [SMILES: *c1cc(-c2ccccc2)c2c(c1)-c1ccccc1C2(C)C] |
| R131 | 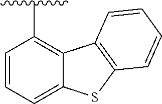 [SMILES: *c1cccc2sc3ccccc3c12] |
| R132 | 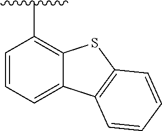 [SMILES: *c1cccc2c1sc1ccccc12] |
| R133 | 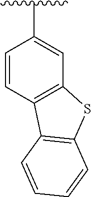 [SMILES: *c1ccc2c(c1)sc1ccccc12] |
| R134 | 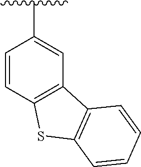 [SMILES: *c1ccc2sc3ccccc3c2c1] |
| R135 | 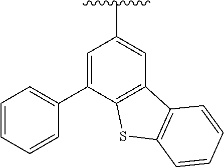 [SMILES: *c1cc(-c2ccccc2)c2sc3ccccc3c2c1] |

16. The compound of claim 1, wherein the compound is selected from the group consisting of:

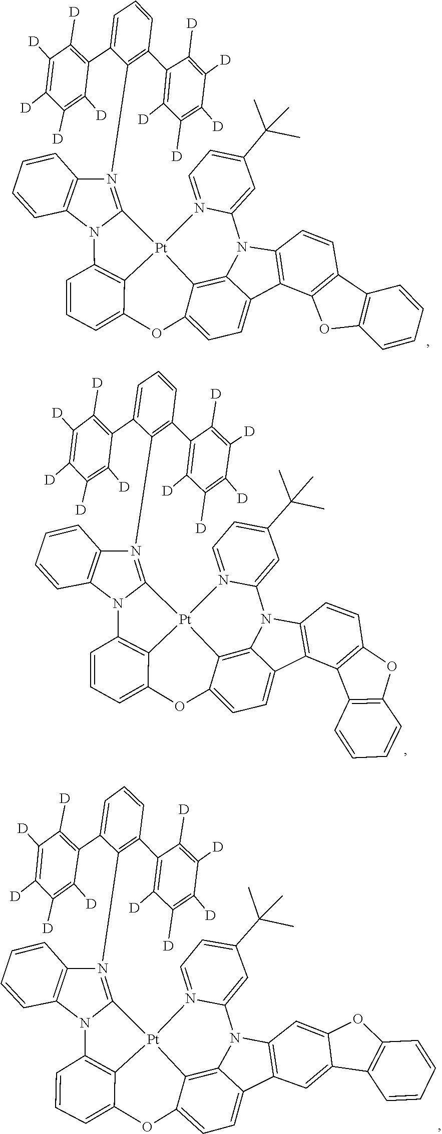

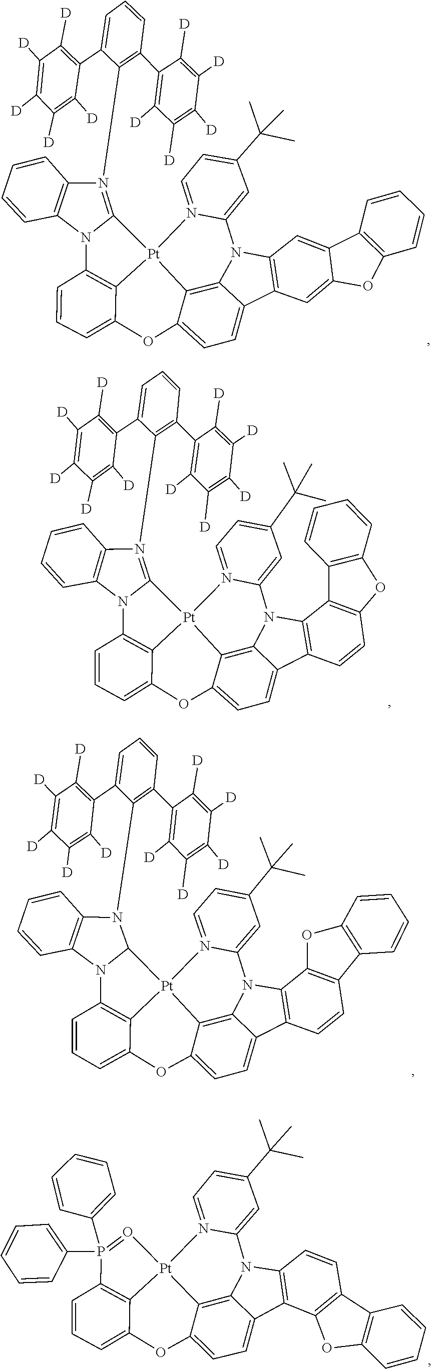

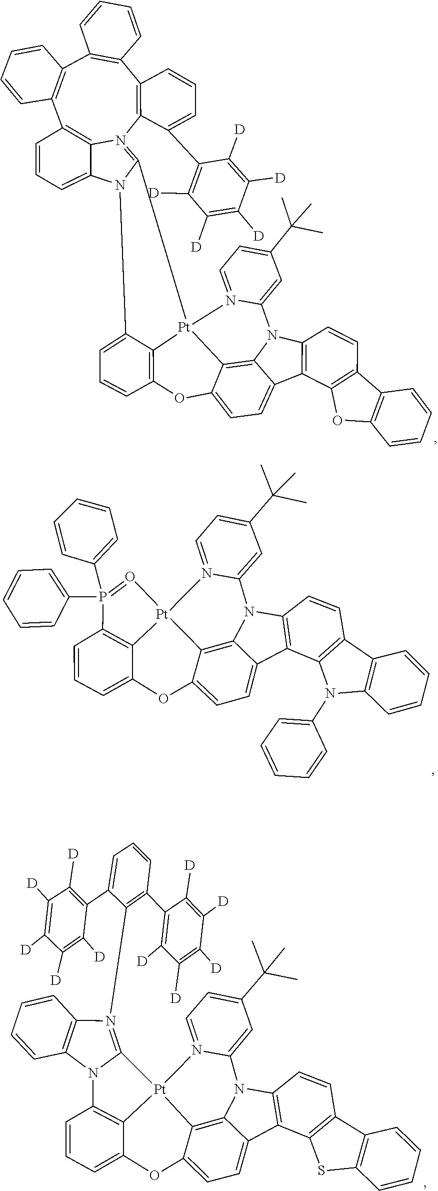

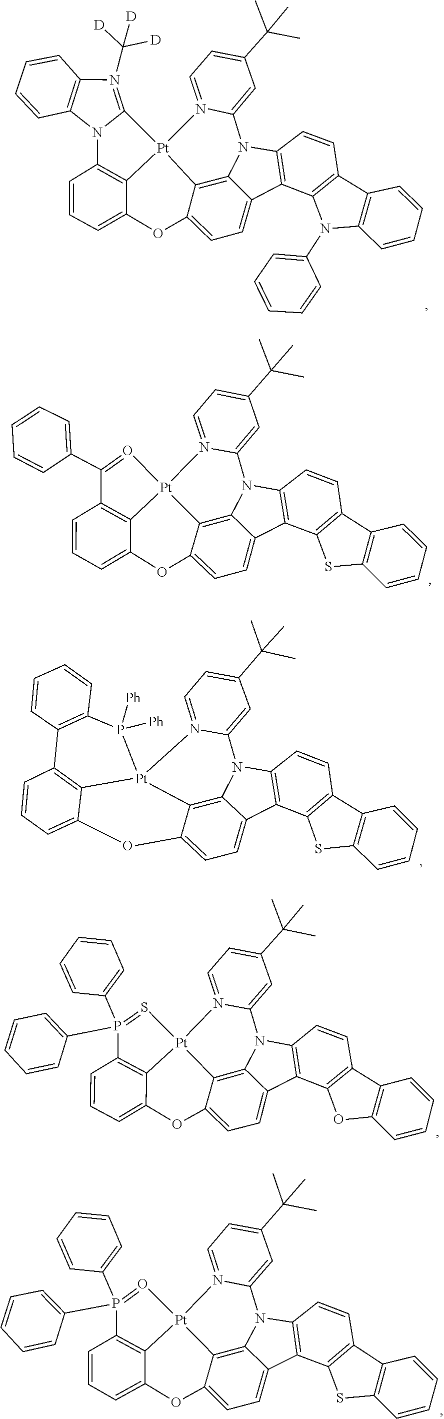

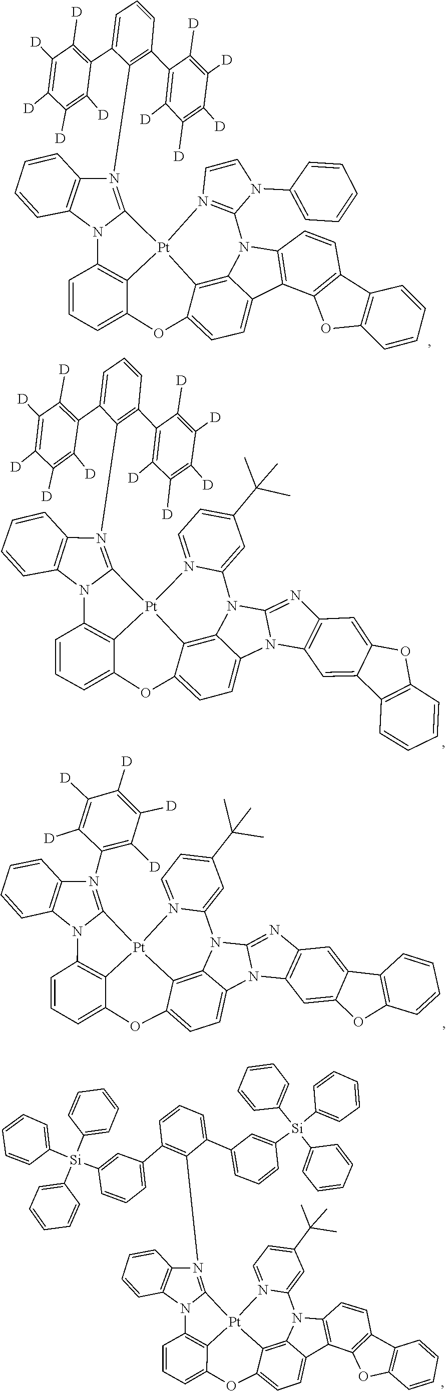

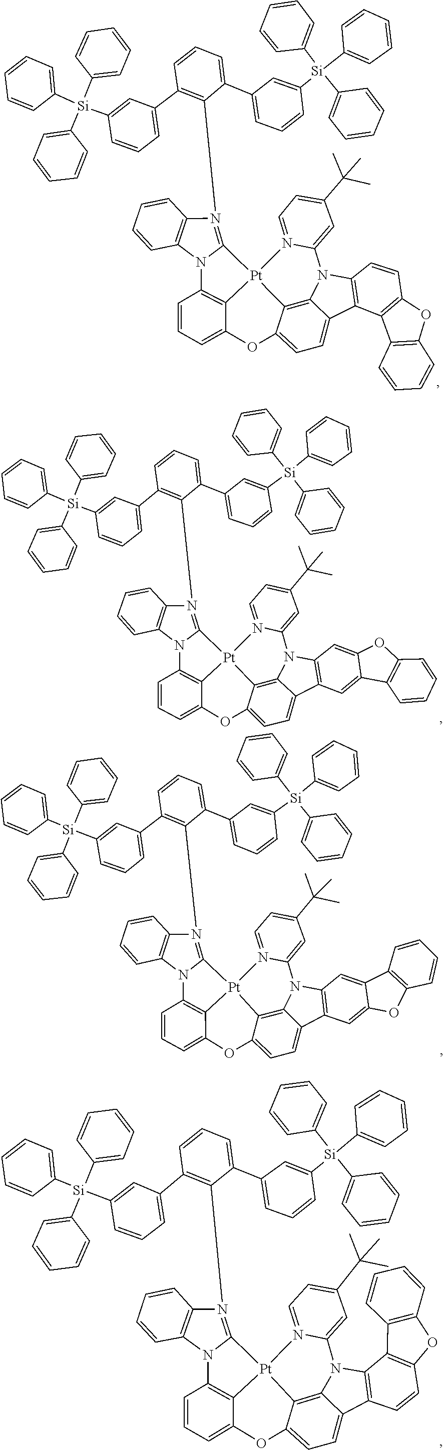

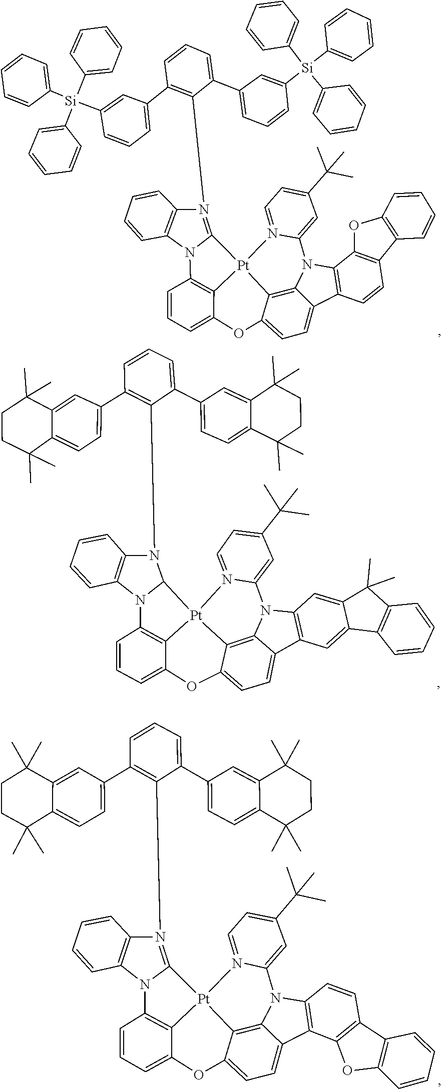

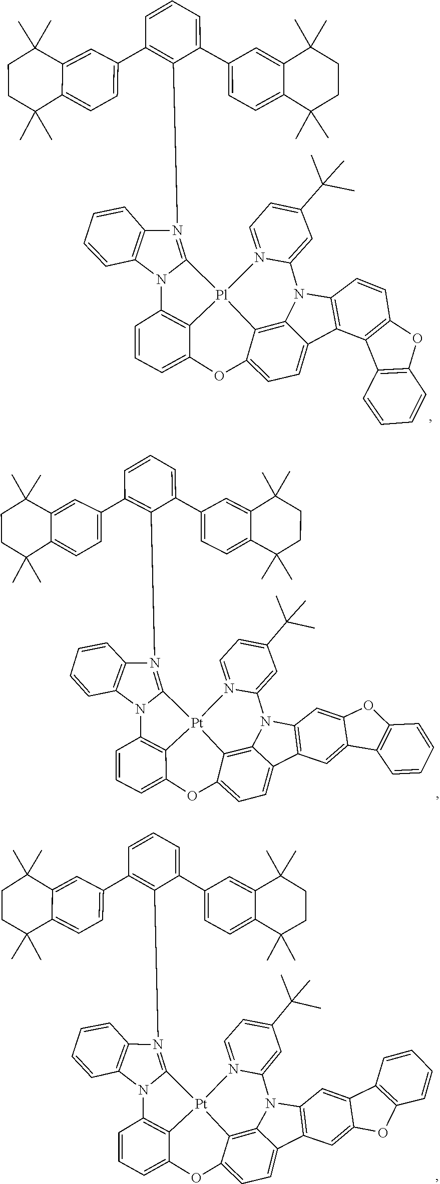

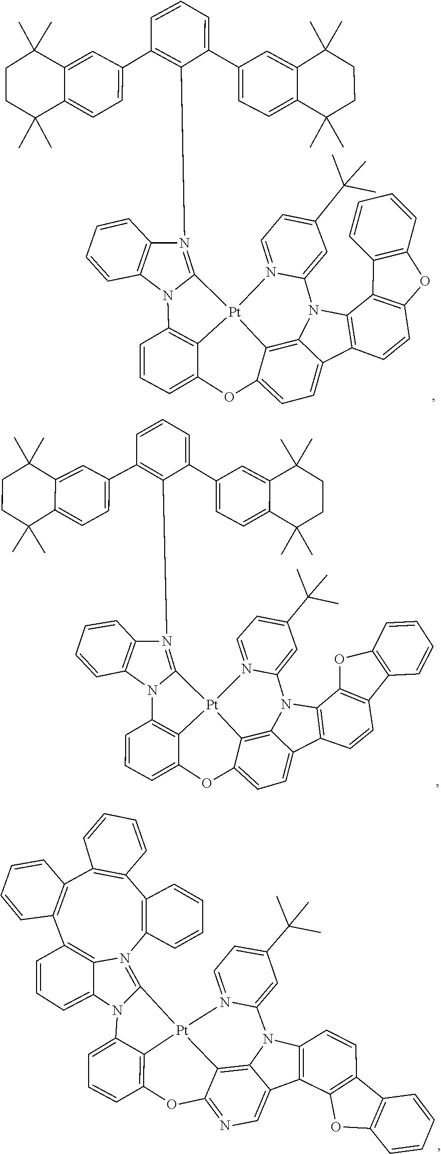

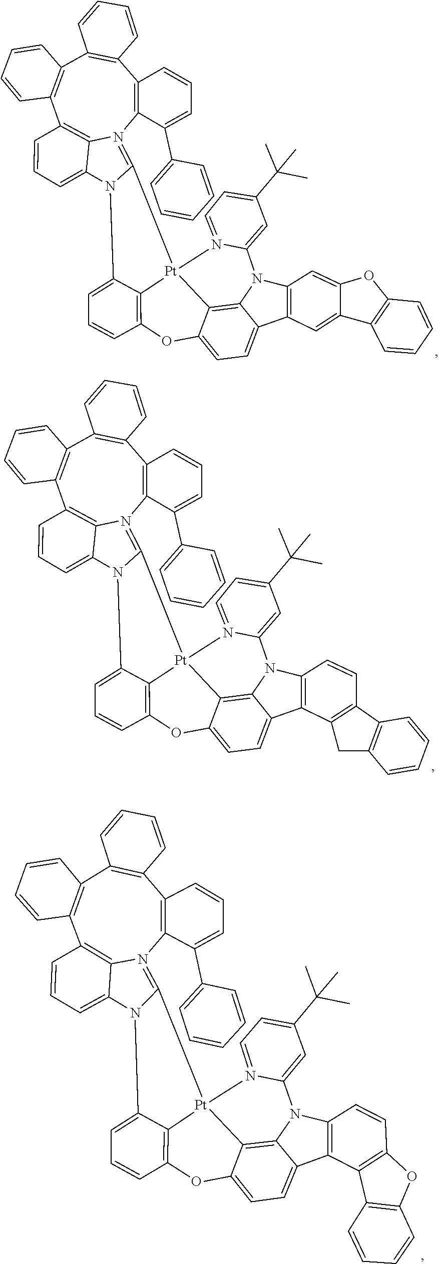

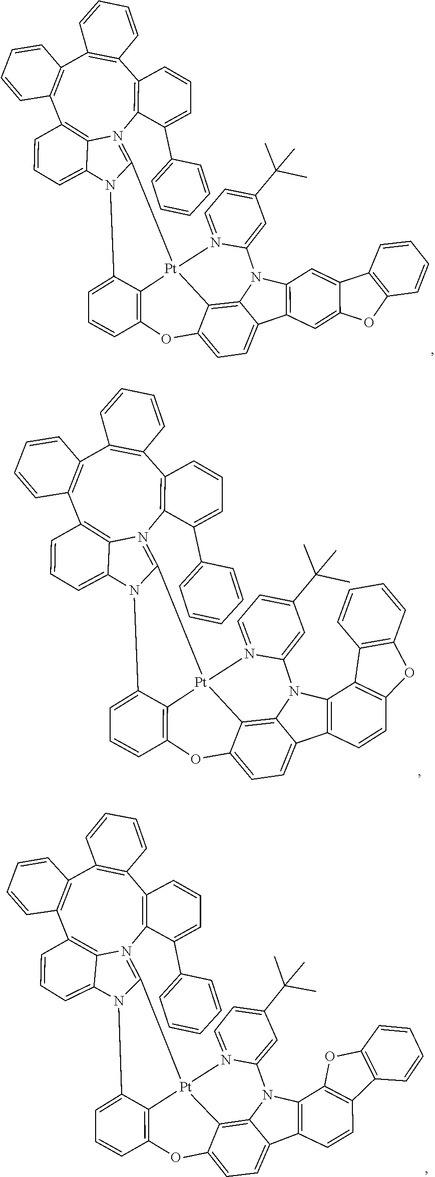

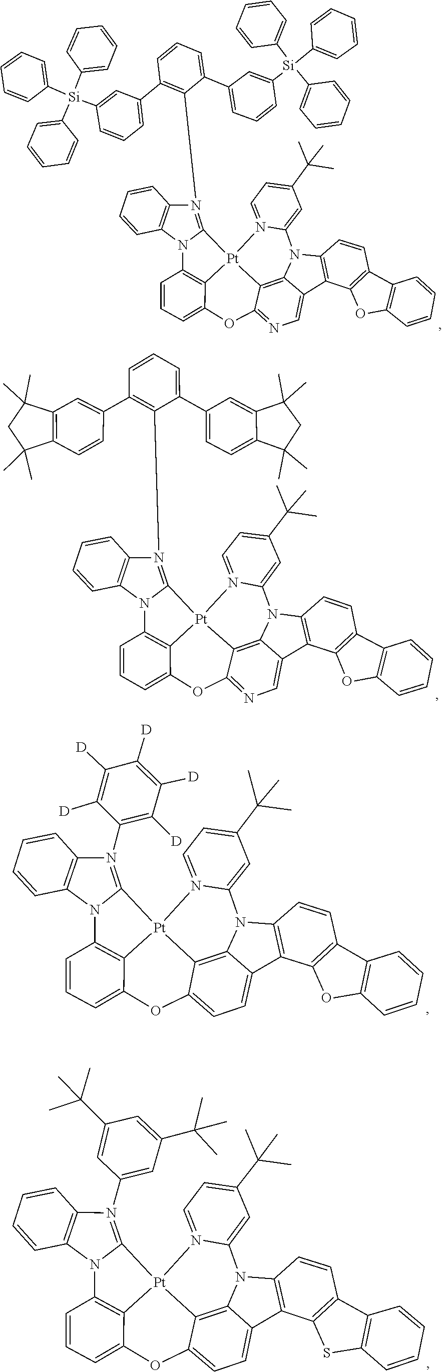

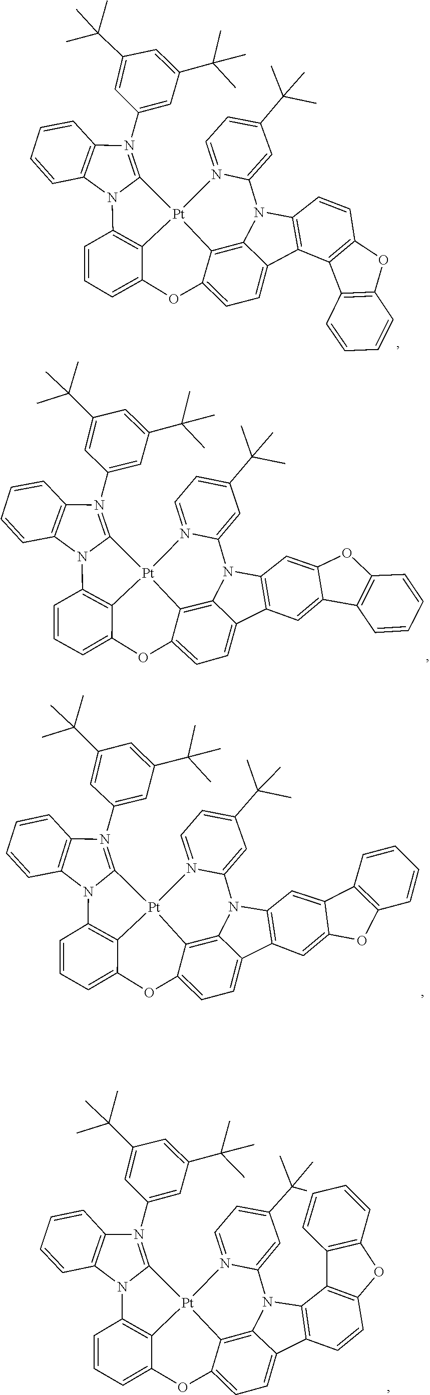

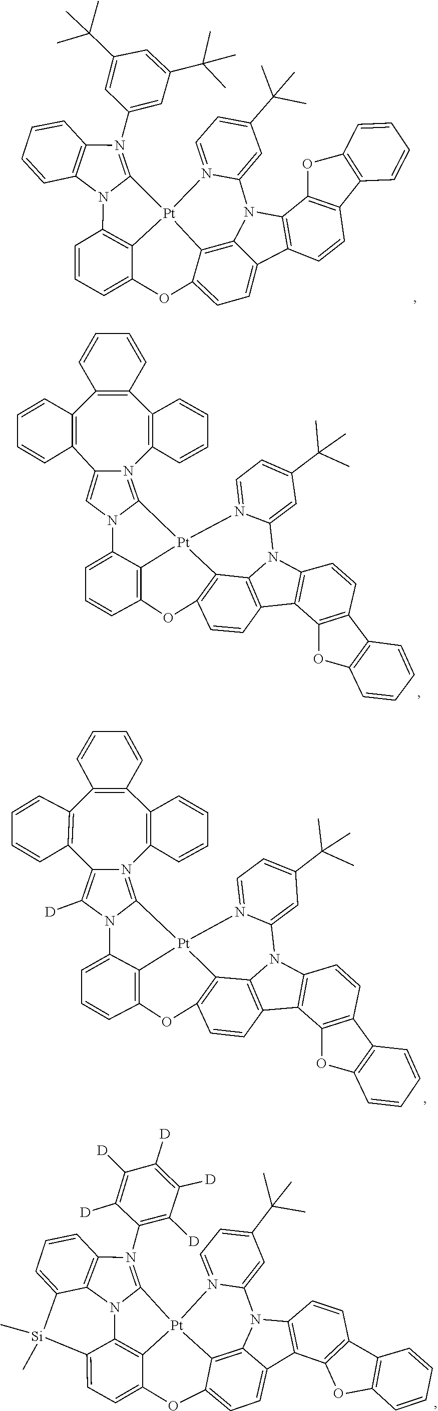

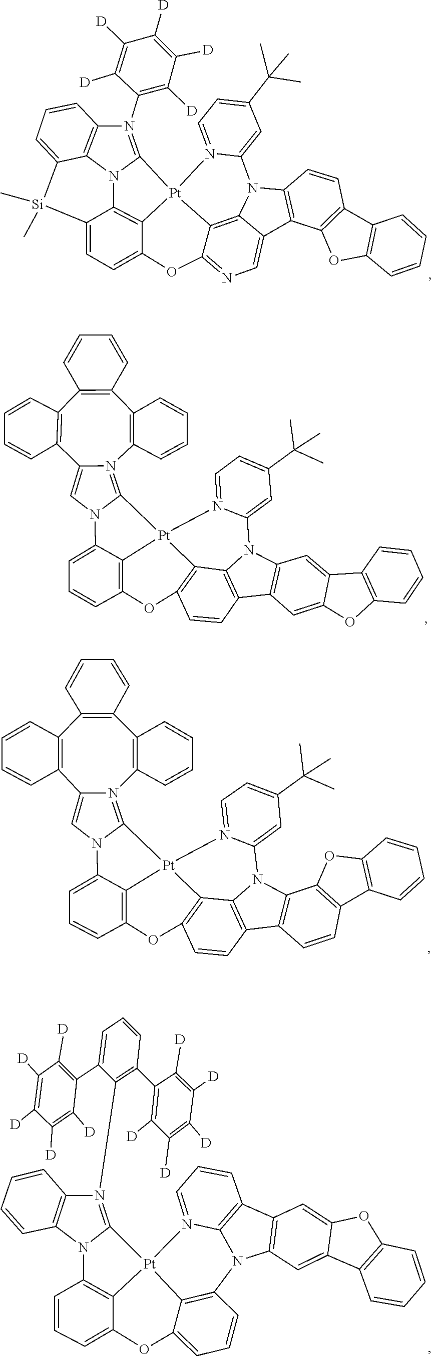

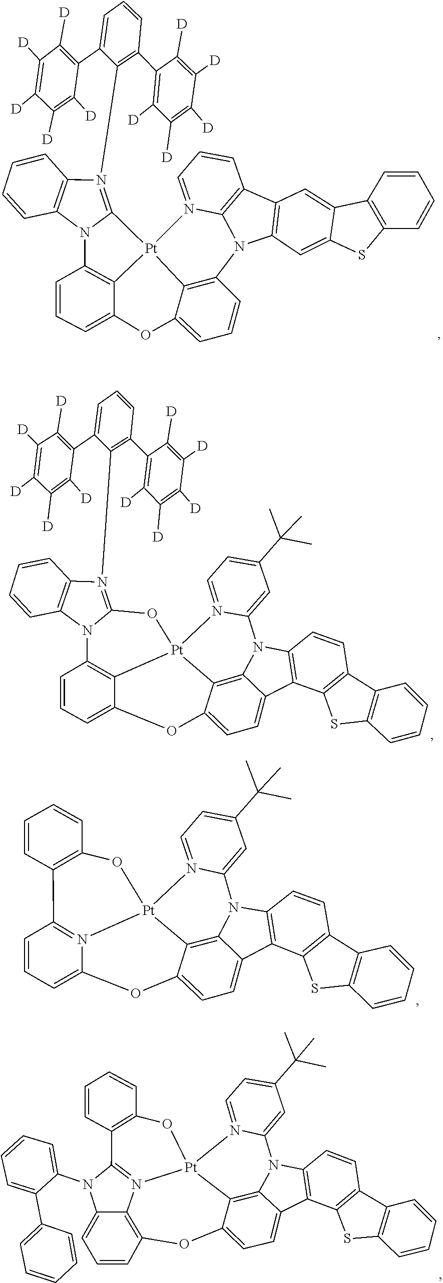

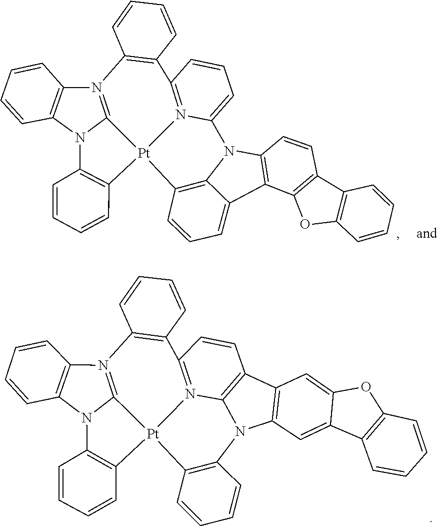

17. An organic light emitting device (OLED) comprising:
an anode;
a cathode; and
an organic layer disposed between the anode and the cathode, wherein the organic layer comprises a compound according to claim 1.

18. The OLED of claim 17, wherein the organic layer further comprises a host, wherein the host comprises at least one chemical moiety selected from the group consisting of triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, triazine, boryl, silyl, aza-triphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene).

19. The OLED of claim 17, wherein the organic layer further comprises a host, wherein the host is selected from the group consisting of: 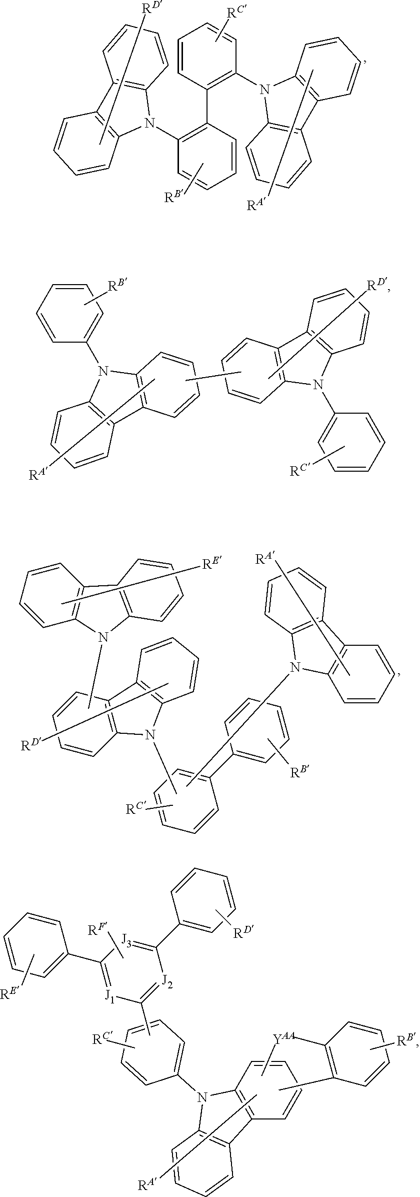 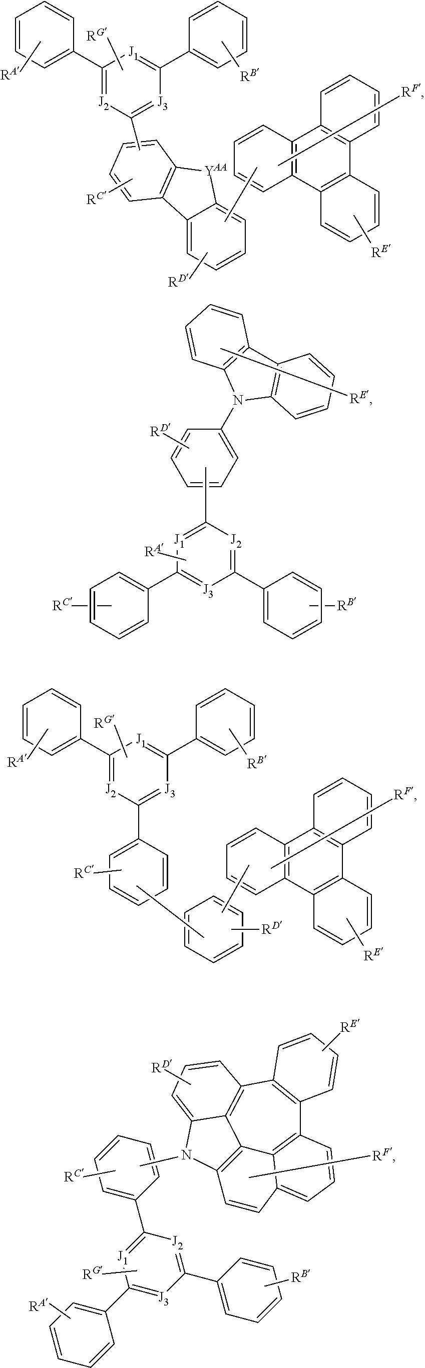 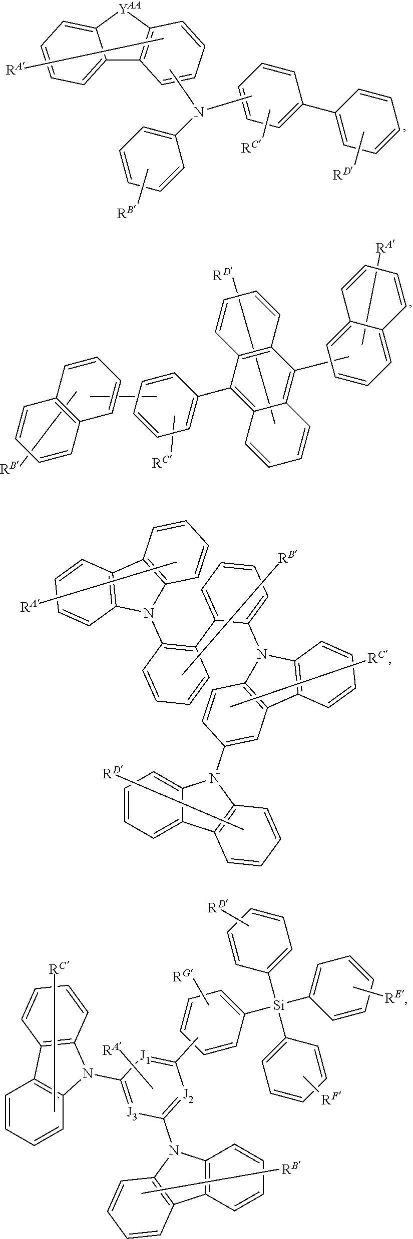 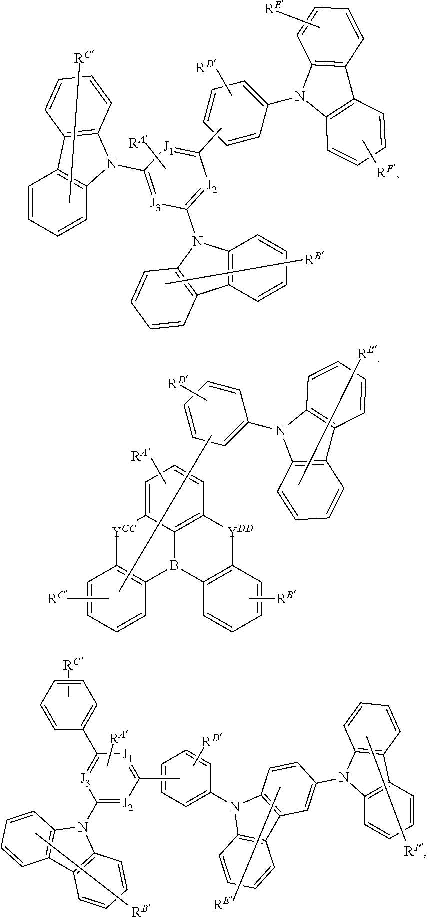 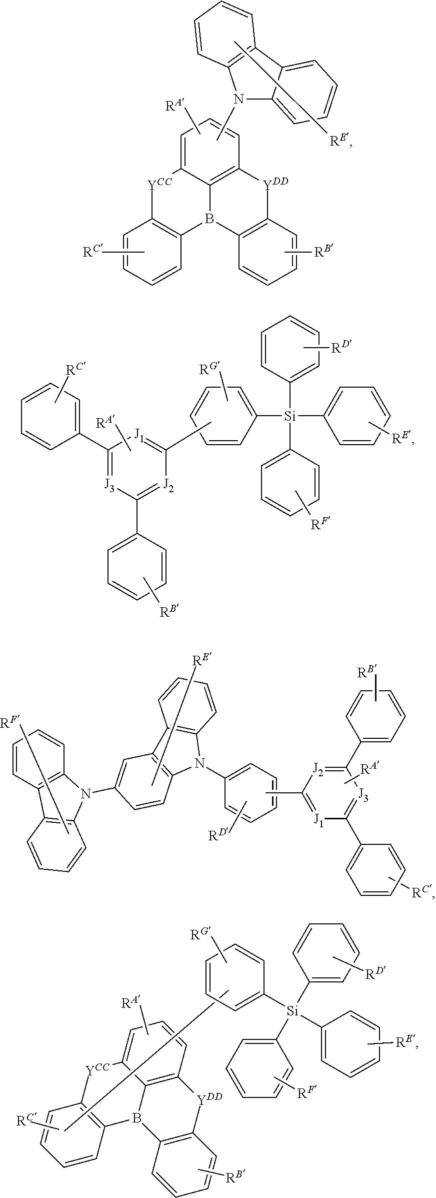 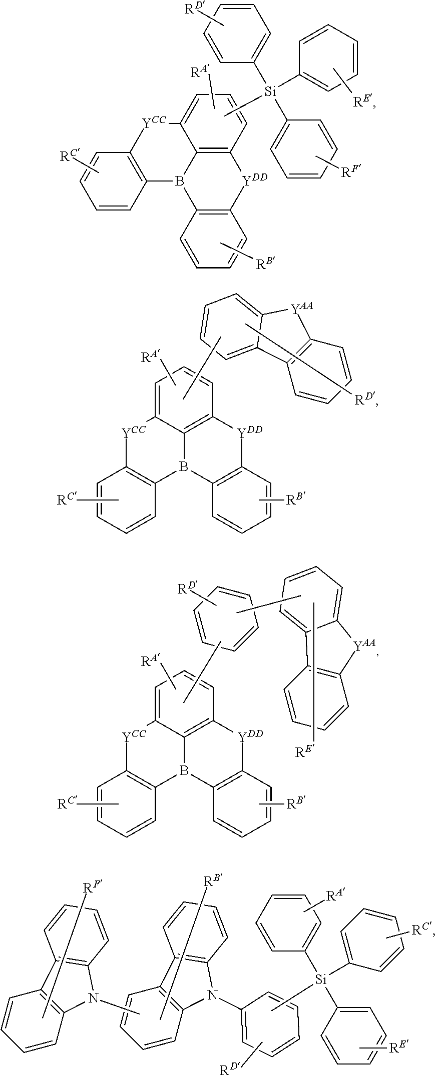 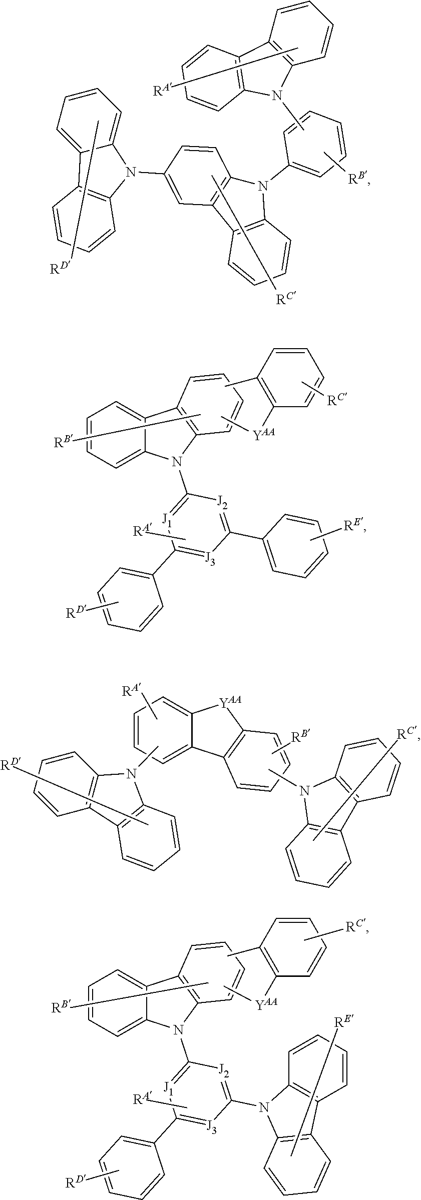 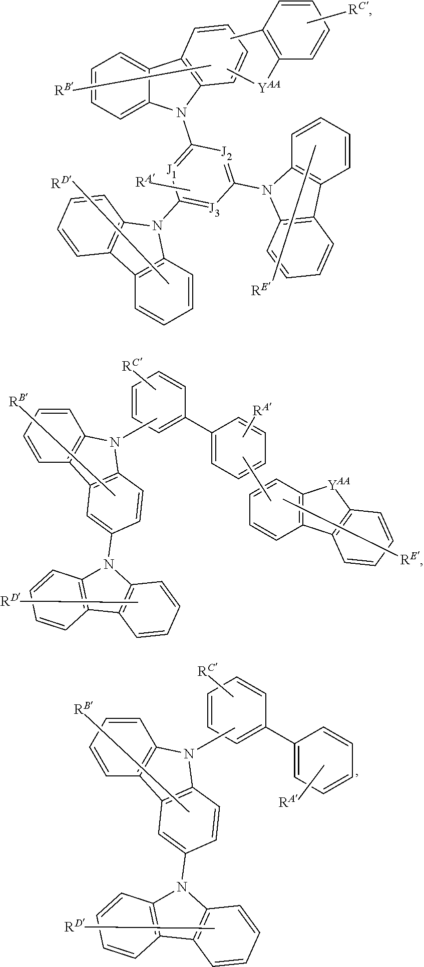 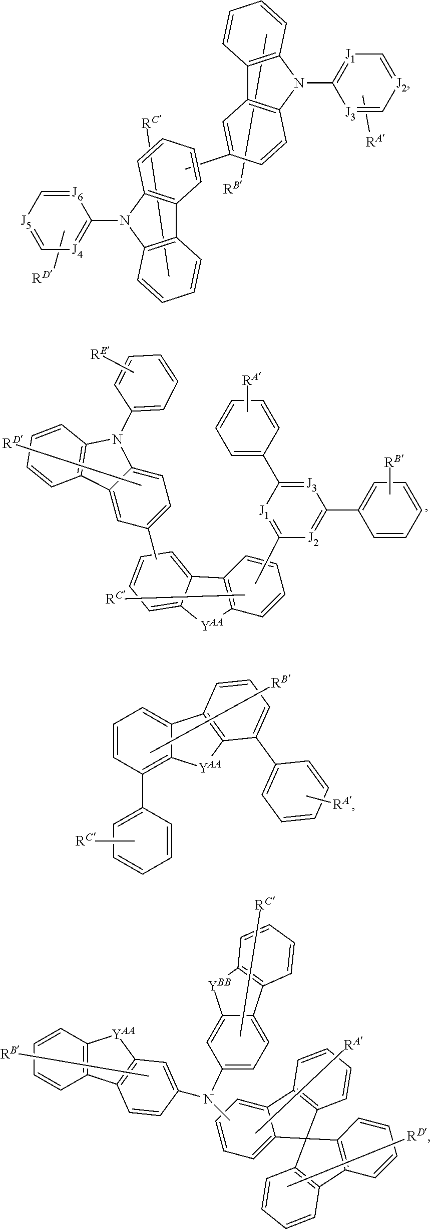 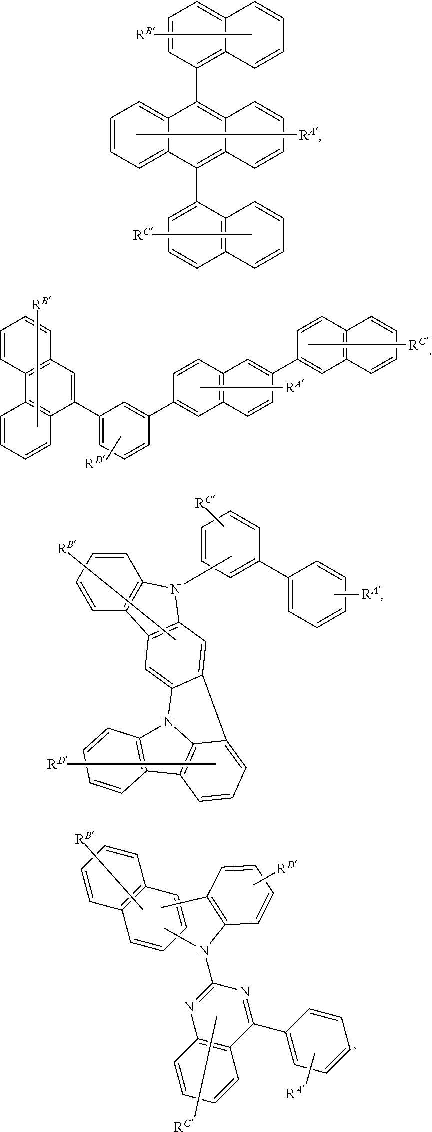 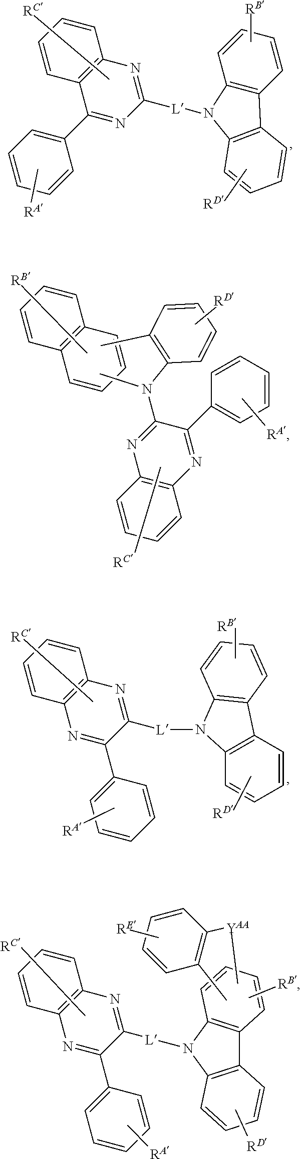 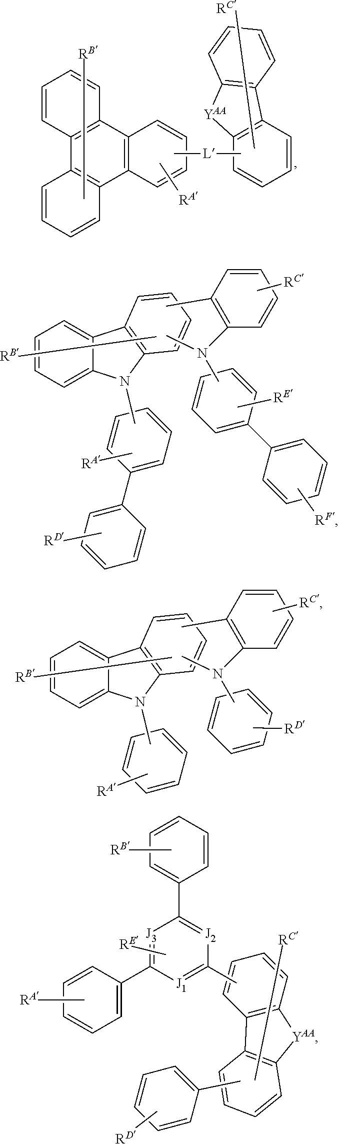 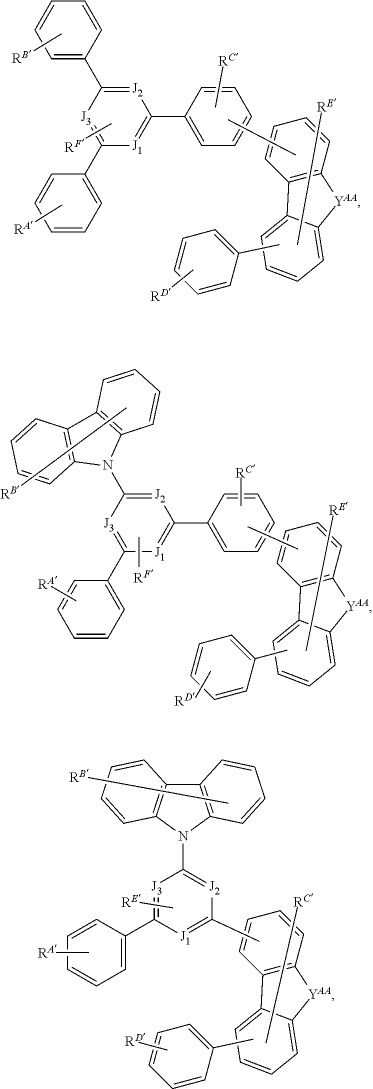 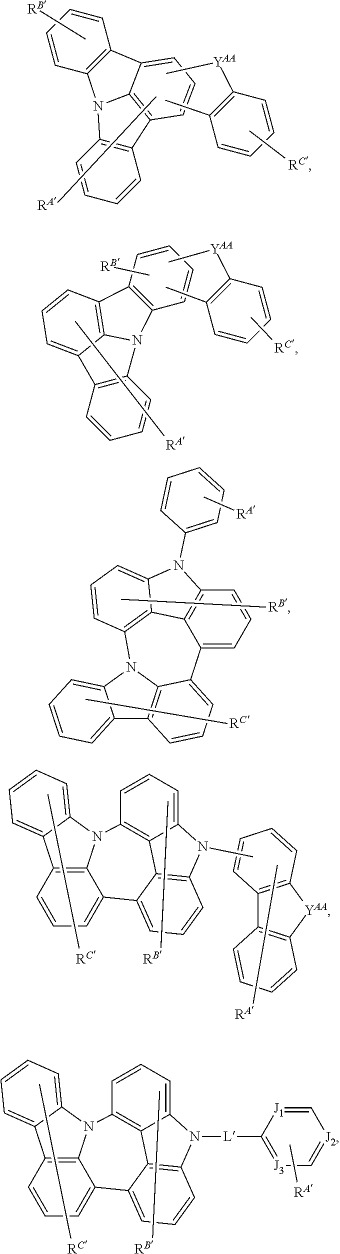 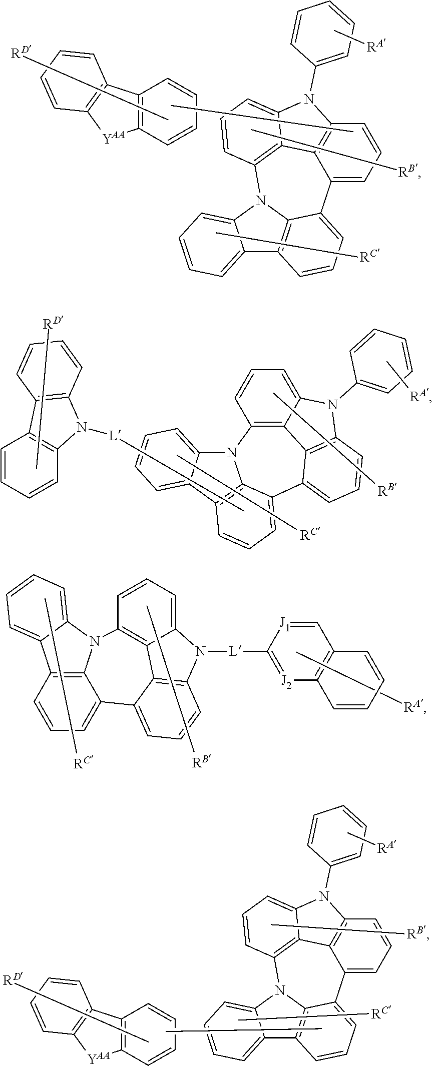 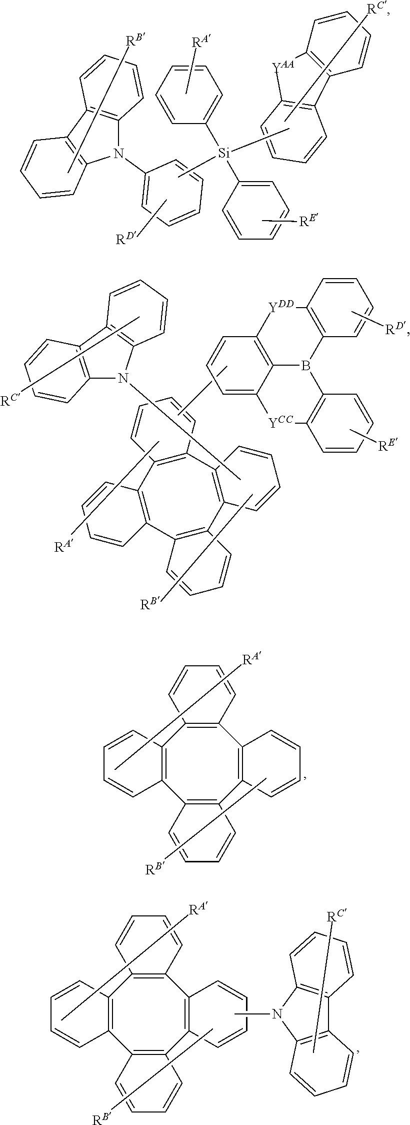 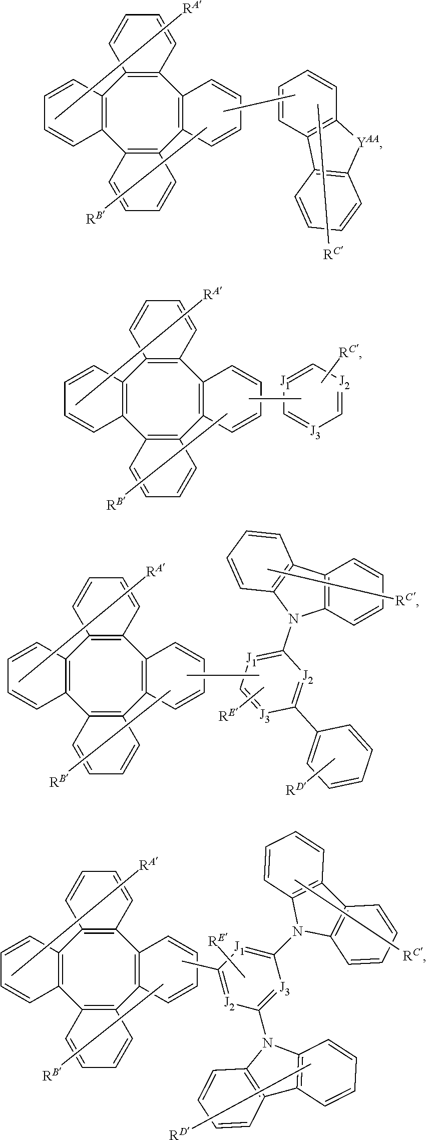 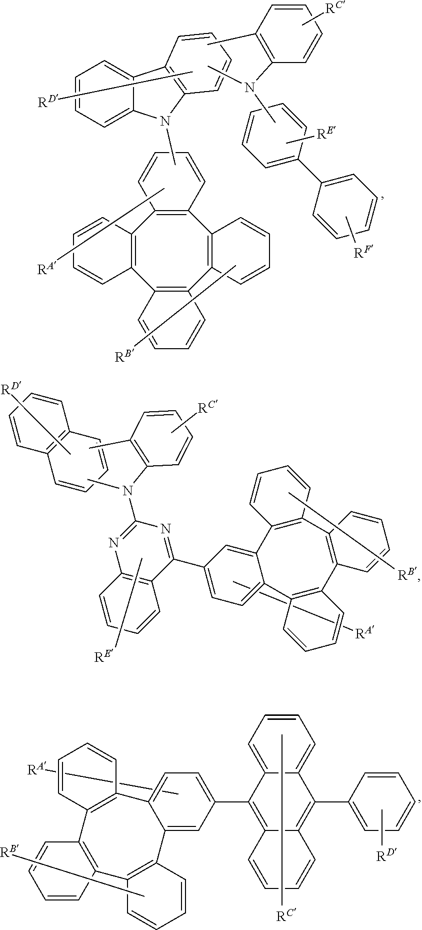 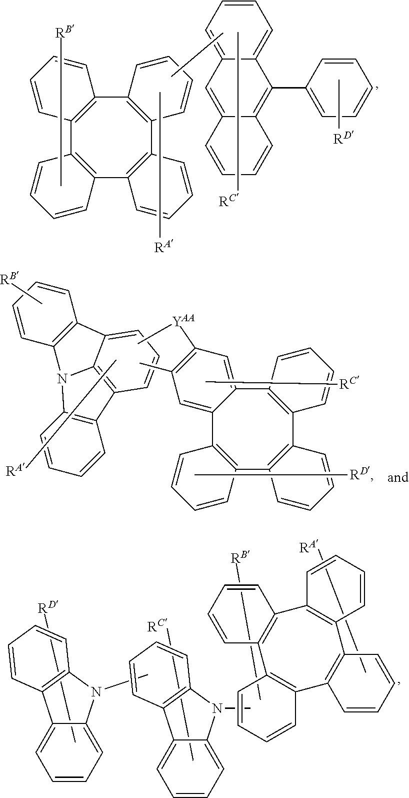
wherein:
each of J₁ to J₆ is independently C or N;
L′ is a direct bond or an organic linker;
each Y^{AA}, Y^{BB}, Y^{CC}, and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and any two substituents can be joined or fused to form a ring;

20. A consumer product comprising an organic light-emitting device (OLED) comprising:
an anode;
a cathode; and
an organic layer disposed between the anode and the cathode, wherein the organic layer comprises a compound according to claim 1.
